(19) United States
(12) Patent Application Publication
(10) Pub. No.: US 2025/0212685 A1
(43) Pub. Date: Jun. 26, 2025

(54) LIGHT-EMITTING DEVICE INCLUDING HETEROCYCLIC COMPOUND, ELECTRONIC APPARATUS INCLUDING THE LIGHT-EMITTING DEVICE, AND THE HETEROCYCLIC COMPOUND

(71) Applicant: Samsung Display Co., Ltd., Yongin-si (KR)

(72) Inventors: Dongjun Kim, Yongin-si (KR); Hankyu Pak, Yongin-si (KR); Hyunbin Park, Yongin-si (KR); Jinyoung Yun, Yongin-si (KR); Sanghyun Han, Yongin-si (KR)

(21) Appl. No.: 18/926,799

(22) Filed: Oct. 25, 2024

(30) Foreign Application Priority Data
Dec. 19, 2023 (KR) 10-2023-0186147

(51) Int. Cl. H10K 85/60; H10K 50/16; H10K 101/20

(52) U.S. Cl. CPC H10K 85/658; H10K 50/16; H10K 85/615; H10K 85/633; H10K 85/654; H10K 85/656; H10K 85/6572; H10K 85/6574; H10K 2101/20

(57) ABSTRACT

A light-emitting device including a heterocyclic compound represented by Formula 1, an electronic apparatus including the light-emitting device, and a heterocyclic compound represented by Formula 1 are provided.

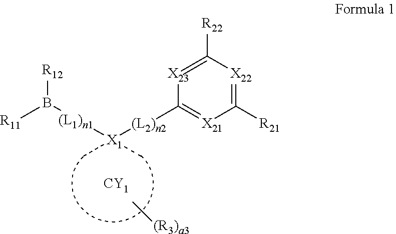

### CROSS-REFERENCE TO RELATED APPLICATION

The present application claims priority to and the benefit of Korean Patent Application No. 10-2023-0186147, filed on Dec. 19, 2023, in the Korean Intellectual Property Office, the entire content of which is incorporated herein by reference.

### BACKGROUND

### 1. Field

One or more embodiments of the present disclosure relate to a light-emitting device including a heterocyclic compound, an electronic apparatus including the light-emitting device, and the heterocyclic compound.

### 2. Description of the Related Art

Among light-emitting devices, self-emissive devices (e.g., organic light emitting devices) have relatively wide viewing angles, high contrast ratios, short response times, and excellent or suitable characteristics in terms of luminance, driving voltage, and response speed.

For example, a light-emitting device may have a structure in which a first electrode is arranged on a substrate, and a hole transport region, an emission layer, an electron transport region, and a second electrode are sequentially arranged on the first electrode in the stated order. Holes provided from the first electrode move toward the emission layer through the hole transport region, and electrons provided from the second electrode move toward the emission layer through the electron transport region. Carriers, such as the holes and the electrons, combine in the emission layer to produce excitons. The excitons transition and decay from an excited state to a ground state, thereby generating light (e.g., to display an image).

### SUMMARY

One or more aspects of embodiments of the present disclosure are directed toward a light-emitting device including a heterocyclic compound, an electronic apparatus including the light-emitting device, and the heterocyclic compound.

Additional aspects will be set forth in part in the description which follows and, in part, will be apparent from the description, or may be learned by practice of the presented embodiments of the disclosure.

According to one or more embodiments of the present disclosure, a light-emitting device includes:
a first electrode;
a second electrode facing the first electrode; and
an interlayer between the first electrode and the second electrode and including an emission layer,
wherein the first electrode is an anode, and the second electrode is a cathode,
the interlayer further includes a hole transport region between the first electrode and the emission layer and an electron transport region between the emission layer and the second electrode, and
the electron transport region includes a heterocyclic compound represented by Formula 1.

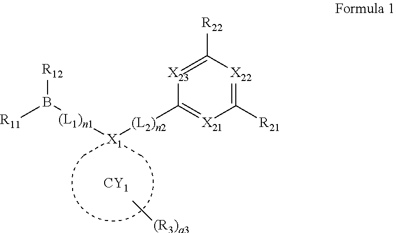

In Formula 1,
X₁ may be carbon (C), and X₁ may be bonded to another carbon or nitrogen atom in one of four direction of X₁ (e.g., in any one selected from among the four directions of X₁),
ring CY₁ may be a C₃-C₂₀ cycloalkyl group,
X₂₁ may be C(Y₂₁) or N, X₂₂ may be C(Y₂₂) or N, X₂₃ may be C(Y₂₃) or N, and the number of N(s) among X₂₁ to X₂₃ may be one or more,
R₁₁, R₁₂, R₂₁, R₂₂, R₃, and Y₂₁ to Y₂₃ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a3 may be an integer from 1 to 20,
L₁ and L₂ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
n1 and n2 may each independently be an integer from 1 to 5,
R₁₁ and L₁ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and L₁ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₁ and R₁₂ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
two or more neighboring groups of R₂₁, R₂₂, and Y₂₁ to Y₂₃ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ may be:
deuterium, —F, —Cl, —Br, —I, a hydroxyl group, a cyano group, or a nitro group:
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; or a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

According to one or more embodiments of the present disclosure, an electronic apparatus includes the light-emitting device.

According to one or more embodiments of the present disclosure, electronic equipment includes the light-emitting device.

According to one more embodiments of the present disclosure, there is provided the heterocyclic compound represented by Formula 1.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a schematic view of a structure of a light-emitting device according to one or more embodiments of the present disclosure;

FIG. 2 is a schematic view of a structure of a light-emitting apparatus according to one or more embodiments of the present disclosure;

FIG. 3 is a schematic view of a structure of a light-emitting apparatus according to one or more embodiments of the present disclosure; and

FIGS. 4, 5, 6A, 6B, and 6C are each a schematic view of a structure of electronic equipment according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout the present disclosure, and duplicative descriptions thereof may not be provided for conciseness. In this regard, the embodiments of the present disclosure may have different forms and should not be construed as being limited to the descriptions set forth herein. Accordingly, one or more embodiments are merely described in more detail, by referring to the drawings, to explain aspects of the present disclosure. As utilized herein, the term “and/or” or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicates only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

According to one or more embodiments of the present disclosure, a light-emitting device includes:
a first electrode;
a second electrode facing the first electrode;
an interlayer between the first electrode and the second electrode and including an emission layer; and
a heterocyclic compound represented by Formula 1.

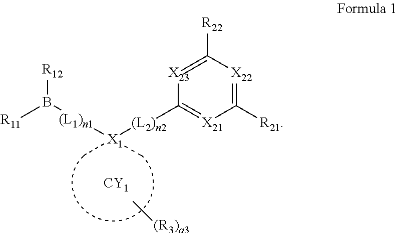

Formula 1 is the same as described in the present disclosure.

In one or more embodiments, the heterocyclic compound represented by Formula 1 may be included in the interlayer.

In one or more embodiments,
the first electrode may be an anode, and the second electrode may be a cathode, and
the interlayer may further include a hole transport region between the first electrode and the emission layer and an electron transport region between the emission layer and the second electrode.

In one or more embodiments, the electron transport region may include the heterocyclic compound represented by Formula 1.

In one or more embodiments,
the hole transport region may include a hole injection layer, a hole transport layer, an emission auxiliary layer, an electron blocking layer, or any combination thereof, and
the electron transport region may include a hole blocking layer, an electron transport layer, an electron injection layer, or any combination thereof.

In one or more embodiments, the electron transport layer may include the heterocyclic compound represented by Formula 1.

In one or more embodiments, the emission layer may include a host and a dopant.

In one or more embodiments, the emission layer may include a first compound that is a transition metal-containing compound, a second compound including at least one π electron-deficient nitrogen-containing C₁-C₆₀ heterocyclic group, a third compound including a group represented by Formula 3, a fourth compound capable of emitting delayed fluorescence, or any combination thereof, and
the first compound, the second compound, the third compound, and the fourth compound may be different from each other.

In one or more embodiments, the emission layer may include a host and a dopant,
the host may include the second compound, the third compound, or any combination thereof, and
the dopant may include the first compound, the fourth compound, or any combination thereof.

In one or more embodiments, the second compound and the third compound may form an exciplex.

In one or more embodiments, the emission layer may further include a luminescent material.

In one or more embodiments, the luminescent material may include the first compound, the fourth compound, or any combination thereof. In the luminescent material, the first compound, and the fourth compound may be different from each other.

In one or more embodiments, the emission layer may include a dopant and a host, the dopant may include the first compound, the first compound may include a transition metal and m ligands, m is an integer from 1 to 6, the m ligands may be substantially identical to or different from each other, the transition metal and at least one of the m ligands may be linked to each other via a carbon-transition metal bond, and the carbon-transition metal bond may be a coordinate bond. For example, at least one ligand of the m ligands may be a carbene ligand (for example, Ir(pmp)₃). The transition metal may be, for example, iridium, platinum, osmium, palladium, rhodium, gold, or the like. In one or more embodiments, the dopant may be to emit blue light.

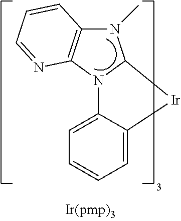

In one or more embodiments, the first compound may include platinum (Pt).

In one or more embodiments, the first compound may include platinum (Pt) and a tetradentate ligand bonded to the platinum, and the platinum and one of carbon atoms of the tetradentate ligand may be bonded together via a coordinate bond.

In one or more embodiments, the first compound may be a carbene-containing compound.

In one or more embodiments, the first compound may be a compound represented by Formula 4.

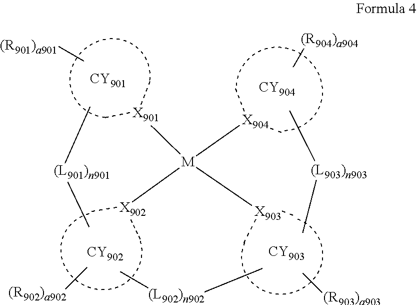

Formula 4 is the same as described in the present disclosure.

In one or more embodiments, the second compound may include a pyridine group, a pyrimidine group, a pyrazine group, a pyridazine group, a triazine group, or any combination thereof.

In one or more embodiments, the second compound may include a compound represented by Formula 2:

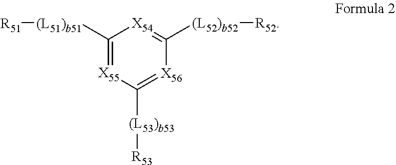

wherein, in Formula 2,
L₅₁ to L₅₃ may each independently be a single bond, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
b51 to b53 may each independently be an integer from 1 to 5,
X₅₄ may be N or C(R₅₄), X₅₅ may be N or C(R₅₅), X₅₆ may be N or C(R₅₆), and at least one of X₅₄ to X₅₆ may be N, and
R₅₁ to R₅₆ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

R₁₀ₐ and Q₁ to Q₃ are each the same as described in the present disclosure.

In one or more embodiments, the third compound may include a group represented by Formula 3:

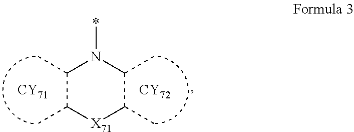

wherein, in Formula 3,
ring CY₇₁ and ring CY₇₂ may each independently be a π electron-rich C₃-C₆₀ cyclic group or a pyridine group,
X₇₁ may be a single bond, or a linking group including O, S, N, B, C, Si, or any combination thereof, and
* indicates a binding site to any atom included in the remaining part other than the group represented by Formula 3 in the third compound.

For example, in one or more embodiments, the third compound may not include (e.g., may exclude) a compound represented by Formula 3-1.

For example, in one or more embodiments, the following compounds may be excluded from the third compound.

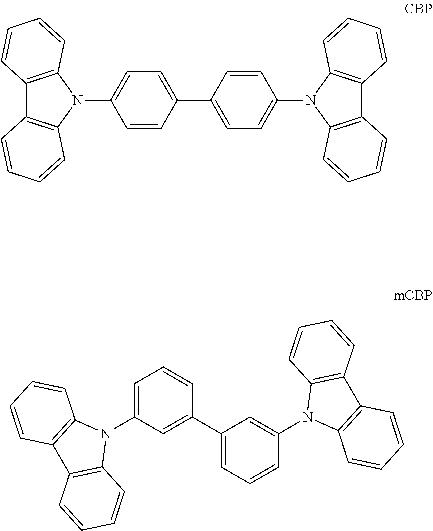 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1]

In one or more embodiments, the third compound may include a compound represented by Formula 3-1, a compound represented by Formula 3-2, a compound represented by Formula 3-3, a compound represented by Formula 3-4, a compound represented by Formula 3-5, or any combination thereof:

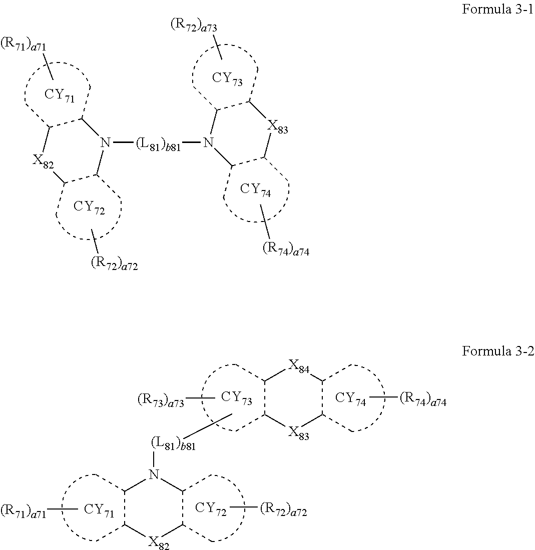

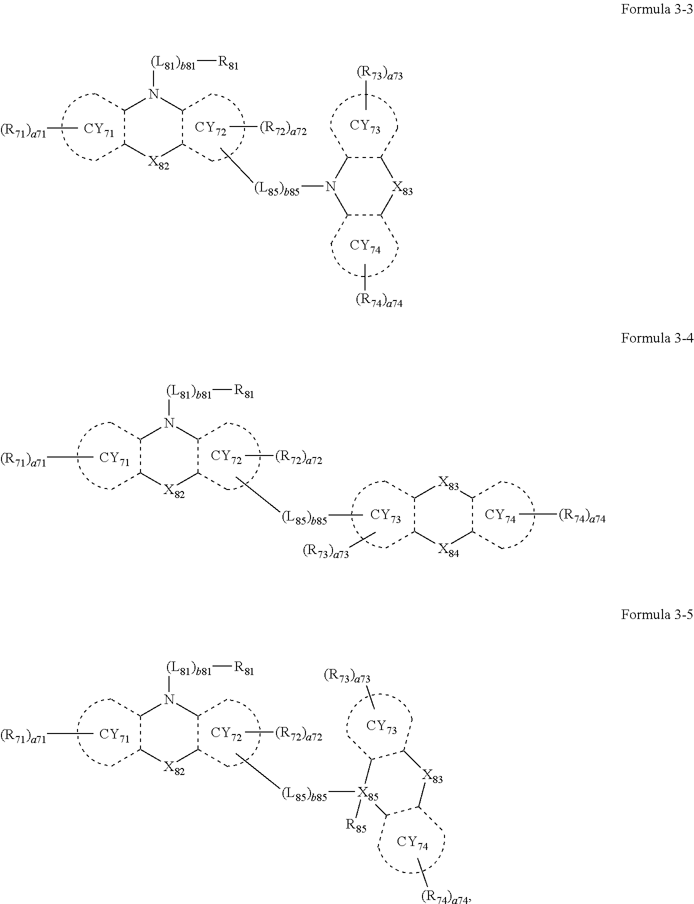

wherein, in Formulae 3-1 to 3-5,
ring CY₇₁ to ring CY₇₄ may each independently be a π electron-rich C₃-C₆₀ cyclic group or a pyridine group,
X₈₂ may be a single bond, O, S, N[(L₈₂)_{b82}-R₈₂], B(R₈₂), C(R₈₂ₐ)(R_{82b}), or Si(R₈₂ₐ)(R_{82b}),
X₈₃ may be a single bond, O, S, N[(L₈₃)_{b83}-R₈₃], B(R₈₃), C(R₈₃ₐ)(R_{83b}), or Si(R₈₃ₐ)(R_{83b}),
X₈₄ may be O, S, N[(L₈₄)_{b84}-R₈₄], B(R₈₄), C(R₈₄ₐ)(R_{84b}), or Si(R₈₄ₐ)(R_{84b}),
X₈₅ may be C or Si,
L₈₁ to L₈₅ may each independently be a single bond, *—C(Q₄)(Q₅)-*′, *—Si(Q₄)(Q₅)-*′, a π electron-rich C₃-C₆₀ cyclic group that is unsubstituted or substituted with at least one R₁₀ₐ, or a pyridine group that is unsubstituted or substituted with at least one R₁₀ₐ, wherein Q₄ and Q₅ are each the same as described with respect to Q₁,
b81 to b85 may each independently be an integer from 1 to 5,
R₇₁ to R₇₄, R₈₁ to R₈₅, R₈₂ₐ, R_{82b}, R₈₃ₐ, R_{83b}, R₈₄ₐ, and R_{84b} may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a71 to a74 may each independently be an integer from 0 to 20, and
R₁₀ₐ and Q₁ to Q₃ are each the same as described in the present specification.

In one or more embodiments, the fourth compound may be a compound including at least one cyclic group including B (boron) and N (nitrogen) as a ring-forming atoms. The fourth compound may improve color purity, luminescence efficiency, and lifespan characteristics of the light-emitting device.

In one or more embodiments, a difference between a triplet energy level (eV) of the fourth compound and a singlet energy level (eV) of the fourth compound is at least about 0 eV and at most (e.g., not more than) about 0.5 eV (or at least about 0 eV and at most (e.g., not more than) about 0.3 eV).

In one or more embodiments, the fourth compound may be a C₈-C₆₀ polycyclic group-containing compound including at least two cyclic groups that are condensed with each other while sharing boron (B) (e.g., one being a first ring and the other being a second ring).

In one or more embodiments, the fourth compound may include a condensed ring in which at least one third ring is condensed with at least one fourth ring, for example, to form the condensed ring including four or more rings,
the at least one third ring of the fourth compound may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and
the at least one fourth ring of the fourth compound may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or 1,4-dihydroborinine group.

In one or more embodiments, the fourth compound may include a compound represented by Formula 502, a compound represented by Formula 503, or any combination thereof:

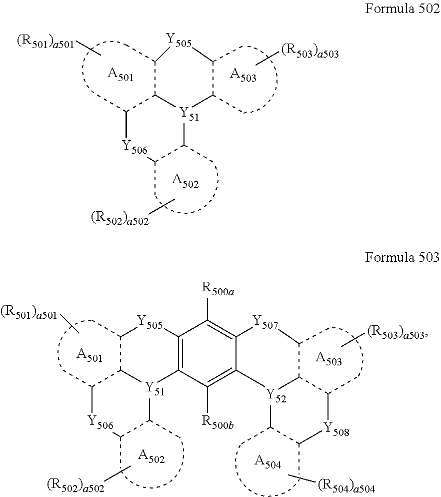

wherein, in Formulae 502 and 503,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{508b}),
Y₅₁ and Y₅₂ may each independently be B, P(═O), or S(═O),
R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each be as the same described in the present disclosure, and
a501 to a504 may each independently be an integer from 0 to 20.
R₁₀ₐ and Q₁ to Q₃ are each as described in the present specification.

In one or more embodiments, the light-emitting device may satisfy at least one selected from among Conditions 1 to 4.

### Condition 1

lowest unoccupied molecular orbital (LUMO) energy level (eV) of third compound>LUMO energy level (eV) of the first compound

### Condition 2

LUMO energy level (eV) of first compound>LUMO energy level (eV) of second compound

### Condition 3

highest occupied molecular orbital (HOMO) energy level (eV) of first compound>HOMO energy level of third compound

### Condition 4

HOMO energy level (eV) of third compound>HOMO energy level (eV) of second compound

In the present disclosure, each of the HOMO energy level and LUMO energy level of each of the first compound, the second compound, and the third compound may be a negative value, and may be measured according to a suitable method.

In one or more embodiments, an absolute value of a difference between the LUMO energy level of the first compound and the LUMO energy level of the second compound may be about 0.1 eV or higher and about 1.0 eV or lower or an absolute value of a difference between the LUMO energy level of the first compound and the LUMO energy level of the third compound may be about 0.1 eV or higher and about 1.0 eV or lower, and an absolute value of a difference between the HOMO energy level of the first compound and the HOMO energy level of the second compound may be 1.25 eV or lower (for example, about 1.25 eV or lower and about 0.2 eV or higher) or an absolute value of a difference between the HOMO energy level of the first compound and the HOMO energy level of the third compound may be 1.25 eV or lower (for example, about 1.25 eV or lower and about 0.2 eV or higher).

When the relationships between LUMO energy level and HOMO energy level satisfy the conditions as described above, a balance between holes and electrons injected into the emission layer may be achieved.

Detailed descriptions of the heterocyclic compound represented by Formula 1, the first compound, the second compound, the third compound, and the fourth compound are provided in the present disclosure.

In one or more embodiments, the electron transport region of the light-emitting device may include a hole blocking layer, and the hole blocking layer may include a phosphine oxide-containing compound, a silicon-containing compound, or any combination thereof. In one or more embodiments, the hole blocking layer may directly contact the emission layer.

In one or more embodiments, the light-emitting device may include a capping layer outside (e.g., on) the first electrode and/or a capping layer outside (e.g., on) the second electrode.

For example, in one or more embodiments, the light-emitting device may further include at least one of a first capping layer arranged on one surface of the first electrode or a second capping layer arranged on one surface of the second electrode, wherein at least one of the first capping layer or the second capping layer may include the heterocyclic compound represented by Formula 1. The first capping layer and/or the second capping layer may each independently be the same as described herein.

In one or more embodiments, the light-emitting device may include:
a first capping layer arranged on one surface of the first electrode and including the heterocyclic compound represented by Formula 1;
a second capping layer arranged on one surface of the second electrode and including the heterocyclic compound represented by Formula 1; or
the first capping layer and the second capping layer.

The expression “(interlayer and/or a capping layer) includes a heterocyclic compound” as utilized herein may be to refer to that the (interlayer and/or the capping layer) may include one kind of heterocyclic compound represented by Formula 1 or two or more different kinds of heterocyclic compounds, each represented by Formula 1.

For example, in one or more embodiments, the interlayer and/or the capping layer may include Compound 1 only as the heterocyclic compound. In this regard, Compound 1 may be included in the electron transport region of the light-emitting device. In one or more embodiments, the interlayer may include, as the heterocyclic compound, Compound 1 and Compound 2. In this regard, Compound 1 and Compound 2 may be included in an substantially identical layer (for example, both (e.g., simultaneously) Compound 1 and Compound 2 may be included in the electron transport region), or may be included in different layers (for example, Compound 1 may be included in the electron transport region and Compound 2 may be included in the hole transport region).

The term “interlayer” as utilized herein refers to a single layer and/or all of a plurality of layers between the first electrode and the second electrode of the light-emitting device.

According to one or more embodiments of the present disclosure, an electronic apparatus may include the light-emitting device. The electronic apparatus may further include a thin-film transistor. For example, in one or more embodiments, the electronic apparatus may further include a thin-film transistor including a source electrode and a drain electrode, wherein the first electrode of the light-emitting device may be electrically connected to the source electrode or the drain electrode. In one or more embodiments, the electronic apparatus may further include a color filter, a color conversion layer, a touch screen layer, a polarizing layer, or any combination thereof. More details of the electronic apparatus may be referred to the descriptions provided herein.

According to one or more embodiments of the present disclosure, an electronic equipment may include the light-emitting device. For example, the electronic equipment may be at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard. More details for the electronic equipment are as described herein.

According to one more embodiments of the present disclosure, there is provided the heterocyclic compound represented by Formula 1. Formula 1 is the same as described in the present disclosure.

Methods of synthesizing the heterocyclic compound of the present disclosure may be easily understood by those of ordinary skill in the art by referring to Synthesis Examples and/or Examples described herein.

### Description of Formula 1

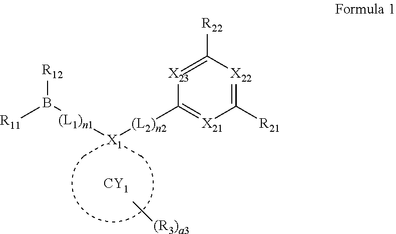

In Formula 1, X₁ may be carbon (C), and X₁ may be bonded to another carbon or nitrogen atom in one of four directions of X₁, e.g., X₁ may be an sp³ hybridized carbon and may form four single bonds with other carbon or nitrogen atoms.

In Formula 1, ring CY₁ may be a C₃-C₂₀ cycloalkyl group.

In one or more embodiments, ring CY₁ may be
a cyclopropane group, a cyclobutane group, a cyclopentane group, a cyclohexane group, a cycloheptane group, a cyclooctane group, an adamantane group, a bicyclo[1.1.1]pentane group, a bicyclo[2.1.1]hexane group, a bicyclo[2.2.1]heptane group, a bicyclo[2.2.2]octane group, a bicyclo[3.2.1]octane group, a bicyclo[3.2.2]nonane group, a bicyclo[3.3.1]nonane group, a tricyclo[3.1.1.0(3,6)]heptane group, or a tricyclo[4.1.1.0(3,7)]octane group.

In one or more embodiments, ring CY₁ may be
a cyclopropane group, a cyclobutane group, a cyclopentane group, a cyclohexane group, a cycloheptane group, an adamantane group, a bicyclo[1.1.1]pentane group, a bicyclo[2.1.1]hexane group, or a bicyclo[2.2.1]heptane group.

In one or more embodiments, ring CY₁ may not be an adamantane group.

In one or more embodiments, ring CY₁ may be
a cyclopropane group, a cyclobutane group, a cyclopentane group, a cyclohexane group, a cycloheptane group, a bicyclo[1.1.1]pentane group, a bicyclo[2.1.1]hexane group, or a bicyclo[2.2.1]heptane group.

In one or more embodiments, a group represented by

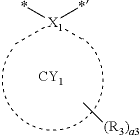

in Formula 1 may be a group represented by one selected from among Formulae CY(1) to CY(11):

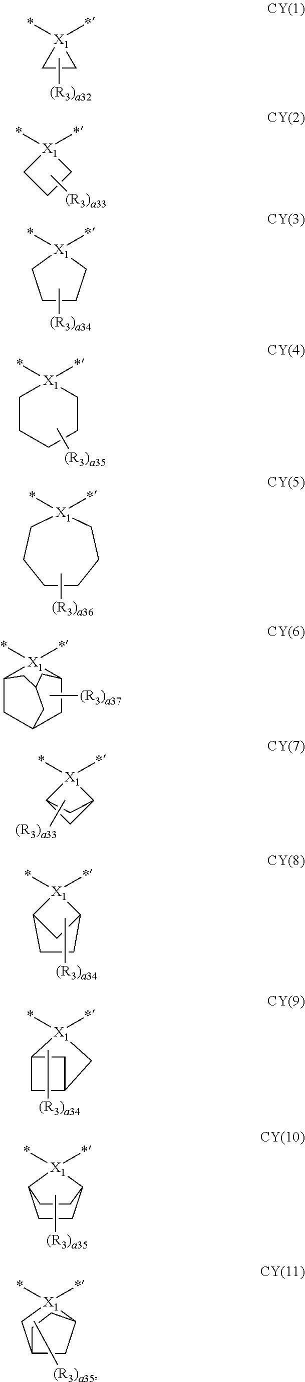

wherein, in Formulae CY(1) to CY(11),
X₁ and R₃ may each be the same as described in the present disclosure.
a32 may be an integer from 1 to 4,
a33 may be an integer from 1 to 6,
a34 may be an integer from 1 to 8,
a35 may be an integer from 1 to 10,
a36 may be an integer from 1 to 12,
a37 may be an integer from 1 to 14,
* indicates a binding site to L₁ in Formula 1, and
** indicates a binding site to L₂ in Formula 1.

In Formula 1, X₂₁ may be C(Y₂₁) or N, X₂₂ may be C(Y₂₂) or N, X₂₃ may be C(Y₂₃) or N, and the number of N(s) among X₂₁ to X₂₃ may be one or more.

In Formula 1, Y₂₁ to Y₂₃ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

R₁₀ₐ and Q₁ to Q₃ may each be the same as described in the present disclosure.

In one or more embodiments, at least two selected from among X₂₁ to X₂₃ may be N.

In one or more embodiments, each of X₂₁ to X₂₃ may be N.

In one or more embodiments, Y₂₁ to Y₂₃ may each independently be:
hydrogen, deuterium, —F, —Cl, —Br, —I, a hydroxyl group, a cyano group, a nitro group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In Formula 1, R₁₁, R₁₂, R₂₁, R₂₂, and R₃ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

R₁₀ₐ and Q₁ to Q₃ may each be the same as described in the present disclosure.

In Formula 1, a3 may indicate the number of R₃ and may be an integer from 1 to 20. When a3 is 2 or more, two or more of R₃(s) may be identical to or different from each other.

In one or more embodiments, R₁₁, R₁₂, R₂₁, R₂₂, and R₃ may each independently be:
hydrogen, deuterium, —F, —Cl, —Br, —I, a hydroxyl group, a cyano group, a nitro group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CDs, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, R₁₁ and R₁₂ may each independently be:
hydrogen, deuterium, —F, a cyano group, or a C₁-C₂₀ alkyl group;
a C₁-C₂₀ alkyl group that is substituted with deuterium, —F, —CD₃, —CD₂H, —CDH₂, —CF₃, —CF₂H, —CFH₂, a cyano group, a C₁-C₁ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a phenyl group, a biphenyl group, a (C₁-C₁ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, an oxadiazolyl group, a triazinyl group, a benzocarbazolyl group, a dibenzocarbazolyl group, an imidazopyridinyl group, an imidazopyrimidinyl group, an azacarbazolyl group, or an azafluorenyl group, each unsubstituted or substituted with deuterium, —F, —CD₃, —CD₂H, —CDH₂, —CF₃, —CF₂H, —CFH₂, a cyano group, a C₁-C₂₀ alkyl group, a cyclopentyl group, a cyclohexyl group, a cycloheptyl group, a phenyl group, a biphenyl group, a (C₁-C₁ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —N(Q₃₁)(Q₃₂), or any combination thereof; or
—C(Q₁)(Q₂)(Q₃) or —N(Q₁)(Q₂), and
Q₁ to Q₃ and Q₃₁ to Q₃₂ may each independently be: hydrogen; deuterium; —F; a cyano group; or a C₁-C₆₀ alkyl group, a C₃-C₆₀ carbocyclic group, or a C₁-C₆₀ heterocyclic group, each unsubstituted or substituted with deuterium, —F, a cyano group, a C₁-C₆₀ alkyl group, a phenyl group, a biphenyl group, or any combination thereof.

In one or more embodiments, R₂₁ and R₂₂ may each independently be:
hydrogen, deuterium, —F, a cyano group, or a C₁-C₂₀ alkyl group;
a C₁-C₂₀ alkyl group that is substituted with deuterium, —F, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a phenyl group, a biphenyl group, a (C₁-C₁₀ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, an oxadiazolyl group, a triazinyl group, a benzocarbazolyl group, a dibenzocarbazolyl group, an imidazopyridinyl group, an imidazopyrimidinyl group, an azacarbazolyl group, or an azafluorenyl group, each unsubstituted or substituted with deuterium, —F, —CD₃, —CD₂H, —CDH₂, —CF₃, —CF₂H, —CFH₂, a cyano group, a C₁-C₂₀ alkyl group, a cyclopentyl group, a cyclohexyl group, a cycloheptyl group, a phenyl group, a biphenyl group, a (C₁-C₁₀ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —N(Q₃₁)(Q₃₂), or any combination thereof; or
—C(Q₁)(Q₂)(Q₃) or —N(Q₁)(Q₂), and
Q₁ to Q₃ and Q₃₁ to Q₃₂ may each independently be: hydrogen; deuterium; —F; a cyano group; or a C₁-C₆₀ alkyl group, a C₃-C₆₀ carbocyclic group, or a C₁-C₆₀ heterocyclic group, each unsubstituted or substituted with deuterium, —F, a cyano group, a C₁-C₆₀ alkyl group, a phenyl group, a biphenyl group, or any combination thereof.

In one or more embodiments, R₃ may be:
hydrogen, deuterium, —F, —Cl, —Br, —I, a cyano group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, a C₁-C₂₀ alkylthio group, a cyclopentyl group, a cyclohexyl group, a cycloheptyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), or any combination thereof; or
—C(Q₁)(Q₂)(Q₃), —Si(Q₁)(Q₂)(Q₃), —N(Q₁)(Q₂), and
Q₁ to Q₃ and Q₃₁ to Q₃₃ may each independently be: hydrogen; deuterium; —F; —Cl; —Br; —I; a cyano group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

In one or more embodiments, R₃ may be:
hydrogen, deuterium, —F, a cyano group, or a C₁-C₂₀ alkyl group;
a C₁-C₂₀ alkyl group that is substituted with deuterium, —F, —CD₃, —CD₂H, —CDH₂, —CF₃, —CF₂H, —CFH₂, a cyano group, a C₁-C₁ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a phenyl group, a biphenyl group, a (C₁-C₁₀ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, an oxadiazolyl group, a triazinyl group, a benzocarbazolyl group, a dibenzocarbazolyl group, an imidazopyridinyl group, an imidazopyrimidinyl group, an azacarbazolyl group, or an azafluorenyl group, each unsubstituted or substituted with deuterium, —F, —CD₃, —CD₂H, —CDH₂, —CF₃, —CF₂H, —CFH₂, a cyano group, a C₁-C₂₀ alkyl group, a cyclopentyl group, a cyclohexyl group, a cycloheptyl group, a phenyl group, a biphenyl group, a (C₁-C₁₀ alkyl)phenyl group, a naphthyl group, a fluorenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a triazolyl group, a tetrazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —N(Q₃₁)(Q₃₂), or any combination thereof; or
C(Q₁)(Q₂)(Q₃) or —N(Q₁)(Q₂), and
Q₁ to Q₃ and Q₃₁ to Q₃₂ may each independently be: hydrogen; deuterium; —F; a cyano group; or a C₁-C₆₀ alkyl group, a C₃-C₆₀ carbocyclic group, or a C₁-C₆₀ heterocyclic group, each unsubstituted or substituted with deuterium, —F, a cyano group, a C₁-C₆₀ alkyl group, a phenyl group, a biphenyl group, or any combination thereof.

In one or more embodiments, R₃ may be:
hydrogen, deuterium, —F, a cyano group; or
a C₁-C₂₀ alkyl group that is unsubstituted or substituted with deuterium, —F, —Cl, —Br, —I, —CD₃, —CD₂H, —CDH₂, —CF₃, —CF₂H, —CFH₂, a cyano group, a C₁-C₁₀ alkyl group, a cyclopentyl group, a cyclohexyl group, a cycloheptyl group, a cyclopentenyl group, a cyclohexenyl group, a cycloheptenyl group, a phenyl group, a biphenyl group, a naphthyl group, a pyridinyl group, a pyrimidinyl group, or any combination thereof.

In Formula 1, L₁ and L₂ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ.

R₁₀ₐ is as described herein.

In Formula 1, n1 and n2 indicate the number of L₁ and the number of L₂, respectively, and may each independently be an integer from 1 to 5. When n1 is 2 or more, two or more of L₁(s) may be identical to or different from each other, and when n2 is 2 or more, two or more of L₂(s) may be identical to or different from each other.

In one or more embodiments, L₁ and L₂ may each independently be a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, a dibenzodihydrodihydrodisiline group, a dibenzodihydrosiline group, a dibenzodioxin group, a dibenzoxathiin group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

In one or more embodiments, L₁ and L₂ may each independently be
a benzene group, a naphthalene group, a pyridine group, a pyrimidine group, a pyrazine group, a pyridazine group, a triazine group, a quinoline group, an isoquinoline group, a quinoxaline group, a quinazoline group, or a phthalazine group, each unsubstituted or substituted with at least one R₁₀ₐ.

In one or more embodiments, L₁ and L₂ may each independently be
a benzene group, a naphthalene group, a pyridine group, a pyrimidine group, a pyrazine group, a pyridazine group, or a triazine group, each unsubstituted or substituted with at least one R₁₀ₐ.

In one or more embodiments, n1 may be 1 or 2, and
n2 may be 1.

In one or more embodiments, L₁ and L₂ may each independently be a group represented by one selected from among Formulae L(1) to L(24):

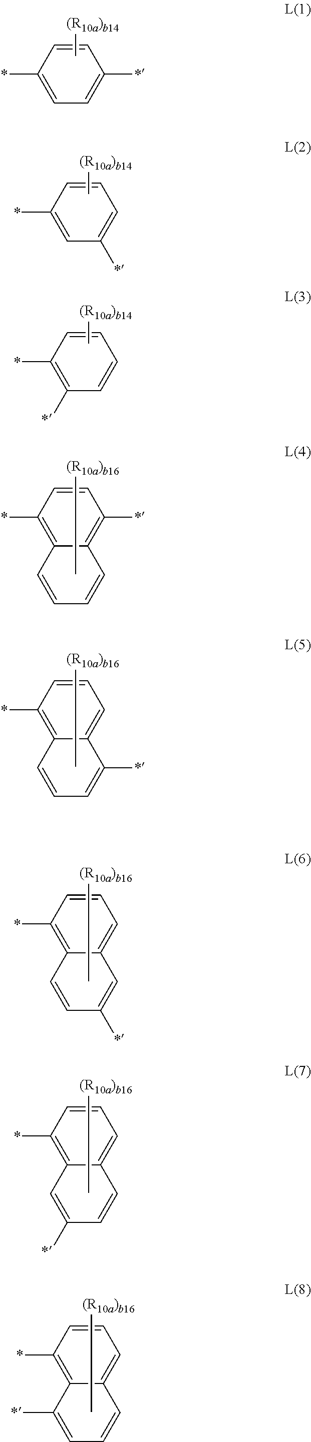

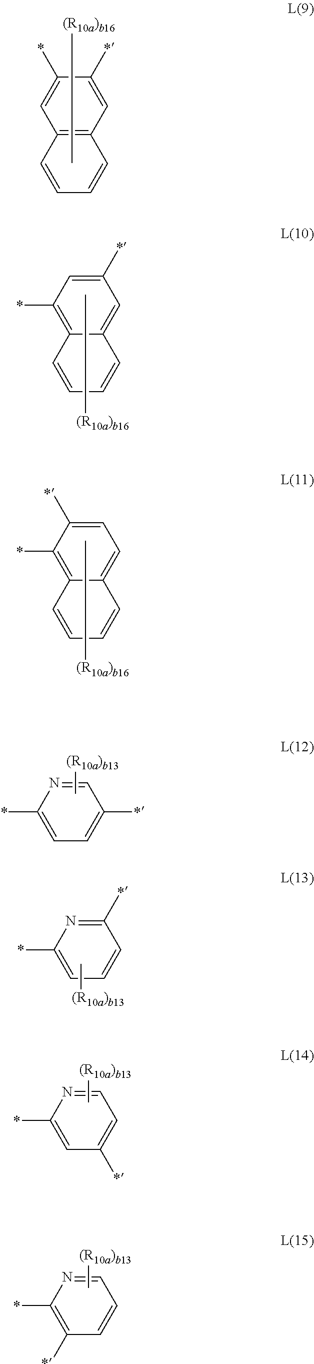

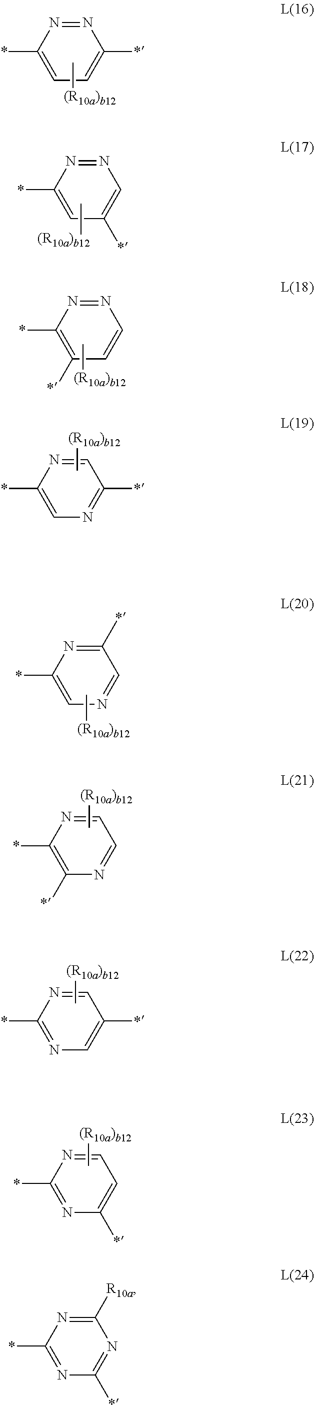

wherein, in Formulae L(1) to L(24),
R₁₀ₐ is the same as described in the present disclosure,
b12 may be an integer from 1 to 2,
b13 may be an integer from 1 to 3,
b14 may be an integer from 1 to 4,
b16 may be an integer from 1 to 6, and
* and *′ each indicate a binding site to a neighboring atom.

In one or more embodiments, R₁₁ and L₁ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ.

In one or more embodiments, R₁₂ and L₁ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ.

In one or more embodiments, R₁₁ and R₁₂ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ.

In one or more embodiments, two or more neighboring groups selected from among R₂₁, R₂₂, and Y₂₁ to Y₂₃ may optionally be bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ.

In one or more embodiments, a group represented by

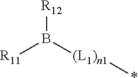

in Formula 1 may be a group represented by one selected from among Formulae B(1) to B(3):

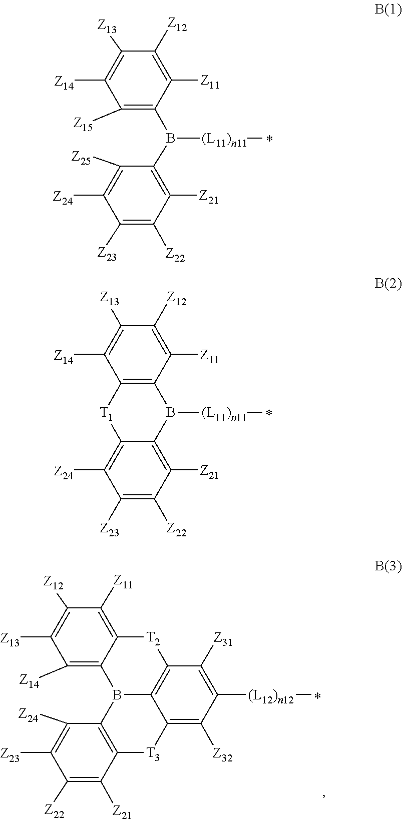

wherein, in Formulae B(1) to B(3),
L₁₁ and L₁₂ may each be the same as described with respect to L₁ in the present disclosure,
n11 may be an integer from 1 to 5, and n12 may be an integer from 1 to 4,
T₁ to T₃ may each independently be a single bond, *—O—*′, *—S—*′, *—Se—*′, *—N(R′)—*′, *—B(R′)—*′, *—C(R′)(R″)—*′, or *—Si(R′)(R″)—*′,
Z₁₁ to Z₁₅, Z₂₁ to Z₂₅, Z₃₁, Z₃₂, R′, and R″ may each be the same as described with respect to R₁₀ₐ in the present disclosure, and
* and *′ each independently indicates a binding site to a neighboring atom.

In one or more embodiments, in Formulae B(1) to B(3), Z₁₁ to Z₁₅ and Z₂₁ to Z₂₅ may each independently be hydrogen, deuterium, or a C₁-C₆₀ alkyl group that is unsubstituted or substituted with at least one R₁₀ₐ.

In the heterocyclic compound represented by Formula 1, ring CY₁, which is a C₃-C₂₀ cycloalkyl group, may connect a boron-based substituent and a nitrogen-containing cyclic group to each other via X₁, which is carbon (C) bonded to another carbon or nitrogen atom in one of four directions of X₁ (e.g., in any one selected from among the four directions of X₁), thereby improving electrical stability and charge transport capability and increasing glass transition temperature to prevent or reduce crystallization. Therefore, if (e.g., when) the heterocyclic compound represented by Formula 1 is applied to a light-emitting device (in particular, an electron transport region of the light-emitting device), relatively high luminescence efficiency and long lifespan may be achieved.

### Description of Other Formulae

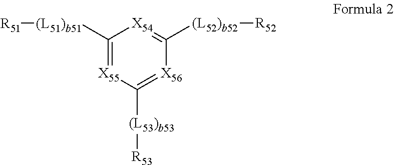

In Formula 2, L₅₁ to L₅₃ may each independently be a single bond, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

b51 to b53 in Formula 2 indicate the number of L₅₁ to the number of L₅₃, respectively, and may each independently be an integer from 1 to 5. If (e.g., when) b51 is 2 or more, two or more of L₅₁(s) may be identical to or different from each other, if (e.g., when) b52 is 2 or more, two or more of L₅₂(s) may be identical to or different from each other, and if (e.g., when) b53 is 2 or more, two or more of L₅₃(s) may be identical to or different from each other. In one or more embodiments, b51 to b53 may each independently be 1 or 2.

L₅₁ to L₅₃ in Formula 2 may each independently be:
a single bond; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, a dibenzodihydrodisiline group, a dibenzodihydrosiline group, a dibenzodioxane group, a dibenzoxathiene group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and
Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, in Formula 2, a bond between L₅₁ and R₅₁, a bond between L₅₂ and R₅₂, a bond between L₅₃ and R₅₃, a bond between two L₅₁(s), a bond between two L₅₂(s), a bond between two L₅₃(s), a bond between L₅₁ and carbon between X₅₄ and X₅₅ in Formula 2, a bond between L₅₂ and carbon between X₅₄ and X₅₆ in Formula 2, and a bond between L₅₃ and carbon between X₅₅ and X₅₆ in Formula 2 may each be a “carbon-carbon single bond”.

In Formula 2, X₅₄ may be N or C(R₅₄), X₅₅ may be N or C(R₅₅), X₅₆ may be N or C(R₅₆), and at least one selected from among X₅₄ to X₅₆ may be N. R₅₄ to R₅₆ may each independently the same as described in the present disclosure. In one or more embodiments, two or three selected from among X₅₄ to X₅₆ may be N.

In Formula 2, R₅₁ to R₅₆ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ and R₁₀ₐ are each the same as described in the present disclosure.

In one or more embodiments, in Formula 2, R₅₁ to R₅₆ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

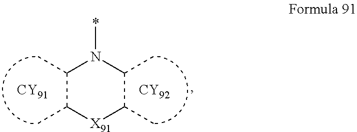

wherein, in Formula 91,
ring CY₉₁ and ring CY₉₂ may each independently be a C₅-C₃₀ carbocyclic group that is unsubstituted or substituted with at least one R₁₀ₐ or a C₁-C₃₀ heterocyclic group that is unsubstituted or substituted with at least one R₁₀ₐ,
X₉₁ may be a single bond, O, S, N(R₉₁), B(R₉₁), C(R₉₁ₐ)(R₁₁b), or Si(R₉₁ₐ)(R_{91b}),
R₉₁, R₉₁ₐ, and R_{91b} may be the same as described with respect to R₈₂, R₈₂ₐ, and R_{82b}, respectively,
R₁₀ₐ is as described in the present disclosure, and
* indicates a binding site to a neighboring atom.

For example, in one or more embodiments, in Formula 91,
ring CY₉₁ and ring CY₉₂ may each independently be a benzene group, a pyridine group, a pyrimidine group, a pyrazine group, a pyridazine group, or a triazine group, each unsubstituted or substituted with at least one R₁₀ₐ,
R₉₁, R₉₁ₐ, and R_{91b} may each independently be:
hydrogen or a C₁-C₁ alkyl group; or
a phenyl group, a pyridinyl group, a pyrimidinyl group, a pyridazinyl group, a pyrazinyl group, or a triazinyl group, each unsubstituted or substituted with deuterium, a C₁-C₁ alkyl group, a phenyl group, a biphenyl group, a pyridinyl group, a pyrimidinyl group, a pyridazinyl group, a pyrazinyl group, a triazinyl group, or any combination thereof.

In one or more embodiments, each of a group represented by *-(L₅₁)_{b51}-R₅₁ and a group represented by *-(L₅₂)_{b52}-R₅₂ in Formula 2 may not be a phenyl group.

In one or more embodiments, a group represented by *-(L₅₁)_{b51}-R₅₁ and a group represented by *-(L₅₂)_{b52}-R₅₂ in Formula 2 may be identical to each other.

In one or more embodiments, a group represented by *-(L₅₁)_{b51}-R₅₁ and a group represented by *-(L₅₂)_{b52}-R₅₂ in Formula 2 may be different from each other.

In one or more embodiments, in Formula 2, b51 and b52 may each be 1, 2, or 3, and L₅₁ and L₅₂ may each independently be a benzene group, a pyridine group, a pyrimidine group, a pyridazine group, a pyrazine group, or a triazine group, each unsubstituted or substituted with at least one R₁₀ₐ.

In one or more embodiments, R₅₁ and R₅₂ in Formula 2 may each independently be a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₁-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), or —Si(Q₁)(Q₂)(Q₃), and
Q₁ to Q₃ may each independently be a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In one or more embodiments,
a group represented by *-(L₅₁)_{b51}-R₅₁ in Formula 2 may be a group represented by one selected from among Formulae CY51-1 to CY51-26, and/or

a group represented by *-(L₅₂)_{b52}-R₅₂ in Formula 2 may be a group represented by one selected from among Formulae CY52-1 to CY52-26, and/or

a group represented by *-(L₅₃)_{b53}-R₅₃ in Formula 2 may be a group represented by one selected from among Formulae CY53-1 to CY53-27, —C(Q₁)(Q₂)(Q₃), or —Si(Q₁)(Q₂)(Q₃):

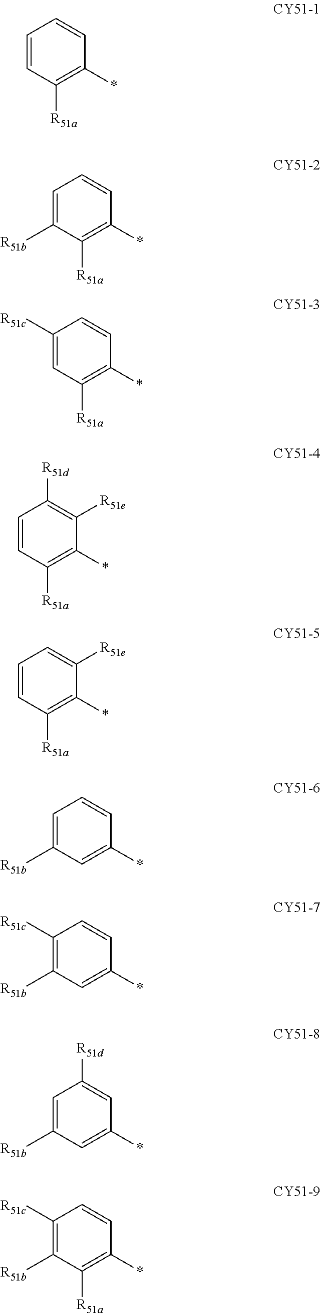

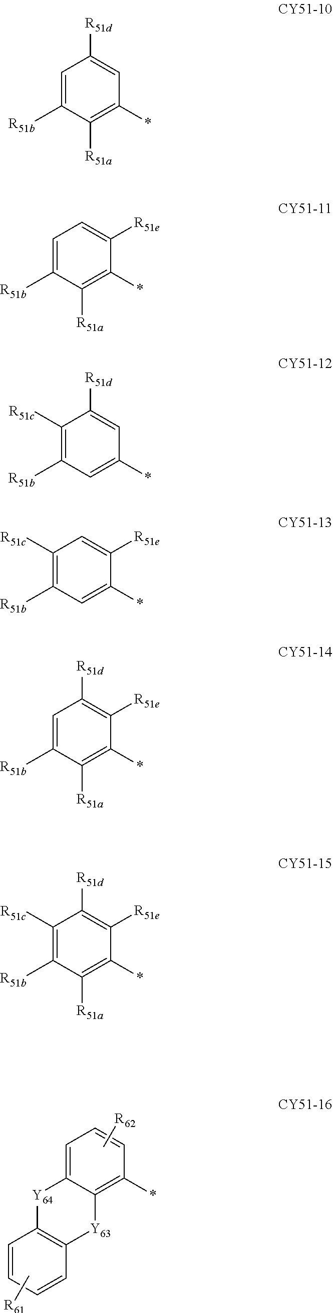

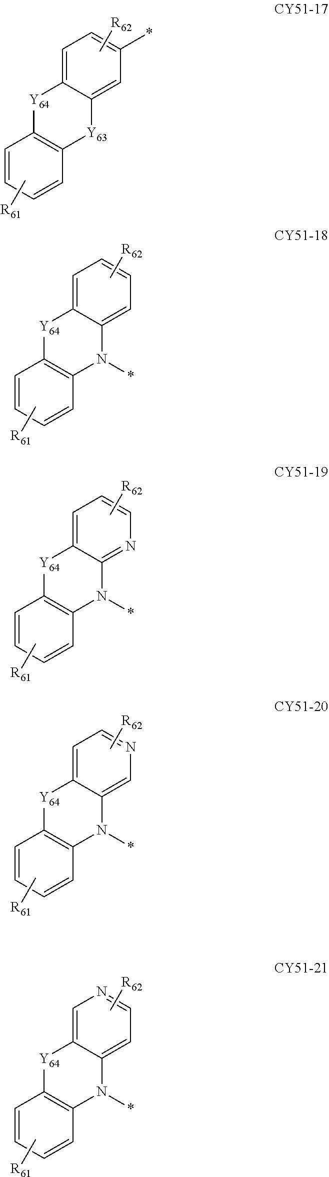

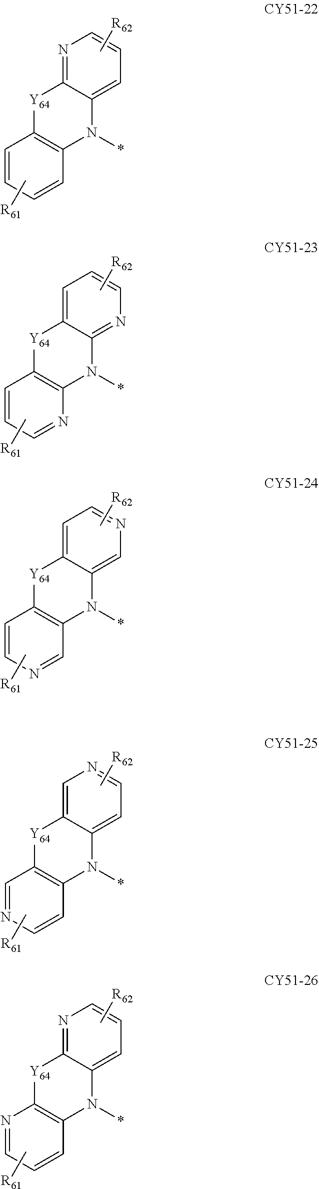

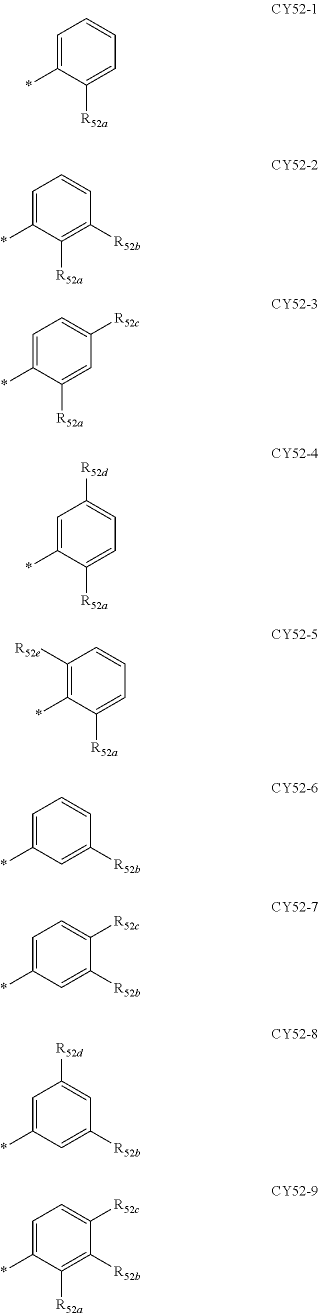

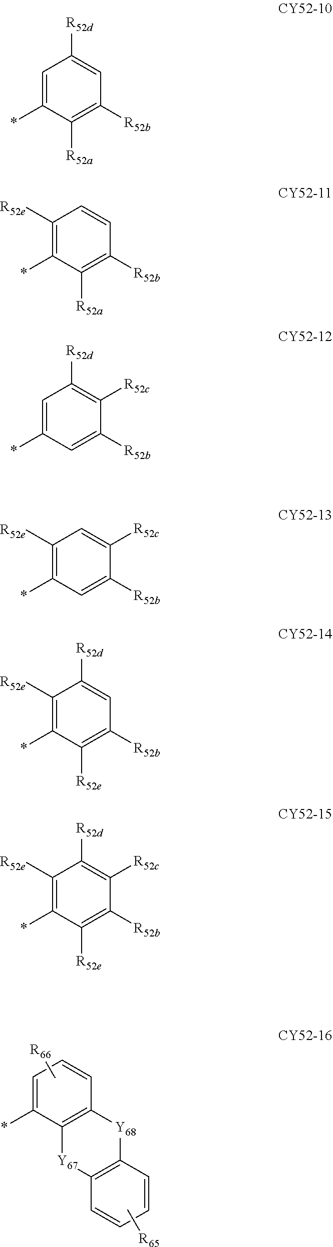

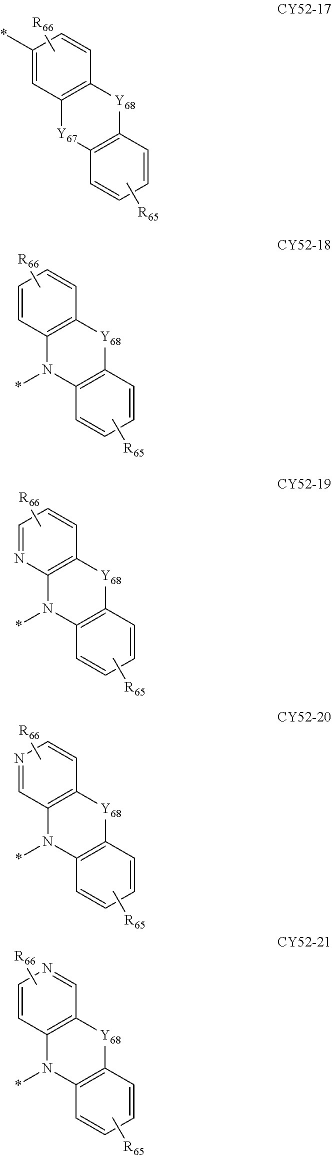

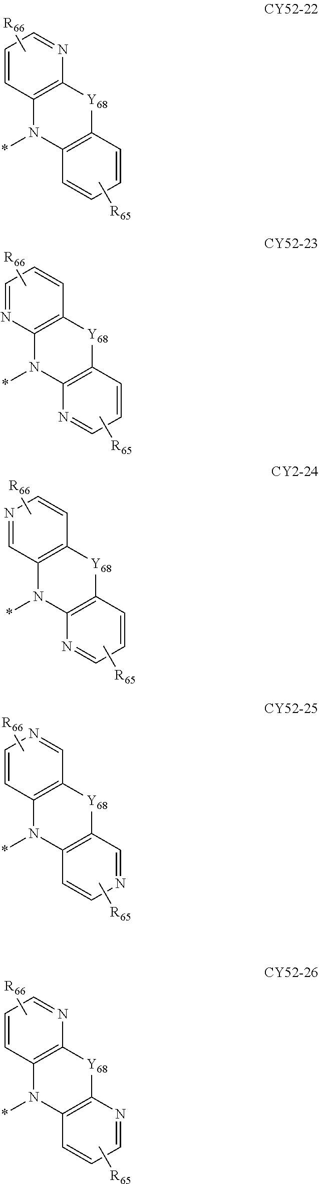

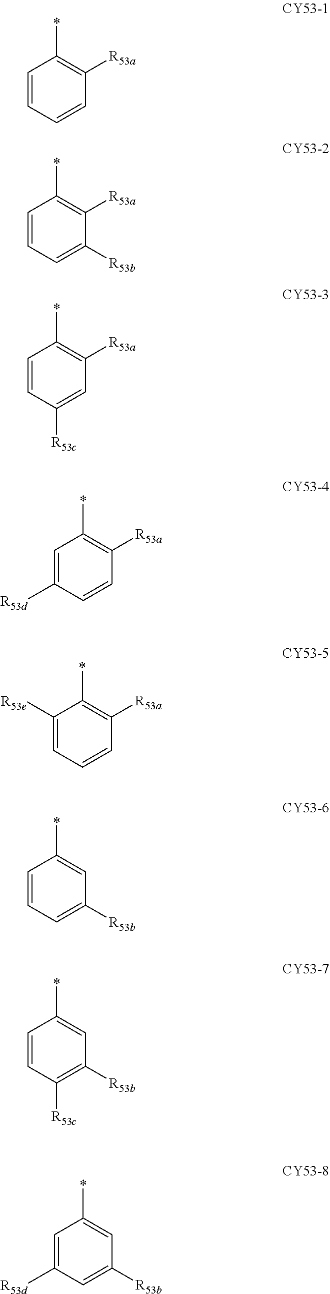

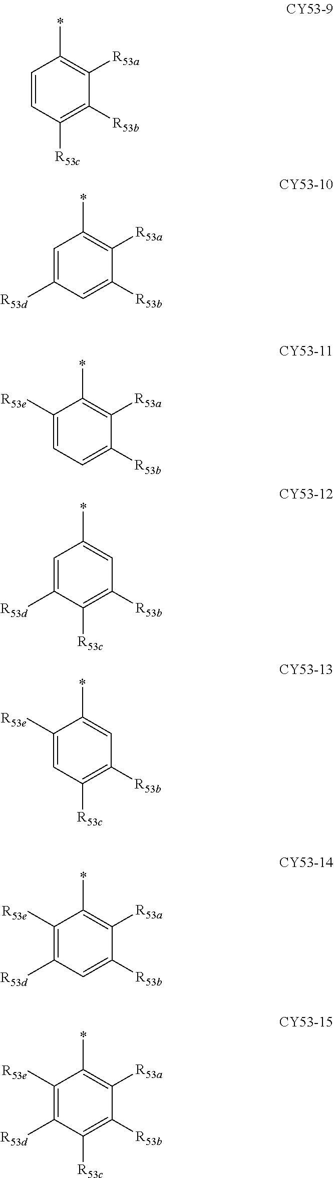

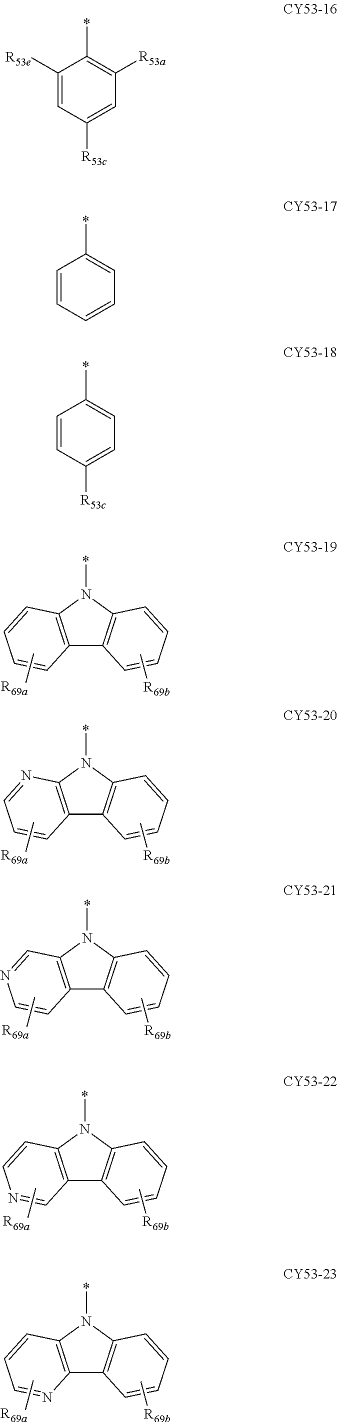

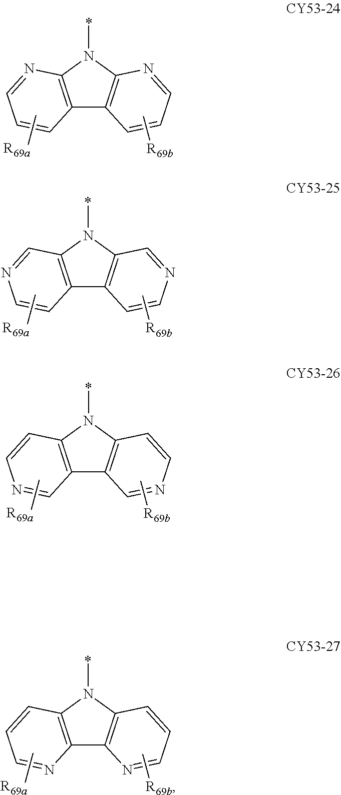

wherein, in Formulae CY51-1 to CY51-26, CY52-1 to CY52-26, and CY53-1 to CY53-27,
Y₆₃ may be a single bond, O, S, N(R₆₃), B(R₆₃), C(R₆₃ₐ)(R_{63b}), or Si(R₆₃ₐ)(R_{63b}),
Y₆₄ may be a single bond, O, S, N(R₆₄), B(R₆₄), C(R₆₄ₐ)(R_{64b}), or Si(R₆₄ₐ)(R_{64b}),
Y₆₇ may be a single bond, O, S, N(R₆₇), B(R₆₇), C(R₆₇ₐ)(R_{67b}), or Si(R₆₇ₐ)(R_{67b}),
Y₆₈ may be a single bond, O, S, N(R₆₈), B(R₆₈), C(R₆₈ₐ)(R_{68b}), or Si(R₆₈ₐ)(R_{68b}),
each of Y₆₃ and Y₆₄ in Formulae CY51-16 and CY51-17 may not be a single bond at the same time,
each of Y₆₇ and Y₆₈ in Formulae CY52-16 and CY52-17 may not be a single bond at the same time,
R₅₁ₐ to R₅₁ₑ, R₆₁ to R₆₄, R₆₃ₐ, R_{63b}, R₆₄ₐ, and R_{64b} may each independently be the same as described with respect to R₅₁, wherein R₅₁ₐ to R₅₁ₑ may not each be hydrogen,
R₅₂ₐ to R₅₂ₑ, R₆₅ to R₆₈, R₆₇ₐ, R_{67b}, R₆₈ₐ, and R_{68b} may each independently be the same as described with respect to R₅₂, wherein R₅₂ₐ to R₅₂ₑ may not each be hydrogen,
R₅₃ₐ to R₅₃ₑ, R₆₉ₐ, and R_{69b} may each independently be the same as described with respect to R₅₃, and R₅₃ₐ to R₅₃ₑ may not each be hydrogen, and
* indicates a binding site to a neighboring atom.

In one or more embodiments,
in Formulae CY51-1 to CY51-26 and Formulae CY52-1 to CY52-26, R₅₁ₐ to R₅₁ₑ and R₅₂ₐ to R₅₂ₑ may each independently be:
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or
—C(Q₁)(Q₂)(Q₃) or —Si(Q₁)(Q₂)(Q₃),
Q₁ to Q₃ may each independently be a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof,
in Formulae CY51-16 and CY51-17, i) Y₆₃ may be O or S, and Y₆₄ may be Si(R₆₄ₐ)(R_{64b}), or ii) Y₆₃ may be Si(R₆₃ₐ)(R_{63b}), and Y₆₄ may be O or S, and
in Formulae CY52-16 and CY52-17, i) Y₆₇ may be O or S, and Y₆₈ may be Si(R₆₈ₐ)(R_{68b}), or ii) Y₆₇ may be Si(R₆₇ₐ)(R_{67b}), and Y₆₈ may be O or S.

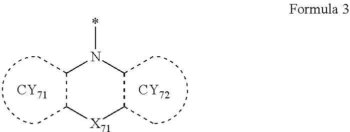

In Formula 3, ring CY₇₁ and ring CY₇₂ may each independently be a π electron-rich C₃-C₆₀ cyclic group or a pyridine group.

In Formula 3, X₇₁ may be a single bond or a linking group including O, S, N, B, C, Si, or any combination thereof.

In Formula 3, * indicates a binding site to any atom included in the remaining part other than the group represented by Formula 3 in the third compound.

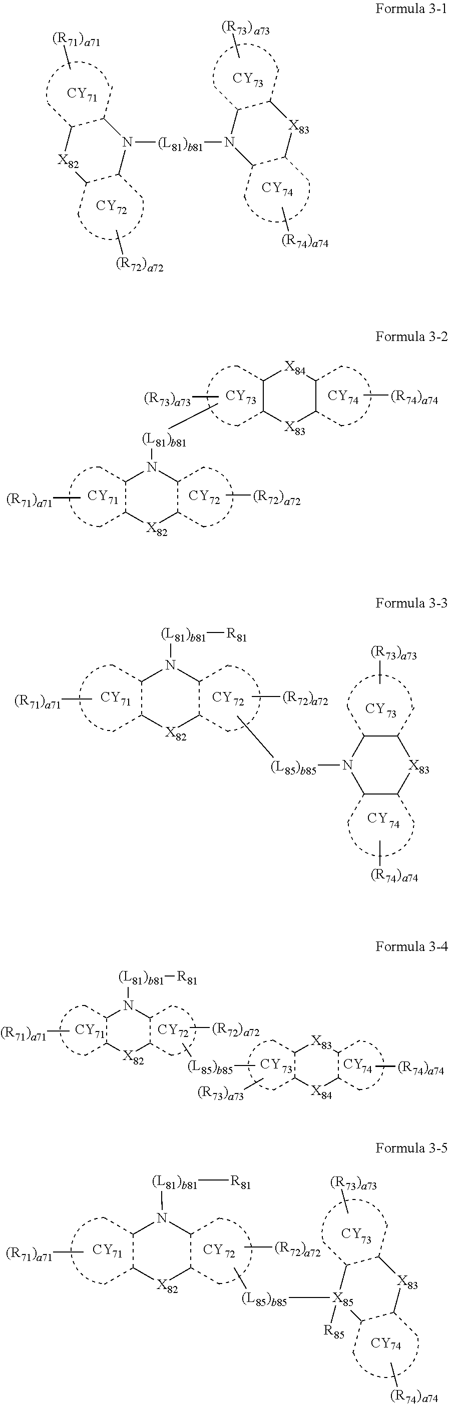

In Formulae 3-1 to 3-5, ring CY₇₁ to ring CY₇₄ may each independently be a π electron-rich C₃-C₆₀ cyclic group or a pyridine group.

In Formulae 3-1 to 3-5, X₈₂ may be a single bond, O, S, N[(L₈₂)_{b82}-R₈₂], C(R₈₂ₐ)(R_{82b}), or Si(R₈₂ₐ)(R_{82b}).

In Formulae 3-1 to 3-5, X₈₃ may be a single bond, O, S, N[(L₈₃)_{b83}-R₈₃], C(R₈₃ₐ)(R_{83b}), or Si(R₈₃ₐ)(R_{83b}).

In Formulae 3-1 to 3-5, X₈₄ may be O, S, N[(L₈₄)_{b84}-R₈₄], C(R₈₄ₐ)(R_{84b}), or Si(R₈₄ₐ)(R_{84b}).

In Formulae 3-1 to 3-5, X₈₅ may be C or Si.

In Formulae 3-1 to 3-5, L₈₁ to L₈₅ may each independently be a single bond, *—C(Q₄)(Q₅)-*′, *—Si(Q₄)(Q₅)-*′, a π electron-rich C₃-C₆₀ cyclic group that is unsubstituted or substituted with at least one R₁₀ₐ, or a pyridine group that is unsubstituted or substituted with at least one R₁₀ₐ.

Q₄ and Q₅ may each be the same as described with respect to Q₁.

In Formulae 3-1 to 3-5, b81 to b85 may each independently be an integer from 1 to 5.

In Formulae 3-1 to 3-5, R₇₁ to R₇₄, R₈₁ to R₈₅, R₈₂ₐ, R_{82b}, R₈₃ₐ, R_{83b}, R₈₄ₐ, and R_{84b} may each be the same as described in the present disclosure.

In Formulae 3-1 to 3-5, a71 to a74 indicate the number of R₇₁ to the number of R₇₄, respectively, and may each independently be an integer from 0 to 20. If (e.g., when) a71 is 2 or more, two or more of R₇₁(s) may be identical to or different from each other, if (e.g., when) a72 is 2 or more, two or more of R₇₂(s) may be identical to or different from each other, if (e.g., when) a73 is 2 or more, two or more of R₇₃(s) may be identical to or different from each other, and if (e.g., when) a74 is 2 or more, two or more of R₇₄(s) may be identical to or different from each other. a71 to a74 may each independently be an integer from 0 to 8.

R₁₀ₐ is the same as described in the present disclosure.

In one or more embodiments, in Formulae 3-1 to 3-5, L₈₁ to L₈₅ may each independently be:
a single bond; or
*—C(Q₄)(Q₅)-*′ or *—Si(Q₄)(Q₅)-*′; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and
Q₄, Q₅, and Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, a group represented by

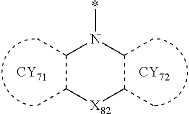

in Formulae 3-1 and 3-2 may be a group represented by one selected from among Formulae CY71-1(1) to CY71-1(8), and/or
a group represented by

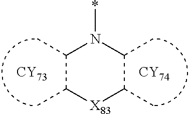

in Formulae 3-1 and 3-3 may be a group represented by one selected from among Formulae CY71-2(1) to CY71-2(8), and/or
a group represented by

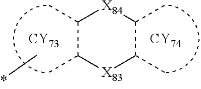

in Formulae 3-2 and 3-4 may be a group represented by one selected from among Formulae CY71-3(1) to CY71-3(32), and/or
a group represented by

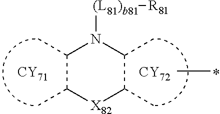

in Formulae 3-3 to 3-5 may be a group represented by one selected from among Formulae CY71-4(1) to CY71-4(32), and/or
a group represented by

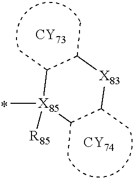

in Formula 3-5 may be a group represented by one selected from among Formulae CY71-5(1) to CY71-5(8):

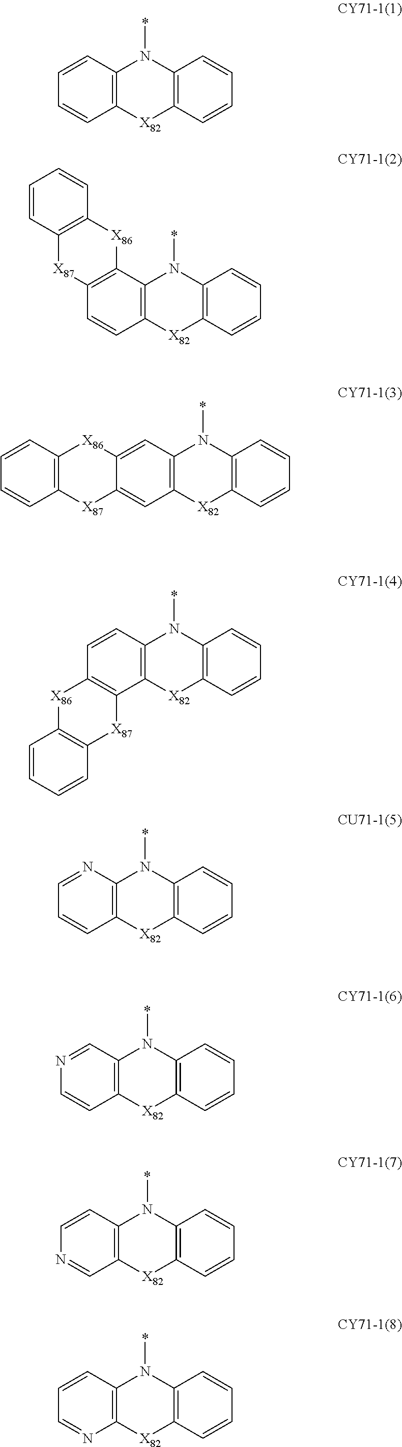

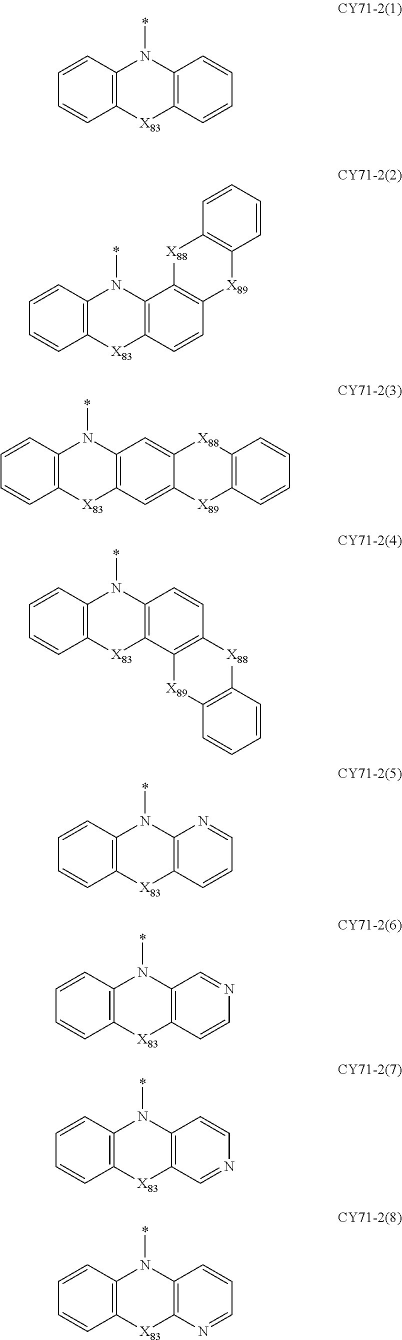

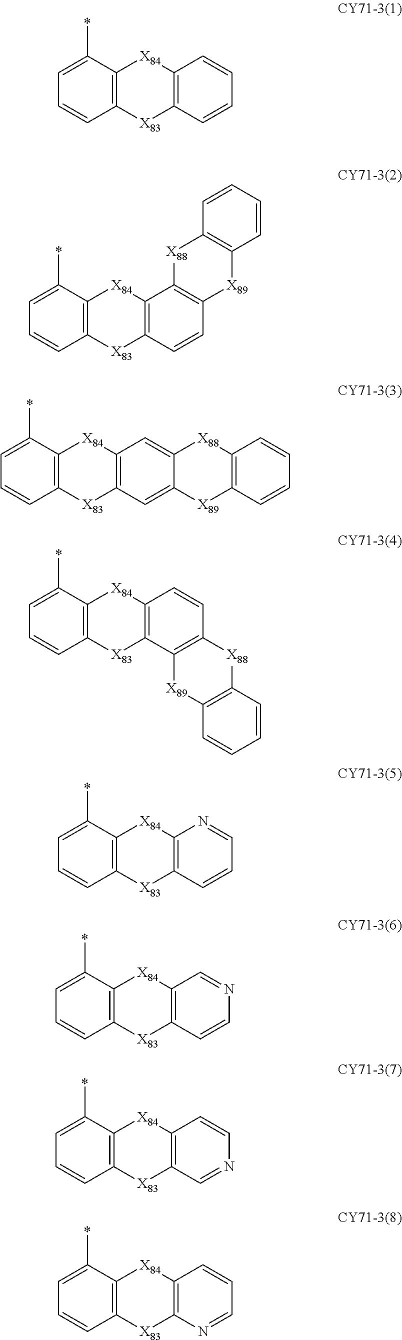

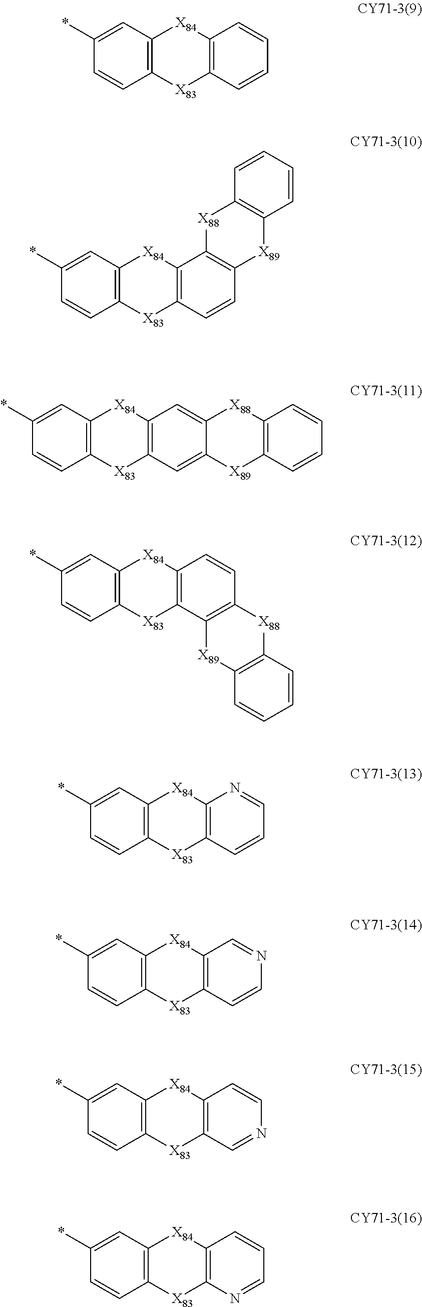

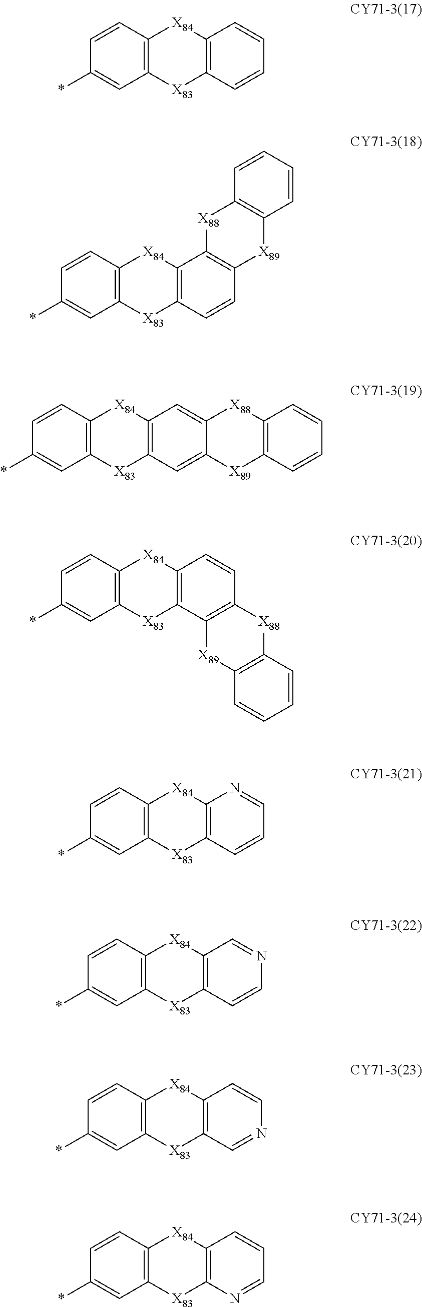

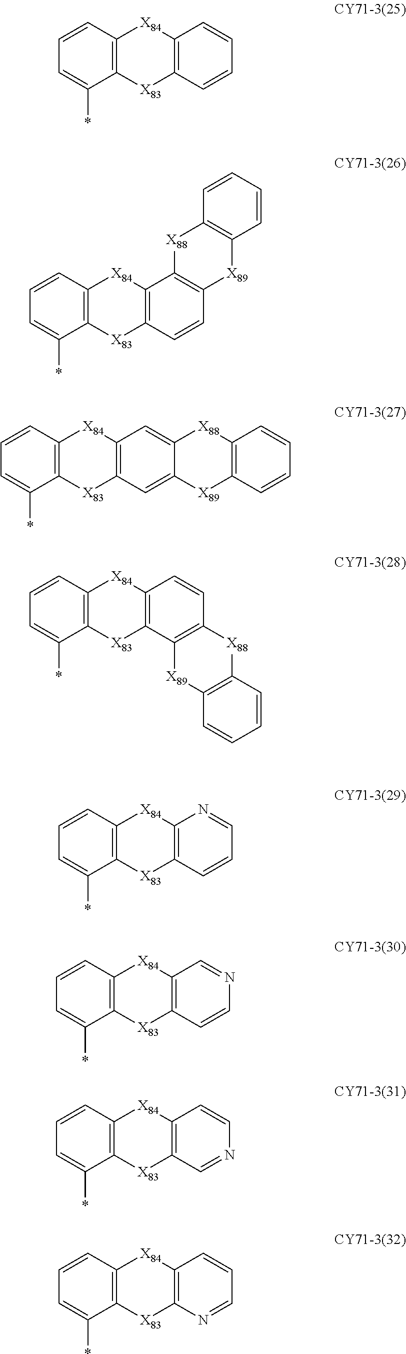

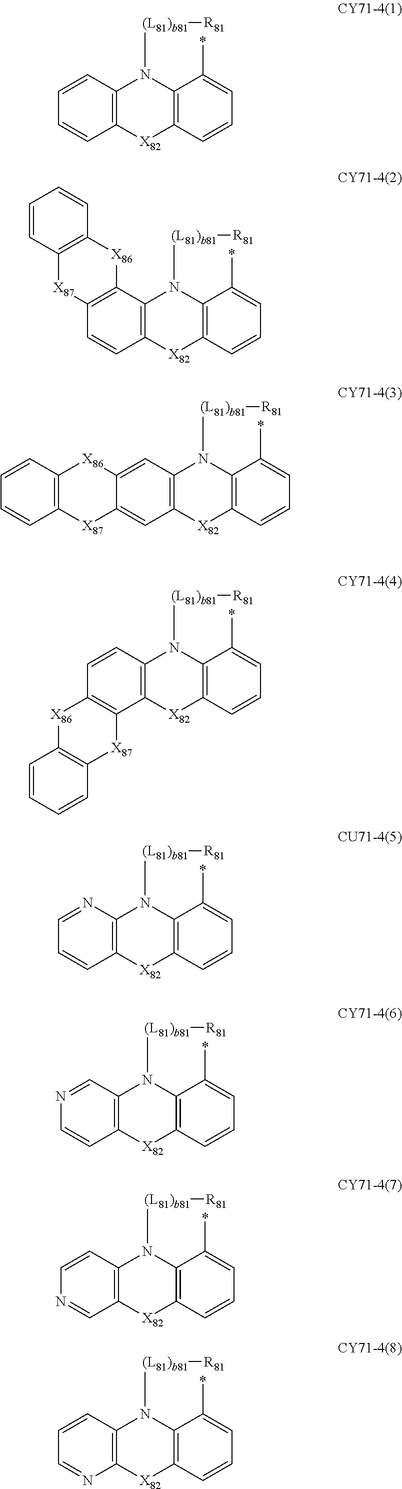

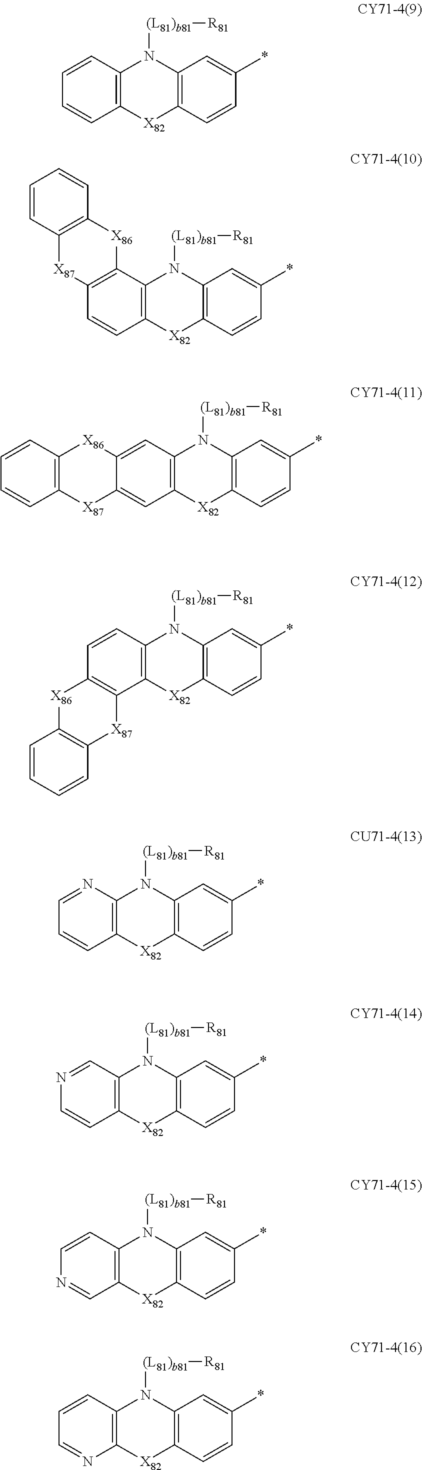

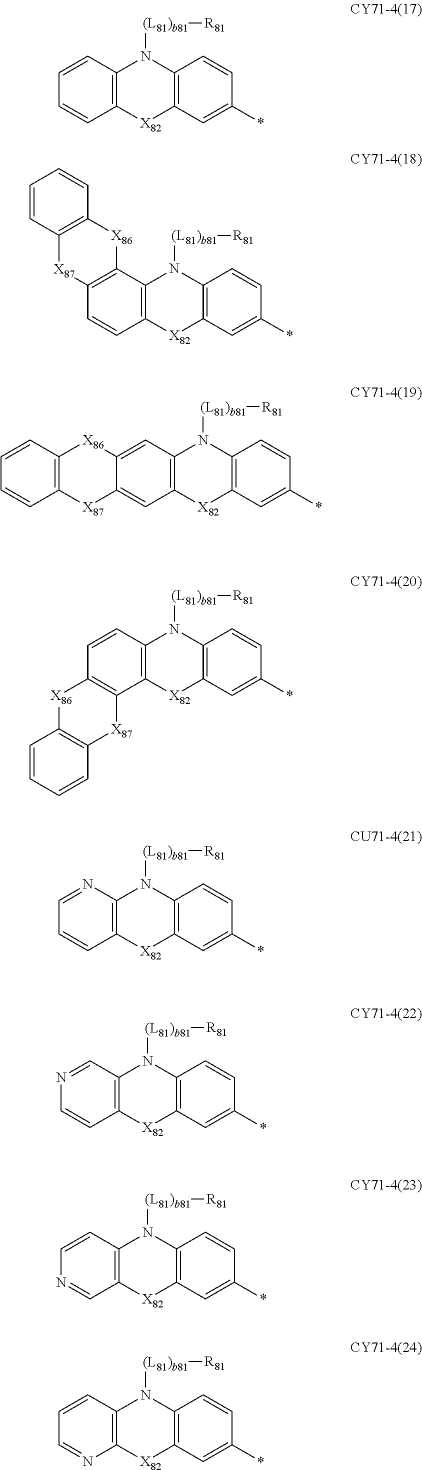

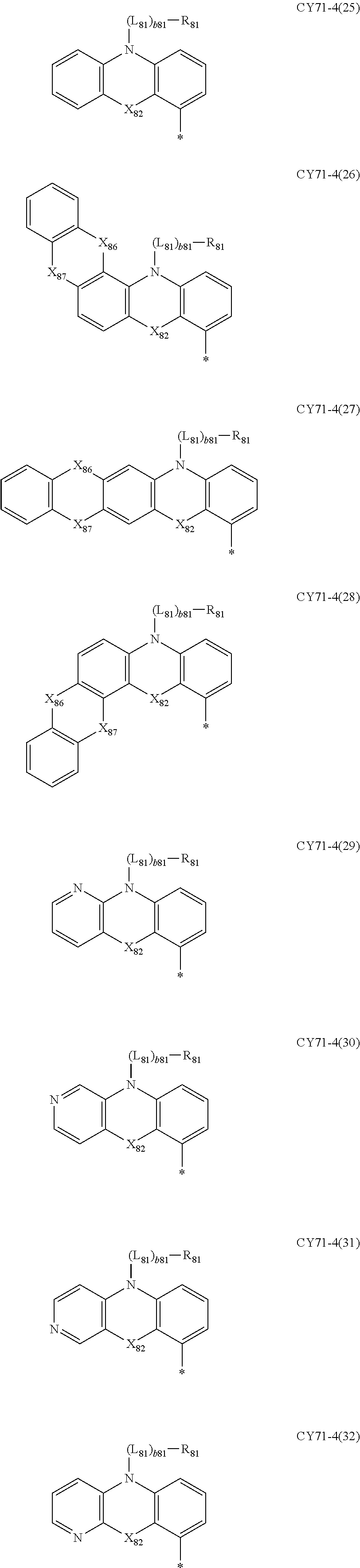

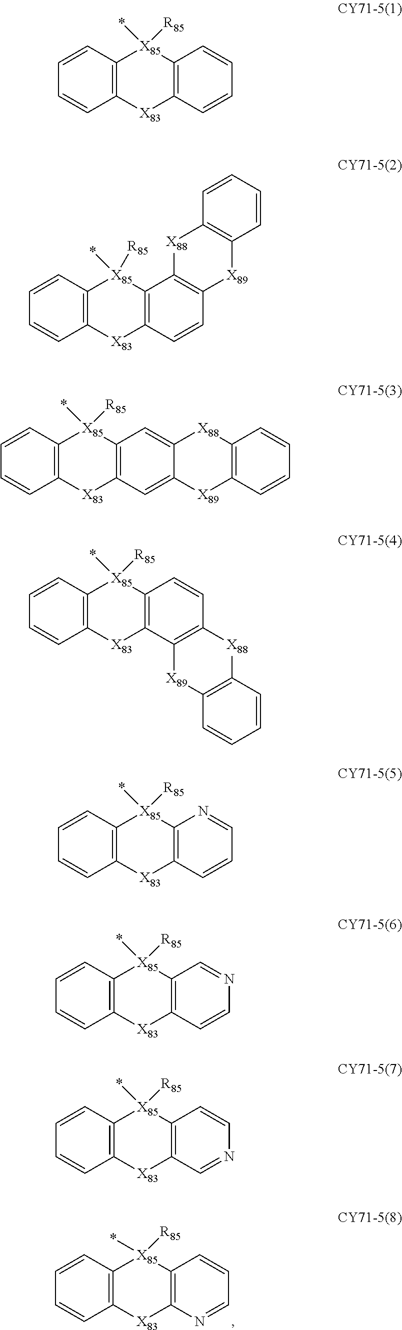

wherein, in Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),
X₈₂ to X₈₅, L₈₁, b81, R₈₁, and R₈₅ are each the same as described in the present disclosure,
X₈₆ may be a single bond, O, S, N(R₈₆), B(R₈₆), C(R₈₆ₐ)(R_{86b}), or Si(R₈₆ₐ)(R_{86b}),
X₈₇ may be a single bond, O, S, N(R₈₇), B(R₈₇), C(R₈₇ₐ)(R_{87b}), or Si(R₈₇ₐ)(R_{87b}),
in Formulae CY71-1(1) to CY71-1(8) and CY71-4(1) to CY71-4(32), each of X₈₆ and X₈₇ may not be a single bond at the same time,
X₈₈ may be a single bond, O, S, N(R₈₈), B(R₈₈), C(R₈₈ₐ)(R_{88b}), or Si(R₈₈ₐ)(R_{88b}),
X₈₉ may be a single bond, O, S, N(R₈₉), B(R₈₉), C(R₈₉ₐ)(R_{89b}), or Si(R₈₉ₐ)(R_{89b}),
in Formulae CY71-2(1) to CY71-2(8), CY71-3(1) to CY71-3(32), and CY71-5(1) to CY71-5(8), each of X₈₈ and X₈₉ may not be a single bond at the same time, and
R₈₆ to R₈₉, R₈₆ₐ, R_{86b}, R₈₇ₐ, R_{87b}, R₈₈ₐ, R_{88b}, R₈₉ₐ, and R_{89b} are each the same as described with respect to R₈₁.

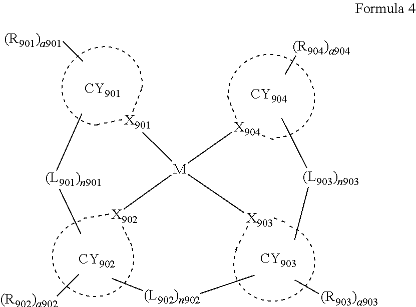

In Formula 4, M may be platinum (Pt), palladium (Pd), copper (Cu), silver (Ag), gold (Au), rhodium (Rh), ruthenium (Ru), osmium (Os), titanium (Ti), zirconium (Zr), hafnium (Hf), europium (Eu), terbium (Tb), or thulium (Tm).

In one or more embodiments, M may be Pt.

In Formula 4, X₉₀₁ to X₉₀₄ may each independently be C or N.

In one or more embodiments, X₉₀₁ may be C. For example, in some embodiments, X₉₀₁ in Formula 4 may be C, and C may be carbon of a carbene moiety.

In one or more embodiments, X₉₀₁ in Formula 4 may be N.

In one or more embodiments, each of X₉₀₂ and X₉₀₃ may be C, and X₉₀₄ may be N.

In Formula 4, i) a bond between X₉₀₁ and M may be a coordinate bond, ii) one selected from among a bond between X₉₀₂ and M, a bond between X₉₀₃ and M, and a bond between X₉₀₄ and M may be a coordinate bond, and the others thereof may each be a covalent bond.

For example, in one or more embodiments, each of a bond between X₉₀₁ and M and a bond between X₉₀₄ and M may be a coordinate bond, each of a bond between X₉₀₂ and M and a bond between X₉₀₃ and M may be a covalent bond.

In one or more embodiments, X₉₀₁ may be C, and a bond between X₉₀₁ and M may be a coordinate bond.

In Formula 4, ring CY₉₀₁ to CY₉₀₄ may each independently be a C₅-C₃₀ carbocyclic group or a C₁-C₃₀ heterocyclic group.

For example, in one or more embodiments, ring CY₉₀₁ may be a nitrogen-containing C₁-C₆₀ heterocyclic group.

In Formula 4, ring CY₉₀₁ may be i) a X₉₀₁-containing 5-membered ring, ii) a X₉₀₁-containing 5-membered ring condensed with at least one 6-membered ring, or iii) a X₉₀₁-containing 6-membered ring. In one or more embodiments, in Formula 4, ring CY₉₀₁ may be i) a X₉₀₁-containing 5-membered ring or ii) a X₉₀₁-containing 5-membered ring condensed with at least one 6-membered ring. For example, ring CY₉₀₁ may include a 5-membered ring bonded to M in Formula 4 via X₉₀₁. In this case, the X₉₀₁-containing 5-membered ring may be a pyrrole group, a pyrazole group, an imidazole group, a triazole group, an oxazole group, an isooxazole group, a thiazole group, an isothiazole group, an oxadiazole group, or a thiadiazole group, and a 6-membered ring that may be optionally condensed with the X₉₀₁-containing 5-membered ring, or the X₉₀₁-containing 6-membered ring may be a benzene group, a pyridine group, or a pyrimidine group.

In one or more embodiments, ring CY₉₀₁ may be a X₉₀₁-containing 5-membered ring, and the X₉₀₁-containing 5-membered ring may be an imidazole group or a triazole group.

In one or more embodiments, ring CY₉₀₁ may be a X₉₀₁-containing 5-membered ring condensed with at least one 6-membered ring, and the X₉₀₁-containing 5-membered ring condensed with at least one 6-membered ring may be a benzimidazole group or an imidazopyridine group.

In one or more embodiments, ring CY₉₀₁ may be an imidazole group, a triazole group, a benzimidazole group, or an imidazopyridine group.

In one or more embodiments, X₉₀₁ may be C, and ring CY₉₀₁ may be an imidazole group, a triazole group, a benzimidazole group, a naphthoimidazole group, or an imidazopyridine group.

In one or more embodiments, ring CY₉₀₂ may be a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

For example, in one or more embodiments, ring CY₉₀₂ may be a benzene group, a pyridine group, a pyrimidine group, a naphthalene group, a dibenzofuran group, a dibenzothiophene group, a carbazole group, a fluorene group, or a dibenzosilole group.

In Formula 4, ring CY₉₀₃ may be: a C₂-C₈ monocyclic group; or a C₄-C₂₀ polycyclic group in which two or three C₂-C₈ monocyclic groups are condensed with each other.

For example, in one or more embodiments, in Formula 4, ring CY₉₀₃ may be: a C₄-C₆ monocyclic group; or a C₄-C₈ polycyclic group in which two or three C₄-C₆ monocyclic groups are condensed with each other.

The C₂-C₈ monocyclic group as utilized herein refers to a non-condensed ring group, and may be, for example, a cyclopentadiene group, a pyrrole group, a pyrazole group, an imidazole group, a triazole group, an oxazole group, an isooxazole group, a thiazole group, an isothiazole group, an oxadiazole group, a thiadiazole group, a benzene group, a pyridine group, a pyrimidine group, a pyrazine group, a pyridazine group, a triazine group, a cycloheptadiene group, or a cyclooctadiene group.

For example, in one or more embodiments, ring CY₉₀₃ may be a benzene group, a pyridine group, a pyrimidine group, a naphthalene group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In Formula 4, ring CY₉₀₄ may be a nitrogen-containing C₁-C₆₀ heterocyclic group.

For example, in one or more embodiments, ring CY₉₀₄ may be a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, a benzopyrazole group, a benzimidazole group, or a benzothiazole group.

In Formula 4, L₉₀₁ to L₉₀₃ may each independently be a single bond, *—C(R₁ₐ)(R_{1b})—*′, *—C(R₁ₐ)═*′, *=C(R₁ₐ)—*′, *—C(R₁ₐ)═C(R_{1b})—*′, *—C(═O)—*′, *—C(═S)—*′, *—C≡C—*′, *—B(R₁ₐ)—*′, *—N(R₁ₐ)—*′, *—O—*′, *—P(R₁ₐ)—*′, *—Si(R₁ₐ)(R_{1b})—*′, *—P(═O)(R₁ₐ)—*′, *—S—*′, *—S(═O)—*′, *—S(═O)₂—*′, or *—Ge(R₁ₐ)(R_{1b})—*′, and * and *′ each indicate a binding site to a neighboring atom.

R₁ₐ and R_{1b} are each the same as described in the present disclosure.

In one or more embodiments, each of L₉₀₁ and L₉₀₃ is a single bond, and L₉₀₂ may be *—C(R₁ₐ)(R_{1b})—*′, *—B(R₁ₐ)—*′, *—N(R₁ₐ)—*′, *—O—*′, *—P(R₁ₐ)—*′, *—Si(R₁ₐ)(R_{1b})—*′, or *—S—*′.

In one or more embodiments, L₉₀₂ may be *—O—*′ or *—S—*′.

In Formula 4, n901 to n903 indicate the number of L₉₀₁ to the number of L₉₀₃, respectively, and may each independently be an integer from 1 to 5. When n901 to n903 are each 2 or more, two or more of each of L₉₀₁(s) to L₉₀₃(s) may be identical to or different from each other.

In one or more embodiments, n902 may be 1.

In Formula 4, R₉₀₁ to R₉₀₄, R₁ₐ, and R_{1b} may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

R₁₀ₐ, Q₁, Q₂, and Q₃ are each the same as described in the present disclosure.

In one or more embodiments, R₉₀₁ to R₉₀₄, R₁ₐ, and R_{1b} may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂).

Q₁ to Q₃ and Q₃₁ to Q₃₃ are each the same as described in the present disclosure.

In one or more embodiments, R₉₀₁ to R₉₀₄, R₁ₐ, and R_{1b} may each independently be:
hydrogen, deuterium, —F, —Cl, —Br, —I, or a C₁-C₂₀ alkyl group;
a C₁-C₂₀ alkyl group that is unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof; or
a phenyl group, a biphenyl group, a terphenyl group, a (C₁-C₁ alkyl)phenyl group, or a naphthyl group, each unsubstituted or substituted with deuterium, —F, —Cl, —Br, —I, —CD₃, —CD₂H, —CDH₂, —CF₃, —CF₂H, —CFH₂, a C₁-C₂₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, a (C₁-C₁ alkyl)phenyl group, or any combination thereof.

In Formula 4, a901 to a904 indicate the number of R₉₀₁ to the number of R₉₀₄, respectively, and may each independently be an integer from 1 to 10. When a901 to a904 are each 2 or more, two or more of each of R₉₀₁(s) to R₉₀₄(s) may be identical to or different from each other.

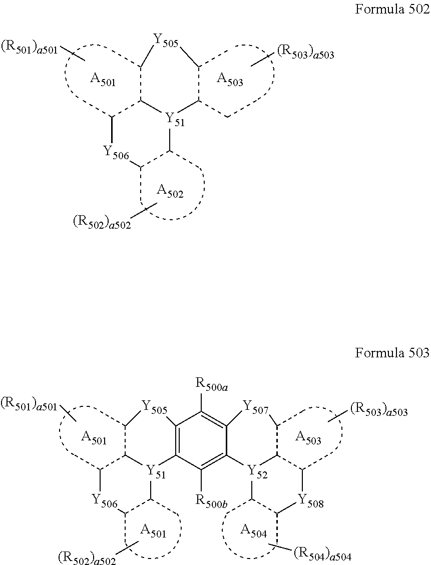

In Formulae 502 and 503, ring A₅₀₁ to ring A₅₀₄ may each independently be a C₃-C₆₀ carbocyclic group or a C₁-C₆₀ heterocyclic group.

In Formulae 502 and 503, Y₅₀₅ may be O, S, N(R₅₀₅), B(R₅₀₅), C(R₅₀₅ₐ)(R_{505b}), or Si(R₅₀₅ₐ)(R_{505b}).

In Formulae 502 and 503, Y₅₀₆ may be O, S, N(R₅₀₆), B(R₅₀₆), C(R₅₀₆ₐ)(R_{506b}), or Si(R₅₀₆ₐ)(R_{506b}).

In Formula 503, Y₅₀₇ may be O, S, N(R₅₀₇), B(R₅₀₇), C(R₅₀₇ₐ)(R_{507b}), or Si(R₅₀₇ₐ)(R_{507b}).

In Formula 503, Y₅₀₈ may be O, S, N(R₅₀₈), B(R₅₀₈), C(R₅₀₈ₐ)(R_{508b}), or Si(R₅₀₈ₐ)(R_{508b}).

In Formulae 502 and 503, Y₅₁ and Y₅₂ may each independently be B, P(═O), or S(═O).

In Formulae 502 and 503, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} are each the same as described in the present disclosure.

In Formulae 502 and 503, a501 to a504 indicate the number of R₅₀₁ to the number of R₅₀₄, respectively, and may each independently be an integer from 0 to 20. If (e.g., when) a501 is 2 or more, two or more of R₅₀₁(s) may be identical to or different from each other, if (e.g., when) a502 is 2 or more, two or more of R₅₀₂(s) may be identical to or different from each other, if (e.g., when) a503 is 2 or more, two or more of R₅₀₃(s) may be identical to or different from each other, and if (e.g., when) a504 is 2 or more, two or more of R₅₀₄(s) may be identical to or different from each other. a501 to a504 may each independently be an integer from 0 to 8.

In one or more embodiments, R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, R_{508b}, and R₉₀₁ to R₉₀₄ may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, a C₇-C₆₀ arylalkyl group that is unsubstituted or substituted with at least one R₁₀ₐ, a C₂-C₆₀ heteroarylalkyl group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ are each the same as described in the present disclosure.

For example, in one or more embodiments, i) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, R_{508b}, and R₉₀₁ to R₉₀₄ in Formulae 2, 3-1 to 3-5, 4, 502, and 503 and ii) R₁₀ₐ may each independently be:
hydrogen, deuterium, —F, —Cl, —Br, —I, a hydroxyl group, a cyano group, a nitro group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzothiazolyl group, a benzoisoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

In one or more embodiments, i) R₁₁, R₁₂, R₂₁, R₂₂, R₃ and Y₂₁ to Y₂₃ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, R_{508b}, and R₉₀₁ to R₉₀₄ in Formulae 2, 3-1 to 3-5, 4, 502 and 503, and iii) R₁₀ₐ may each independently be:
hydrogen, deuterium, —F, a cyano group, a nitro group, —CH₃, —CD₃, —CD₂H, —CDH₂, —CF₃, —CF₂H, or —CFH₂;
a group represented by one of Formulae 9-1 to 9-19; or
a group represented by one of Formulae 10-1 to 10-246, —C(Q₁)(Q₂)(Q₃), —Si(Q₁)(Q₂)(Q₃), or —P(═O)(Q₁)(Q₂) (wherein Q₁ to Q₃ are each the same as described in the present disclosure):

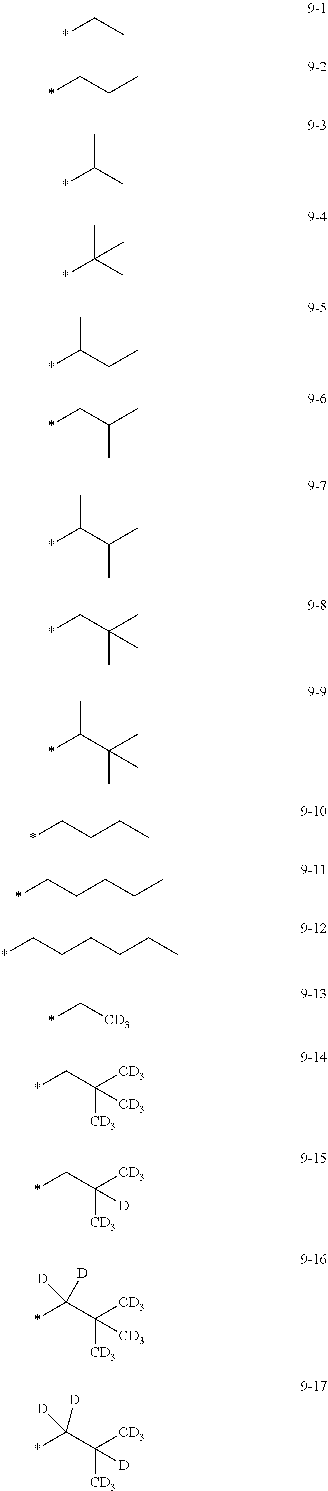

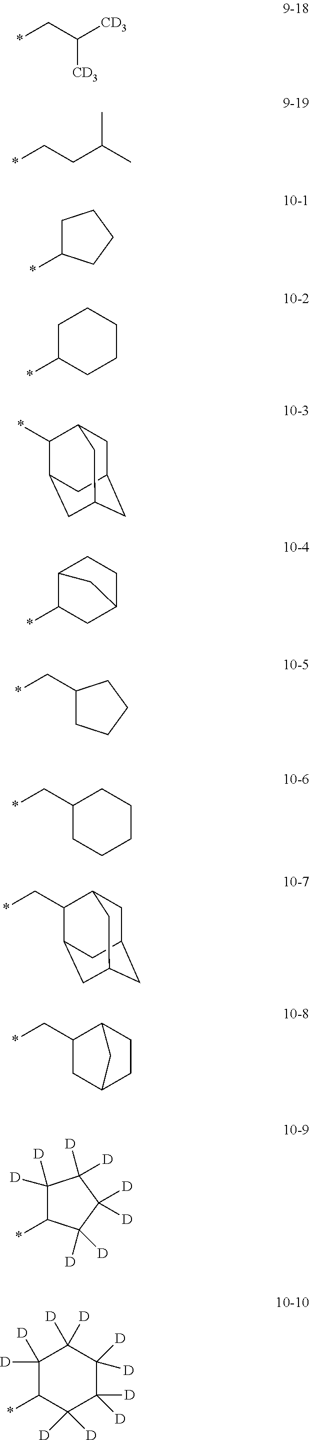

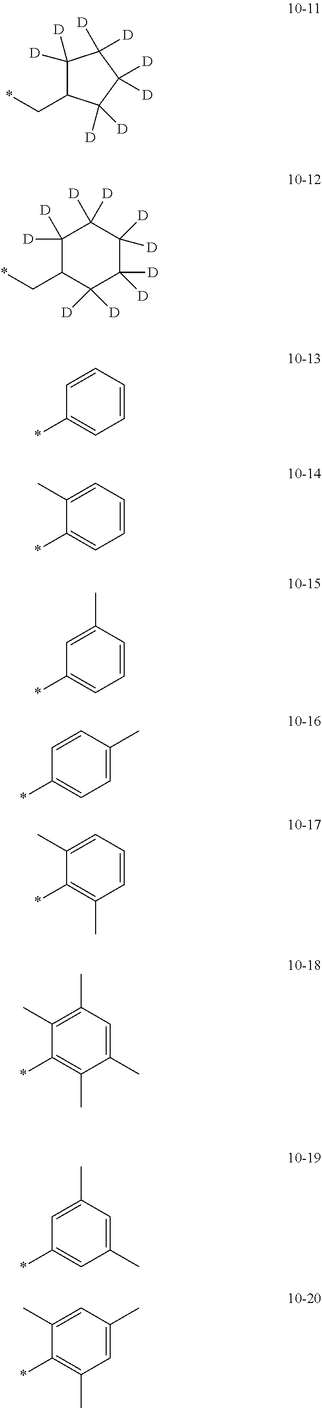

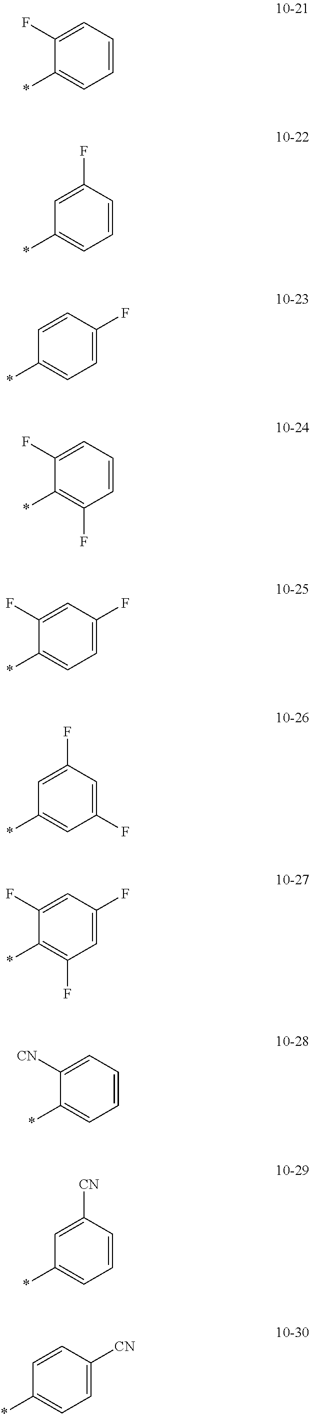

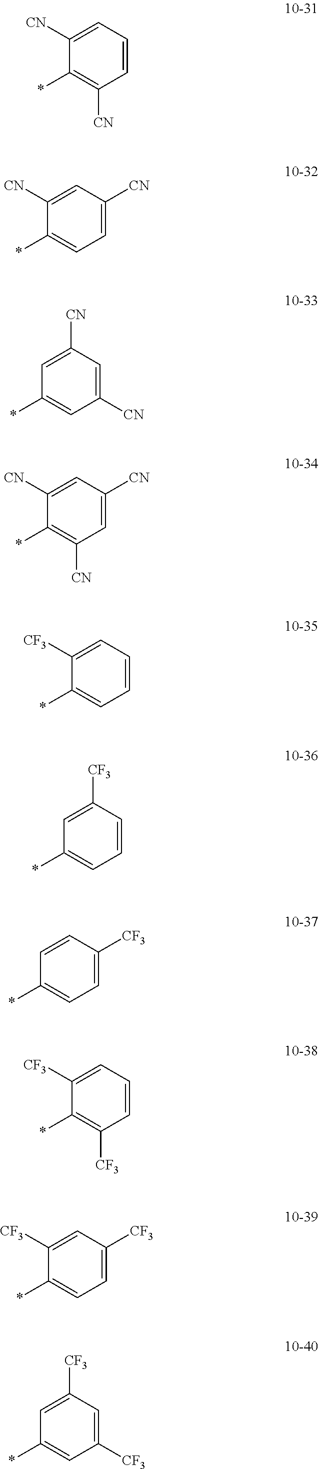

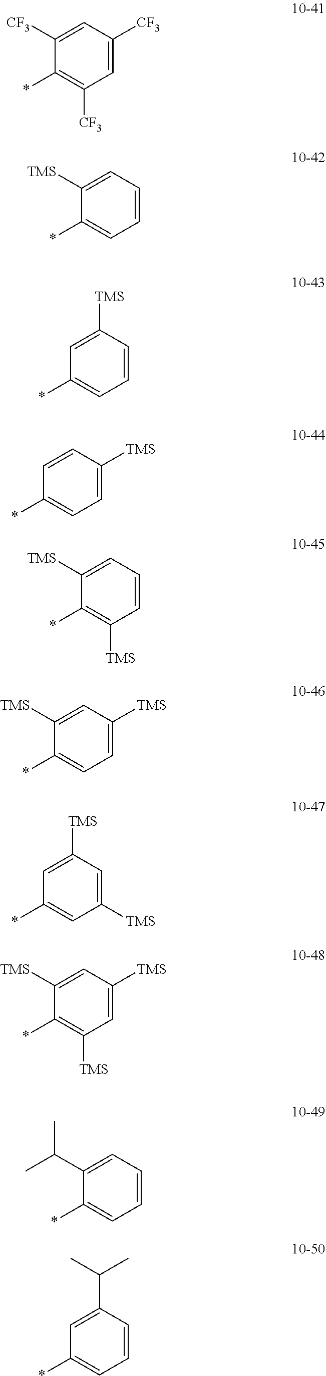

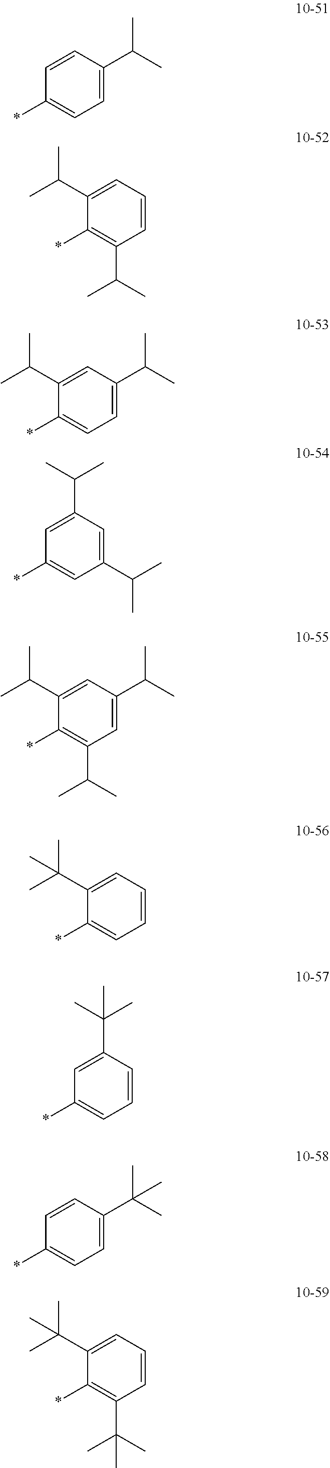

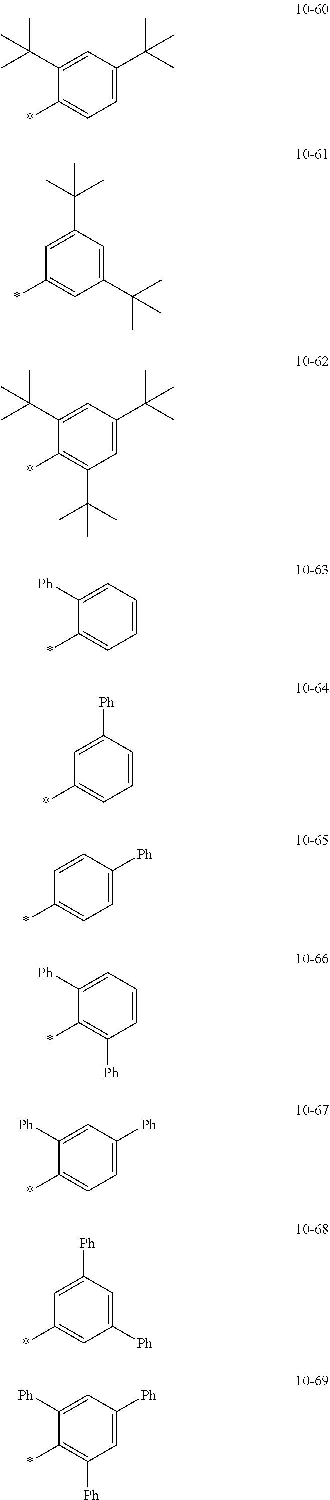

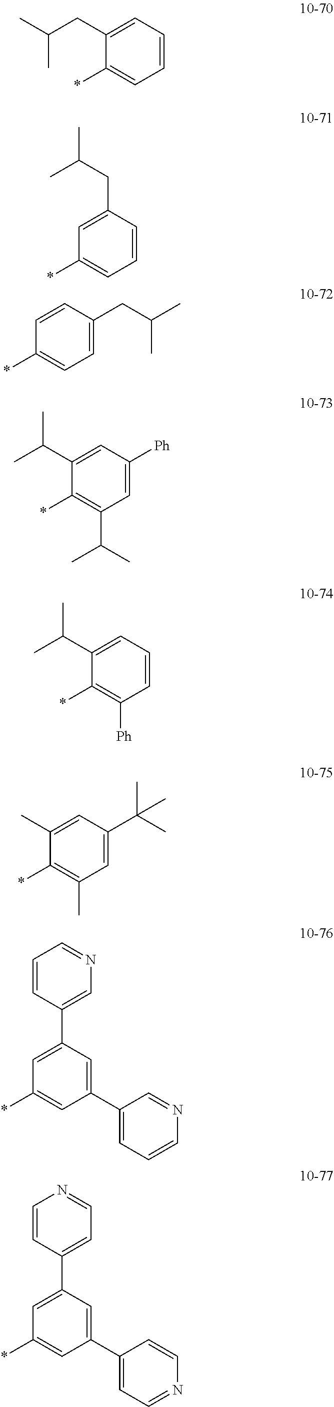

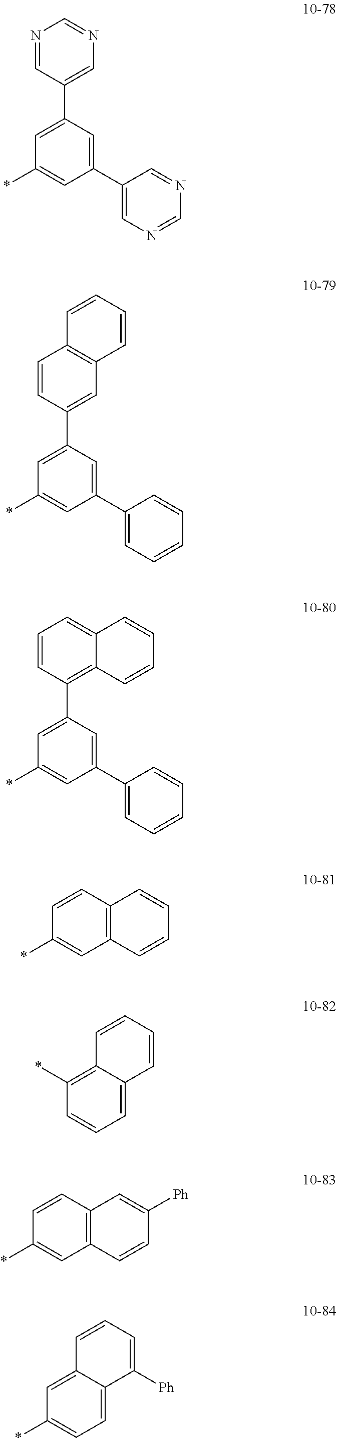

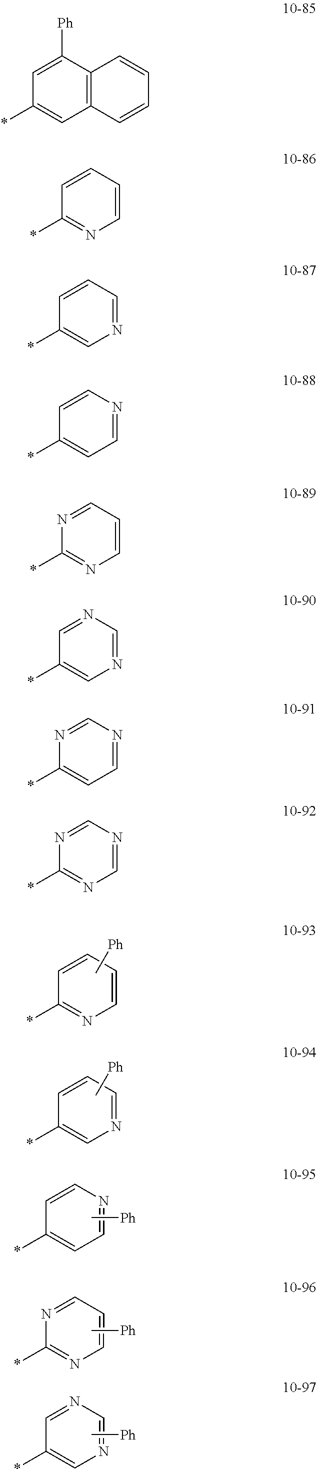

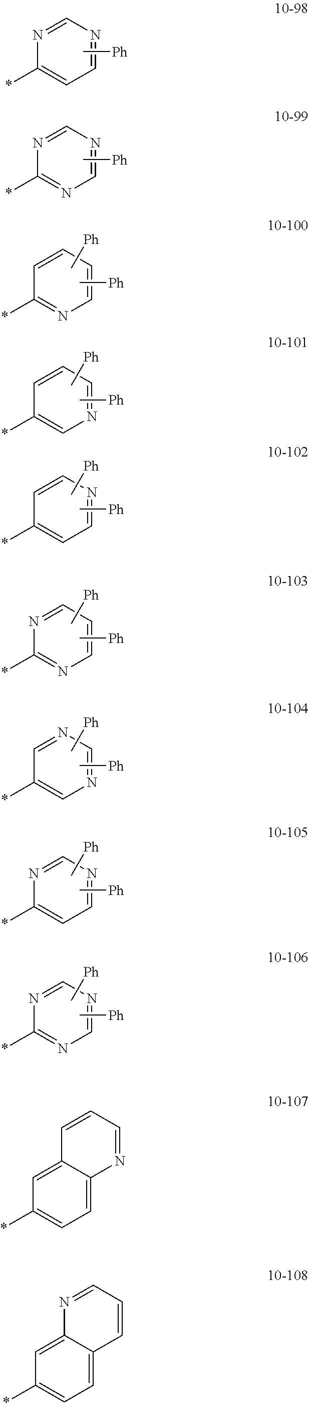

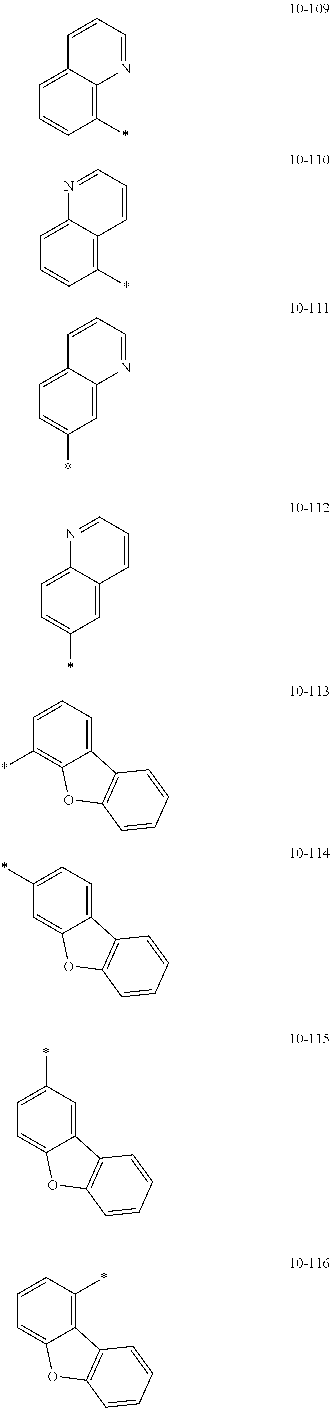

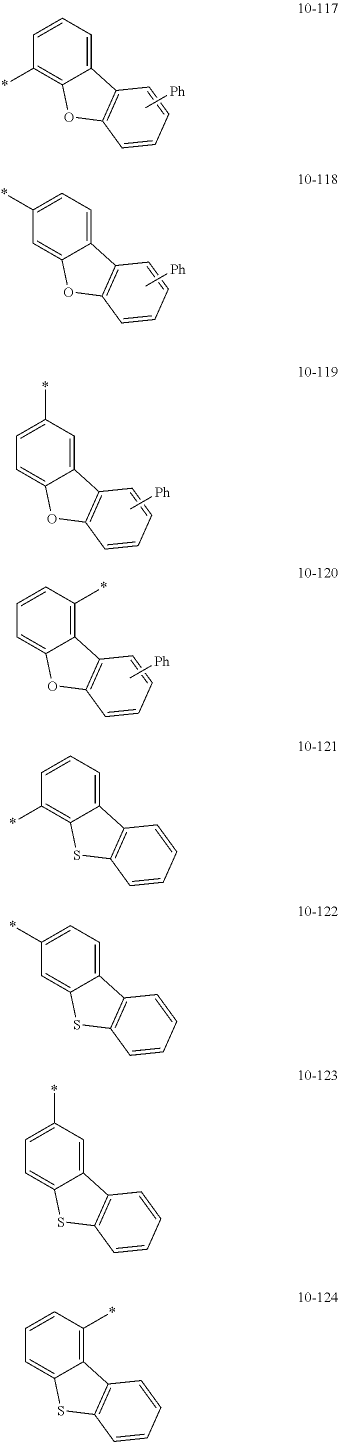

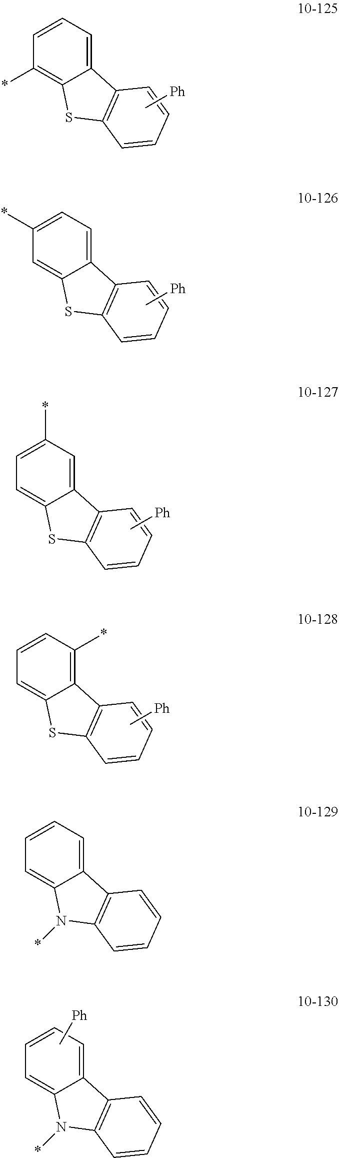

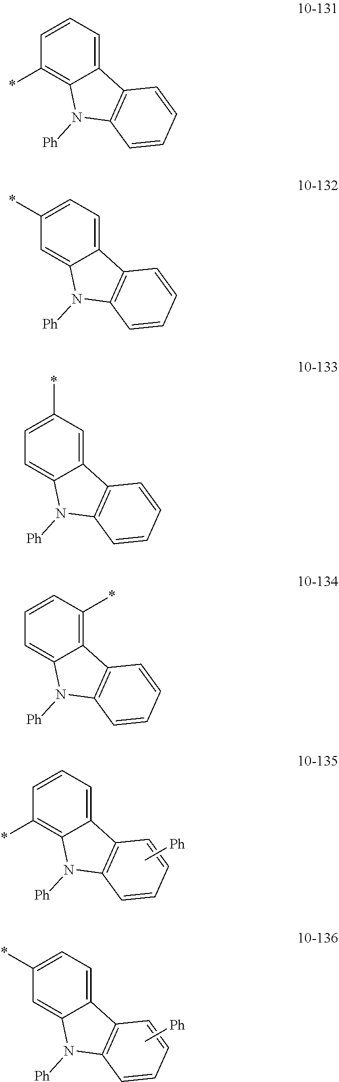

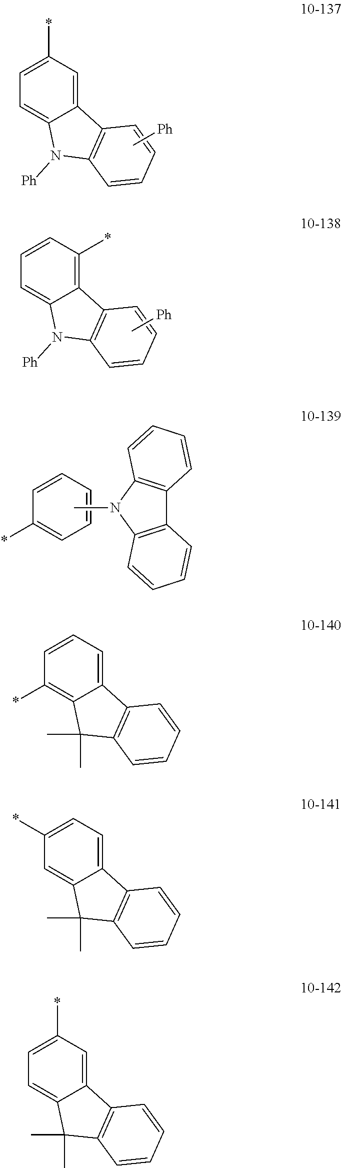

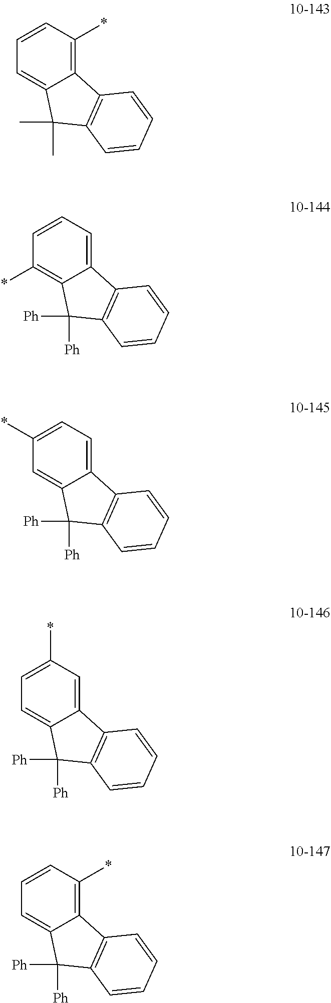

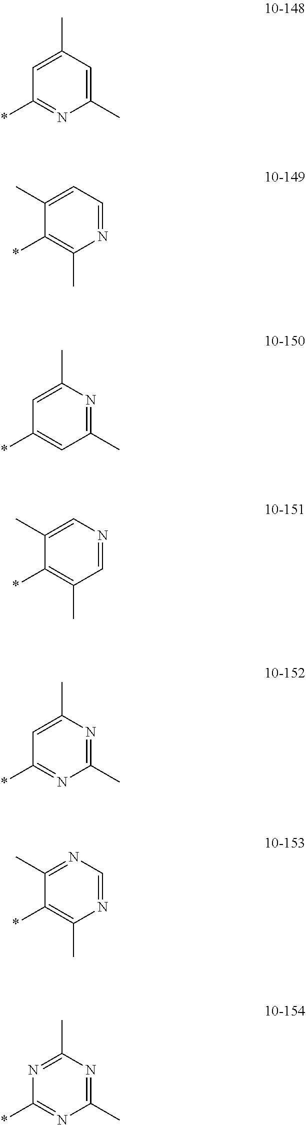

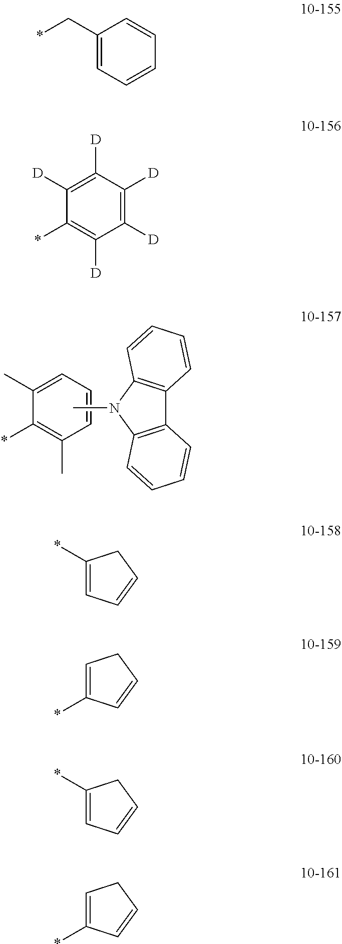

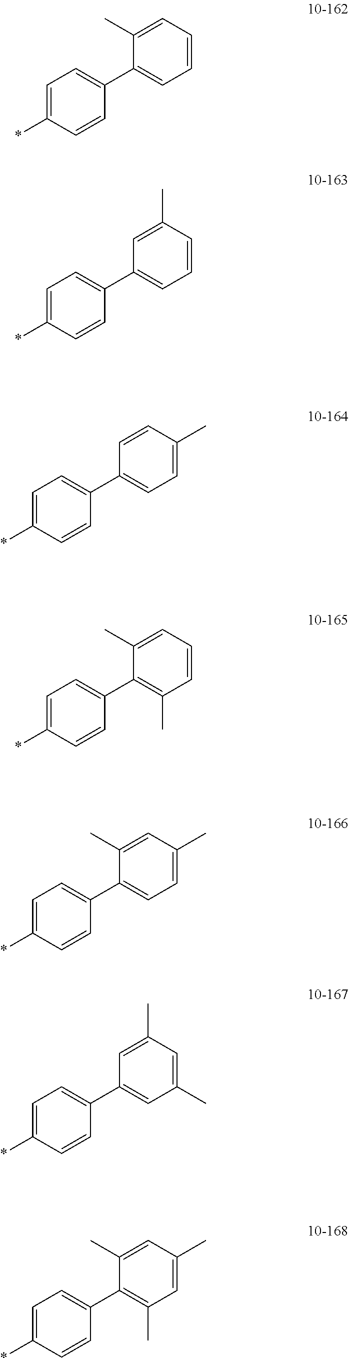

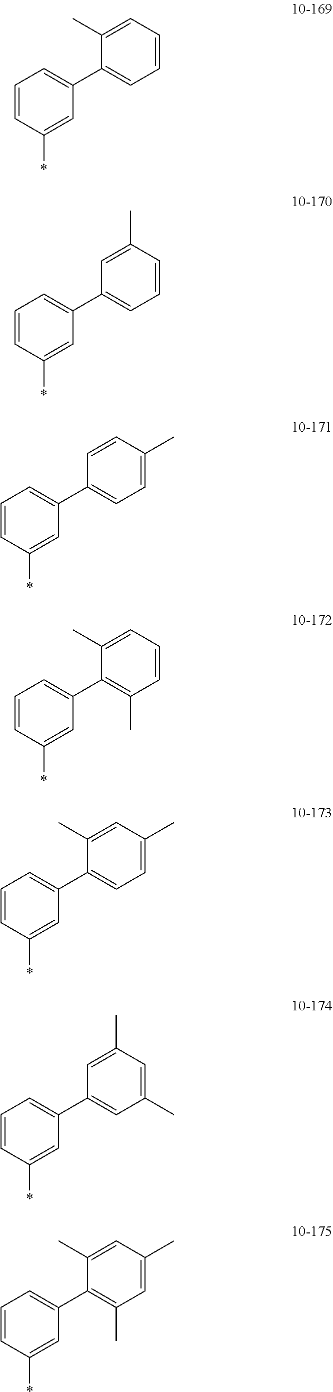

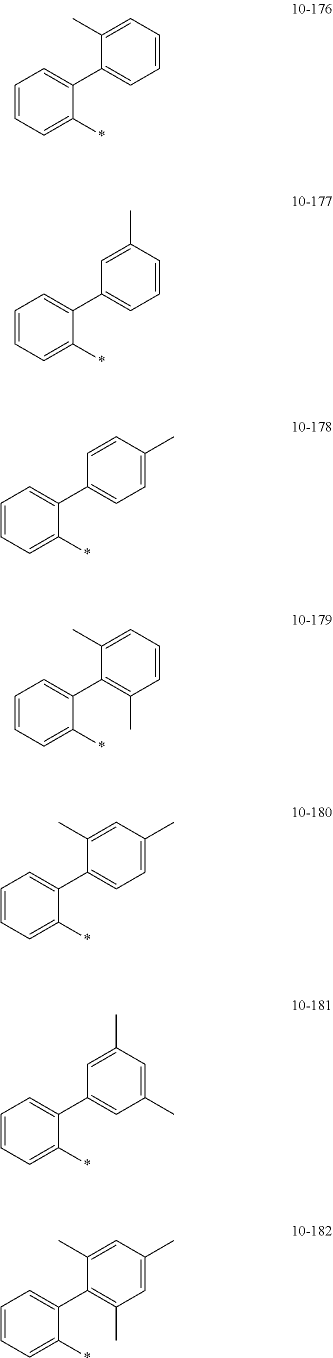

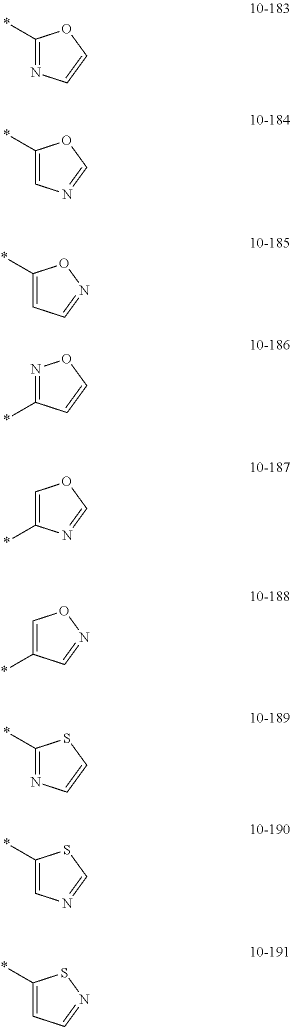

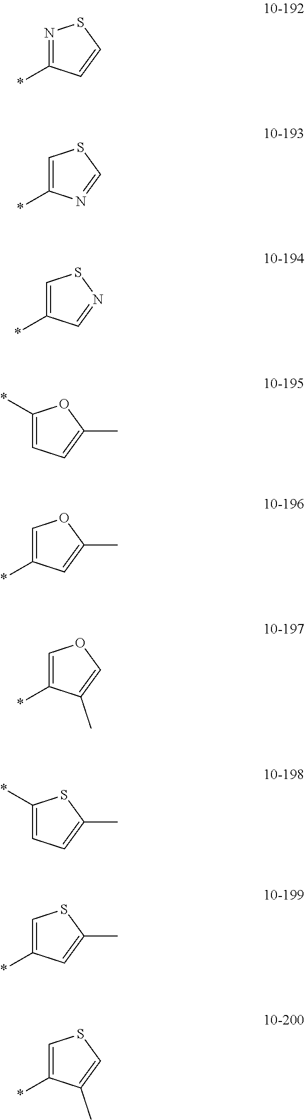

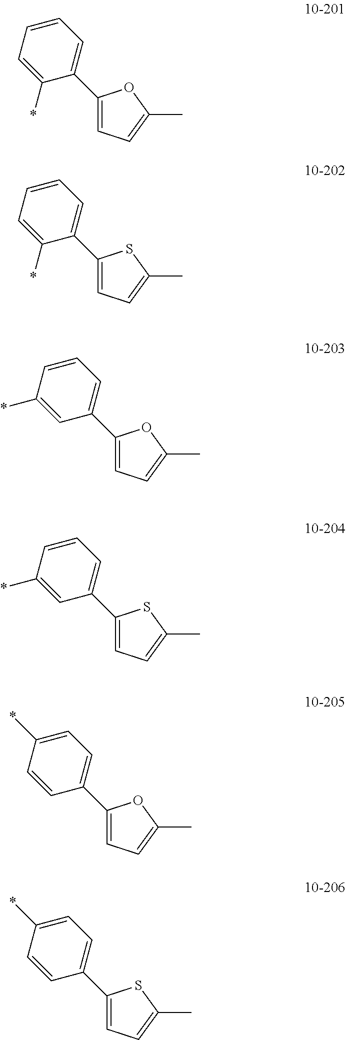

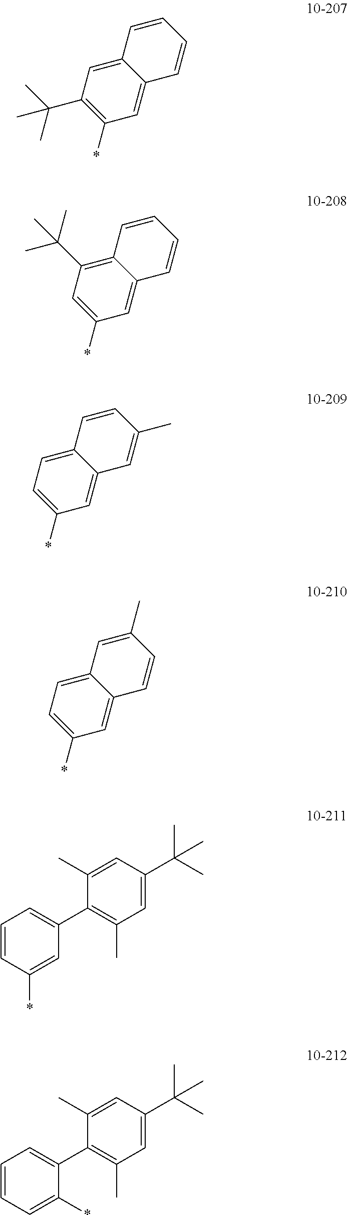

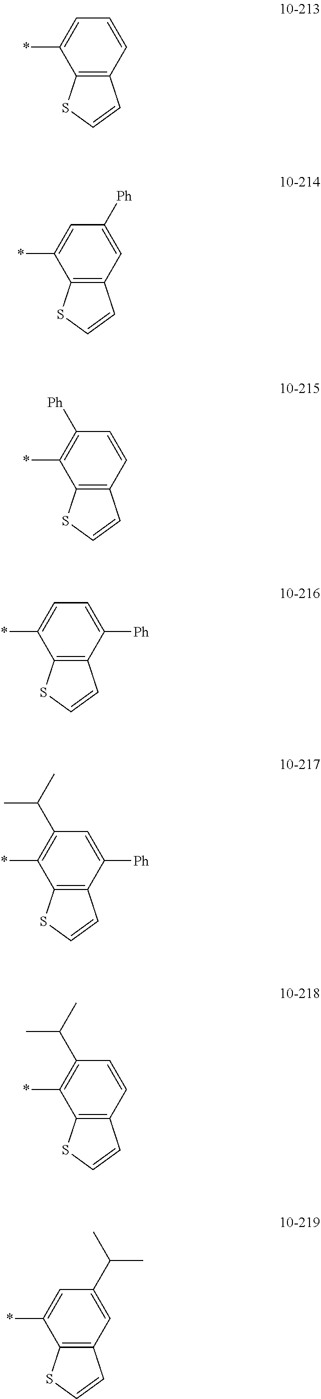

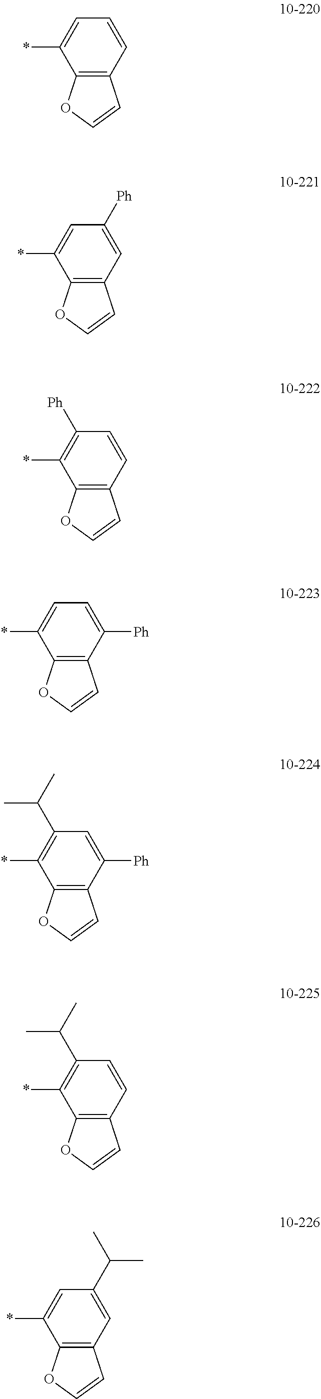

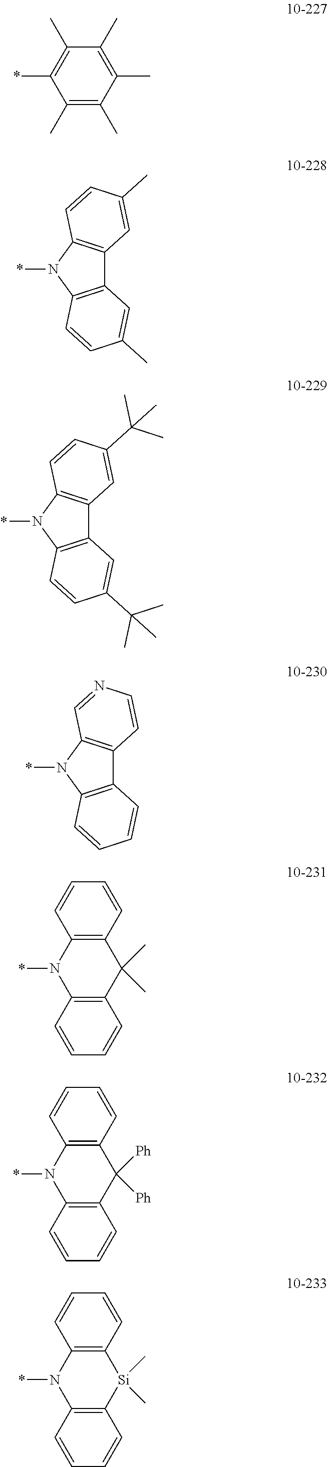

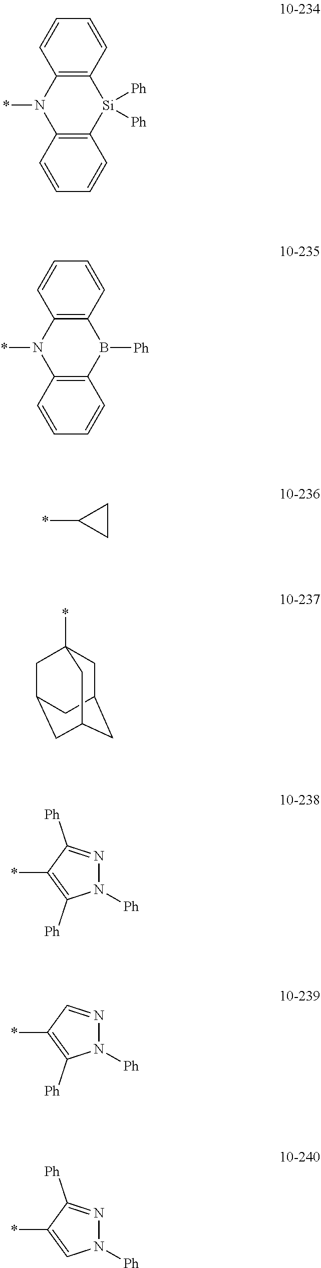

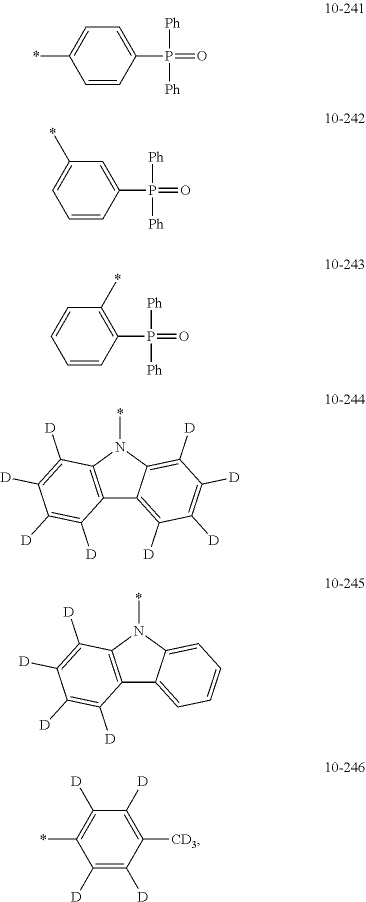

wherein, in Formulae 9-1 to 9-19 and 10-1 to 10-246, * indicates a binding site to a neighboring atom, “Ph” represents a phenyl group, “D” represents deuterium, and “TMS” represents a trimethylsilyl group.

### Examples of Compounds

In one or more embodiments, the heterocyclic compound represented by Formula 1 may be any one selected from among Compounds 1 to 355:

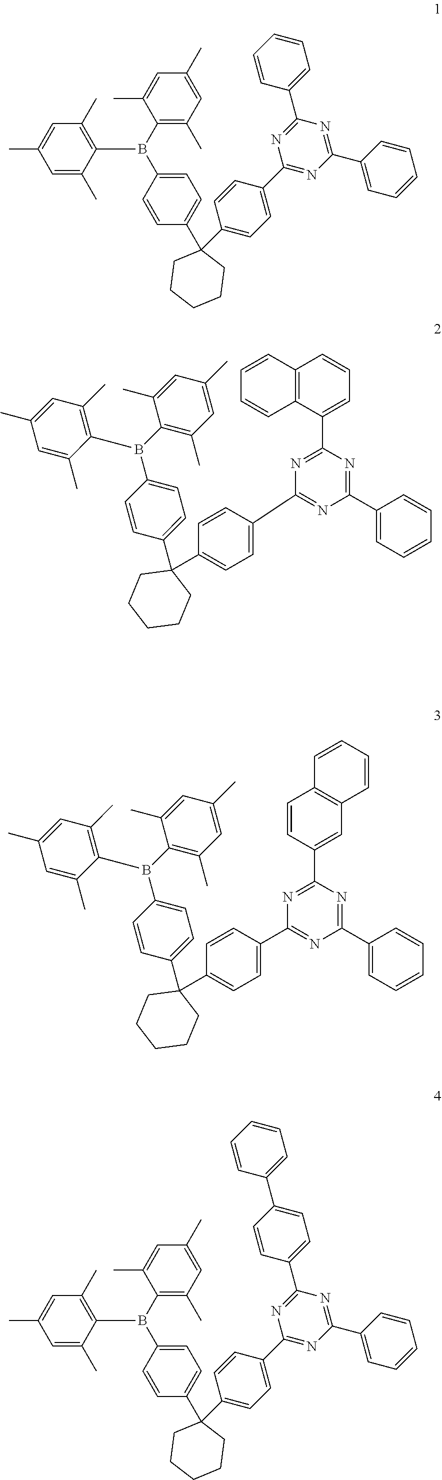 [SMILES: Cc1cc(C)c(B(c2ccc(C3(c4ccc(-c5nc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc(-c7ccccc7)cc6)n5)cc4)CCCCC3)cc2)c2c(C)cc(C)cc2C)c(C)c1]

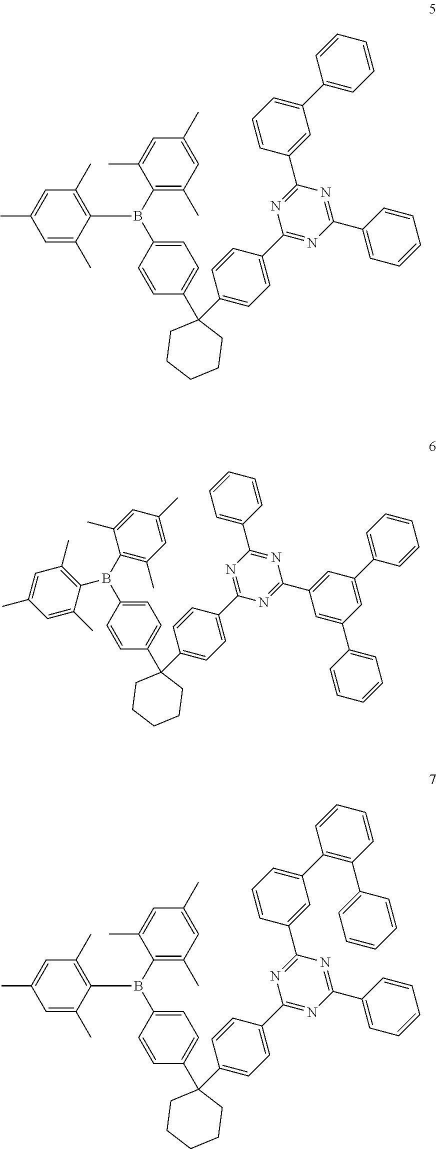 [SMILES: Cc1cc(C)c(B(c2ccc(C3(c4ccc(-c5nc(-c6ccccc6)nc(-c6cccc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cc(-c7ccccc7)cc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7-c7ccccc7)c6)n5)cc4)CCCCC3)cc2)c2c(C)cc(C)cc2C)c(C)c1]

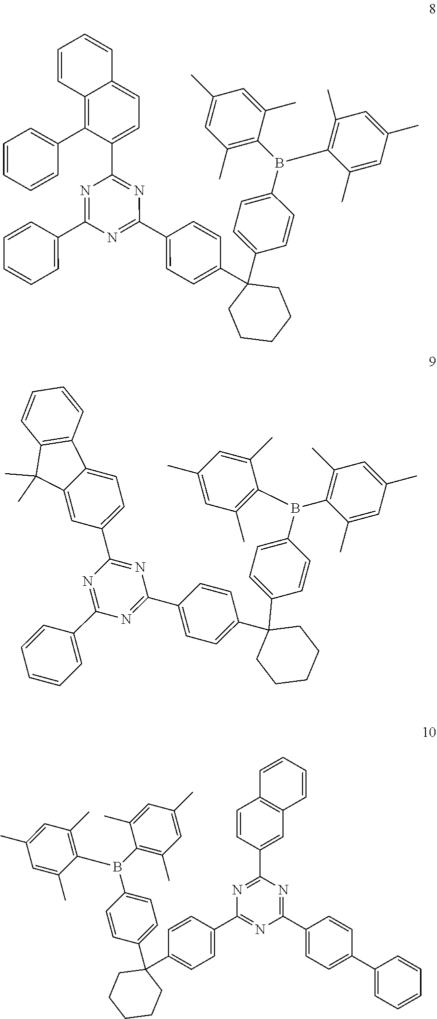

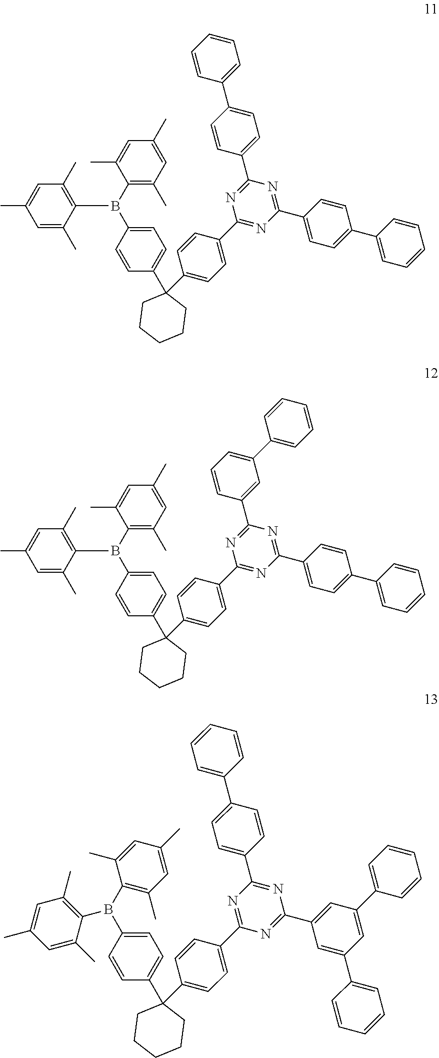 [SMILES: Cc1cc(C)c(B(c2ccc(C3(c4ccc(-c5nc(-c6ccc(-c7ccccc7)cc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cc(-c7ccccc7)cc(-c7ccccc7)c6)n5)cc4)CCCCC3)cc2)c2c(C)cc(C)cc2C)c(C)c1]

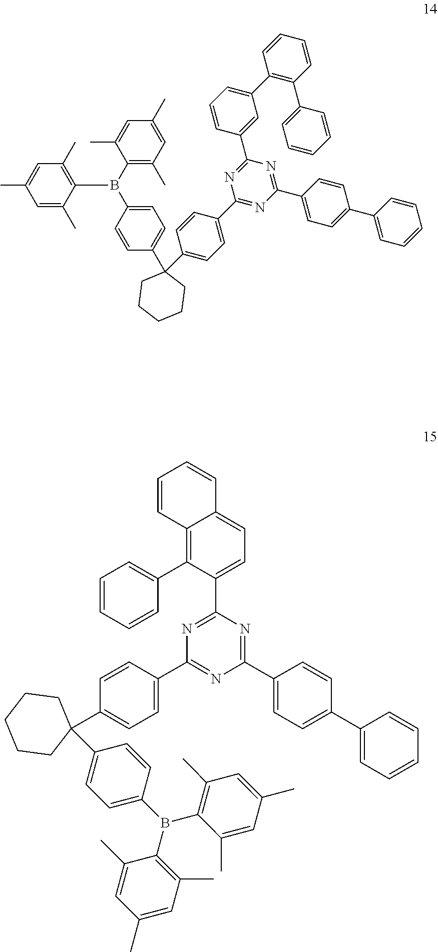 [SMILES: Cc1cc(C)c(B(c2ccc(C3(c4ccc(-c5nc(-c6ccc(-c7ccccc7)cc6)nc(-c6cccc(-c7ccccc7-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc7ccccc7c6-c6ccccc6)n5)cc4)CCCCC3)cc2)c2c(C)cc(C)cc2C)c(C)c1]

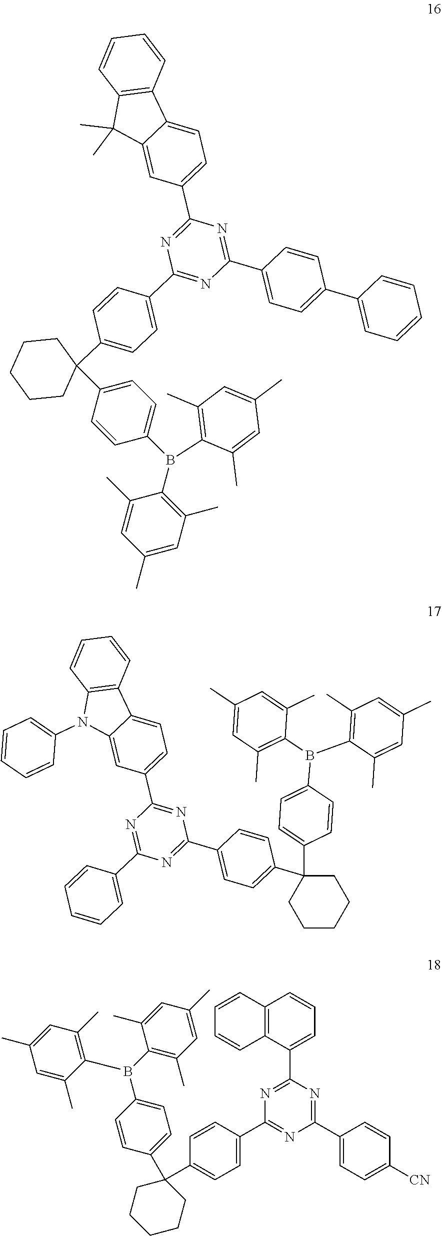

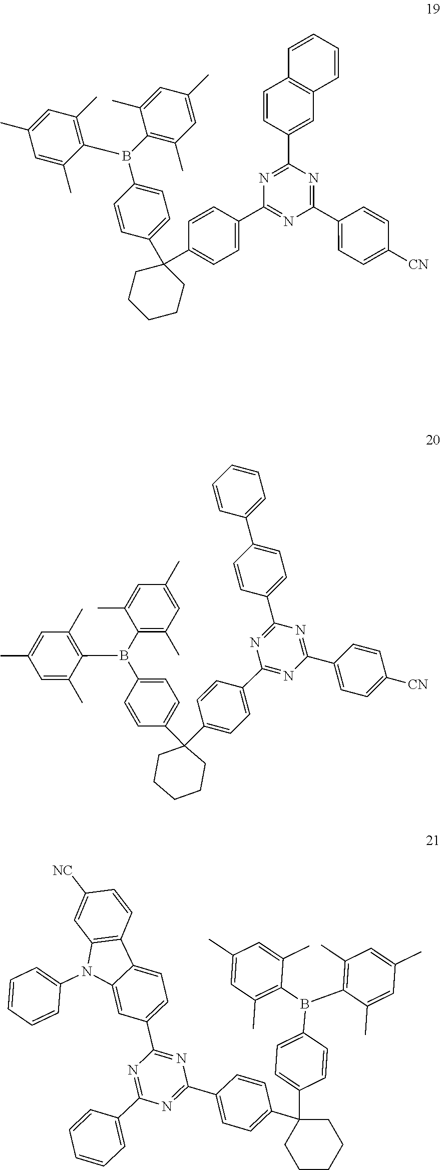 [SMILES: Cc1cc(C)c(B(c2ccc(C3(c4ccc(-c5nc(-c6ccc(C#N)cc6)nc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5nc(-c6ccc(C#N)cc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc7c8ccc(C#N)cc8n(-c8ccccc8)c7c6)n5)cc4)CCCCC3)cc2)c2c(C)cc(C)cc2C)c(C)c1]

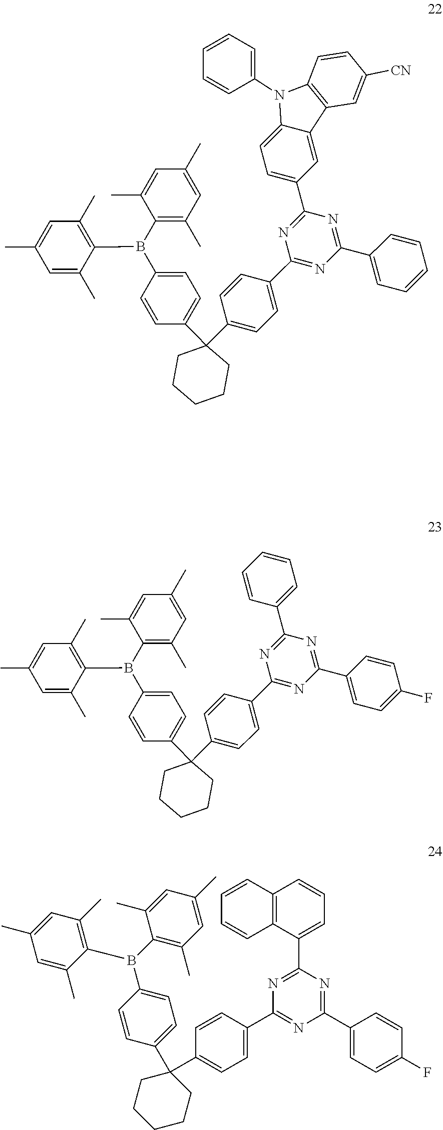 [SMILES: Cc1cc(C)c(B(c2ccc(C3(c4ccc(-c5nc(-c6ccccc6)nc(-c6ccc7c(c6)c6cc(C#N)ccc6n7-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccc(F)cc6)n5)cc4)CCCCC3)cc2)c2c(C)cc(C)cc2C)c(C)c1 ; Cc1cc(C)c(B(c2ccc(C3(c4ccc(-c5nc(-c6ccc(F)cc6)nc(-c6cccc7ccccc67)n5)cc4)CCCCC3)cc2)c2c(C)cc(C)cc2C)c(C)c1]

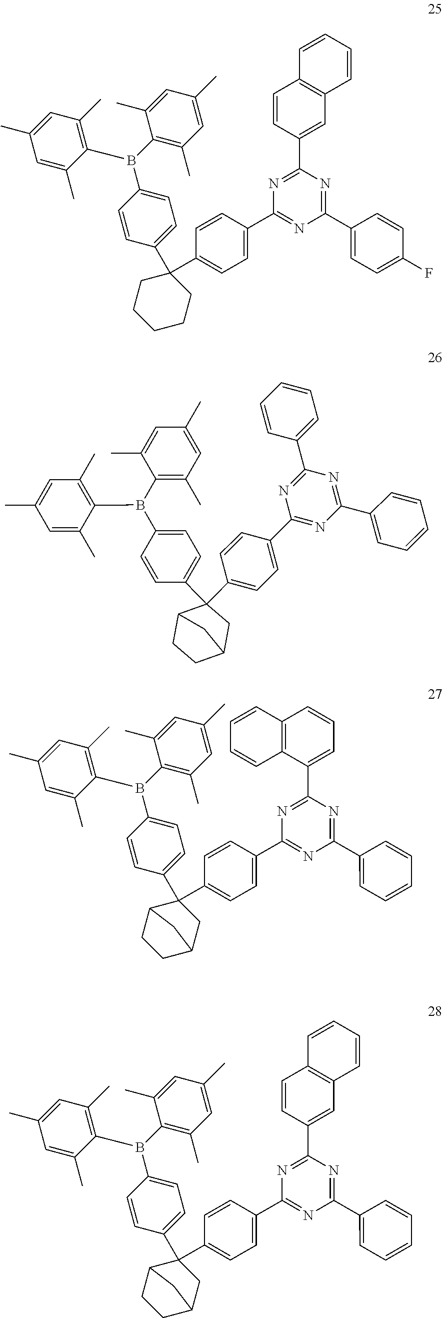 [SMILES: Cc1cc(C)c(B(c2ccc(C3(c4ccc(-c5nc(-c6ccc(F)cc6)nc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccccc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6)n5)cc4)CC4CCC3C4)cc2)c2c(C)cc(C)cc2C)c(C)c1]

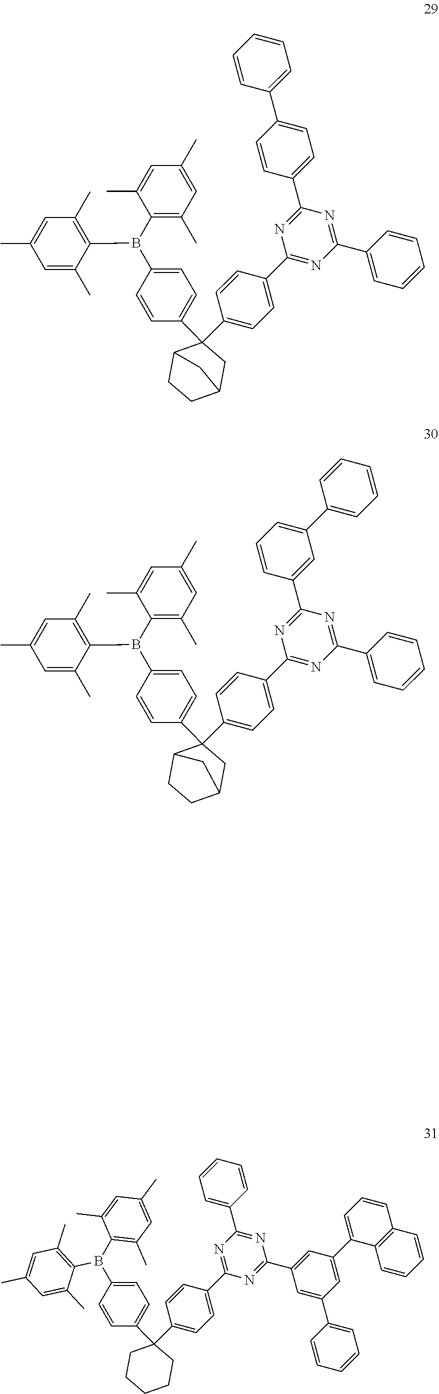 [SMILES: Cc1cc(C)c(B(c2ccc(C3(c4ccc(-c5nc(-c6ccccc6)nc(-c6ccc(-c7ccccc7)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7)c6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6cc(-c7ccccc7)cc(-c7cccc8ccccc78)c6)n5)cc4)CCCCC3)cc2)c2c(C)cc(C)cc2C)c(C)c1]

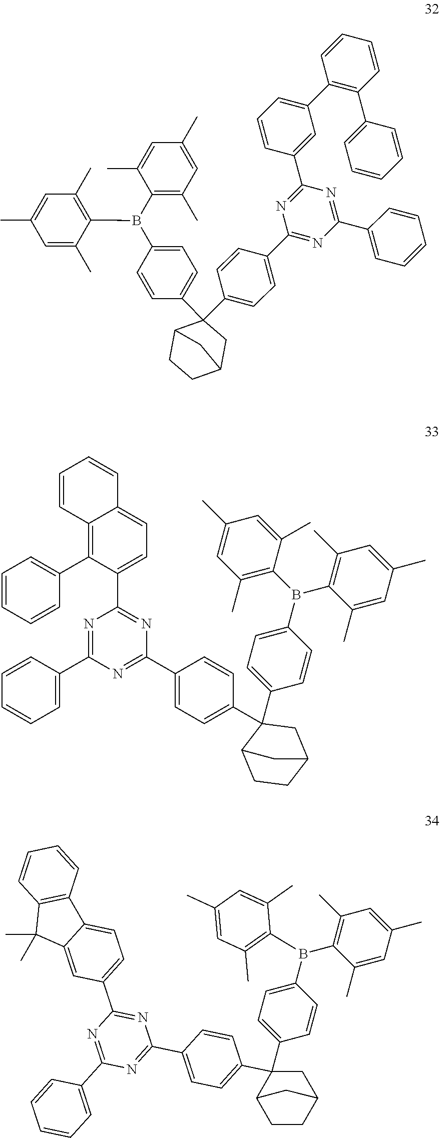

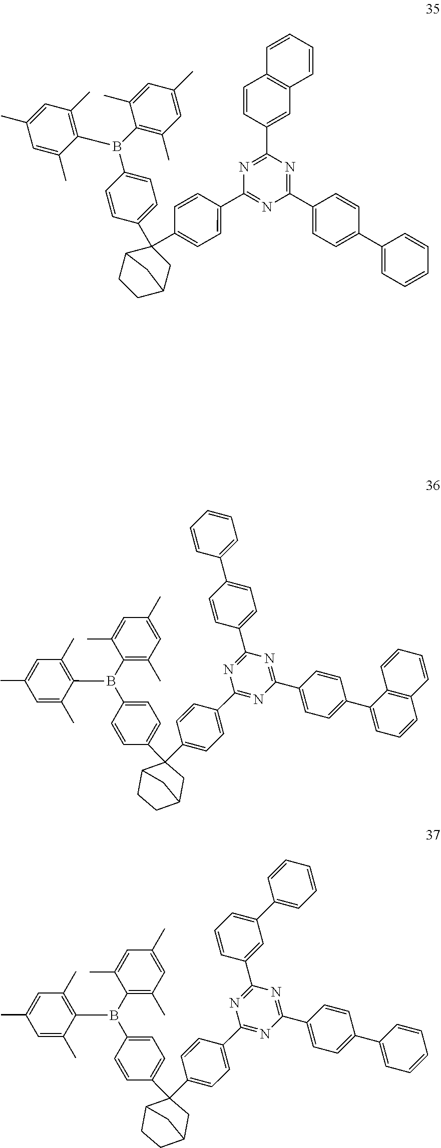 [SMILES: Cc1cc(C)c(B(c2ccc(C3(c4ccc(-c5nc(-c6ccc(-c7ccccc7)cc6)nc(-c6ccc7ccccc7c6)n5)cc4)CC4CCC3C4)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc(-c7cccc8ccccc78)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7)c6)n5)cc4)CC4CCC3C4)cc2)c2c(C)cc(C)cc2C)c(C)c1]

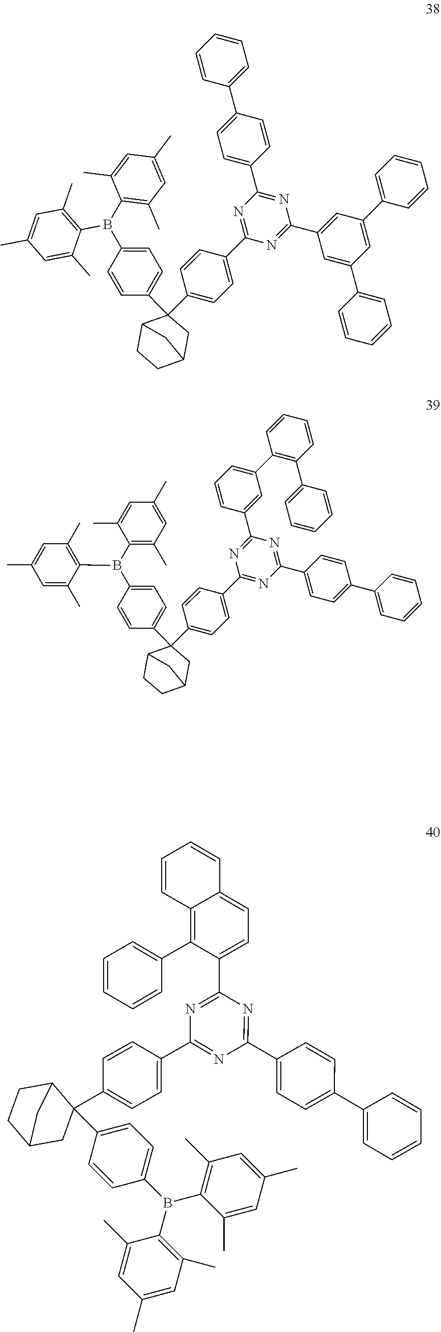 [SMILES: Cc1cc(C)c(B(c2ccc(C3(c4ccc(-c5nc(-c6ccc(-c7ccccc7)cc6)nc(-c6cc(-c7ccccc7)cc(-c7ccccc7)c6)n5)cc4)CC4CCC3C4)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7-c7ccccc7)c6)n5)cc4)CC4CCC3C4)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc7ccccc7c6-c6ccccc6)n5)cc4)CC4CCC3C4)cc2)c2c(C)cc(C)cc2C)c(C)c1]

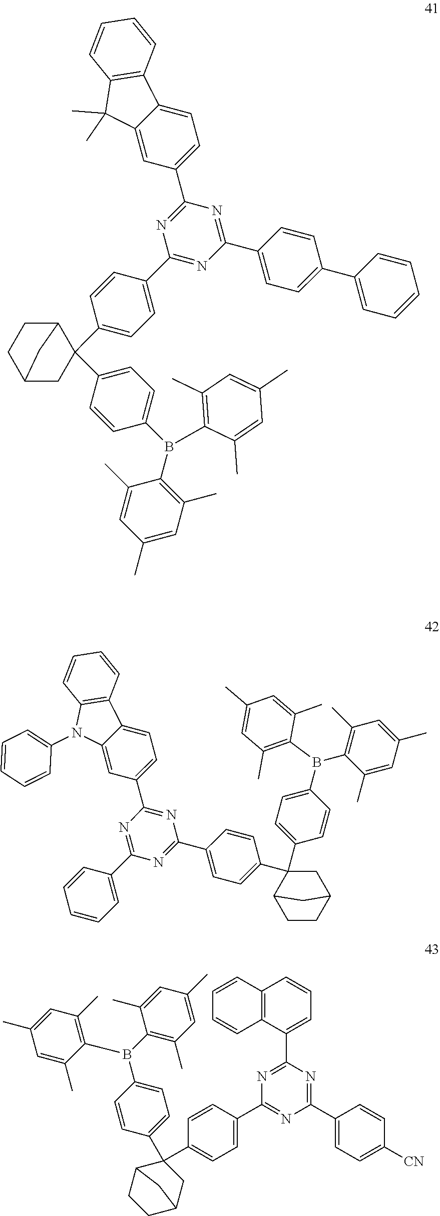

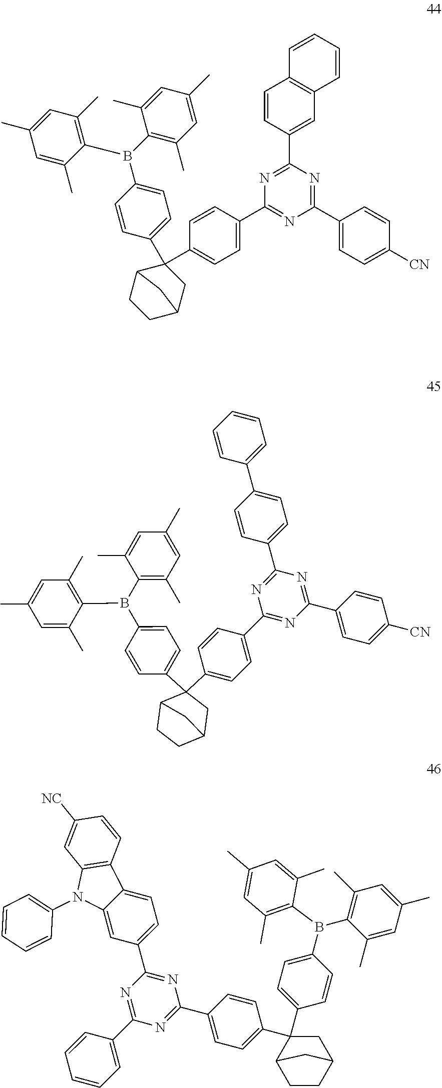 [SMILES: Cc1cc(C)c(B(c2ccc(C3(c4ccc(-c5nc(-c6ccc(C#N)cc6)nc(-c6ccc7ccccc7c6)n5)cc4)CC4CCC3C4)cc2)c2c(C)cc(C)cc2C)c(C)c1 ; Cc1cc(C)c(B(c2ccc(C3(c4ccc(-c5nc(-c6ccc(C#N)cc6)nc(-c6ccc(-c7ccccc7)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6ccc7c8ccc(C#N)cc8n(-c8ccccc8)c7c6)n5)cc4)CC4CCC3C4)cc2)c2c(C)cc(C)cc2C)c(C)c1]

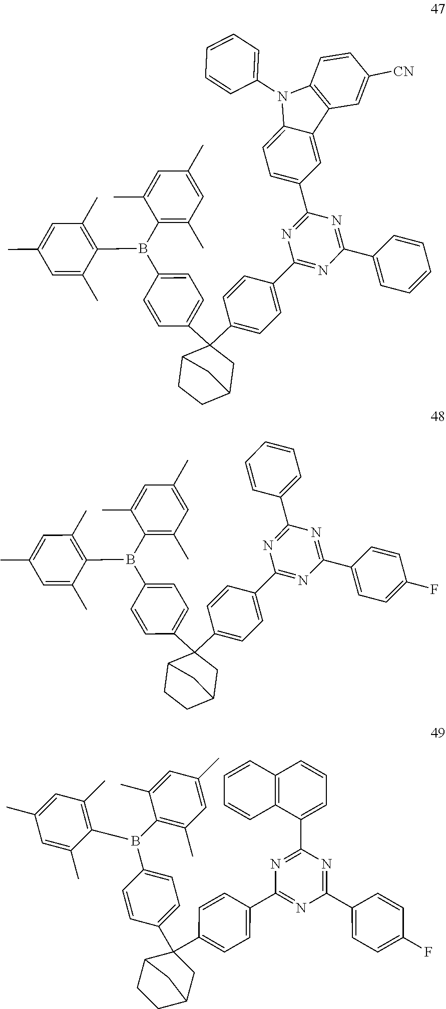 [SMILES: Cc1cc(C)c(B(c2ccc(C3(c4ccc(-c5nc(-c6ccccc6)nc(-c6ccc7c(c6)c6cc(C#N)ccc6n7-c6ccccc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6ccc(F)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccc(F)cc6)nc(-c6cccc7ccccc67)n5)cc4)CC4CCC3C4)cc2)c2c(C)cc(C)cc2C)c(C)c1]

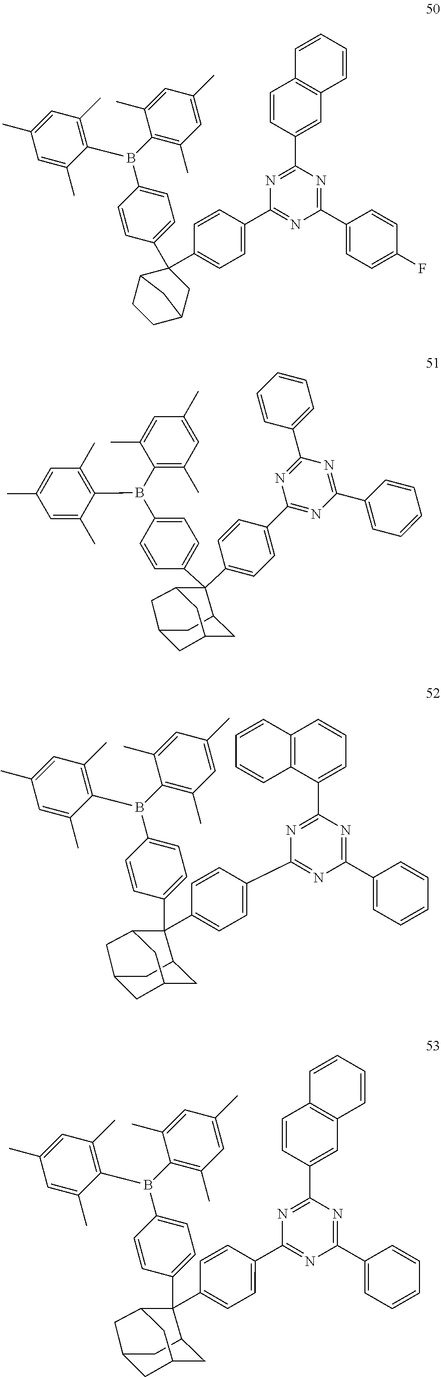 [SMILES: Cc1cc(C)c(B(c2ccc(C3(c4ccc(-c5nc(-c6ccc(F)cc6)nc(-c6ccc7ccccc7c6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)nc(-c6ccccc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6)n5)cc4)C4CC5CC(C4)CC3C5)cc2)c2c(C)cc(C)cc2C)c(C)c1]

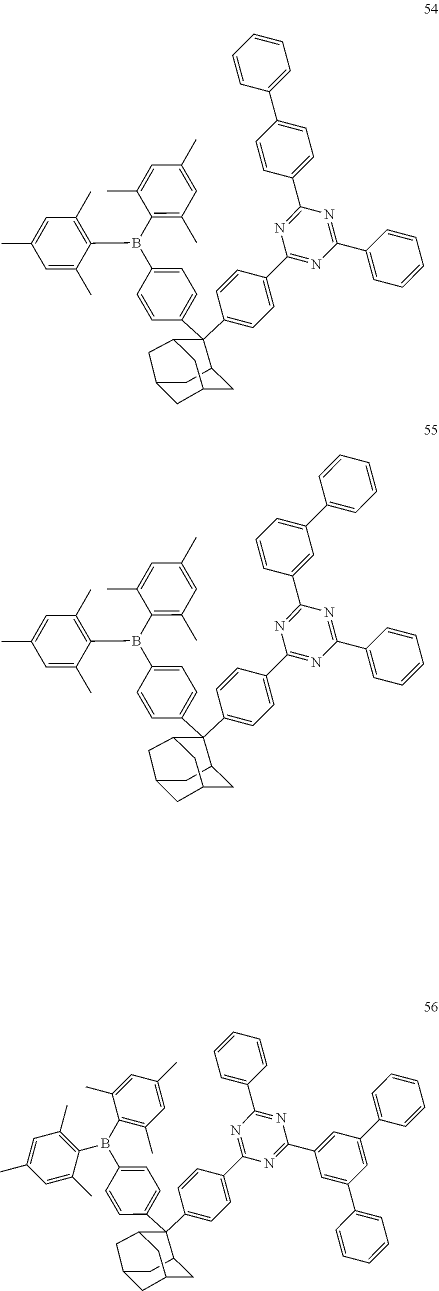 [SMILES: Cc1cc(C)c(B(c2ccc(C3(c4ccc(-c5nc(-c6ccccc6)nc(-c6ccc(-c7ccccc7)cc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7)c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6cc(-c7ccccc7)cc(-c7ccccc7)c6)n5)cc4)C4CC5CC(C4)CC3C5)cc2)c2c(C)cc(C)cc2C)c(C)c1]

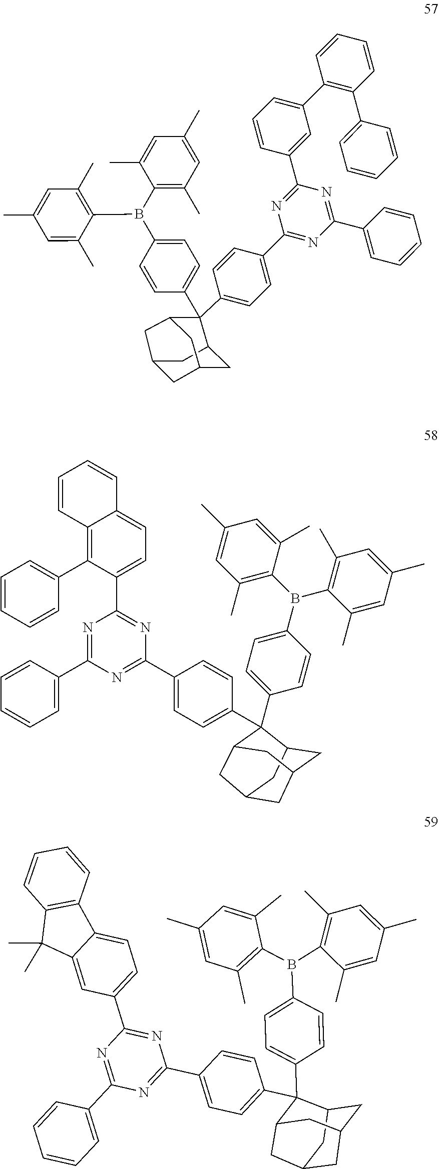

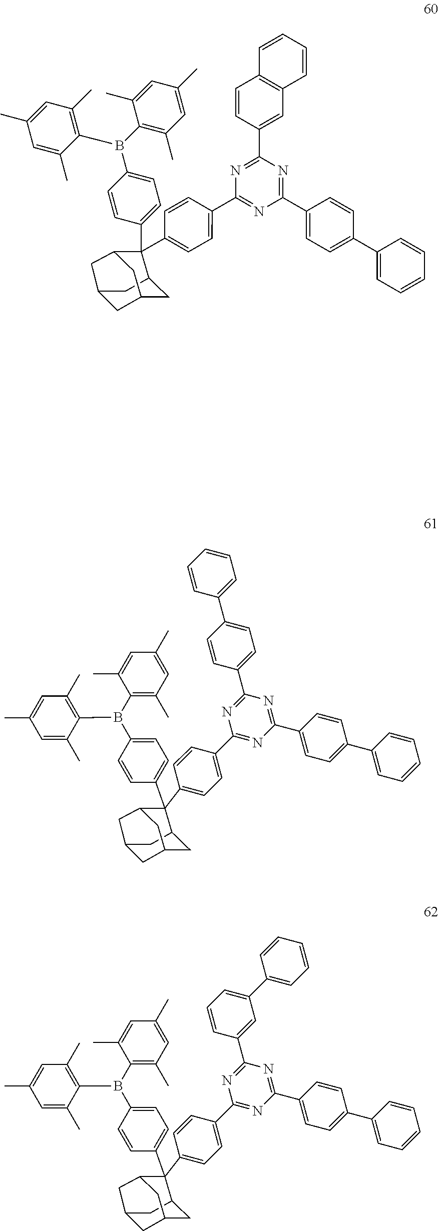 [SMILES: Cc1cc(C)c(B(c2ccc(C3(c4ccc(-c5nc(-c6ccc(-c7ccccc7)cc6)nc(-c6ccc7ccccc7c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)c2c(C)cc(C)cc2C)c(C)c1]

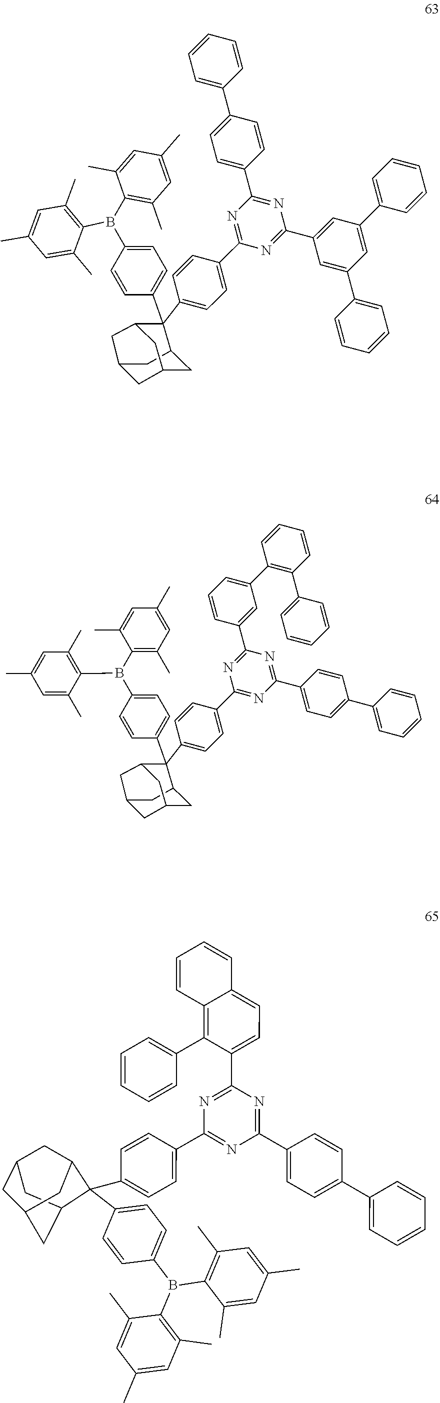 [SMILES: Cc1cc(C)c(B(c2ccc(C3(c4ccc(-c5nc(-c6ccc(-c7ccccc7)cc6)nc(-c6cc(-c7ccccc7)cc(-c7ccccc7)c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7-c7ccccc7)c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc7ccccc7c6-c6ccccc6)n5)cc4)C4CC5CC(C4)CC3C5)cc2)c2c(C)cc(C)cc2C)c(C)c1]

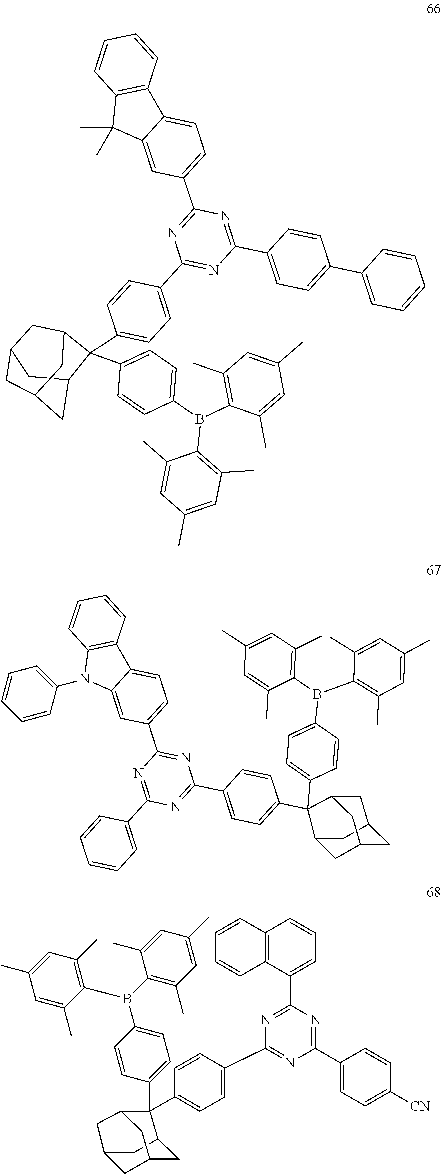

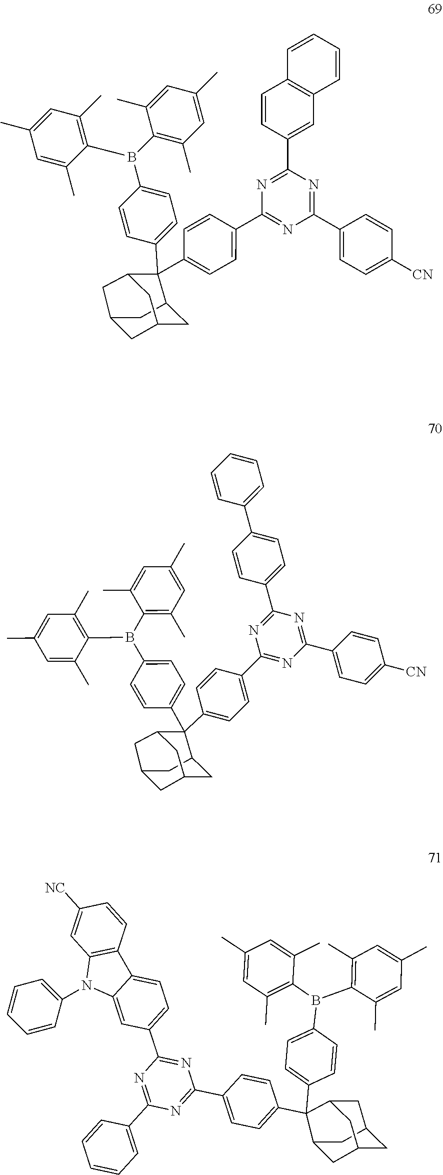 [SMILES: Cc1cc(C)c(B(c2ccc(C3(c4ccc(-c5nc(-c6ccc(C#N)cc6)nc(-c6ccc7ccccc7c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(C#N)cc6)nc(-c6ccc(-c7ccccc7)cc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6ccc7c8ccc(C#N)cc8n(-c8ccccc8)c7c6)n5)cc4)C4CC5CC(C4)CC3C5)cc2)c2c(C)cc(C)cc2C)c(C)c1]

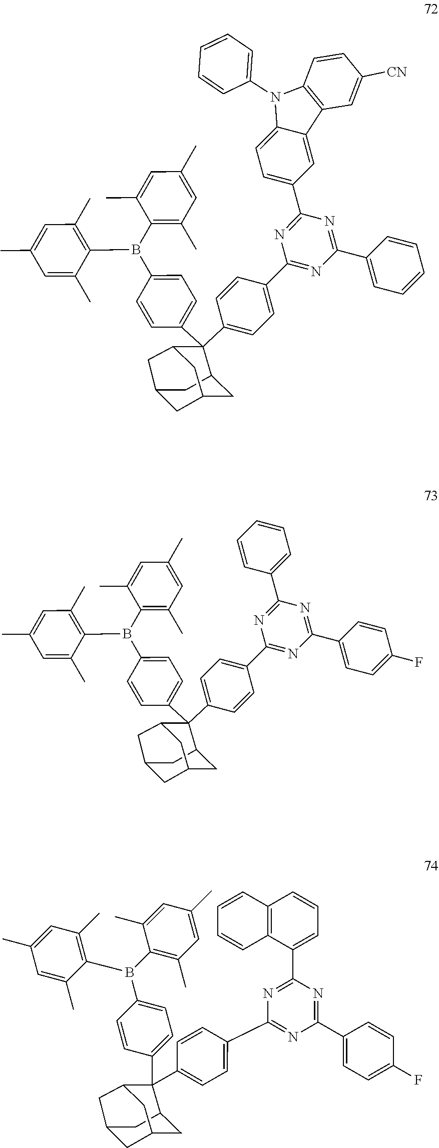 [SMILES: Cc1cc(C)c(B(c2ccc(C3(c4ccc(-c5nc(-c6ccccc6)nc(-c6ccc7c(c6)c6cc(C#N)ccc6n7-c6ccccc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6ccc(F)cc6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccc(F)cc6)nc(-c6cccc7ccccc67)n5)cc4)C4CC5CC(C4)CC3C5)cc2)c2c(C)cc(C)cc2C)c(C)c1]

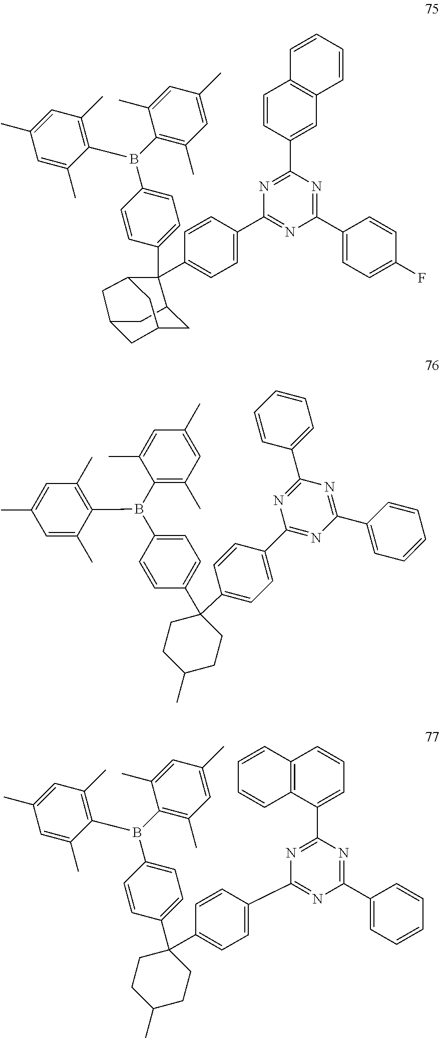 [SMILES: Cc1cc(C)c(B(c2ccc(C3(c4ccc(-c5nc(-c6ccc(F)cc6)nc(-c6ccc7ccccc7c6)n5)cc4)C4CC5CC(C4)CC3C5)cc2)c2c(C)cc(C)cc2C)c(C)c1 ; Cc1cc(C)c(B(c2ccc(C3(c4ccc(-c5nc(-c6ccccc6)nc(-c6ccccc6)n5)cc4)CCC(C)CC3)cc2)c2c(C)cc(C)cc2C)c(C)c1 ; Cc1cc(C)c(B(c2ccc(C3(c4ccc(-c5nc(-c6ccccc6)nc(-c6cccc7ccccc67)n5)cc4)CCC(C)CC3)cc2)c2c(C)cc(C)cc2C)c(C)c1]

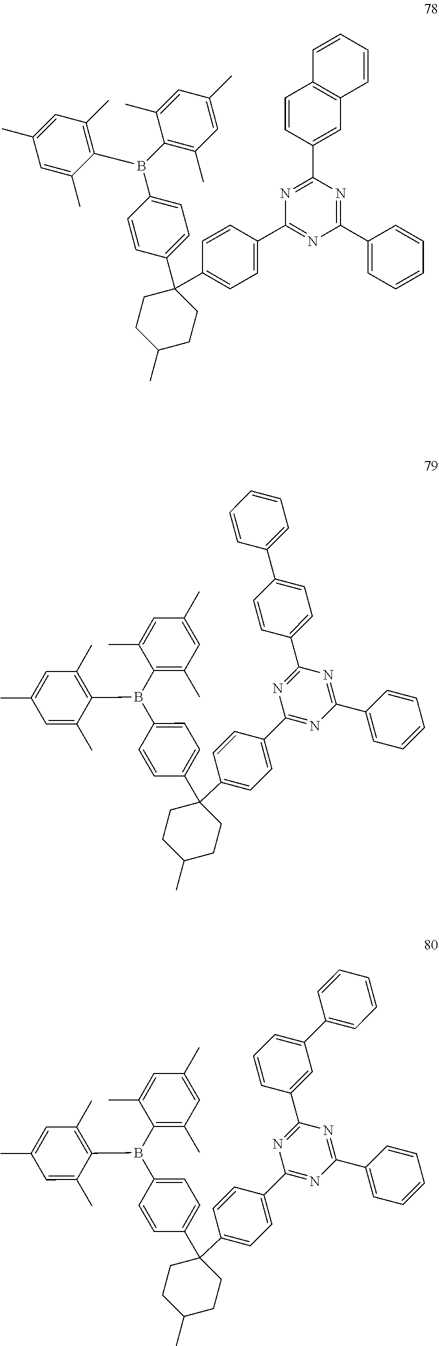 [SMILES: Cc1cc(C)c(B(c2ccc(C3(c4ccc(-c5nc(-c6ccccc6)nc(-c6ccc7ccccc7c6)n5)cc4)CCC(C)CC3)cc2)c2c(C)cc(C)cc2C)c(C)c1 ; Cc1cc(C)c(B(c2ccc(C3(c4ccc(-c5nc(-c6ccccc6)nc(-c6ccc(-c7ccccc7)cc6)n5)cc4)CCC(C)CC3)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7)c6)n5)cc4)CCC(C)CC3)cc2)c2c(C)cc(C)cc2C)c(C)c1]

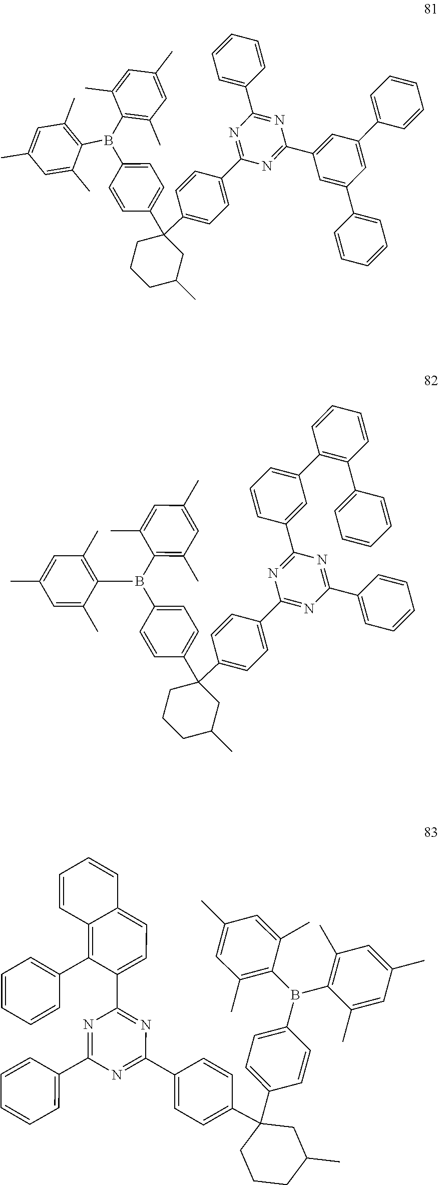 [SMILES: Cc1cc(C)c(B(c2ccc(C3(c4ccc(-c5nc(-c6ccccc6)nc(-c6cc(-c7ccccc7)cc(-c7ccccc7)c6)n5)cc4)CCCC(C)C3)cc2)c2c(C)cc(C)cc2C)c(C)c1 ; Cc1cc(C)c(B(c2ccc(C3(c4ccc(-c5nc(-c6ccccc6)nc(-c6cccc(-c7ccccc7-c7ccccc7)c6)n5)cc4)CCCC(C)C3)cc2)c2c(C)cc(C)cc2C)c(C)c1 ; Cc1cc(C)c(B(c2ccc(C3(c4ccc(-c5nc(-c6ccccc6)nc(-c6ccc7ccccc7c6-c6ccccc6)n5)cc4)CCCC(C)C3)cc2)c2c(C)cc(C)cc2C)c(C)c1]

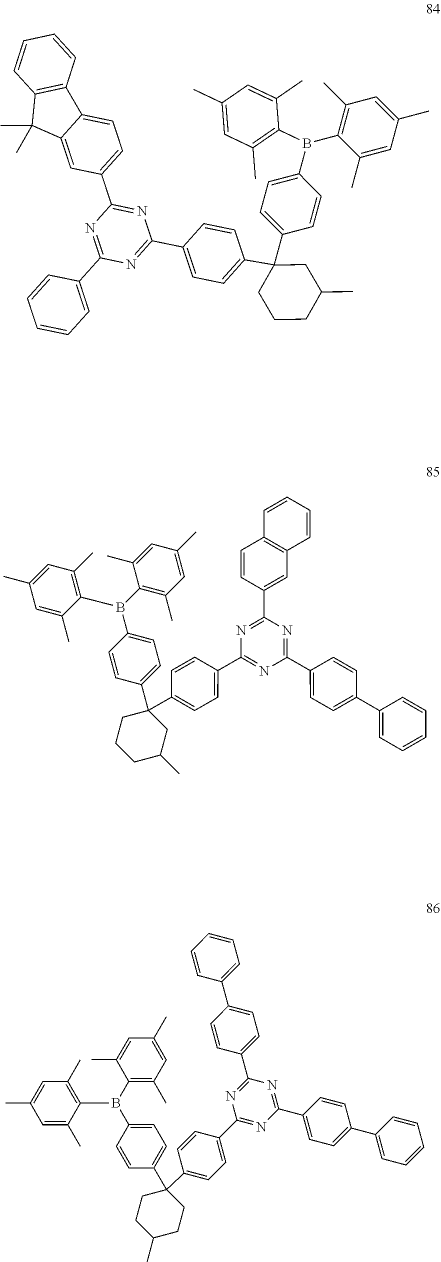

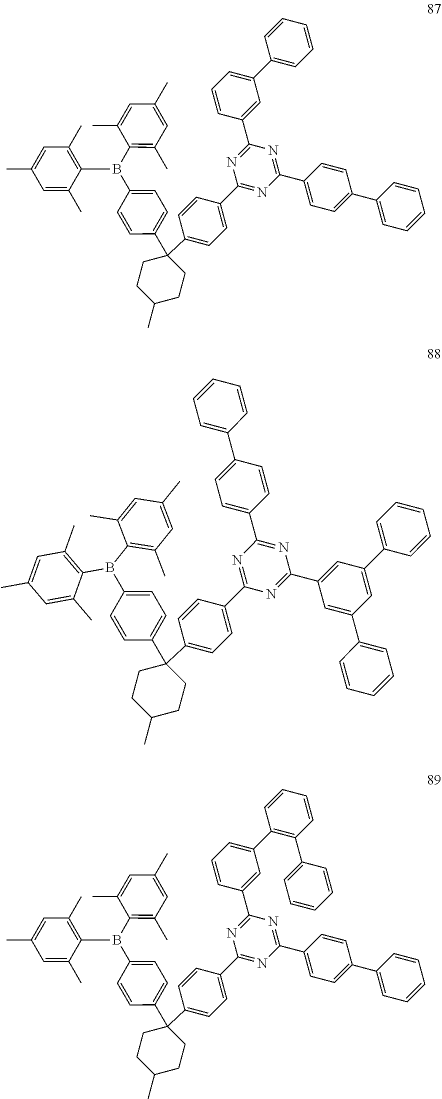 [SMILES: Cc1cc(C)c(B(c2ccc(C3(c4ccc(-c5nc(-c6ccc(-c7ccccc7)cc6)nc(-c6cccc(-c7ccccc7)c6)n5)cc4)CCC(C)CC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cc(-c7ccccc7)cc(-c7ccccc7)c6)n5)cc4)CCC(C)CC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7-c7ccccc7)c6)n5)cc4)CCC(C)CC3)cc2)c2c(C)cc(C)cc2C)c(C)c1]

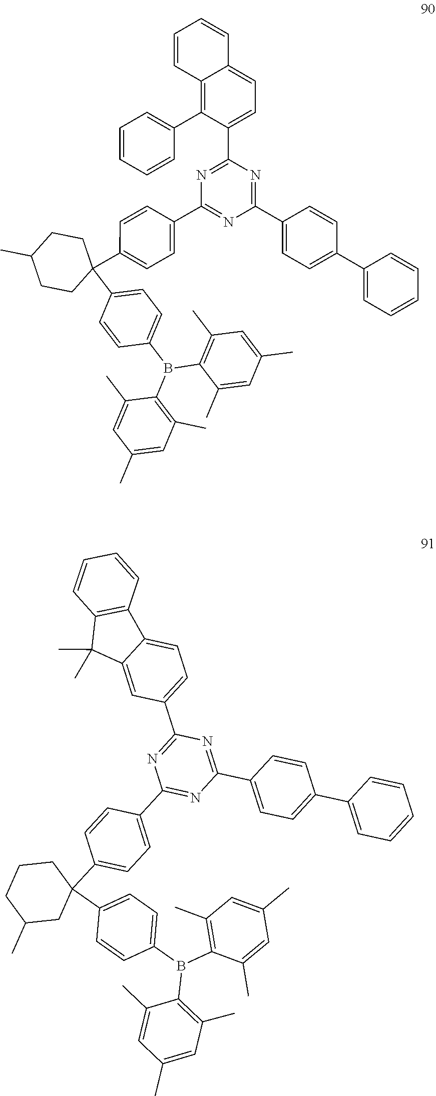 [SMILES: Cc1cc(C)c(B(c2ccc(C3(c4ccc(-c5nc(-c6ccc(-c7ccccc7)cc6)nc(-c6ccc7ccccc7c6-c6ccccc6)n5)cc4)CCC(C)CC3)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6ccc7c(c6)C(C)(C)c6ccccc6-7)n5)cc4)CCCC(C)C3)cc2)c2c(C)cc(C)cc2C)c(C)c1]

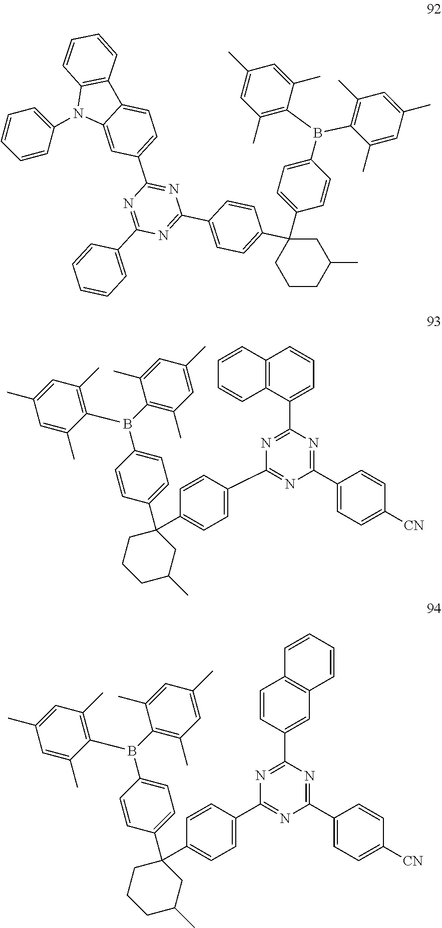

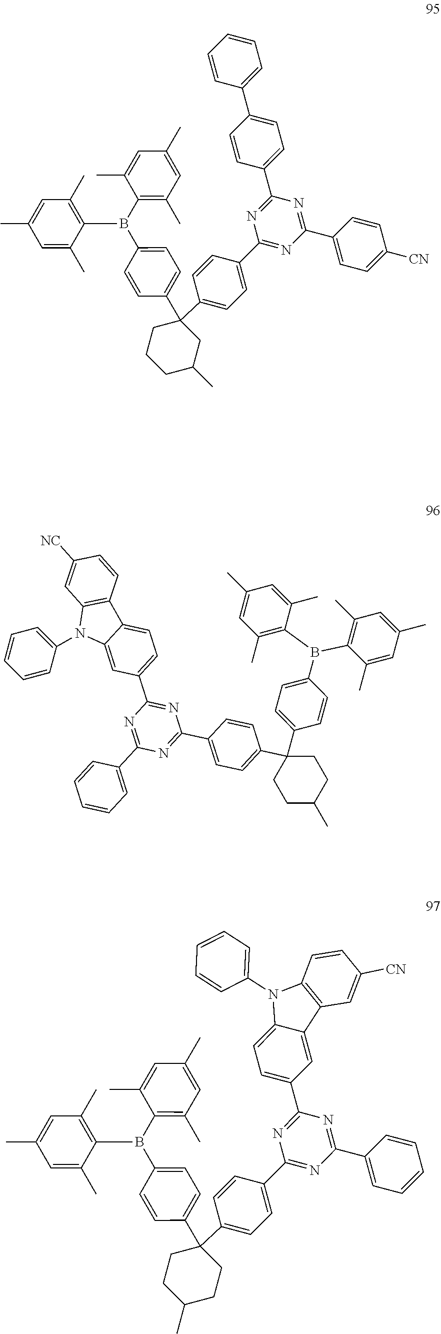

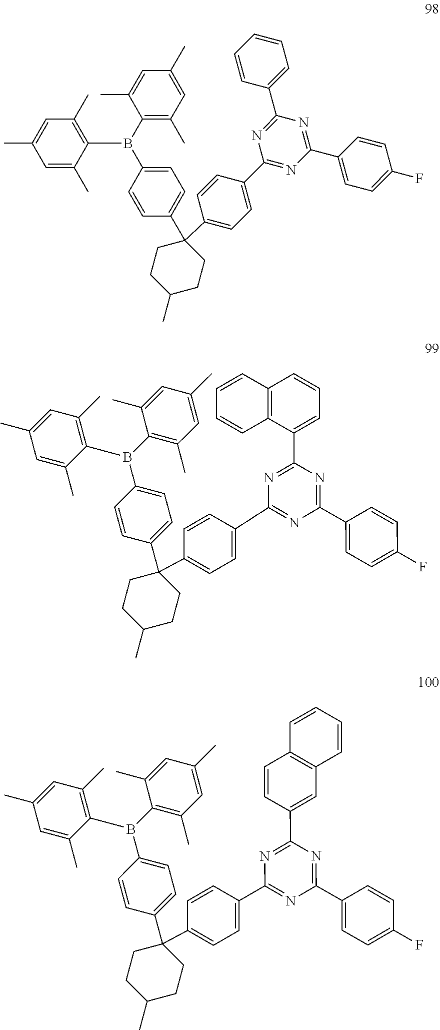 [SMILES: Cc1cc(C)c(B(c2ccc(C3(c4ccc(-c5nc(-c6ccccc6)nc(-c6ccc(F)cc6)n5)cc4)CCC(C)CC3)cc2)c2c(C)cc(C)cc2C)c(C)c1 ; Cc1cc(C)c(B(c2ccc(C3(c4ccc(-c5nc(-c6ccc(F)cc6)nc(-c6cccc7ccccc67)n5)cc4)CCC(C)CC3)cc2)c2c(C)cc(C)cc2C)c(C)c1 ; Cc1cc(C)c(B(c2ccc(C3(c4ccc(-c5nc(-c6ccc(F)cc6)nc(-c6ccc7ccccc7c6)n5)cc4)CCC(C)CC3)cc2)c2c(C)cc(C)cc2C)c(C)c1]

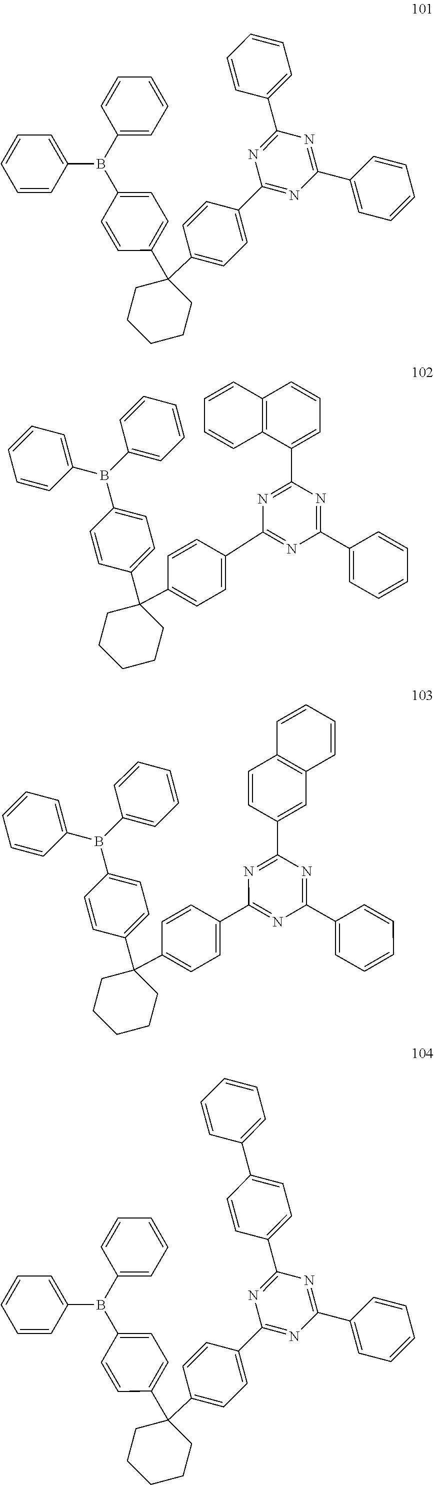 [SMILES: c1ccc(B(c2ccccc2)c2ccc(C3(c4ccc(-c5nc(-c6ccccc6)nc(-c6ccccc6)n5)cc4)CCCCC3)cc2)cc1 ; c1ccc(B(c2ccccc2)c2ccc(C3(c4ccc(-c5nc(-c6ccccc6)nc(-c6cccc7ccccc67)n5)cc4)CCCCC3)cc2)cc1 ; c1ccc(B(c2ccccc2)c2ccc(C3(c4ccc(-c5nc(-c6ccccc6)nc(-c6ccc7ccccc7c6)n5)cc4)CCCCC3)cc2)cc1 ; c1ccc(B(c2ccccc2)c2ccc(C3(c4ccc(-c5nc(-c6ccccc6)nc(-c6ccc(-c7ccccc7)cc6)n5)cc4)CCCCC3)cc2)cc1]

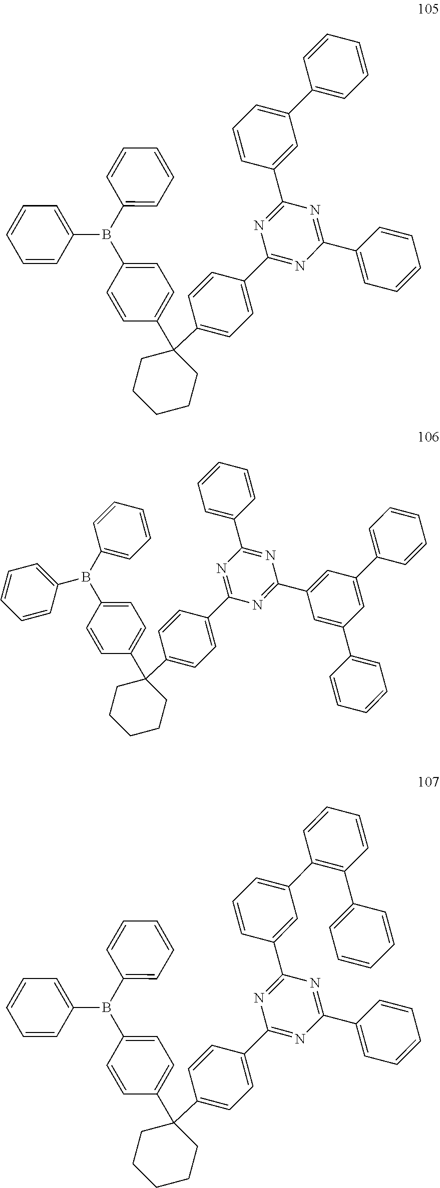 [SMILES: c1ccc(B(c2ccccc2)c2ccc(C3(c4ccc(-c5nc(-c6ccccc6)nc(-c6cccc(-c7ccccc7)c6)n5)cc4)CCCCC3)cc2)cc1 ; c1ccc(B(c2ccccc2)c2ccc(C3(c4ccc(-c5nc(-c6ccccc6)nc(-c6cc(-c7ccccc7)cc(-c7ccccc7)c6)n5)cc4)CCCCC3)cc2)cc1 ; c1ccc(B(c2ccccc2)c2ccc(C3(c4ccc(-c5nc(-c6ccccc6)nc(-c6cccc(-c7ccccc7-c7ccccc7)c6)n5)cc4)CCCCC3)cc2)cc1]

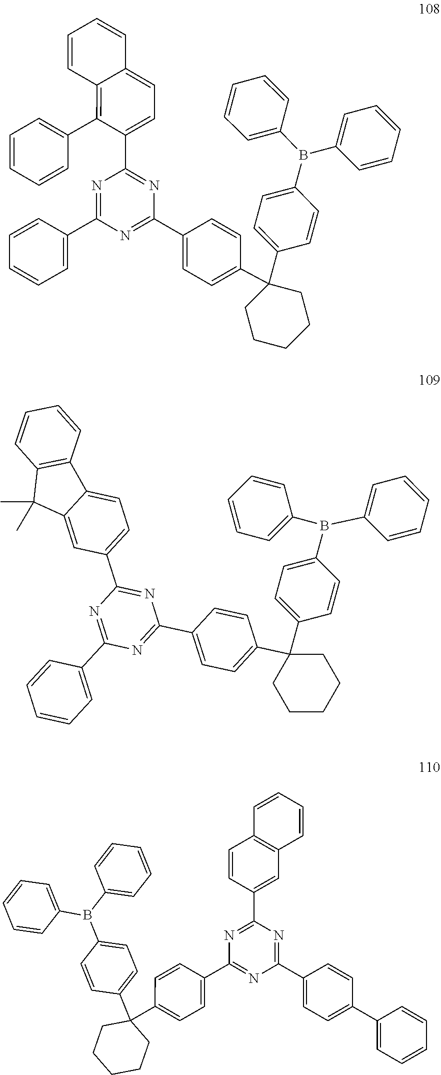 [SMILES: c1ccc(B(c2ccccc2)c2ccc(C3(c4ccc(-c5nc(-c6ccccc6)nc(-c6ccc7ccccc7c6-c6ccccc6)n5)cc4)CCCCC3)cc2)cc1 ; CC1(C)c2ccccc2-c2ccc(-c3nc(-c4ccccc4)nc(-c4ccc(C5(c6ccc(B(c7ccccc7)c7ccccc7)cc6)CCCCC5)cc4)n3)cc21 ; c1ccc(B(c2ccccc2)c2ccc(C3(c4ccc(-c5nc(-c6ccc(-c7ccccc7)cc6)nc(-c6ccc7ccccc7c6)n5)cc4)CCCCC3)cc2)cc1]

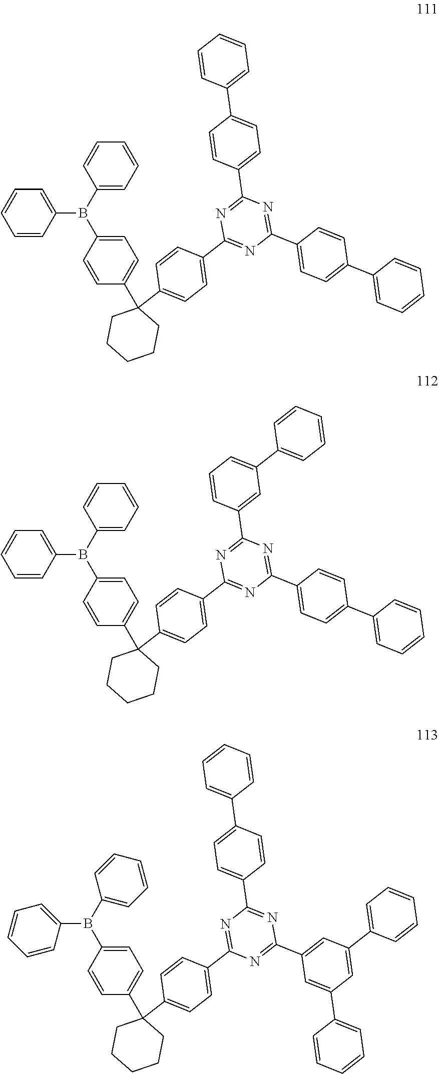 [SMILES: c1ccc(B(c2ccccc2)c2ccc(C3(c4ccc(-c5nc(-c6ccc(-c7ccccc7)cc6)nc(-c6ccc(-c7ccccc7)cc6)n5)cc4)CCCCC3)cc2)cc1 ; c1ccc(B(c2ccccc2)c2ccc(C3(c4ccc(-c5nc(-c6ccc(-c7ccccc7)cc6)nc(-c6cccc(-c7ccccc7)c6)n5)cc4)CCCCC3)cc2)cc1 ; c1ccc(B(c2ccccc2)c2ccc(C3(c4ccc(-c5nc(-c6ccc(-c7ccccc7)cc6)nc(-c6cc(-c7ccccc7)cc(-c7ccccc7)c6)n5)cc4)CCCCC3)cc2)cc1]

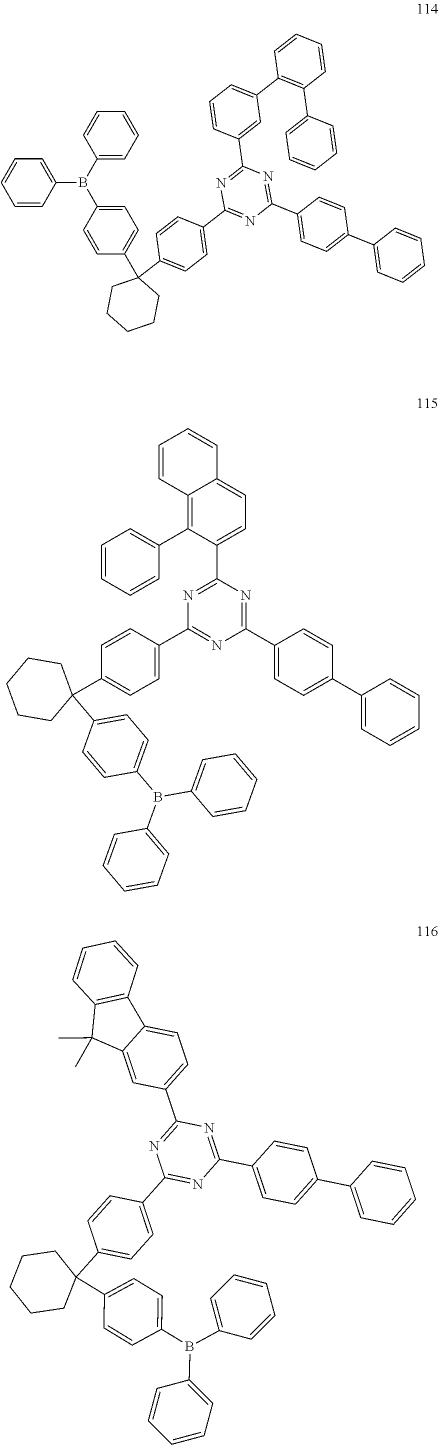 [SMILES: c1ccc(B(c2ccccc2)c2ccc(C3(c4ccc(-c5nc(-c6ccc(-c7ccccc7)cc6)nc(-c6cccc(-c7ccccc7-c7ccccc7)c6)n5)cc4)CCCCC3)cc2)cc1 ; c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)CCCCC3)cc2)cc1 ; CC1(C)c2ccccc2-c2ccc(-c3nc(-c4ccc(-c5ccccc5)cc4)nc(-c4ccc(C5(c6ccc(B(c7ccccc7)c7ccccc7)cc6)CCCCC5)cc4)n3)cc21]

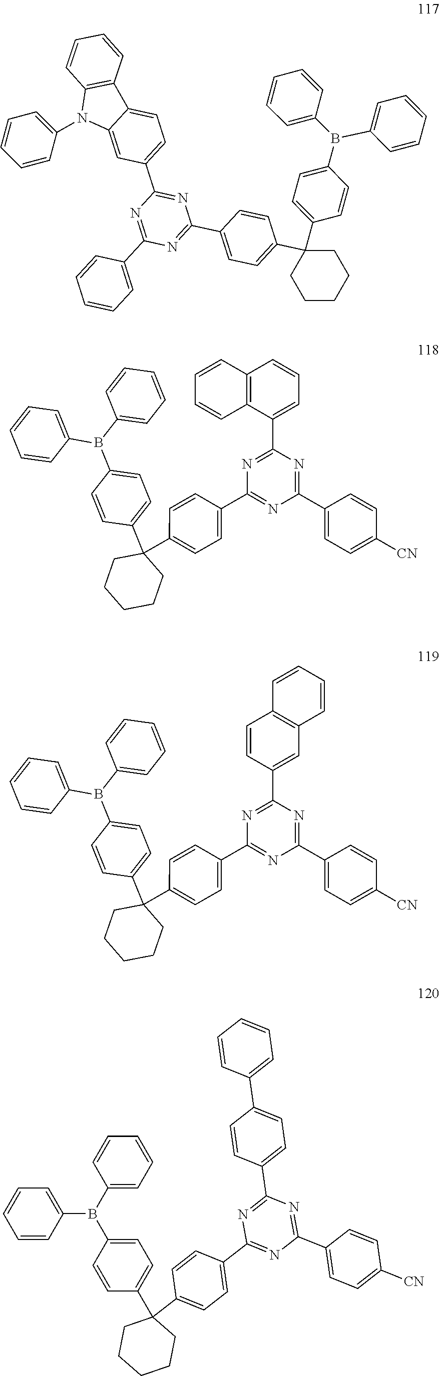 [SMILES: c1ccc(B(c2ccccc2)c2ccc(C3(c4ccc(-c5nc(-c6ccccc6)nc(-c6ccc7c8ccccc8n(-c8ccccc8)c7c6)n5)cc4)CCCCC3)cc2)cc1 ; N#Cc1ccc(-c2nc(-c3ccc(C4(c5ccc(B(c6ccccc6)c6ccccc6)cc5)CCCCC4)cc3)nc(-c3cccc4ccccc34)n2)cc1 ; N#Cc1ccc(-c2nc(-c3ccc(C4(c5ccc(B(c6ccccc6)c6ccccc6)cc5)CCCCC4)cc3)nc(-c3ccc4ccccc4c3)n2)cc1 ; N#Cc1ccc(-c2nc(-c3ccc(-c4ccccc4)cc3)nc(-c3ccc(C4(c5ccc(B(c6ccccc6)c6ccccc6)cc5)CCCCC4)cc3)n2)cc1]

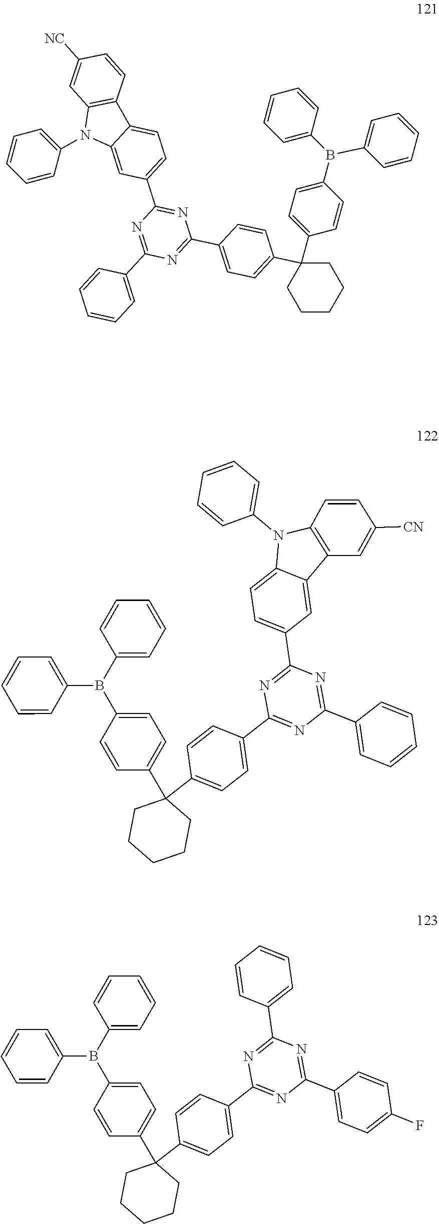 [SMILES: N#Cc1ccc2c3ccc(-c4nc(-c5ccccc5)nc(-c5ccc(C6(c7ccc(B(c8ccccc8)c8ccccc8)cc7)CCCCC6)cc5)n4)cc3n(-c3ccccc3)c2c1 ; N#Cc1ccc2c(c1)c1cc(-c3nc(-c4ccccc4)nc(-c4ccc(C5(c6ccc(B(c7ccccc7)c7ccccc7)cc6)CCCCC5)cc4)n3)ccc1n2-c1ccccc1 ; Fc1ccc(-c2nc(-c3ccccc3)nc(-c3ccc(C4(c5ccc(B(c6ccccc6)c6ccccc6)cc5)CCCCC4)cc3)n2)cc1]

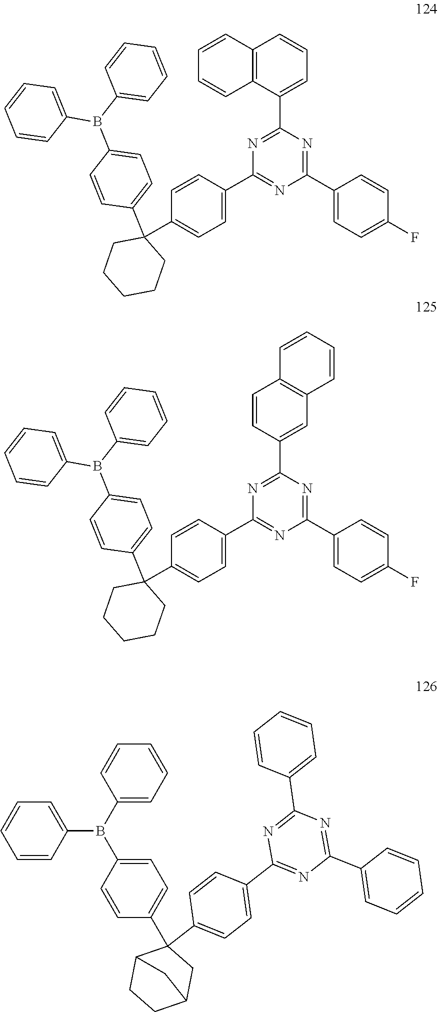 [SMILES: Fc1ccc(-c2nc(-c3ccc(C4(c5ccc(B(c6ccccc6)c6ccccc6)cc5)CCCCC4)cc3)nc(-c3cccc4ccccc34)n2)cc1 ; Fc1ccc(-c2nc(-c3ccc(C4(c5ccc(B(c6ccccc6)c6ccccc6)cc5)CCCCC4)cc3)nc(-c3ccc4ccccc4c3)n2)cc1 ; c1ccc(B(c2ccccc2)c2ccc(C3(c4ccc(-c5nc(-c6ccccc6)nc(-c6ccccc6)n5)cc4)CC4CCC3C4)cc2)cc1]

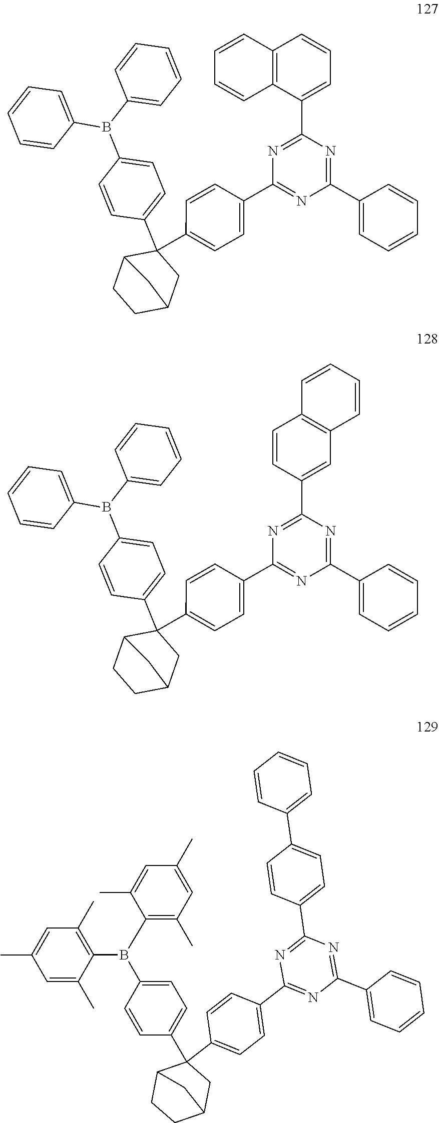 [SMILES: c1ccc(B(c2ccccc2)c2ccc(C3(c4ccc(-c5nc(-c6ccccc6)nc(-c6cccc7ccccc67)n5)cc4)CC4CCC3C4)cc2)cc1 ; c1ccc(B(c2ccccc2)c2ccc(C3(c4ccc(-c5nc(-c6ccccc6)nc(-c6ccc7ccccc7c6)n5)cc4)CC4CCC3C4)cc2)cc1 ; Cc1cc(C)c(B(c2ccc(C3(c4ccc(-c5nc(-c6ccccc6)nc(-c6ccc(-c7ccccc7)cc6)n5)cc4)CC4CCC3C4)cc2)c2c(C)cc(C)cc2C)c(C)c1]

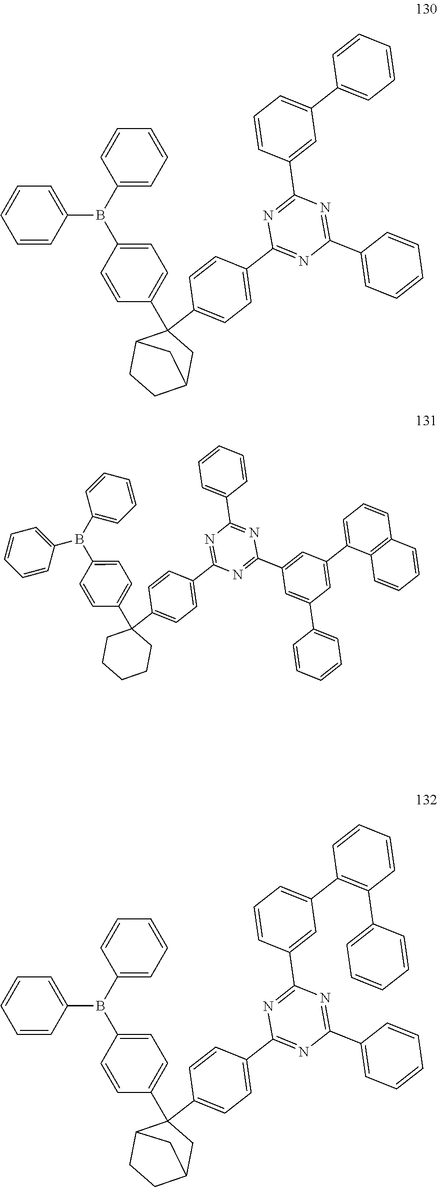 [SMILES: c1ccc(B(c2ccccc2)c2ccc(C3(c4ccc(-c5nc(-c6ccccc6)nc(-c6cccc(-c7ccccc7)c6)n5)cc4)CC4CCC3C4)cc2)cc1 ; c1ccc(B(c2ccccc2)c2ccc(C3(c4ccc(-c5nc(-c6ccccc6)nc(-c6cc(-c7ccccc7)cc(-c7cccc8ccccc78)c6)n5)cc4)CCCCC3)cc2)cc1 ; c1ccc(B(c2ccccc2)c2ccc(C3(c4ccc(-c5nc(-c6ccccc6)nc(-c6cccc(-c7ccccc7-c7ccccc7)c6)n5)cc4)CC4CCC3C4)cc2)cc1]

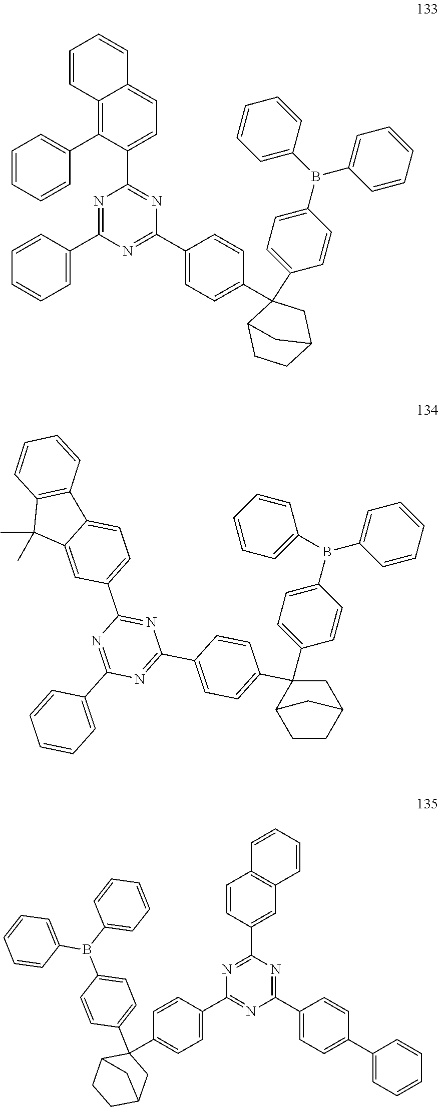 [SMILES: c1ccc(B(c2ccccc2)c2ccc(C3(c4ccc(-c5nc(-c6ccccc6)nc(-c6ccc7ccccc7c6-c6ccccc6)n5)cc4)CC4CCC3C4)cc2)cc1 ; CC1(C)c2ccccc2-c2ccc(-c3nc(-c4ccccc4)nc(-c4ccc(C5(c6ccc(B(c7ccccc7)c7ccccc7)cc6)CC6CCC5C6)cc4)n3)cc21 ; c1ccc(B(c2ccccc2)c2ccc(C3(c4ccc(-c5nc(-c6ccc(-c7ccccc7)cc6)nc(-c6ccc7ccccc7c6)n5)cc4)CC4CCC3C4)cc2)cc1]

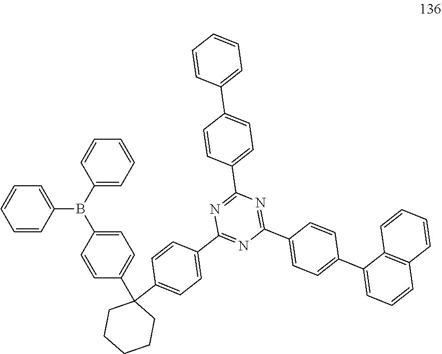 [SMILES: c1ccc(B(c2ccccc2)c2ccc(C3(c4ccc(-c5nc(-c6ccc(-c7ccccc7)cc6)nc(-c6ccc(-c7cccc8ccccc78)cc6)n5)cc4)CCCCC3)cc2)cc1]

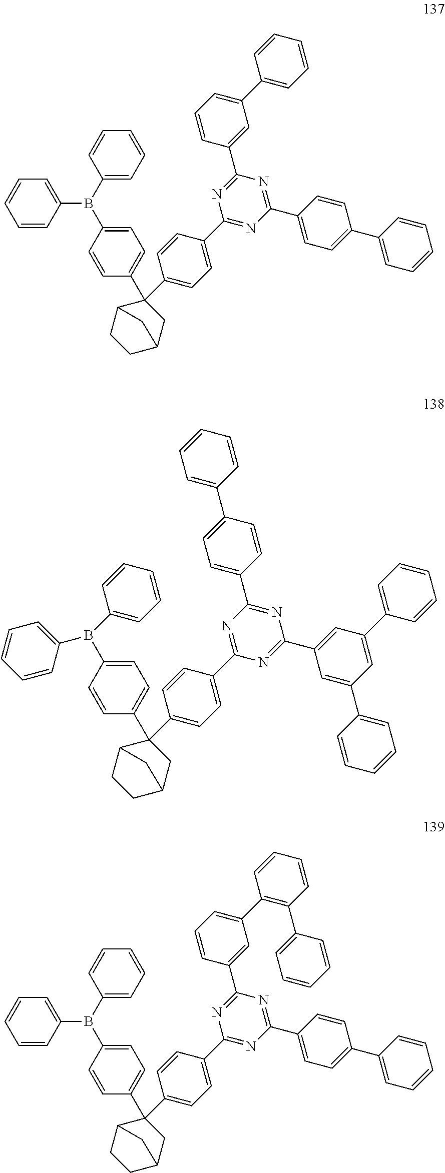 [SMILES: c1ccc(B(c2ccccc2)c2ccc(C3(c4ccc(-c5nc(-c6ccc(-c7ccccc7)cc6)nc(-c6cccc(-c7ccccc7)c6)n5)cc4)CC4CCC3C4)cc2)cc1 ; c1ccc(B(c2ccccc2)c2ccc(C3(c4ccc(-c5nc(-c6ccc(-c7ccccc7)cc6)nc(-c6cc(-c7ccccc7)cc(-c7ccccc7)c6)n5)cc4)CC4CCC3C4)cc2)cc1 ; c1ccc(B(c2ccccc2)c2ccc(C3(c4ccc(-c5nc(-c6ccc(-c7ccccc7)cc6)nc(-c6cccc(-c7ccccc7-c7ccccc7)c6)n5)cc4)CC4CCC3C4)cc2)cc1]

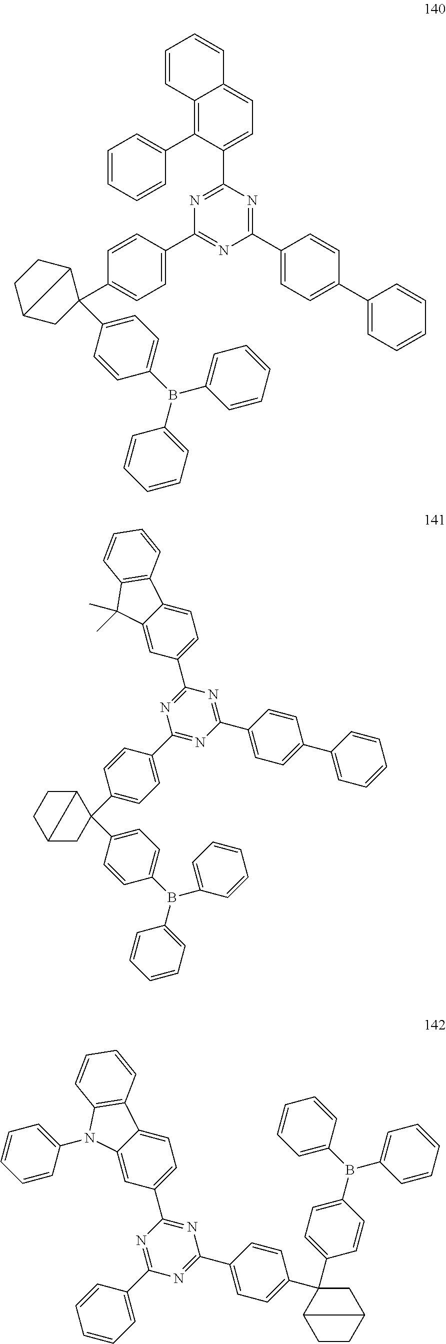

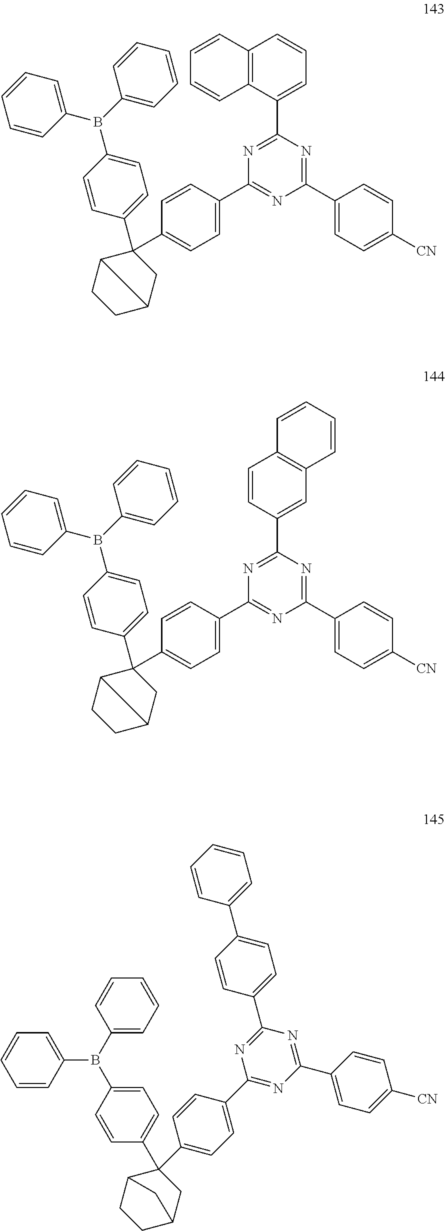 [SMILES: N#Cc1ccc(-c2nc(-c3ccc(C4(c5ccc(B(c6ccccc6)c6ccccc6)cc5)CC5CCC54)cc3)nc(-c3cccc4ccccc34)n2)cc1 ; N#Cc1ccc(-c2nc(-c3ccc(C4(c5ccc(B(c6ccccc6)c6ccccc6)cc5)CC5CCC54)cc3)nc(-c3ccc4ccccc4c3)n2)cc1 ; N#Cc1ccc(-c2nc(-c3ccc(-c4ccccc4)cc3)nc(-c3ccc(C4(c5ccc(B(c6ccccc6)c6ccccc6)cc5)CC5CCC4C5)cc3)n2)cc1]

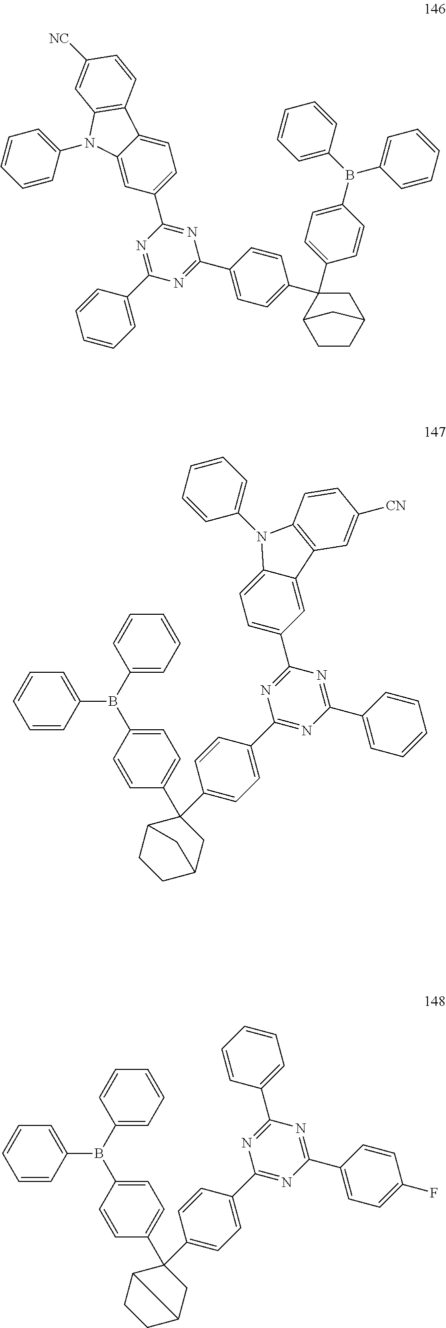 [SMILES: N#Cc1ccc2c3ccc(-c4nc(-c5ccccc5)nc(-c5ccc(C6(c7ccc(B(c8ccccc8)c8ccccc8)cc7)CC7CCC6C7)cc5)n4)cc3n(-c3ccccc3)c2c1 ; N#Cc1ccc2c(c1)c1cc(-c3nc(-c4ccccc4)nc(-c4ccc(C5(c6ccc(B(c7ccccc7)c7ccccc7)cc6)CC6CCC5C6)cc4)n3)ccc1n2-c1ccccc1 ; Fc1ccc(-c2nc(-c3ccccc3)nc(-c3ccc(C4(c5ccc(B(c6ccccc6)c6ccccc6)cc5)CC5CCC54)cc3)n2)cc1]

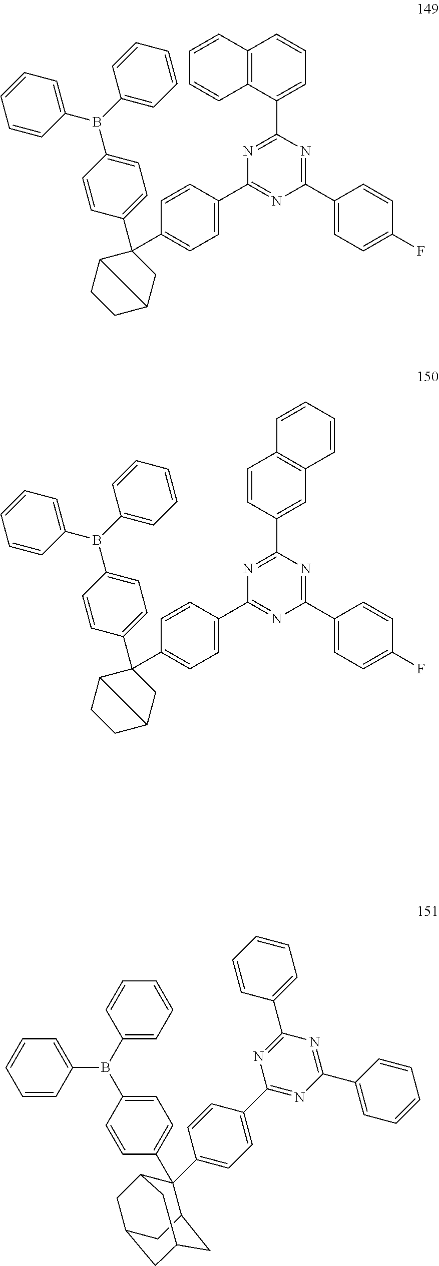 [SMILES: Fc1ccc(-c2nc(-c3ccc(C4(c5ccc(B(c6ccccc6)c6ccccc6)cc5)CC5CCC54)cc3)nc(-c3cccc4ccccc34)n2)cc1 ; Fc1ccc(-c2nc(-c3ccc(C4(c5ccc(B(c6ccccc6)c6ccccc6)cc5)CC5CCC54)cc3)nc(-c3ccc4ccccc4c3)n2)cc1 ; c1ccc(B(c2ccccc2)c2ccc(C3(c4ccc(-c5nc(-c6ccccc6)nc(-c6ccccc6)n5)cc4)C4CC5CC(C4)CC3C5)cc2)cc1]

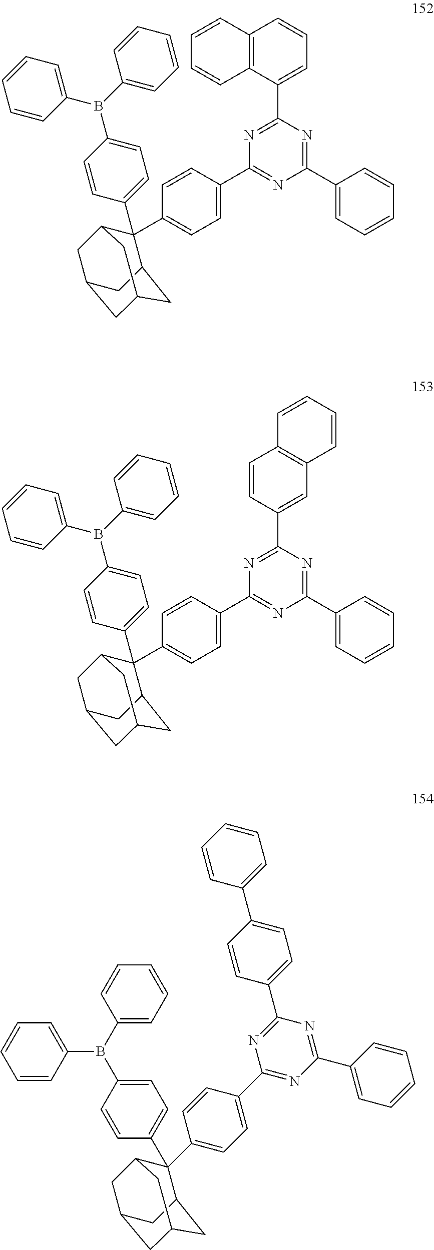 [SMILES: c1ccc(B(c2ccccc2)c2ccc(C3(c4ccc(-c5nc(-c6ccccc6)nc(-c6cccc7ccccc67)n5)cc4)C4CC5CC(C4)CC3C5)cc2)cc1 ; c1ccc(B(c2ccccc2)c2ccc(C3(c4ccc(-c5nc(-c6ccccc6)nc(-c6ccc7ccccc7c6)n5)cc4)C4CC5CC(C4)CC3C5)cc2)cc1 ; c1ccc(B(c2ccccc2)c2ccc(C3(c4ccc(-c5nc(-c6ccccc6)nc(-c6ccc(-c7ccccc7)cc6)n5)cc4)C4CC5CC(C4)CC3C5)cc2)cc1]

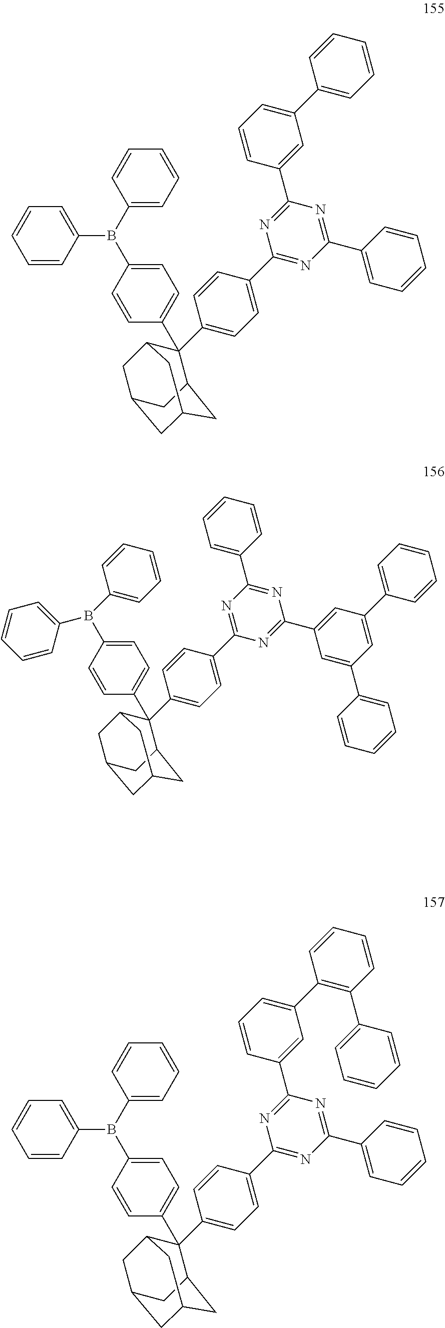 [SMILES: c1ccc(B(c2ccccc2)c2ccc(C3(c4ccc(-c5nc(-c6ccccc6)nc(-c6cccc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccccc6)nc(-c6cc(-c7ccccc7)cc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccccc6)nc(-c6cccc(-c7ccccc7-c7ccccc7)c6)n5)cc4)C4CC5CC(C4)CC3C5)cc2)cc1]

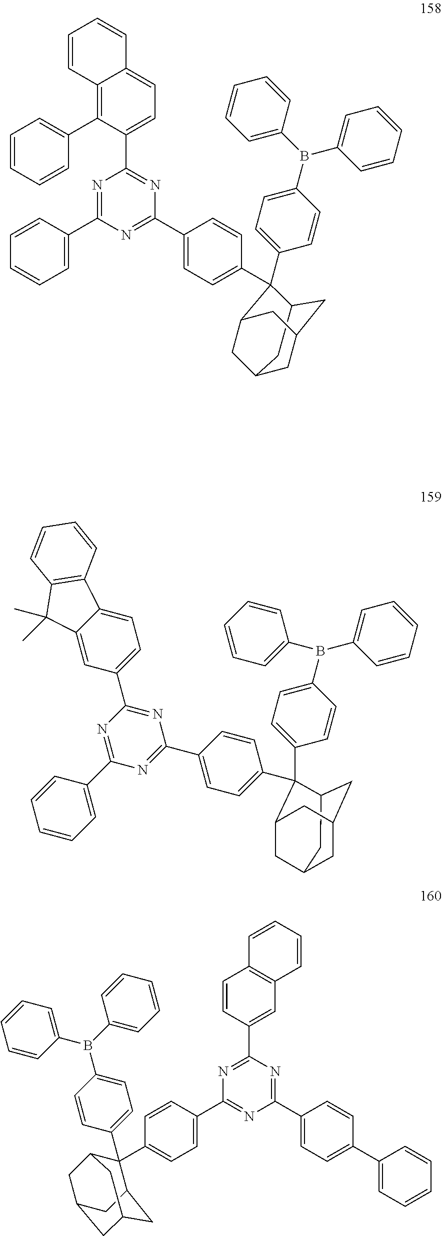 [SMILES: c1ccc(B(c2ccccc2)c2ccc(C3(c4ccc(-c5nc(-c6ccccc6)nc(-c6ccc7ccccc7c6-c6ccccc6)n5)cc4)C4CC5CC(C4)CC3C5)cc2)cc1 ; CC1(C)c2ccccc2-c2ccc(-c3nc(-c4ccccc4)nc(-c4ccc(C5(c6ccc(B(c7ccccc7)c7ccccc7)cc6)C6CC7CC(C6)CC5C7)cc4)n3)cc21 ; c1ccc(B(c2ccccc2)c2ccc(C3(c4ccc(-c5nc(-c6ccc(-c7ccccc7)cc6)nc(-c6ccc7ccccc7c6)n5)cc4)C4CC5CC(C4)CC3C5)cc2)cc1]

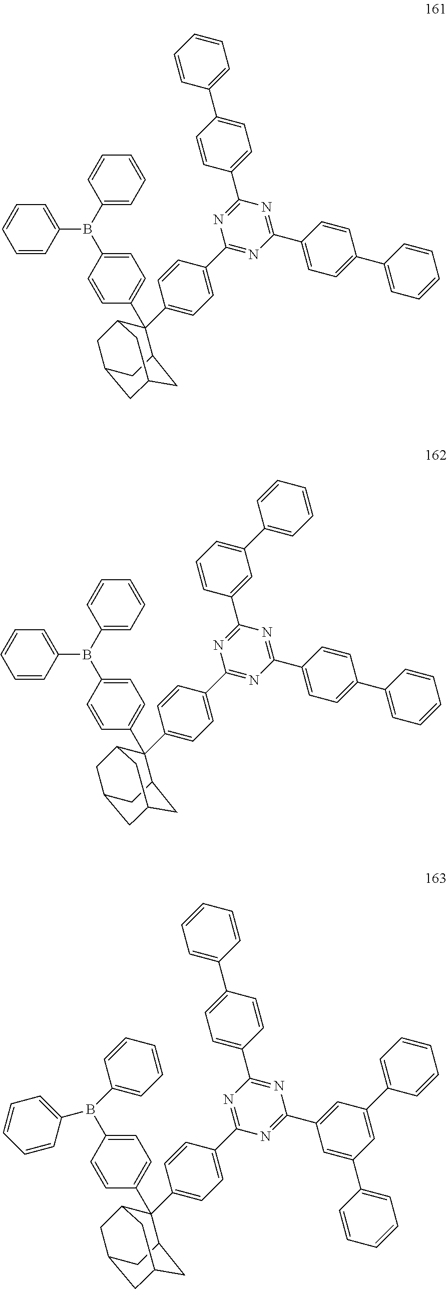 [SMILES: c1ccc(B(c2ccccc2)c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6cc(-c7ccccc7)cc(-c7ccccc7)c6)n5)cc4)C4CC5CC(C4)CC3C5)cc2)cc1]

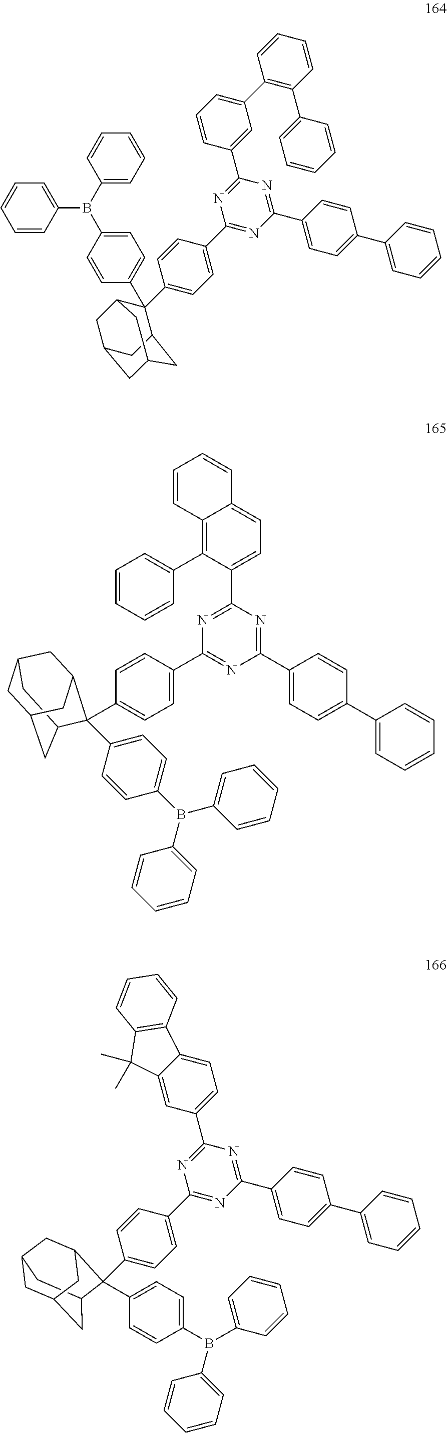 [SMILES: c1ccc(B(c2ccccc2)c2ccc(C3(c4ccc(-c5nc(-c6ccc(-c7ccccc7)cc6)nc(-c6cccc(-c7ccccc7-c7ccccc7)c6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)C4CC5CC(C4)CC3C5)cc2)cc1 ; CC1(C)c2ccccc2-c2ccc(-c3nc(-c4ccc(-c5ccccc5)cc4)nc(-c4ccc(C5(c6ccc(B(c7ccccc7)c7ccccc7)cc6)C6CC7CC(C6)CC5C7)cc4)n3)cc21]

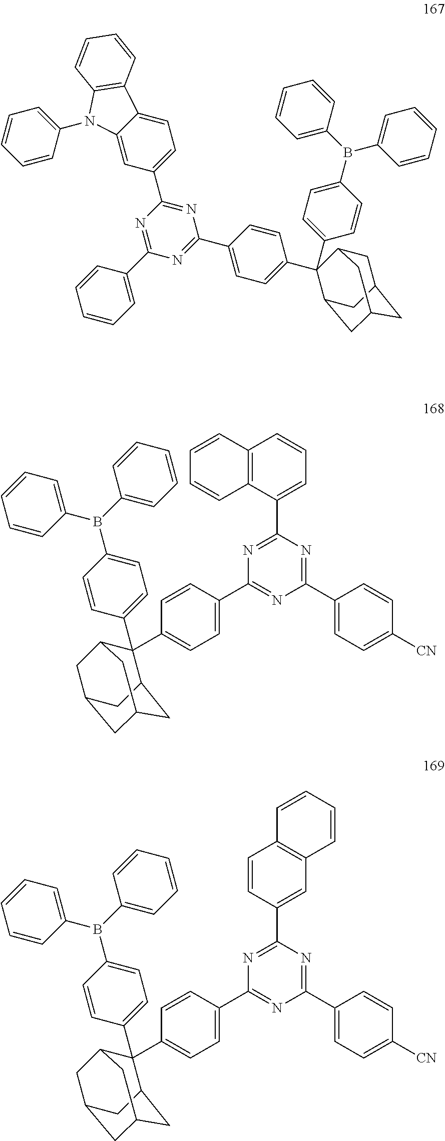 [SMILES: c1ccc(B(c2ccccc2)c2ccc(C3(c4ccc(-c5nc(-c6ccccc6)nc(-c6ccc7c8ccccc8n(-c8ccccc8)c7c6)n5)cc4)C4CC5CC(C4)CC3C5)cc2)cc1 ; N#Cc1ccc(-c2nc(-c3ccc(C4(c5ccc(B(c6ccccc6)c6ccccc6)cc5)C5CC6CC(C5)CC4C6)cc3)nc(-c3cccc4ccccc34)n2)cc1 ; N#Cc1ccc(-c2nc(-c3ccc(C4(c5ccc(B(c6ccccc6)c6ccccc6)cc5)C5CC6CC(C5)CC4C6)cc3)nc(-c3ccc4ccccc4c3)n2)cc1]

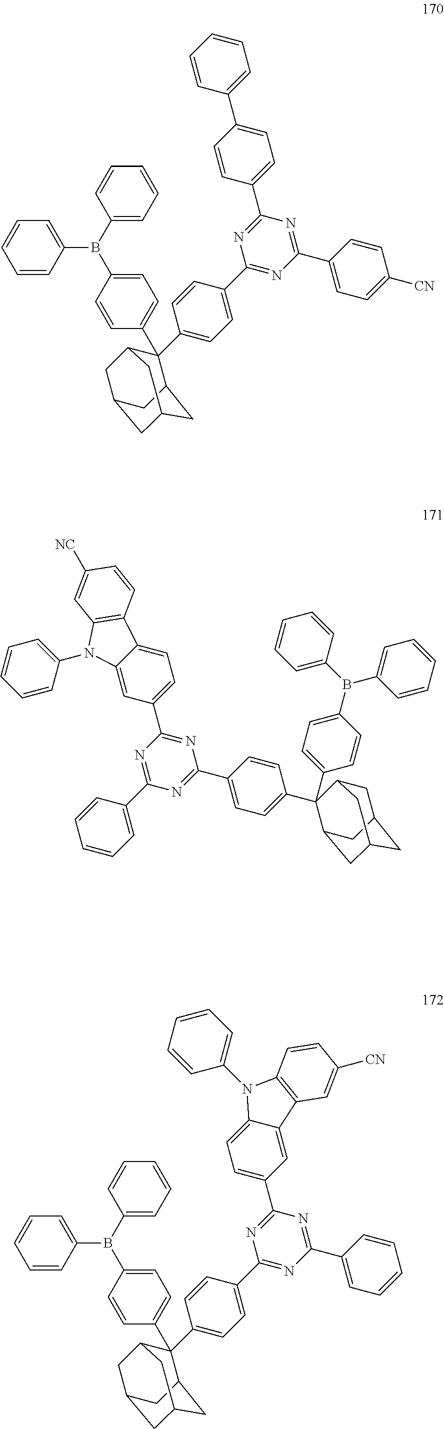 [SMILES: N#Cc1ccc(-c2nc(-c3ccc(-c4ccccc4)cc3)nc(-c3ccc(C4(c5ccc(B(c6ccccc6)c6ccccc6)cc5)C5CC6CC(C5)CC4C6)cc3)n2)cc1 ; N#Cc1ccc2c3ccc(-c4nc(-c5ccccc5)nc(-c5ccc(C6(c7ccc(B(c8ccccc8)c8ccccc8)cc7)C7CC8CC(C7)CC6C8)cc5)n4)cc3n(-c3ccccc3)c2c1 ; N#Cc1ccc2c(c1)c1cc(-c3nc(-c4ccccc4)nc(-c4ccc(C5(c6ccc(B(c7ccccc7)c7ccccc7)cc6)C6CC7CC(C6)CC5C7)cc4)n3)ccc1n2-c1ccccc1]

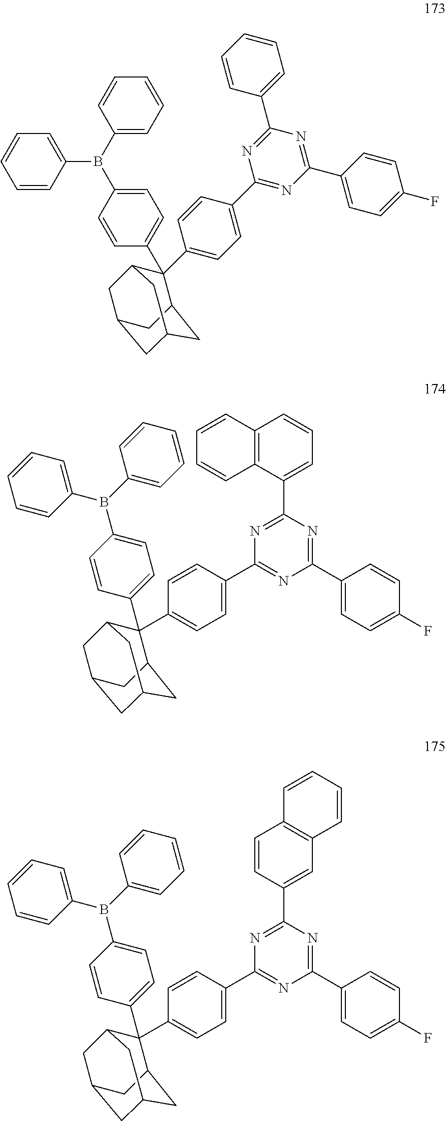 [SMILES: Fc1ccc(-c2nc(-c3ccccc3)nc(-c3ccc(C4(c5ccc(B(c6ccccc6)c6ccccc6)cc5)C5CC6CC(C5)CC4C6)cc3)n2)cc1 ; Fc1ccc(-c2nc(-c3ccc(C4(c5ccc(B(c6ccccc6)c6ccccc6)cc5)C5CC6CC(C5)CC4C6)cc3)nc(-c3cccc4ccccc34)n2)cc1 ; Fc1ccc(-c2nc(-c3ccc(C4(c5ccc(B(c6ccccc6)c6ccccc6)cc5)C5CC6CC(C5)CC4C6)cc3)nc(-c3ccc4ccccc4c3)n2)cc1]

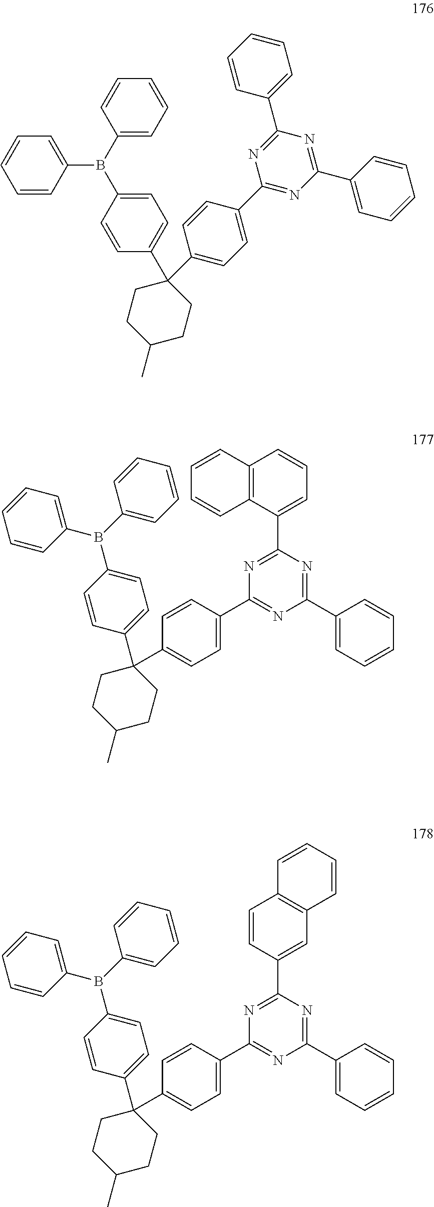 [SMILES: CC1CCC(c2ccc(B(c3ccccc3)c3ccccc3)cc2)(c2ccc(-c3nc(-c4ccccc4)nc(-c4ccccc4)n3)cc2)CC1 ; CC1CCC(c2ccc(B(c3ccccc3)c3ccccc3)cc2)(c2ccc(-c3nc(-c4ccccc4)nc(-c4cccc5ccccc45)n3)cc2)CC1 ; CC1CCC(c2ccc(B(c3ccccc3)c3ccccc3)cc2)(c2ccc(-c3nc(-c4ccccc4)nc(-c4ccc5ccccc5c4)n3)cc2)CC1]

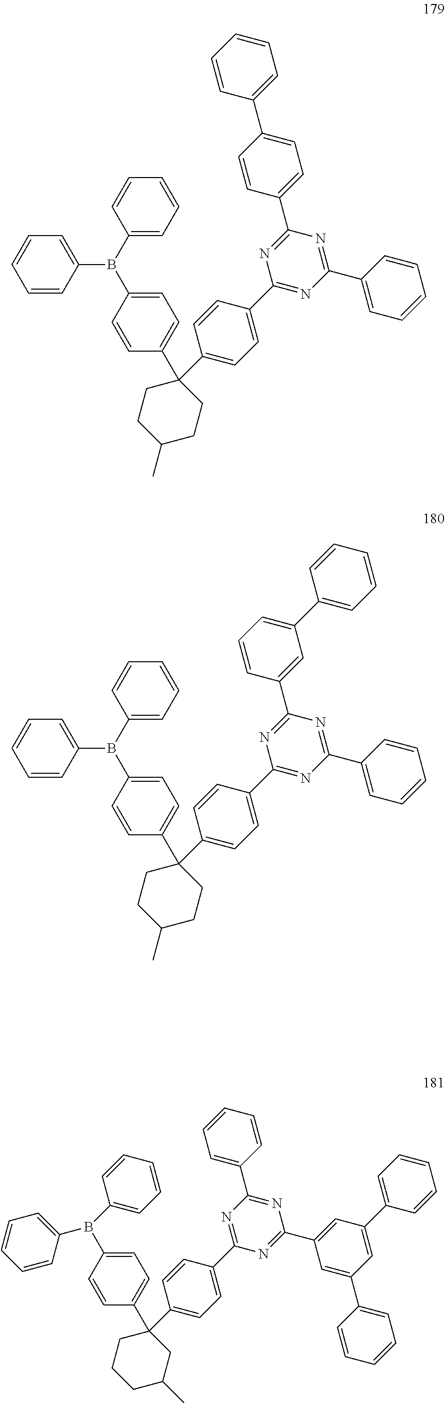 [SMILES: CC1CCC(c2ccc(B(c3ccccc3)c3ccccc3)cc2)(c2ccc(-c3nc(-c4ccccc4)nc(-c4ccc(-c5ccccc5)cc4)n3)cc2)CC1 ; CC1CCC(c2ccc(B(c3ccccc3)c3ccccc3)cc2)(c2ccc(-c3nc(-c4ccccc4)nc(-c4cccc(-c5ccccc5)c4)n3)cc2)CC1 ; CC1CCCC(c2ccc(B(c3ccccc3)c3ccccc3)cc2)(c2ccc(-c3nc(-c4ccccc4)nc(-c4cc(-c5ccccc5)cc(-c5ccccc5)c4)n3)cc2)C1]

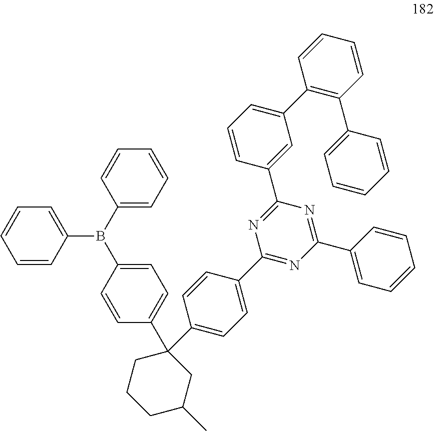 [SMILES: CC1CCCC(c2ccc(B(c3ccccc3)c3ccccc3)cc2)(c2ccc(-c3nc(-c4ccccc4)nc(-c4cccc(-c5ccccc5-c5ccccc5)c4)n3)cc2)C1]

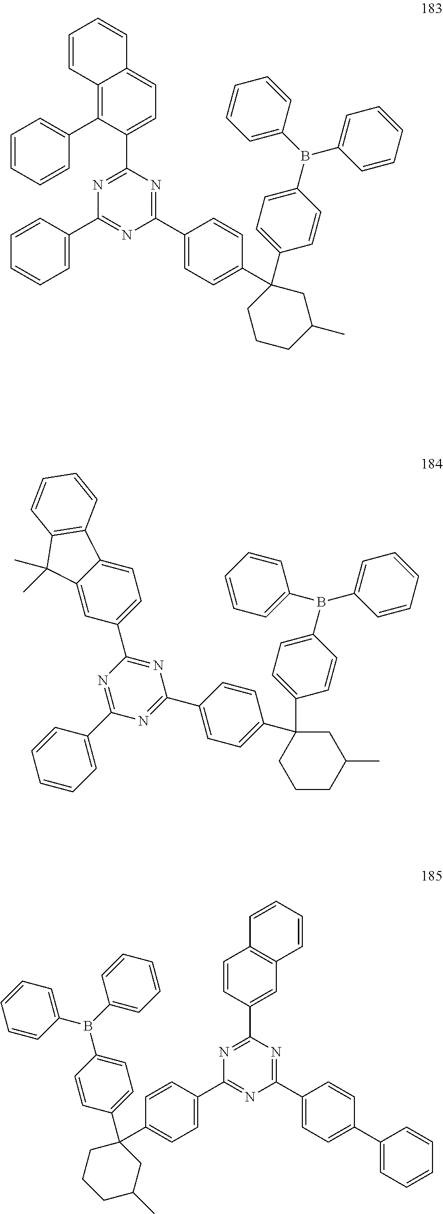 [SMILES: CC1CCCC(c2ccc(B(c3ccccc3)c3ccccc3)cc2)(c2ccc(-c3nc(-c4ccccc4)nc(-c4ccc5ccccc5c4-c4ccccc4)n3)cc2)C1 ; CC1CCCC(c2ccc(B(c3ccccc3)c3ccccc3)cc2)(c2ccc(-c3nc(-c4ccccc4)nc(-c4ccc5c(c4)C(C)(C)c4ccccc4-5)n3)cc2)C1 ; CC1CCCC(c2ccc(B(c3ccccc3)c3ccccc3)cc2)(c2ccc(-c3nc(-c4ccc(-c5ccccc5)cc4)nc(-c4ccc5ccccc5c4)n3)cc2)C1]

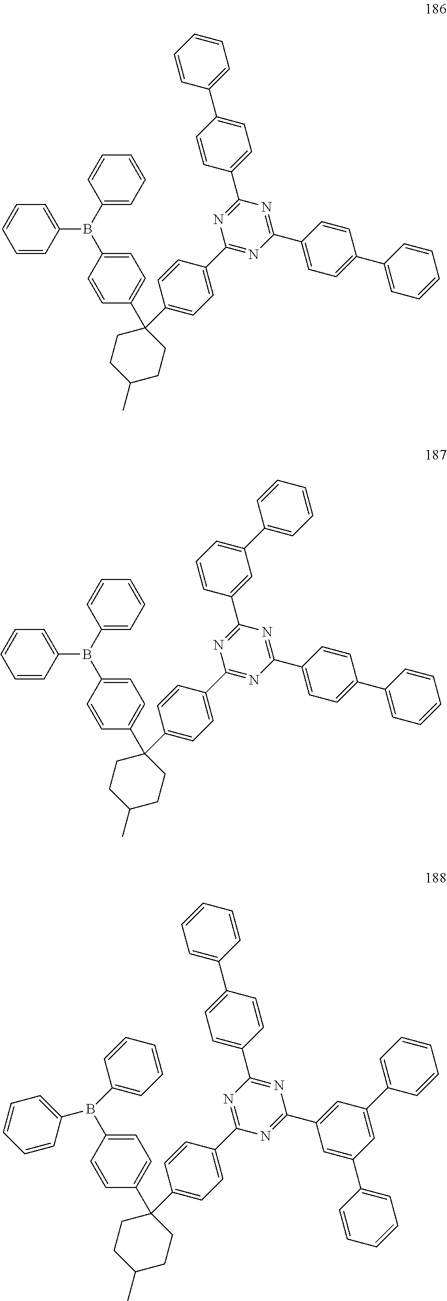 [SMILES: CC1CCC(c2ccc(B(c3ccccc3)c3ccccc3)cc2)(c2ccc(-c3nc(-c4ccc(-c5ccccc5)cc4)nc(-c4ccc(-c5ccccc5)cc4)n3)cc2)CC1 ; CC1CCC(c2ccc(B(c3ccccc3)c3ccccc3)cc2)(c2ccc(-c3nc(-c4ccc(-c5ccccc5)cc4)nc(-c4cccc(-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4cc(-c5ccccc5)cc(-c5ccccc5)c4)n3)cc2)CC1]

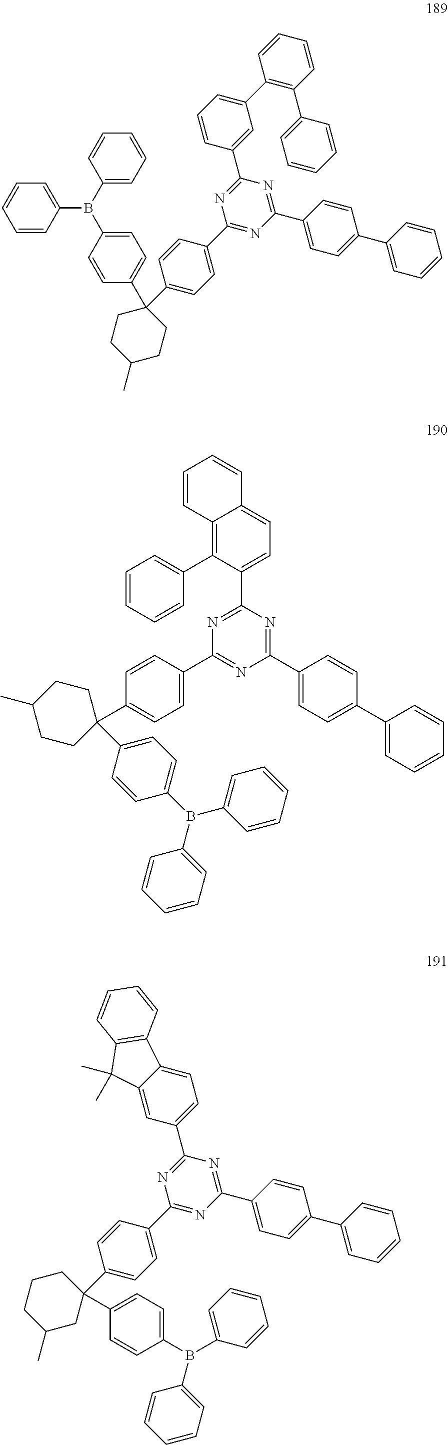 [SMILES: CC1CCC(c2ccc(B(c3ccccc3)c3ccccc3)cc2)(c2ccc(-c3nc(-c4ccc(-c5ccccc5)cc4)nc(-c4cccc(-c5ccccc5-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4ccc5ccccc5c4-c4ccccc4)n3)cc2)CC1 ; CC1CCCC(c2ccc(B(c3ccccc3)c3ccccc3)cc2)(c2ccc(-c3nc(-c4ccc(-c5ccccc5)cc4)nc(-c4ccc5c(c4)C(C)(C)c4ccccc4-5)n3)cc2)C1]

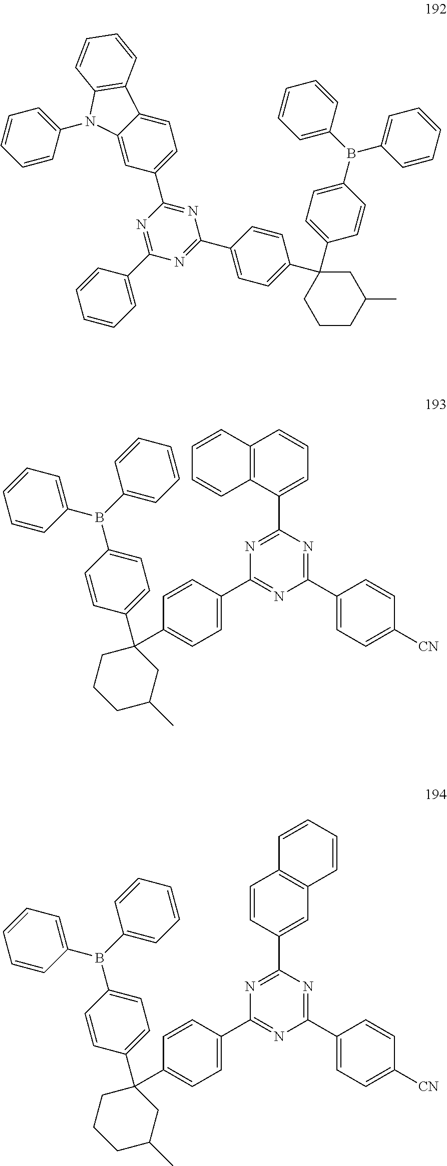 [SMILES: CC1CCCC(c2ccc(B(c3ccccc3)c3ccccc3)cc2)(c2ccc(-c3nc(-c4ccccc4)nc(-c4ccc5c6ccccc6n(-c6ccccc6)c5c4)n3)cc2)C1 ; CC1CCCC(c2ccc(B(c3ccccc3)c3ccccc3)cc2)(c2ccc(-c3nc(-c4ccc(C#N)cc4)nc(-c4cccc5ccccc45)n3)cc2)C1 ; CC1CCCC(c2ccc(B(c3ccccc3)c3ccccc3)cc2)(c2ccc(-c3nc(-c4ccc(C#N)cc4)nc(-c4ccc5ccccc5c4)n3)cc2)C1]

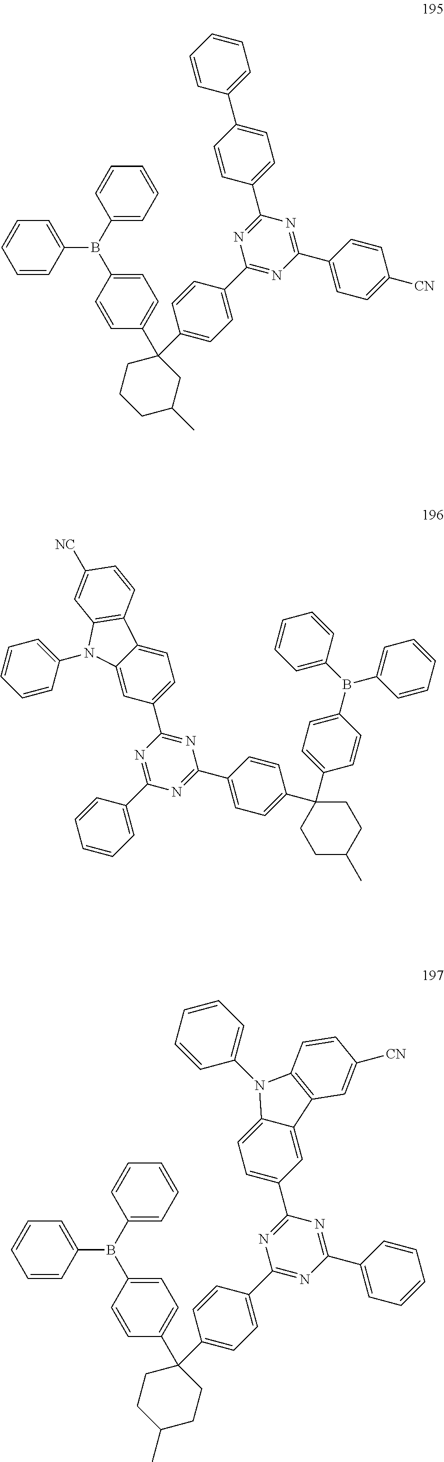 [SMILES: CC1CCCC(c2ccc(B(c3ccccc3)c3ccccc3)cc2)(c2ccc(-c3nc(-c4ccc(C#N)cc4)nc(-c4ccc(-c5ccccc5)cc4)n3)cc2)C1 ; CC1CCC(c2ccc(B(c3ccccc3)c3ccccc3)cc2)(c2ccc(-c3nc(-c4ccccc4)nc(-c4ccc5c6ccc(C#N)cc6n(-c6ccccc6)c5c4)n3)cc2)CC1 ; CC1CCC(c2ccc(B(c3ccccc3)c3ccccc3)cc2)(c2ccc(-c3nc(-c4ccccc4)nc(-c4ccc5c(c4)c4cc(C#N)ccc4n5-c4ccccc4)n3)cc2)CC1]

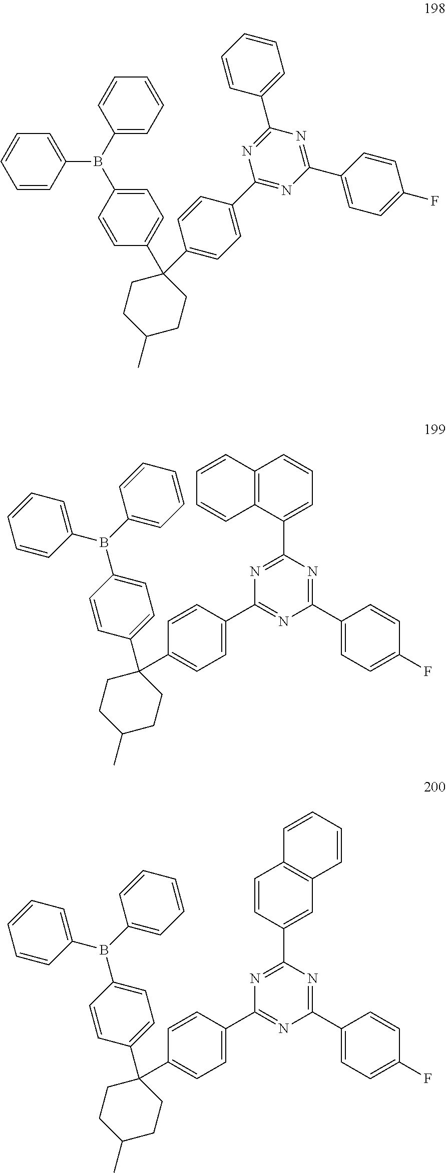 [SMILES: CC1CCC(c2ccc(B(c3ccccc3)c3ccccc3)cc2)(c2ccc(-c3nc(-c4ccccc4)nc(-c4ccc(F)cc4)n3)cc2)CC1 ; CC1CCC(c2ccc(B(c3ccccc3)c3ccccc3)cc2)(c2ccc(-c3nc(-c4ccc(F)cc4)nc(-c4cccc5ccccc45)n3)cc2)CC1 ; CC1CCC(c2ccc(B(c3ccccc3)c3ccccc3)cc2)(c2ccc(-c3nc(-c4ccc(F)cc4)nc(-c4ccc5ccccc5c4)n3)cc2)CC1]

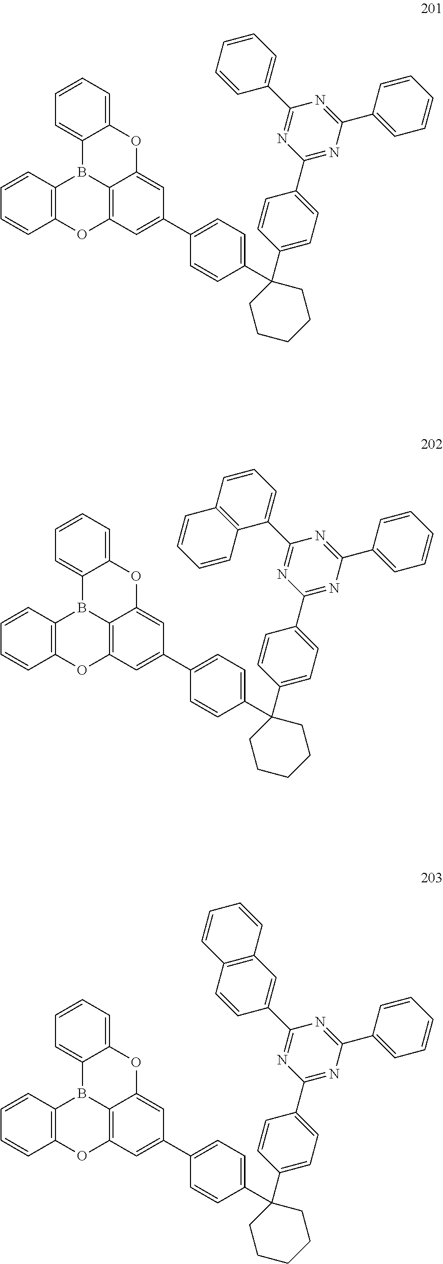 [SMILES: c1ccc(-c2nc(-c3ccccc3)nc(-c3ccc(C4(c5ccc(-c6cc7c8c(c6)Oc6ccccc6B8c6ccccc6O7)cc5)CCCCC4)cc3)n2)cc1 ; c1ccc(-c2nc(-c3ccc(C4(c5ccc(-c6cc7c8c(c6)Oc6ccccc6B8c6ccccc6O7)cc5)CCCCC4)cc3)nc(-c3cccc4ccccc34)n2)cc1 ; c1ccc(-c2nc(-c3ccc(C4(c5ccc(-c6cc7c8c(c6)Oc6ccccc6B8c6ccccc6O7)cc5)CCCCC4)cc3)nc(-c3ccc4ccccc4c3)n2)cc1]

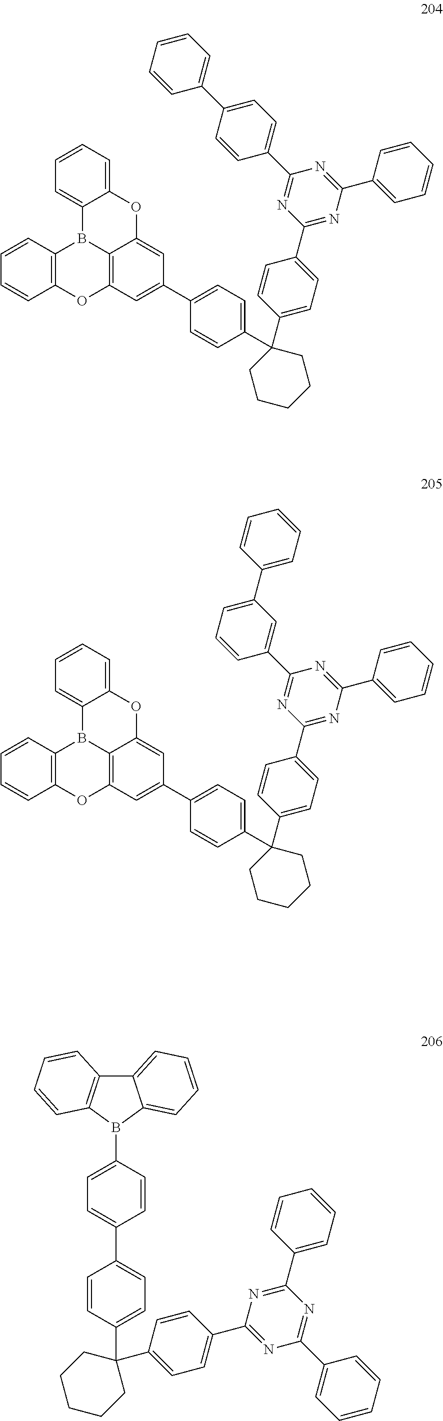 [SMILES: c1ccc(-c2ccc(-c3nc(-c4ccccc4)nc(-c4ccc(C5(c6ccc(-c7cc8c9c(c7)Oc7ccccc7B9c7ccccc7O8)cc6)CCCCC5)cc4)n3)cc2)cc1 ; c1ccc(-c2cccc(-c3nc(-c4ccccc4)nc(-c4ccc(C5(c6ccc(-c7cc8c9c(c7)Oc7ccccc7B9c7ccccc7O8)cc6)CCCCC5)cc4)n3)c2)cc1 ; c1ccc(-c2nc(-c3ccccc3)nc(-c3ccc(C4(c5ccc(-c6ccc(B7c8ccccc8-c8ccccc87)cc6)cc5)CCCCC4)cc3)n2)cc1]

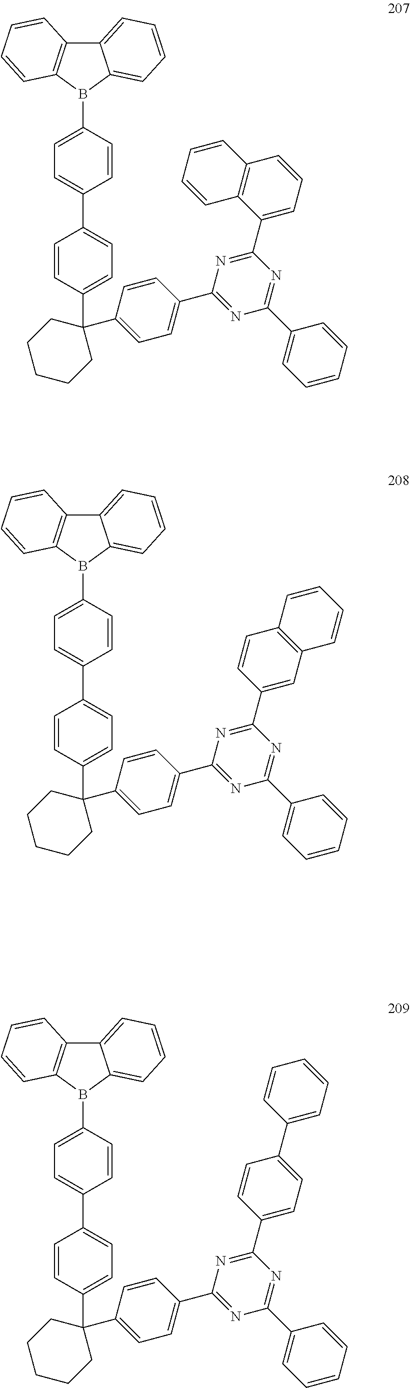 [SMILES: c1ccc(-c2nc(-c3ccc(C4(c5ccc(-c6ccc(B7c8ccccc8-c8ccccc87)cc6)cc5)CCCCC4)cc3)nc(-c3cccc4ccccc34)n2)cc1 ; c1ccc(-c2nc(-c3ccc(C4(c5ccc(-c6ccc(B7c8ccccc8-c8ccccc87)cc6)cc5)CCCCC4)cc3)nc(-c3ccc4ccccc4c3)n2)cc1 ; c1ccc(-c2ccc(-c3nc(-c4ccccc4)nc(-c4ccc(C5(c6ccc(-c7ccc(B8c9ccccc9-c9ccccc98)cc7)cc6)CCCCC5)cc4)n3)cc2)cc1]

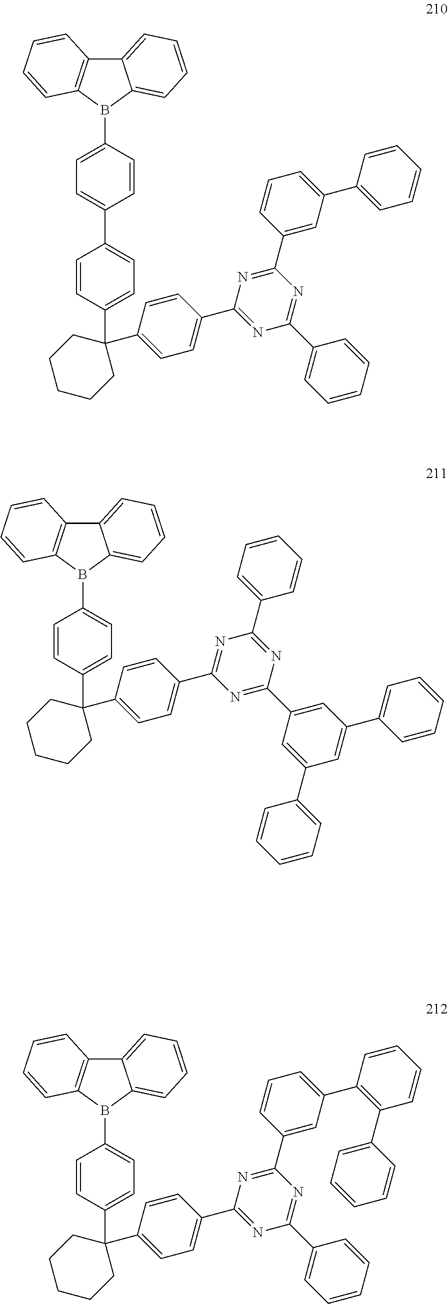 [SMILES: c1ccc(-c2cccc(-c3nc(-c4ccccc4)nc(-c4ccc(C5(c6ccc(-c7ccc(B8c9ccccc9-c9ccccc98)cc7)cc6)CCCCC5)cc4)n3)c2)cc1 ; c1ccc(-c2cc(-c3ccccc3)cc(-c3nc(-c4ccccc4)nc(-c4ccc(C5(c6ccc(B7c8ccccc8-c8ccccc87)cc6)CCCCC5)cc4)n3)c2)cc1 ; c1ccc(-c2nc(-c3ccc(C4(c5ccc(B6c7ccccc7-c7ccccc76)cc5)CCCCC4)cc3)nc(-c3cccc(-c4ccccc4-c4ccccc4)c3)n2)cc1]

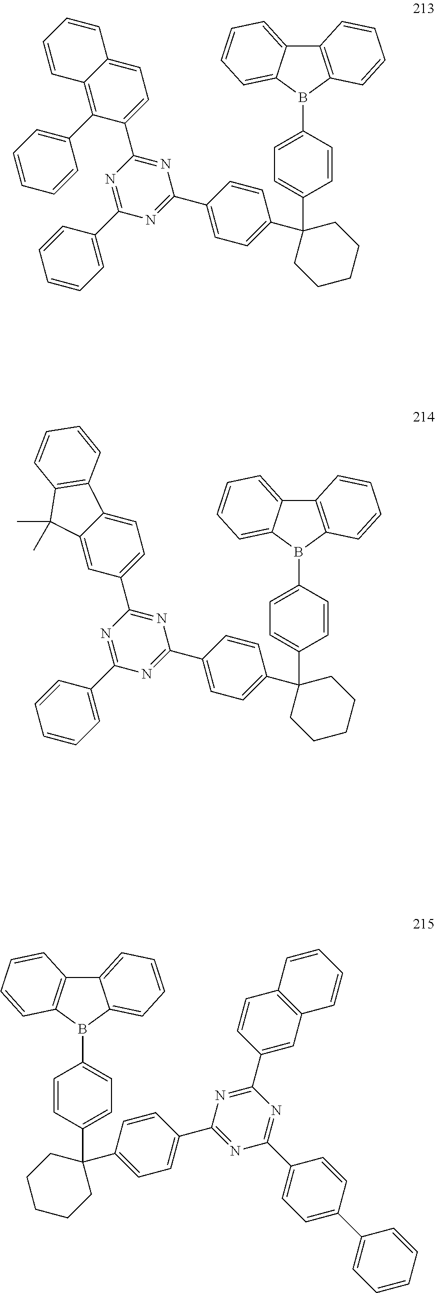 [SMILES: c1ccc(-c2nc(-c3ccc(C4(c5ccc(B6c7ccccc7-c7ccccc76)cc5)CCCCC4)cc3)nc(-c3ccc4ccccc4c3-c3ccccc3)n2)cc1 ; CC1(C)c2ccccc2-c2ccc(-c3nc(-c4ccccc4)nc(-c4ccc(C5(c6ccc(B7c8ccccc8-c8ccccc87)cc6)CCCCC5)cc4)n3)cc21 ; c1ccc(-c2ccc(-c3nc(-c4ccc(C5(c6ccc(B7c8ccccc8-c8ccccc87)cc6)CCCCC5)cc4)nc(-c4ccc5ccccc5c4)n3)cc2)cc1]

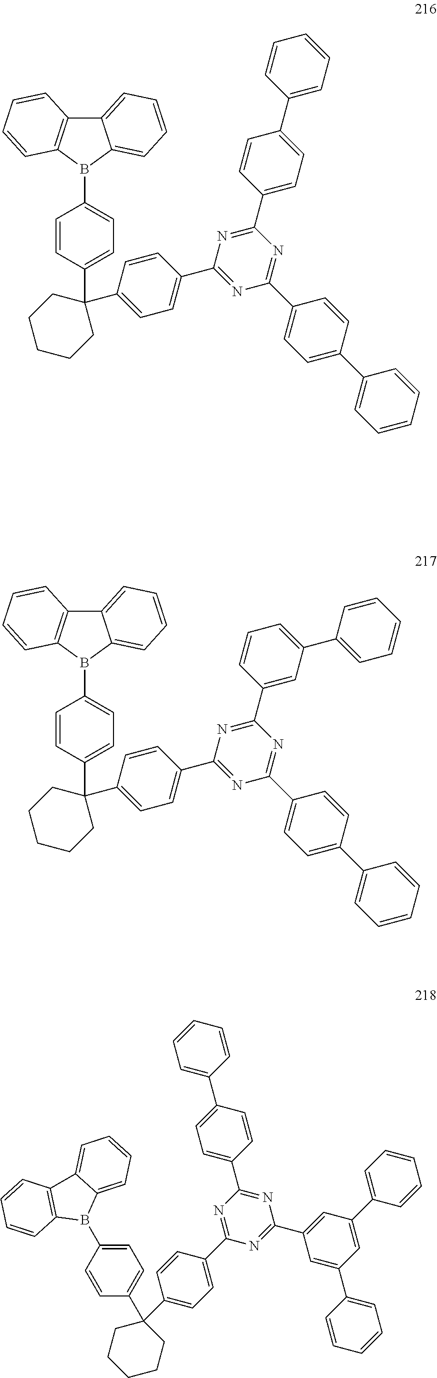 [SMILES: c1ccc(-c2ccc(-c3nc(-c4ccc(-c5ccccc5)cc4)nc(-c4ccc(C5(c6ccc(B7c8ccccc8-c8ccccc87)cc6)CCCCC5)cc4)n3)cc2)cc1 ; c1ccc(-c2ccc(-c3nc(-c4ccc(C5(c6ccc(B7c8ccccc8-c8ccccc87)cc6)CCCCC5)cc4)nc(-c4cccc(-c5ccccc5)c4)n3)cc2)cc1 ; c1ccc(-c2ccc(-c3nc(-c4ccc(C5(c6ccc(B7c8ccccc8-c8ccccc87)cc6)CCCCC5)cc4)nc(-c4cc(-c5ccccc5)cc(-c5ccccc5)c4)n3)cc2)cc1]

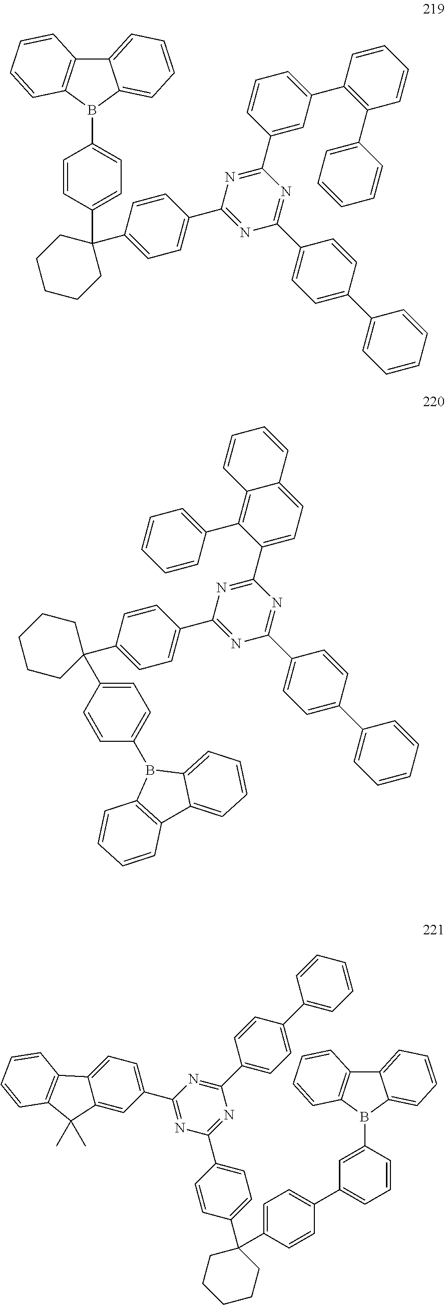 [SMILES: c1ccc(-c2ccc(-c3nc(-c4ccc(C5(c6ccc(B7c8ccccc8-c8ccccc87)cc6)CCCCC5)cc4)nc(-c4cccc(-c5ccccc5-c5ccccc5)c4)n3)cc2)cc1 ; c1ccc(-c2ccc(-c3nc(-c4ccc(C5(c6ccc(B7c8ccccc8-c8ccccc87)cc6)CCCCC5)cc4)nc(-c4ccc5ccccc5c4-c4ccccc4)n3)cc2)cc1 ; CC1(C)c2ccccc2-c2ccc(-c3nc(-c4ccc(-c5ccccc5)cc4)nc(-c4ccc(C5(c6ccc(-c7cccc(B8c9ccccc9-c9ccccc98)c7)cc6)CCCCC5)cc4)n3)cc21]

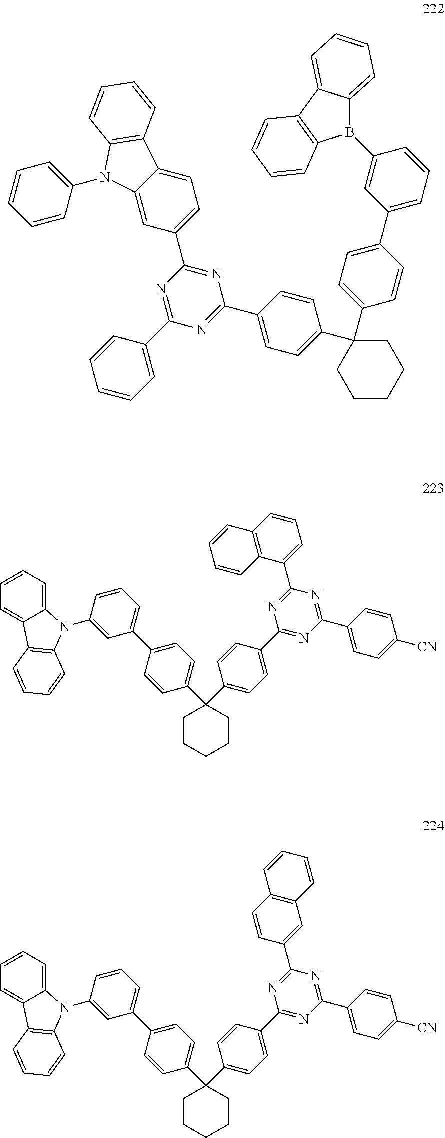 [SMILES: c1ccc(-c2nc(-c3ccc(C4(c5ccc(-c6cccc(B7c8ccccc8-c8ccccc87)c6)cc5)CCCCC4)cc3)nc(-c3ccc4c5ccccc5n(-c5ccccc5)c4c3)n2)cc1 ; N#Cc1ccc(-c2nc(-c3ccc(C4(c5ccc(-c6cccc(-n7c8ccccc8c8ccccc87)c6)cc5)CCCCC4)cc3)nc(-c3cccc4ccccc34)n2)cc1 ; N#Cc1ccc(-c2nc(-c3ccc(C4(c5ccc(-c6cccc(-n7c8ccccc8c8ccccc87)c6)cc5)CCCCC4)cc3)nc(-c3ccc4ccccc4c3)n2)cc1]

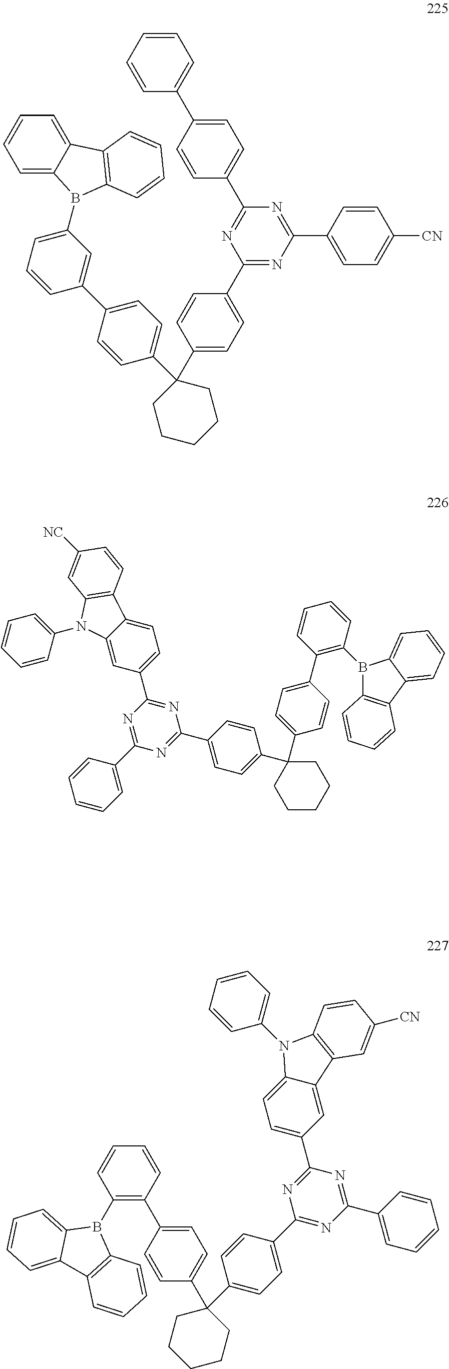 [SMILES: N#Cc1ccc(-c2nc(-c3ccc(-c4ccccc4)cc3)nc(-c3ccc(C4(c5ccc(-c6cccc(B7c8ccccc8-c8ccccc87)c6)cc5)CCCCC4)cc3)n2)cc1 ; N#Cc1ccc2c3ccc(-c4nc(-c5ccccc5)nc(-c5ccc(C6(c7ccc(-c8ccccc8B8c9ccccc9-c9ccccc98)cc7)CCCCC6)cc5)n4)cc3n(-c3ccccc3)c2c1 ; N#Cc1ccc2c(c1)c1cc(-c3nc(-c4ccccc4)nc(-c4ccc(C5(c6ccc(-c7ccccc7B7c8ccccc8-c8ccccc87)cc6)CCCCC5)cc4)n3)ccc1n2-c1ccccc1]

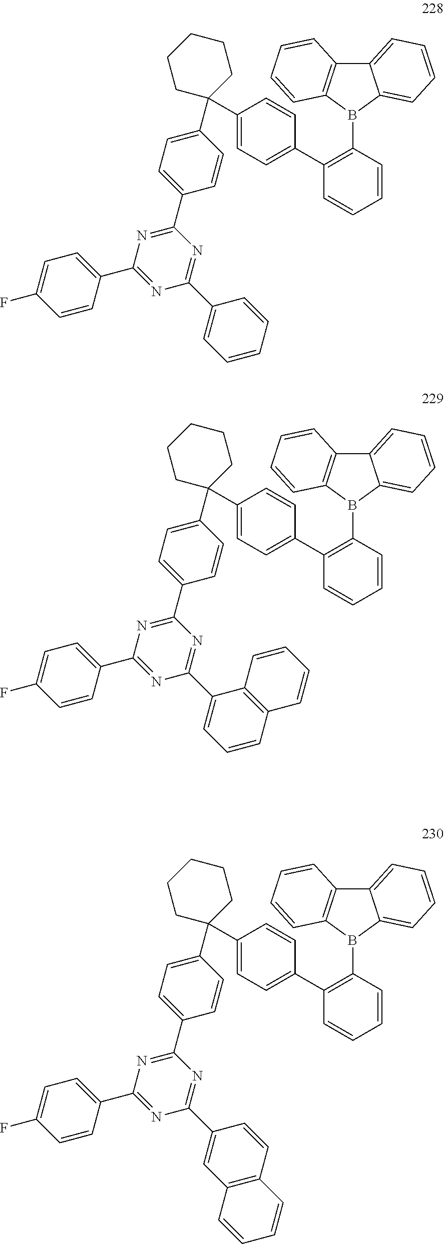 [SMILES: Fc1ccc(-c2nc(-c3ccccc3)nc(-c3ccc(C4(c5ccc(-c6ccccc6B6c7ccccc7-c7ccccc76)cc5)CCCCC4)cc3)n2)cc1 ; Fc1ccc(-c2nc(-c3ccc(C4(c5ccc(-c6ccccc6B6c7ccccc7-c7ccccc76)cc5)CCCCC4)cc3)nc(-c3cccc4ccccc34)n2)cc1 ; Fc1ccc(-c2nc(-c3ccc(C4(c5ccc(-c6ccccc6B6c7ccccc7-c7ccccc76)cc5)CCCCC4)cc3)nc(-c3ccc4ccccc4c3)n2)cc1]

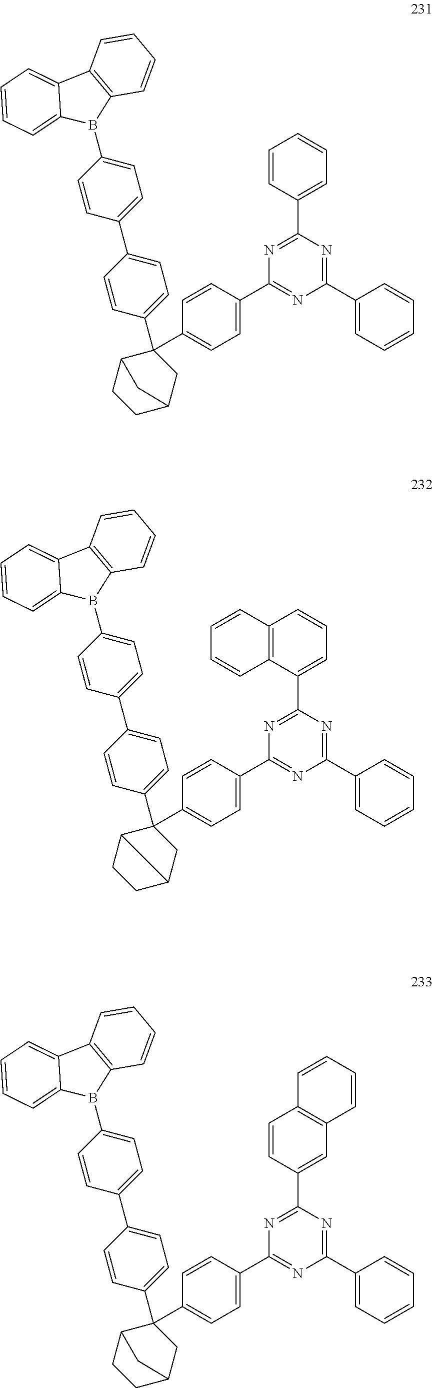 [SMILES: c1ccc(-c2nc(-c3ccccc3)nc(-c3ccc(C4(c5ccc(-c6ccc(B7c8ccccc8-c8ccccc87)cc6)cc5)CC5CCC4C5)cc3)n2)cc1 ; c1ccc(-c2nc(-c3ccc(C4(c5ccc(-c6ccc(B7c8ccccc8-c8ccccc87)cc6)cc5)CC5CCC54)cc3)nc(-c3cccc4ccccc34)n2)cc1 ; c1ccc(-c2nc(-c3ccc(C4(c5ccc(-c6ccc(B7c8ccccc8-c8ccccc87)cc6)cc5)CC5CCC4C5)cc3)nc(-c3ccc4ccccc4c3)n2)cc1]

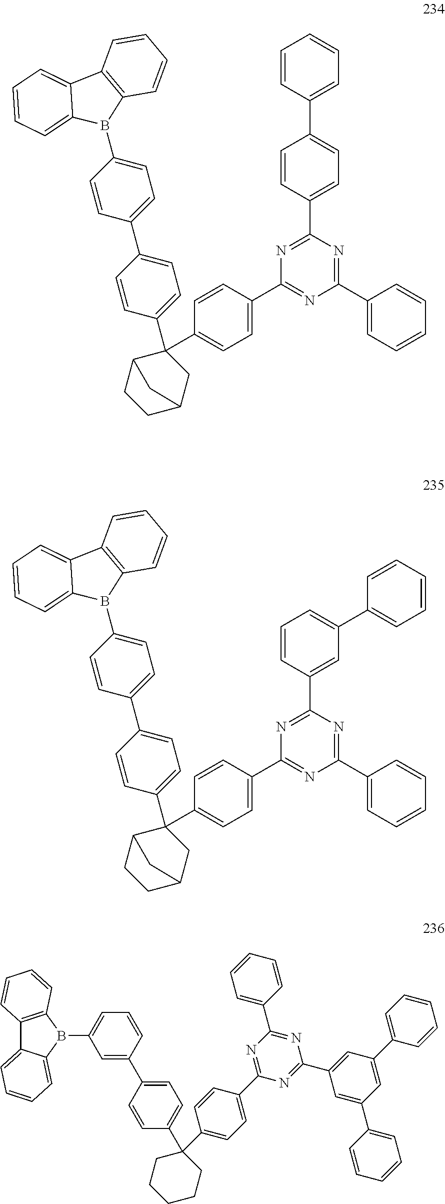 [SMILES: c1ccc(-c2ccc(-c3nc(-c4ccccc4)nc(-c4ccc(C5(c6ccc(-c7ccc(B8c9ccccc9-c9ccccc98)cc7)cc6)CC6CCC5C6)cc4)n3)cc2)cc1 ; c1ccc(-c2cccc(-c3nc(-c4ccccc4)nc(-c4ccc(C5(c6ccc(-c7ccc(B8c9ccccc9-c9ccccc98)cc7)cc6)CC6CCC5C6)cc4)n3)c2)cc1 ; c1ccc(-c2cc(-c3ccccc3)cc(-c3nc(-c4ccccc4)nc(-c4ccc(C5(c6ccc(-c7cccc(B8c9ccccc9-c9ccccc98)c7)cc6)CCCCC5)cc4)n3)c2)cc1]

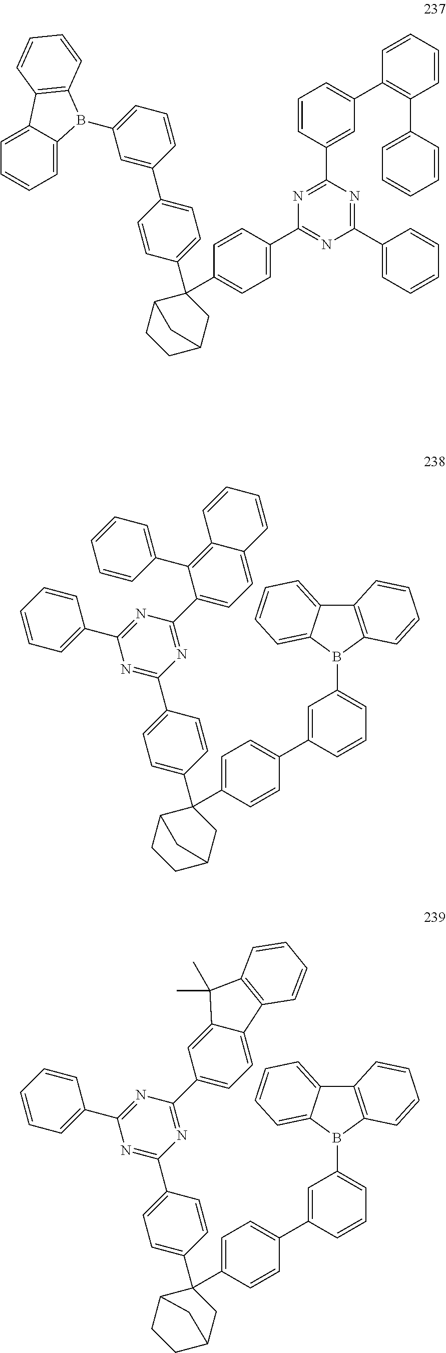 [SMILES: c1ccc(-c2nc(-c3ccc(C4(c5ccc(-c6cccc(B7c8ccccc8-c8ccccc87)c6)cc5)CC5CCC4C5)cc3)nc(-c3cccc(-c4ccccc4-c4ccccc4)c3)n2)cc1 ; c1ccc(-c2nc(-c3ccc(C4(c5ccc(-c6cccc(B7c8ccccc8-c8ccccc87)c6)cc5)CC5CCC4C5)cc3)nc(-c3ccc4ccccc4c3-c3ccccc3)n2)cc1 ; CC1(C)c2ccccc2-c2ccc(-c3nc(-c4ccccc4)nc(-c4ccc(C5(c6ccc(-c7cccc(B8c9ccccc9-c9ccccc98)c7)cc6)CC6CCC5C6)cc4)n3)cc21]

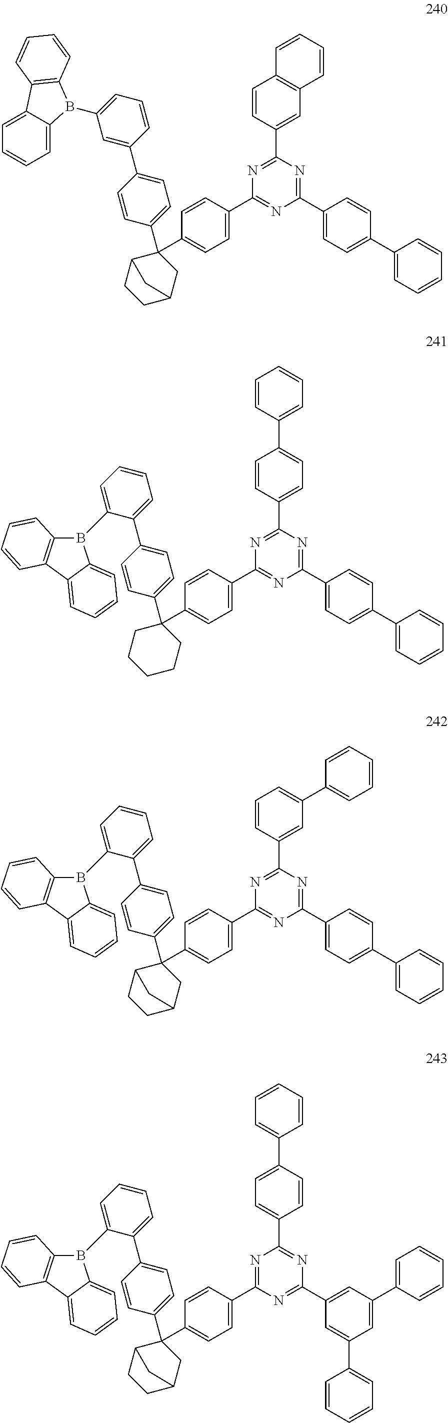 [SMILES: c1ccc(-c2ccc(-c3nc(-c4ccc(C5(c6ccc(-c7cccc(B8c9ccccc9-c9ccccc98)c7)cc6)CC6CCC5C6)cc4)nc(-c4ccc5ccccc5c4)n3)cc2)cc1 ; c1ccc(-c2ccc(-c3nc(-c4ccc(-c5ccccc5)cc4)nc(-c4ccc(C5(c6ccc(-c7ccccc7B7c8ccccc8-c8ccccc87)cc6)CCCCC5)cc4)n3)cc2)cc1 ; c1ccc(-c2ccc(-c3nc(-c4ccc(C5(c6ccc(-c7ccccc7B7c8ccccc8-c8ccccc87)cc6)CC6CCC5C6)cc4)nc(-c4cccc(-c5ccccc5)c4)n3)cc2)cc1 ; c1ccc(-c2ccc(-c3nc(-c4ccc(C5(c6ccc(-c7ccccc7B7c8ccccc8-c8ccccc87)cc6)CC6CCC5C6)cc4)nc(-c4cc(-c5ccccc5)cc(-c5ccccc5)c4)n3)cc2)cc1]

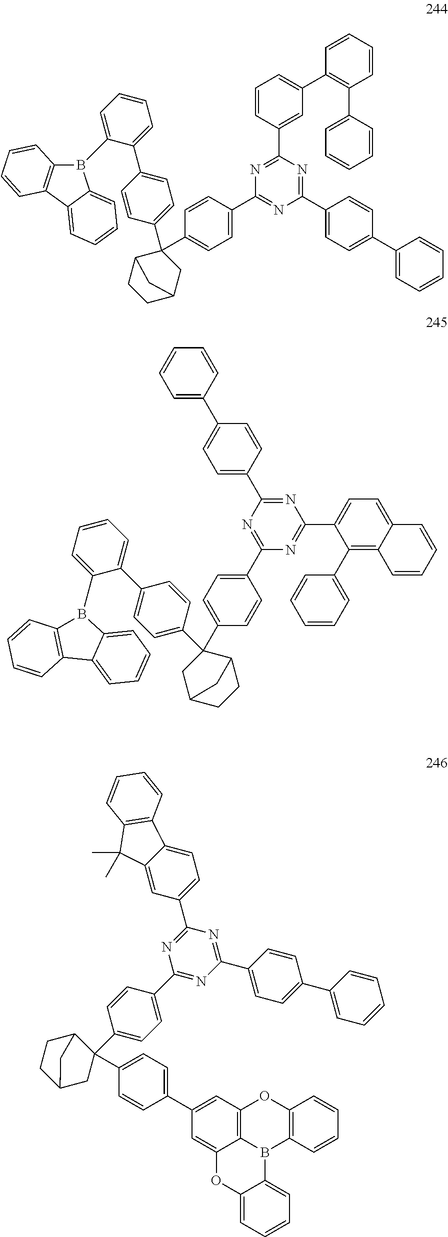 [SMILES: c1ccc(-c2ccc(-c3nc(-c4ccc(C5(c6ccc(-c7ccccc7B7c8ccccc8-c8ccccc87)cc6)CC6CCC5C6)cc4)nc(-c4cccc(-c5ccccc5-c5ccccc5)c4)n3)cc2)cc1 ; c1ccc(-c2ccc(-c3nc(-c4ccc(C5(c6ccc(-c7ccccc7B7c8ccccc8-c8ccccc87)cc6)CC6CCC5C6)cc4)nc(-c4ccc5ccccc5c4-c4ccccc4)n3)cc2)cc1 ; CC1(C)c2ccccc2-c2ccc(-c3nc(-c4ccc(-c5ccccc5)cc4)nc(-c4ccc(C5(c6ccc(-c7cc8c9c(c7)Oc7ccccc7B9c7ccccc7O8)cc6)CC6CCC5C6)cc4)n3)cc21]

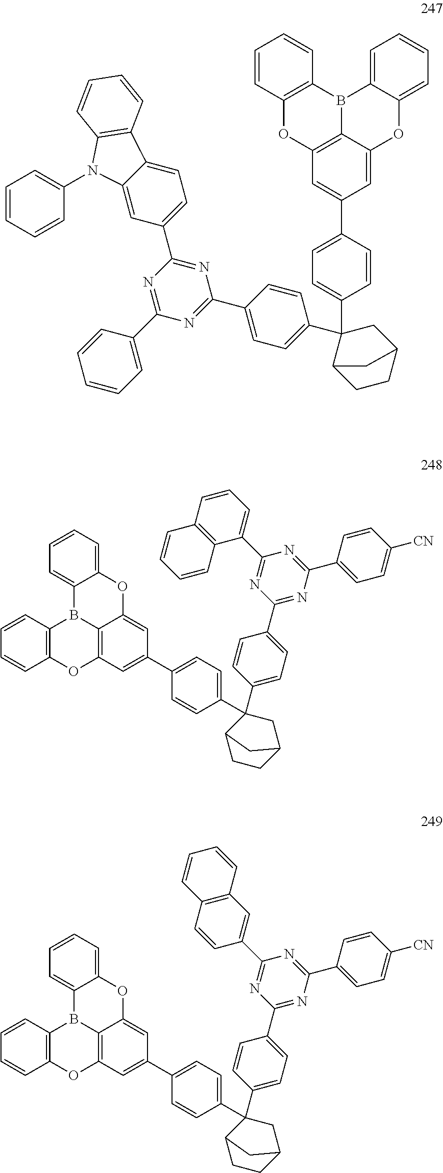 [SMILES: c1ccc(-c2nc(-c3ccc(C4(c5ccc(-c6cc7c8c(c6)Oc6ccccc6B8c6ccccc6O7)cc5)CC5CCC4C5)cc3)nc(-c3ccc4c5ccccc5n(-c5ccccc5)c4c3)n2)cc1 ; N#Cc1ccc(-c2nc(-c3ccc(C4(c5ccc(-c6cc7c8c(c6)Oc6ccccc6B8c6ccccc6O7)cc5)CC5CCC4C5)cc3)nc(-c3cccc4ccccc34)n2)cc1 ; N#Cc1ccc(-c2nc(-c3ccc(C4(c5ccc(-c6cc7c8c(c6)Oc6ccccc6B8c6ccccc6O7)cc5)CC5CCC4C5)cc3)nc(-c3ccc4ccccc4c3)n2)cc1]

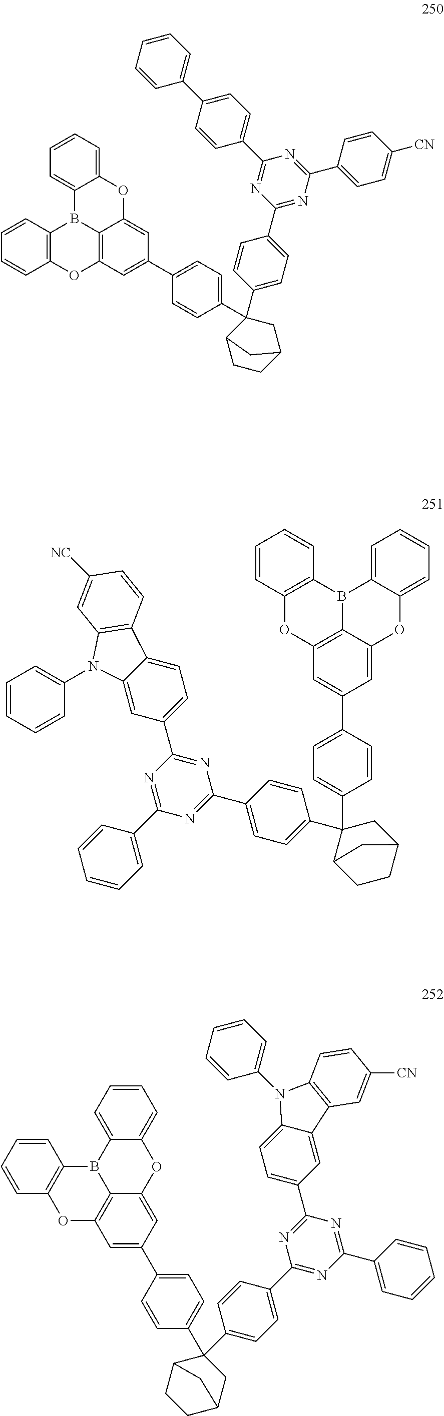 [SMILES: N#Cc1ccc(-c2nc(-c3ccc(-c4ccccc4)cc3)nc(-c3ccc(C4(c5ccc(-c6cc7c8c(c6)Oc6ccccc6B8c6ccccc6O7)cc5)CC5CCC4C5)cc3)n2)cc1 ; N#Cc1ccc2c3ccc(-c4nc(-c5ccccc5)nc(-c5ccc(C6(c7ccc(-c8cc9c%10c(c8)Oc8ccccc8B%10c8ccccc8O9)cc7)CC7CCC6C7)cc5)n4)cc3n(-c3ccccc3)c2c1 ; N#Cc1ccc2c(c1)c1cc(-c3nc(-c4ccccc4)nc(-c4ccc(C5(c6ccc(-c7cc8c9c(c7)Oc7ccccc7B9c7ccccc7O8)cc6)CC6CCC5C6)cc4)n3)ccc1n2-c1ccccc1]

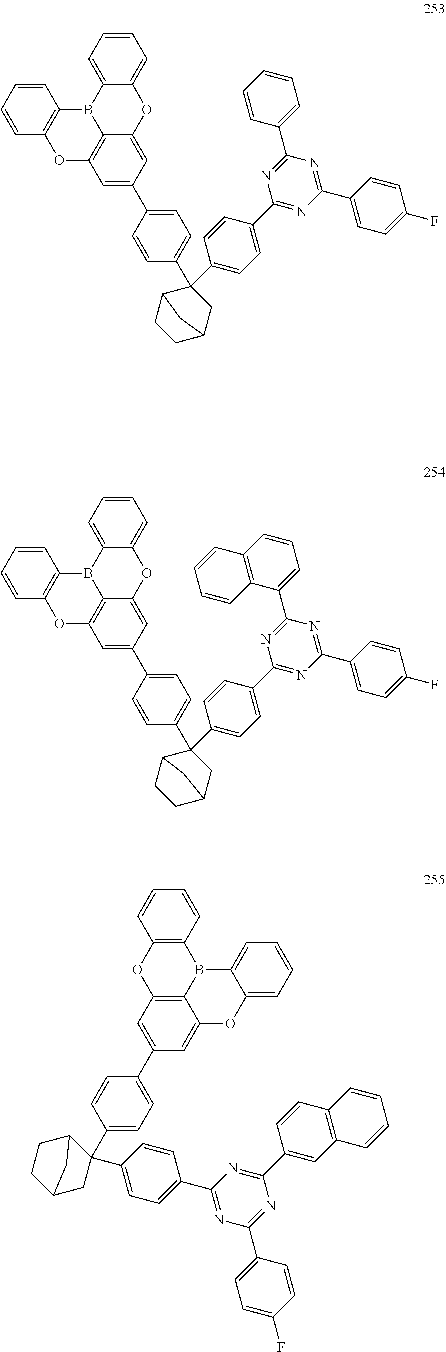 [SMILES: Fc1ccc(-c2nc(-c3ccccc3)nc(-c3ccc(C4(c5ccc(-c6cc7c8c(c6)Oc6ccccc6B8c6ccccc6O7)cc5)CC5CCC4C5)cc3)n2)cc1 ; Fc1ccc(-c2nc(-c3ccc(C4(c5ccc(-c6cc7c8c(c6)Oc6ccccc6B8c6ccccc6O7)cc5)CC5CCC4C5)cc3)nc(-c3cccc4ccccc34)n2)cc1 ; Fc1ccc(-c2nc(-c3ccc(C4(c5ccc(-c6cc7c8c(c6)Oc6ccccc6B8c6ccccc6O7)cc5)CC5CCC4C5)cc3)nc(-c3ccc4ccccc4c3)n2)cc1]

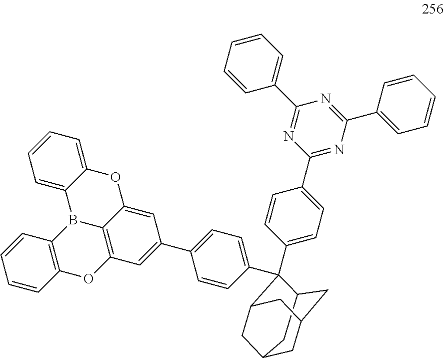 [SMILES: c1ccc(-c2nc(-c3ccccc3)nc(-c3ccc(C4(c5ccc(-c6cc7c8c(c6)Oc6ccccc6B8c6ccccc6O7)cc5)C5CC6CC(C5)CC4C6)cc3)n2)cc1]

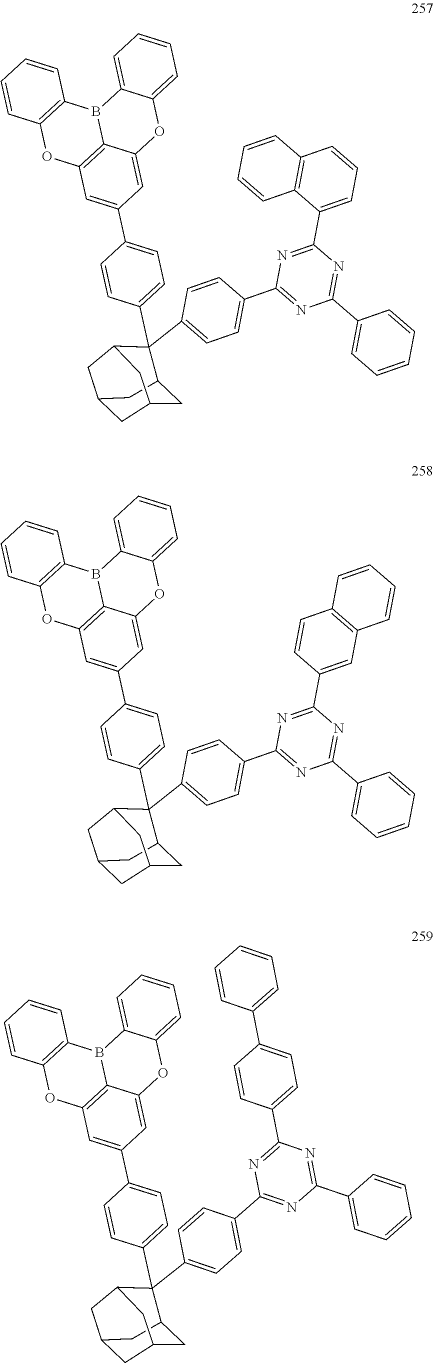 [SMILES: c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3cccc4ccccc34)n2)cc1 ; c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3ccc4ccccc4c3)n2)cc1 ; c1ccc(-c2ccc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)cc2)cc1]

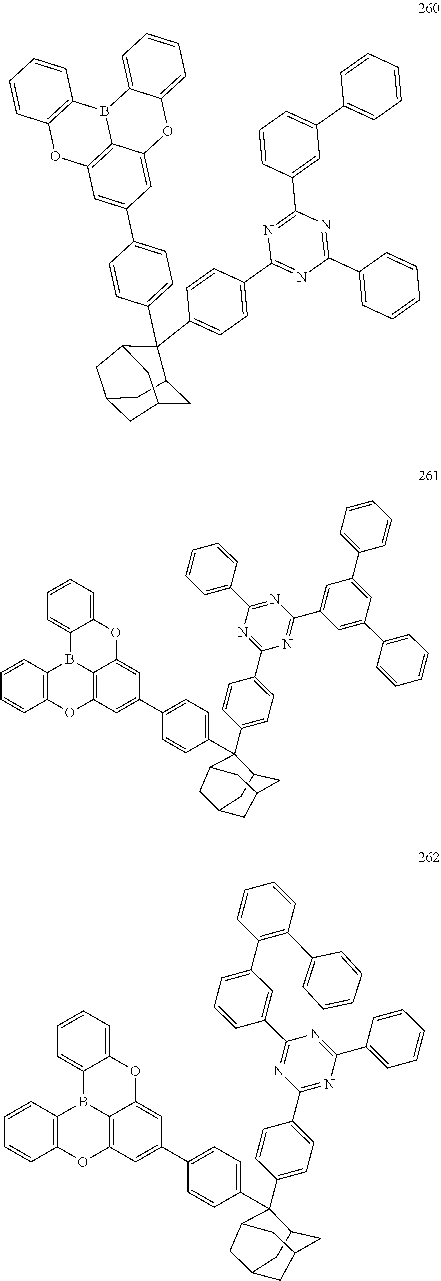 [SMILES: c1ccc(-c2cccc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)c2)cc1 ; c1ccc(-c2cc(-c3ccccc3)cc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)c2)cc1 ; c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3cccc(-c4ccccc4-c4ccccc4)c3)n2)cc1]

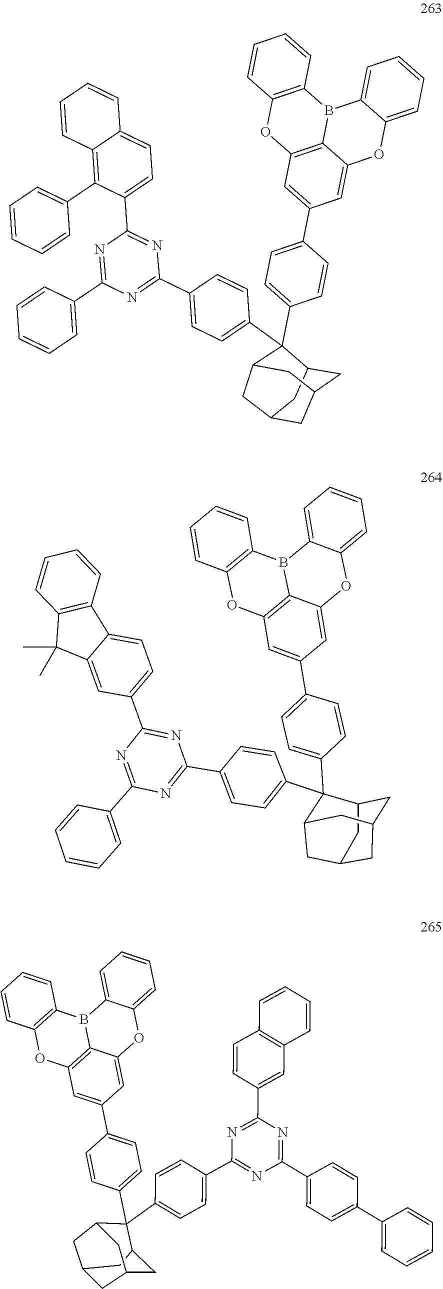 [SMILES: c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3ccc4ccccc4c3-c3ccccc3)n2)cc1 ; CC1(C)c2ccccc2-c2ccc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)cc21 ; c1ccc(-c2ccc(-c3nc(-c4ccc(C5(c6ccc(-c7cc8c9c(c7)Oc7ccccc7B9c7ccccc7O8)cc6)C6CC7CC(C6)CC5C7)cc4)nc(-c4ccc5ccccc5c4)n3)cc2)cc1]

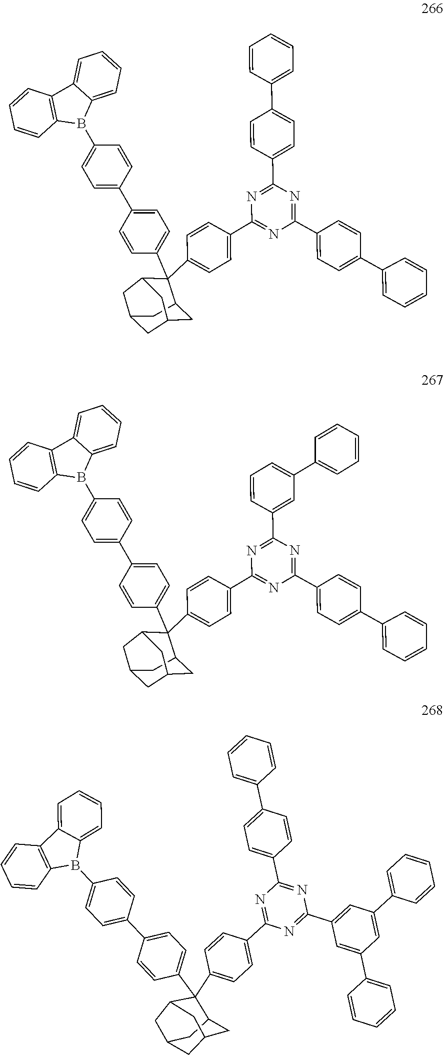 [SMILES: c1ccc(-c2ccc(-c3nc(-c4ccc(-c5ccccc5)cc4)nc(-c4ccc(C5(c6ccc(-c7ccc(B8c9ccccc9-c9ccccc98)cc7)cc6)C6CC7CC(C6)CC5C7)cc4)n3)cc2)cc1 ; c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cccc(-c5ccccc5)c4)n3)cc2)cc1 ; c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cc(-c5ccccc5)cc(-c5ccccc5)c4)n3)cc2)cc1]

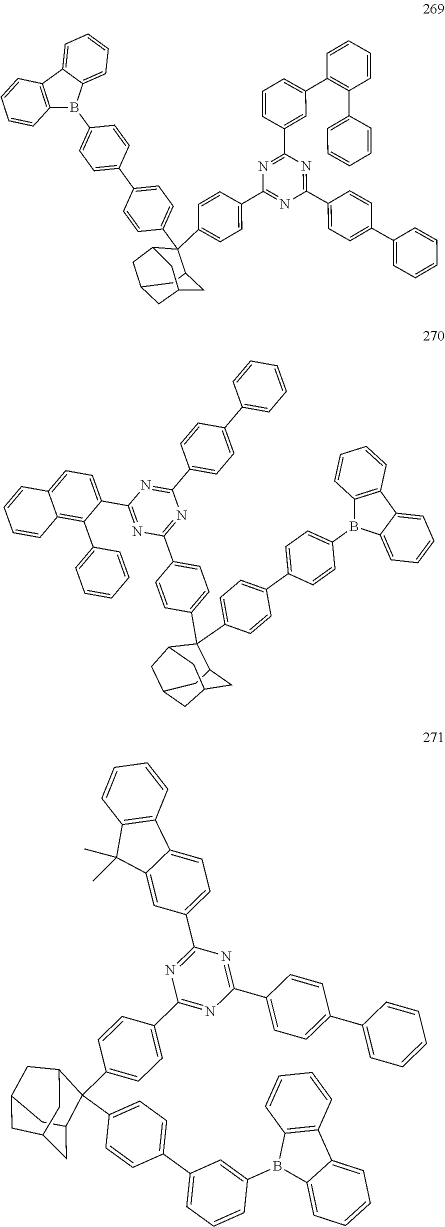 [SMILES: c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cccc(-c5ccccc5-c5ccccc5)c4)n3)cc2)cc1 ; c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4ccc5ccccc5c4-c4ccccc4)n3)cc2)cc1 ; CC1(C)c2ccccc2-c2ccc(-c3nc(-c4ccc(-c5ccccc5)cc4)nc(-c4ccc(C5(c6ccc(-c7cccc(B8c9ccccc9-c9ccccc98)c7)cc6)C6CC7CC(C6)CC5C7)cc4)n3)cc21]

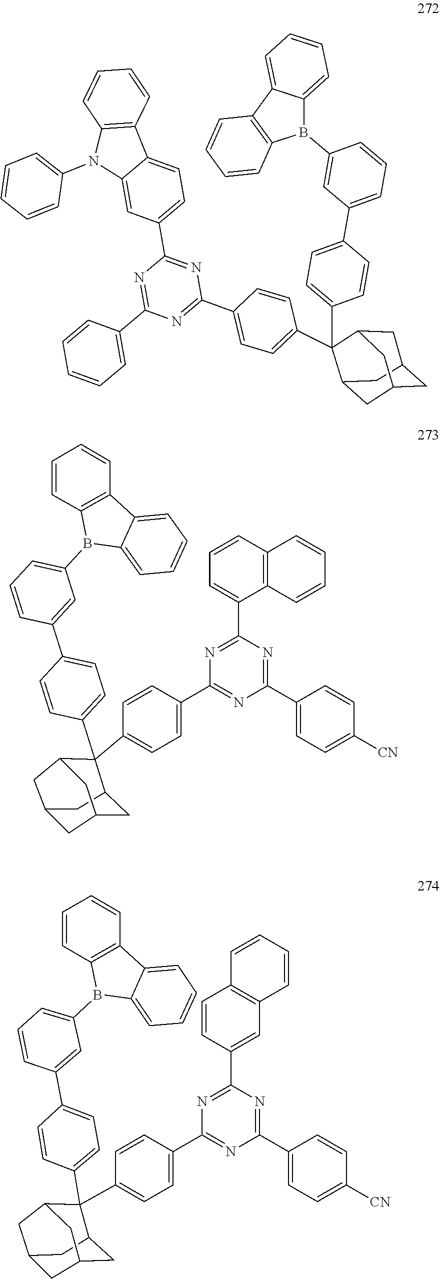 [SMILES: c1ccc(-c2nc(-c3ccc(C4(c5ccc(-c6cccc(B7c8ccccc8-c8ccccc87)c6)cc5)C5CC6CC(C5)CC4C6)cc3)nc(-c3ccc4c5ccccc5n(-c5ccccc5)c4c3)n2)cc1 ; N#Cc1ccc(-c2nc(-c3ccc(C4(c5ccc(-c6cccc(B7c8ccccc8-c8ccccc87)c6)cc5)C5CC6CC(C5)CC4C6)cc3)nc(-c3cccc4ccccc34)n2)cc1 ; N#Cc1ccc(-c2nc(-c3ccc(C4(c5ccc(-c6cccc(B7c8ccccc8-c8ccccc87)c6)cc5)C5CC6CC(C5)CC4C6)cc3)nc(-c3ccc4ccccc4c3)n2)cc1]

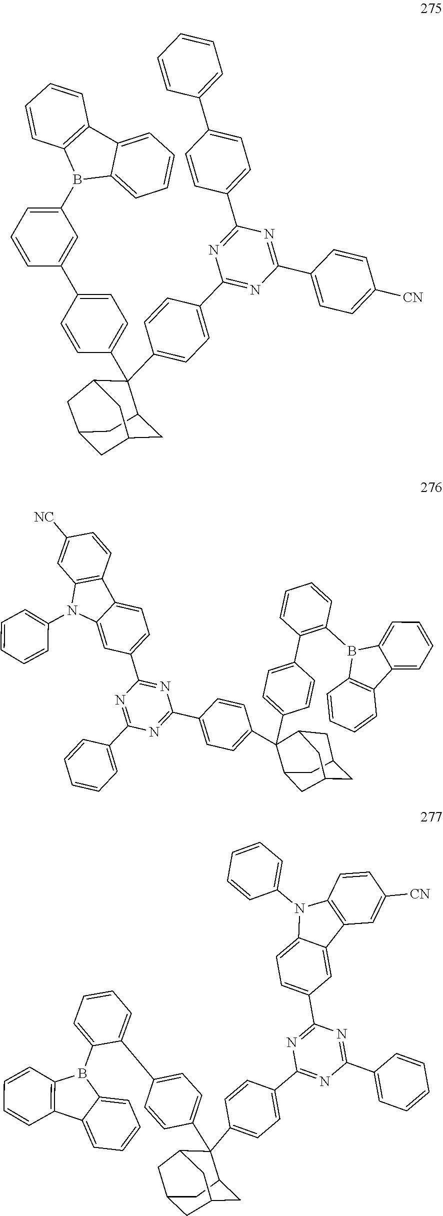 [SMILES: N#Cc1ccc(-c2nc(-c3ccc(-c4ccccc4)cc3)nc(-c3ccc(C4(c5ccc(-c6cccc(B7c8ccccc8-c8ccccc87)c6)cc5)C5CC6CC(C5)CC4C6)cc3)n2)cc1 ; N#Cc1ccc2c3ccc(-c4nc(-c5ccccc5)nc(-c5ccc(C6(c7ccc(-c8ccccc8B8c9ccccc9-c9ccccc98)cc7)C7CC8CC(C7)CC6C8)cc5)n4)cc3n(-c3ccccc3)c2c1 ; N#Cc1ccc2c(c1)c1cc(-c3nc(-c4ccccc4)nc(-c4ccc(C5(c6ccc(-c7ccccc7B7c8ccccc8-c8ccccc87)cc6)C6CC7CC(C6)CC5C7)cc4)n3)ccc1n2-c1ccccc1]

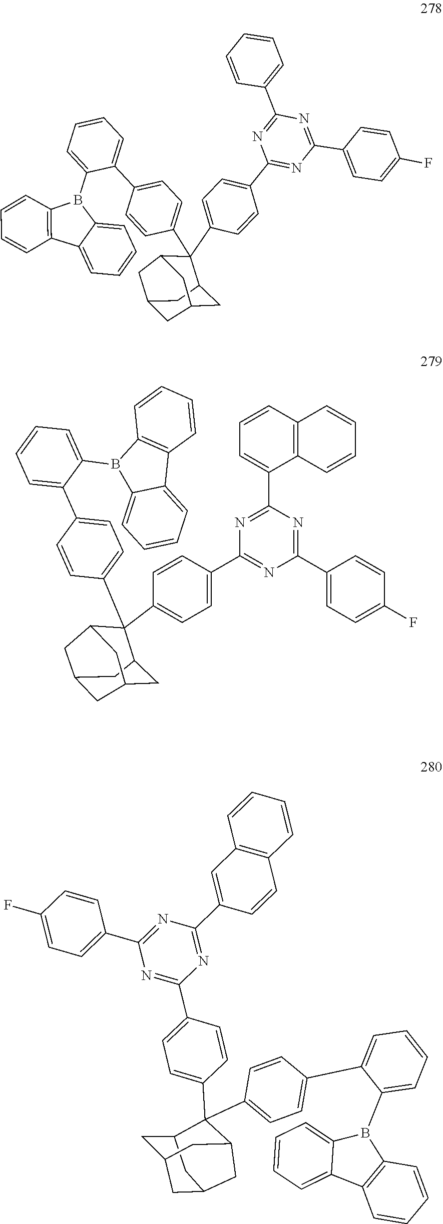 [SMILES: Fc1ccc(-c2nc(-c3ccccc3)nc(-c3ccc(C4(c5ccc(-c6ccccc6B6c7ccccc7-c7ccccc76)cc5)C5CC6CC(C5)CC4C6)cc3)n2)cc1 ; Fc1ccc(-c2nc(-c3ccc(C4(c5ccc(-c6ccccc6B6c7ccccc7-c7ccccc76)cc5)C5CC6CC(C5)CC4C6)cc3)nc(-c3cccc4ccccc34)n2)cc1 ; Fc1ccc(-c2nc(-c3ccc(C4(c5ccc(-c6ccccc6B6c7ccccc7-c7ccccc76)cc5)C5CC6CC(C5)CC4C6)cc3)nc(-c3ccc4ccccc4c3)n2)cc1]

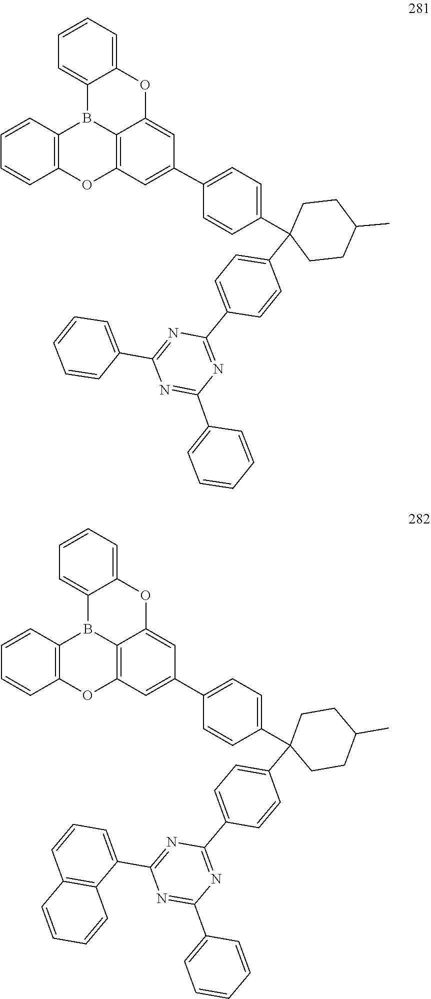 [SMILES: CC1CCC(c2ccc(-c3cc4c5c(c3)Oc3ccccc3B5c3ccccc3O4)cc2)(c2ccc(-c3nc(-c4ccccc4)nc(-c4ccccc4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4cccc5ccccc45)n3)cc2)CC1]

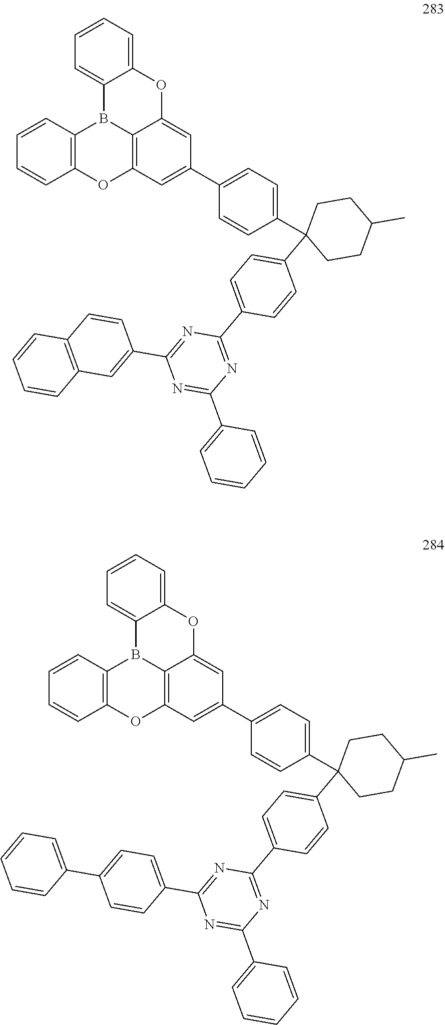 [SMILES: CC1CCC(c2ccc(-c3cc4c5c(c3)Oc3ccccc3B5c3ccccc3O4)cc2)(c2ccc(-c3nc(-c4ccccc4)nc(-c4ccc5ccccc5c4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4ccc(-c5ccccc5)cc4)n3)cc2)CC1]

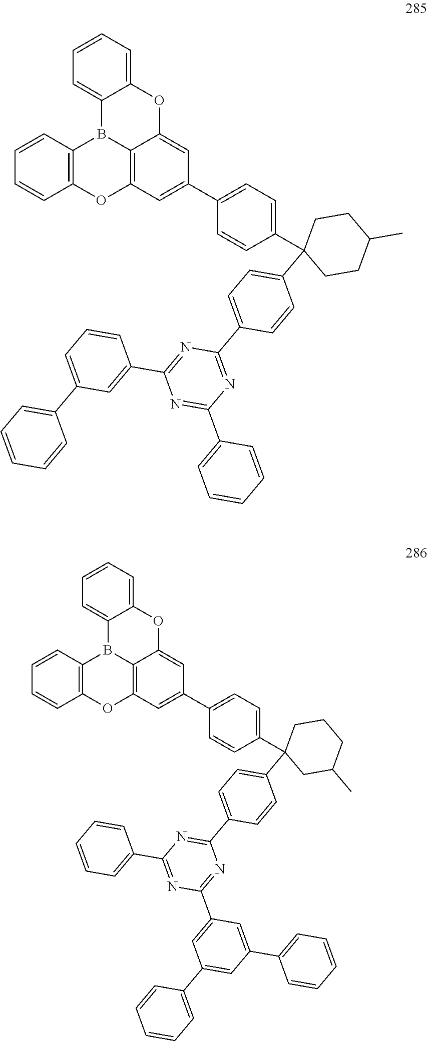 [SMILES: CC1CCC(c2ccc(-c3cc4c5c(c3)Oc3ccccc3B5c3ccccc3O4)cc2)(c2ccc(-c3nc(-c4ccccc4)nc(-c4cccc(-c5ccccc5)c4)n3)cc2)CC1 ; CC1CCCC(c2ccc(-c3cc4c5c(c3)Oc3ccccc3B5c3ccccc3O4)cc2)(c2ccc(-c3nc(-c4ccccc4)nc(-c4cc(-c5ccccc5)cc(-c5ccccc5)c4)n3)cc2)C1]

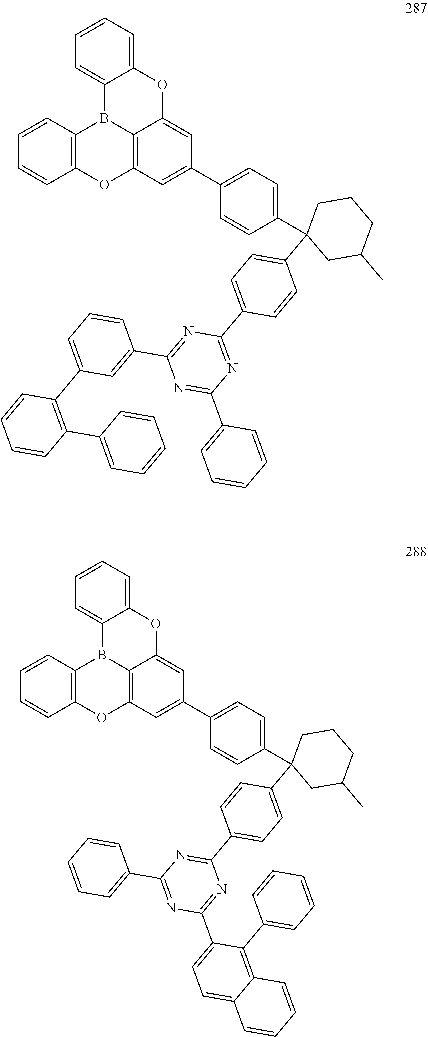 [SMILES: CC1CCCC(c2ccc(-c3cc4c5c(c3)Oc3ccccc3B5c3ccccc3O4)cc2)(c2ccc(-c3nc(-c4ccccc4)nc(-c4cccc(-c5ccccc5-c5ccccc5)c4)n3)cc2)C1 ; CC1CCCC(c2ccc(-c3cc4c5c(c3)Oc3ccccc3B5c3ccccc3O4)cc2)(c2ccc(-c3nc(-c4ccccc4)nc(-c4ccc5ccccc5c4-c4ccccc4)n3)cc2)C1]

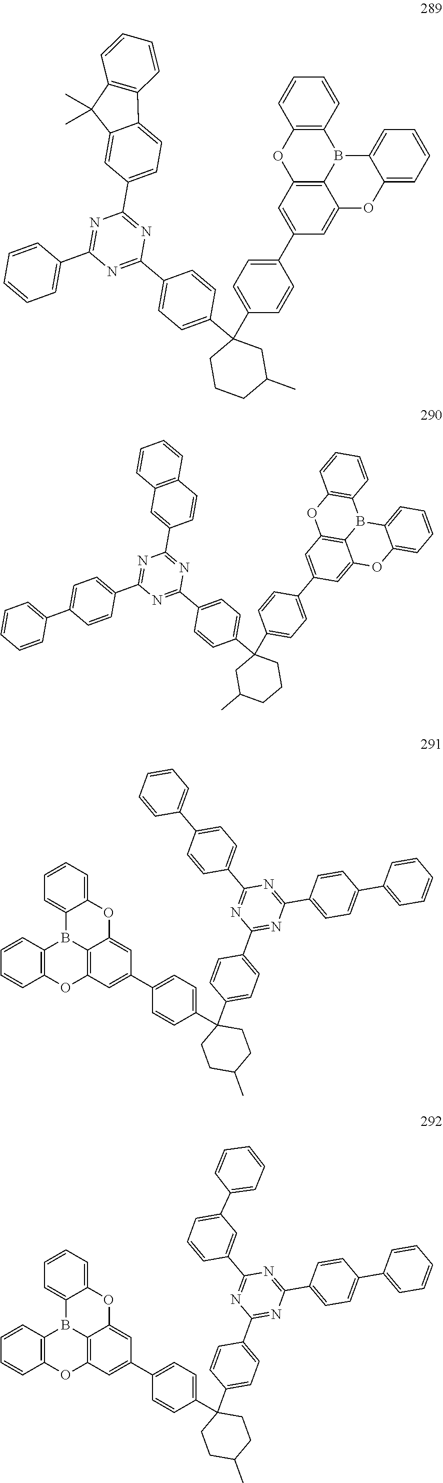 [SMILES: CC1CCCC(c2ccc(-c3cc4c5c(c3)Oc3ccccc3B5c3ccccc3O4)cc2)(c2ccc(-c3nc(-c4ccccc4)nc(-c4ccc5c(c4)C(C)(C)c4ccccc4-5)n3)cc2)C1 ; CC1CCCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5ccccc5c4)n3)cc2)C1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4ccc(-c5ccccc5)cc4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5)c4)n3)cc2)CC1]

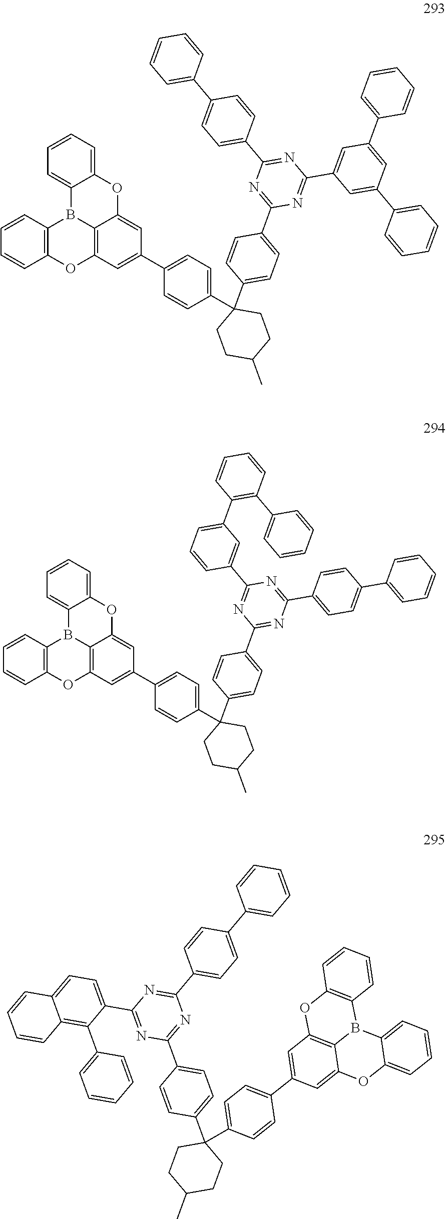 [SMILES: CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cc(-c5ccccc5)cc(-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5ccccc5c4-c4ccccc4)n3)cc2)CC1]

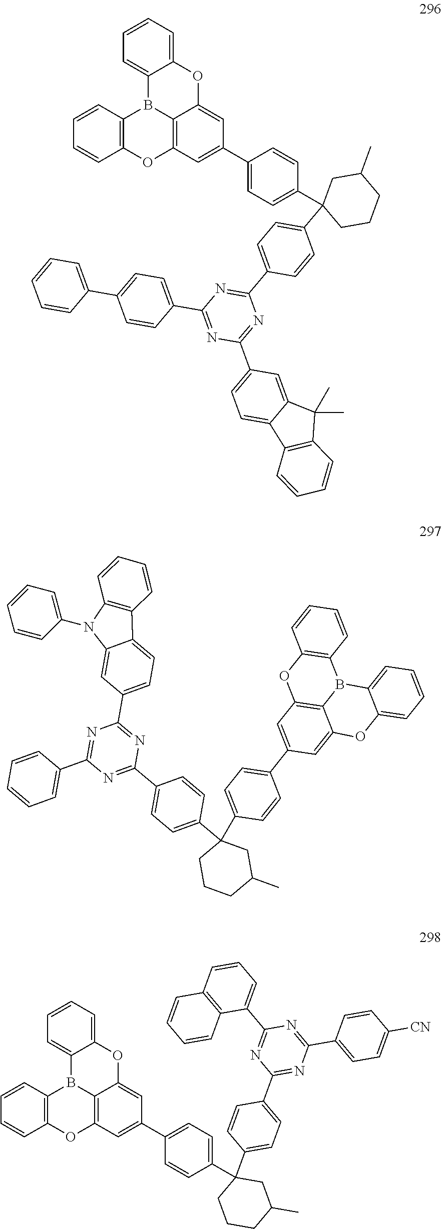 [SMILES: CC1CCCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5c(c4)C(C)(C)c4ccccc4-5)n3)cc2)C1 ; CC1CCCC(c2ccc(-c3cc4c5c(c3)Oc3ccccc3B5c3ccccc3O4)cc2)(c2ccc(-c3nc(-c4ccccc4)nc(-c4ccc5c6ccccc6n(-c6ccccc6)c5c4)n3)cc2)C1 ; CC1CCCC(c2ccc(-c3cc4c5c(c3)Oc3ccccc3B5c3ccccc3O4)cc2)(c2ccc(-c3nc(-c4ccc(C#N)cc4)nc(-c4cccc5ccccc45)n3)cc2)C1]

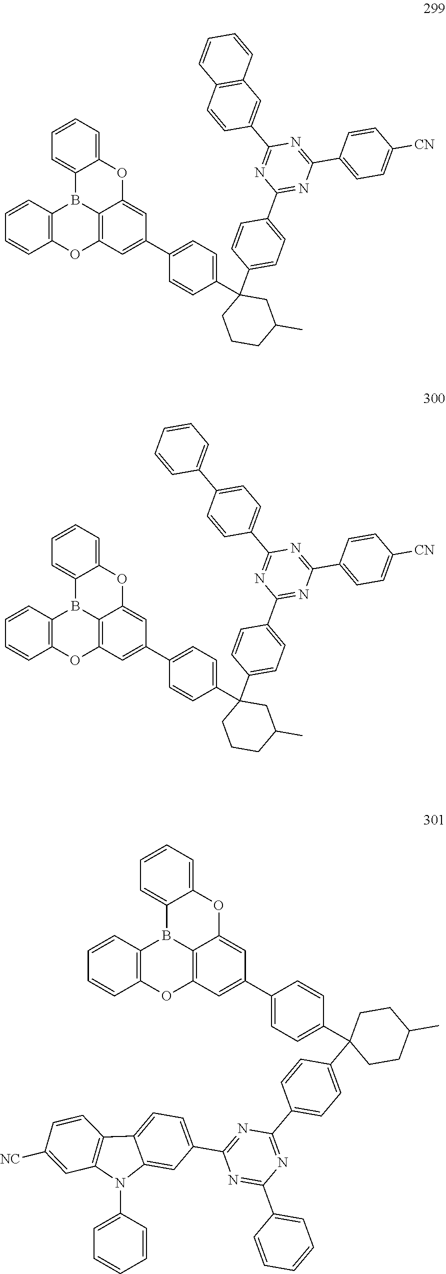

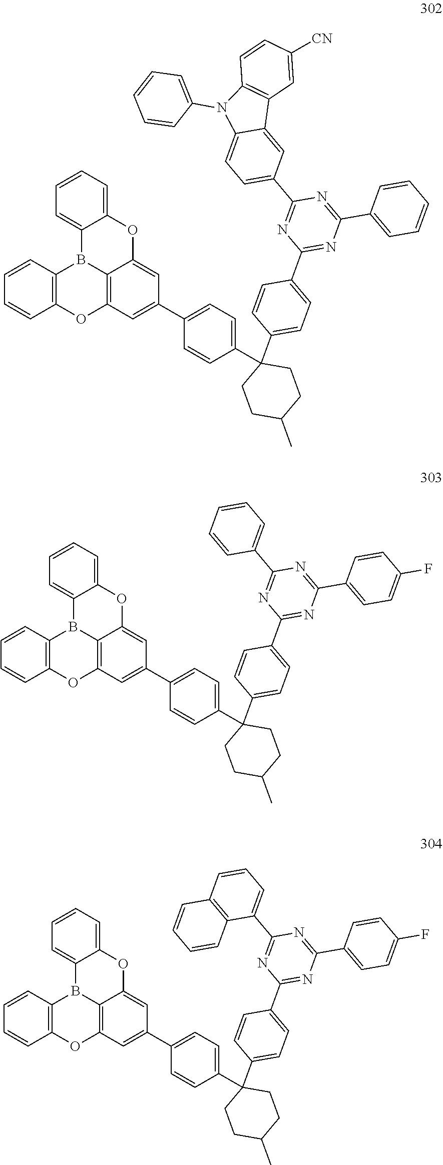 [SMILES: CC1CCC(c2ccc(-c3cc4c5c(c3)Oc3ccccc3B5c3ccccc3O4)cc2)(c2ccc(-c3nc(-c4ccccc4)nc(-c4ccc5c(c4)c4cc(C#N)ccc4n5-c4ccccc4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4ccc(F)cc4)n3)cc2)CC1 ; CC1CCC(c2ccc(-c3cc4c5c(c3)Oc3ccccc3B5c3ccccc3O4)cc2)(c2ccc(-c3nc(-c4ccc(F)cc4)nc(-c4cccc5ccccc45)n3)cc2)CC1]

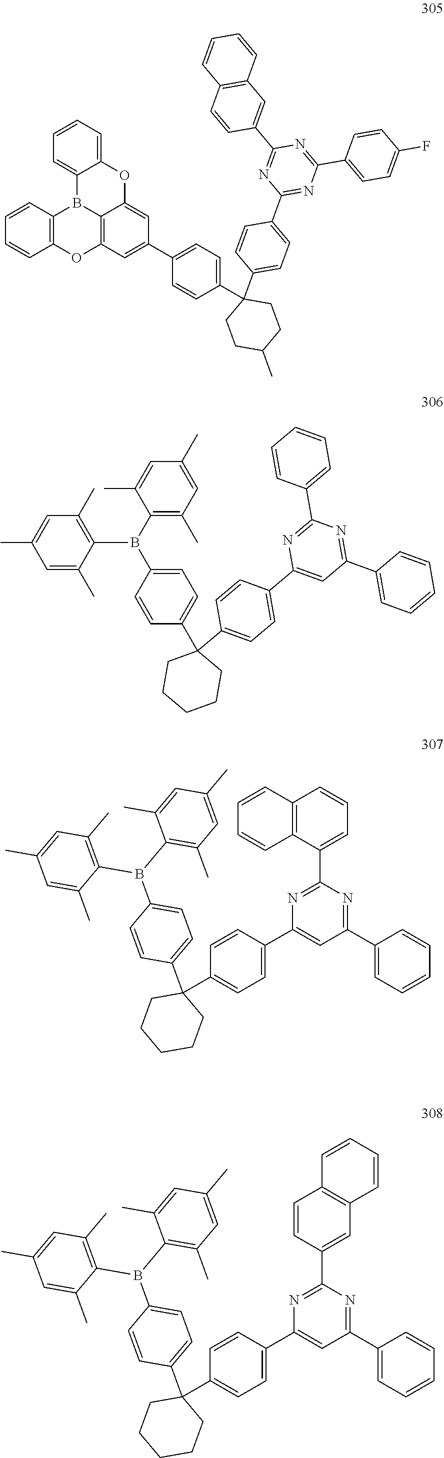 [SMILES: CC1CCC(c2ccc(-c3cc4c5c(c3)Oc3ccccc3B5c3ccccc3O4)cc2)(c2ccc(-c3nc(-c4ccc(F)cc4)nc(-c4ccc5ccccc5c4)n3)cc2)CC1 ; Cc1cc(C)c(B(c2ccc(C3(c4ccc(-c5cc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6cccc7ccccc67)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6ccc7ccccc7c6)n5)cc4)CCCCC3)cc2)c2c(C)cc(C)cc2C)c(C)c1]

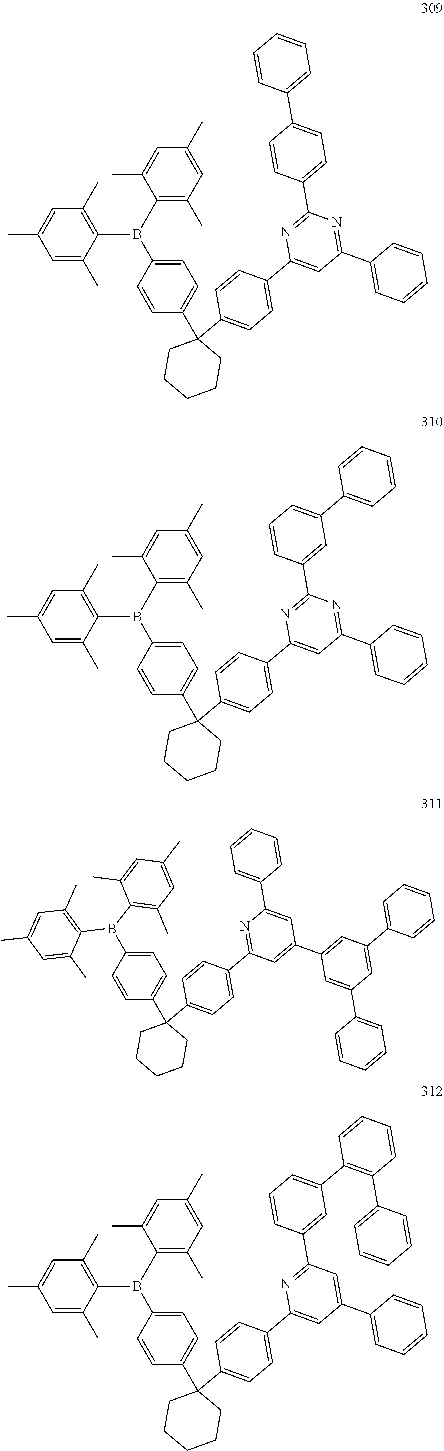 [SMILES: Cc1cc(C)c(B(c2ccc(C3(c4ccc(-c5cc(-c6ccccc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6cccc(-c7ccccc7)c6)n5)cc4)CCCCC3)cc2)c2c(C)cc(C)cc2C)c(C)c1 ; Cc1cc(C)c(B(c2ccc(C3(c4ccc(-c5cc(-c6cc(-c7ccccc7)cc(-c7ccccc7)c6)cc(-c6ccccc6)n5)cc4)CCCCC3)cc2)c2c(C)cc(C)cc2C)c(C)c1 ; Cc1cc(C)c(B(c2ccc(C3(c4ccc(-c5cc(-c6ccccc6)cc(-c6cccc(-c7ccccc7-c7ccccc7)c6)n5)cc4)CCCCC3)cc2)c2c(C)cc(C)cc2C)c(C)c1]

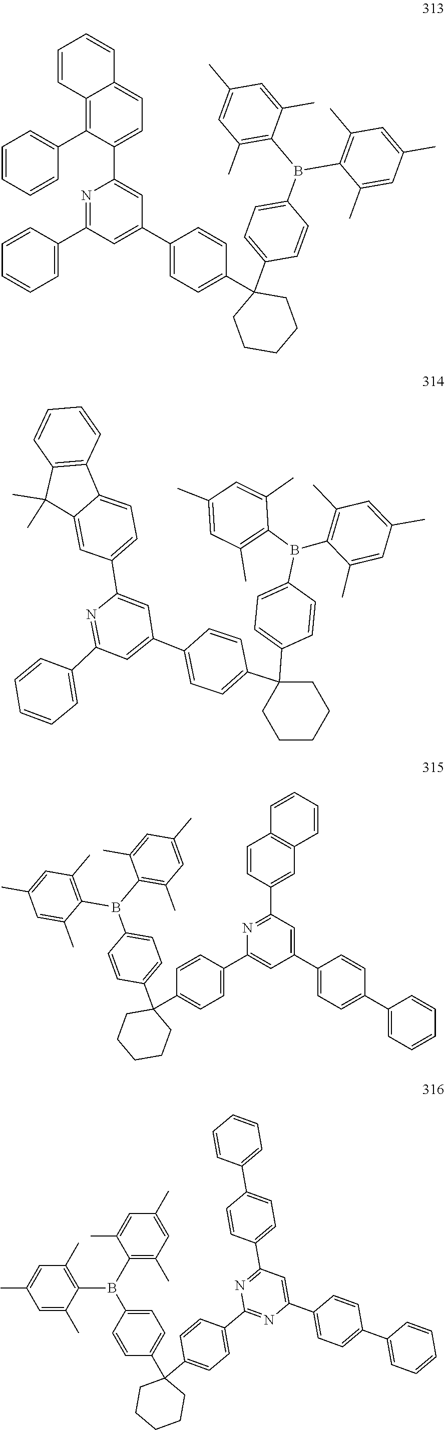

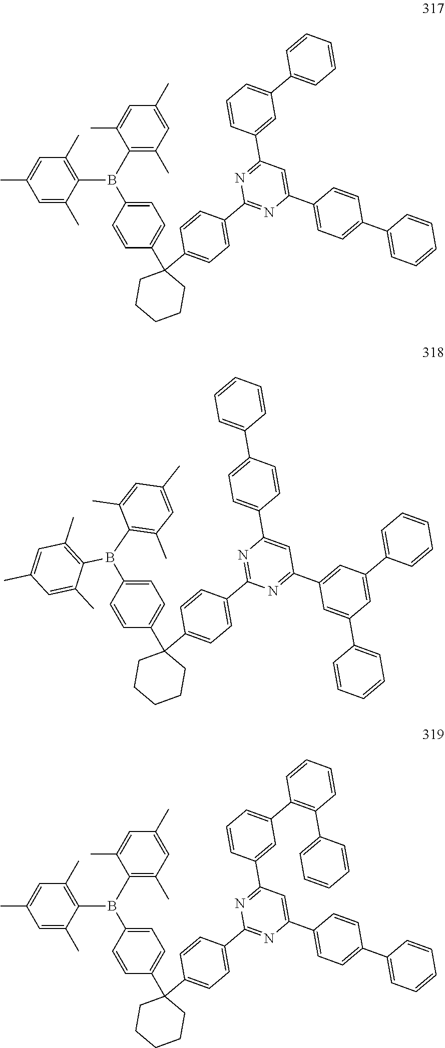 [SMILES: Cc1cc(C)c(B(c2ccc(C3(c4ccc(-c5nc(-c6ccc(-c7ccccc7)cc6)cc(-c6cccc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)cc(-c6cc(-c7ccccc7)cc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)cc(-c6cccc(-c7ccccc7-c7ccccc7)c6)n5)cc4)CCCCC3)cc2)c2c(C)cc(C)cc2C)c(C)c1]

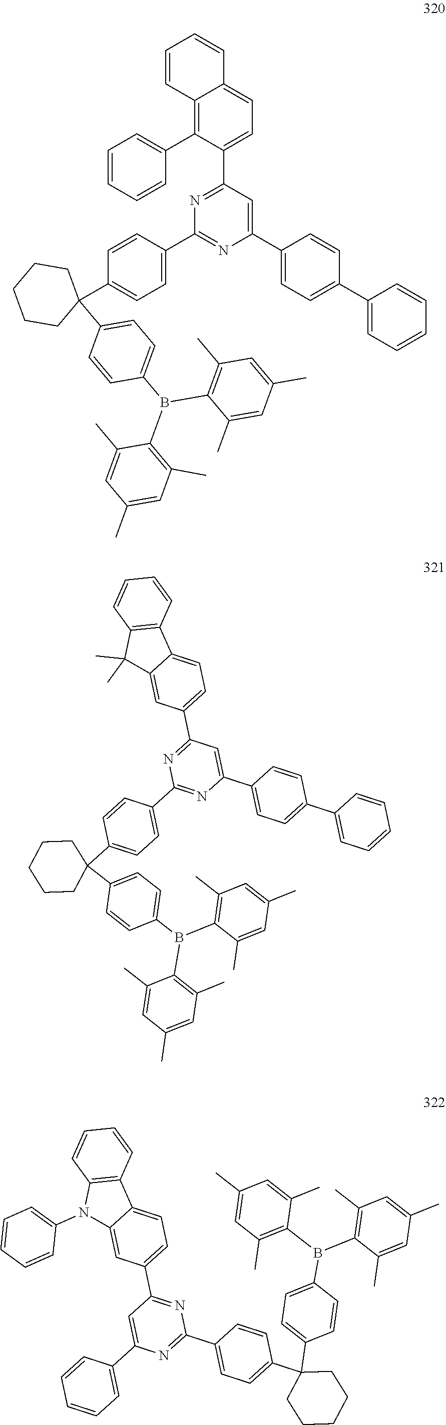 [SMILES: Cc1cc(C)c(B(c2ccc(C3(c4ccc(-c5nc(-c6ccc(-c7ccccc7)cc6)cc(-c6ccc7ccccc7c6-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)cc(-c6ccc7c(c6)C(C)(C)c6ccccc6-7)n5)cc4)CCCCC3)cc2)c2c(C)cc(C)cc2C)c(C)c1 ; Cc1cc(C)c(B(c2ccc(C3(c4ccc(-c5nc(-c6ccccc6)cc(-c6ccc7c8ccccc8n(-c8ccccc8)c7c6)n5)cc4)CCCCC3)cc2)c2c(C)cc(C)cc2C)c(C)c1]

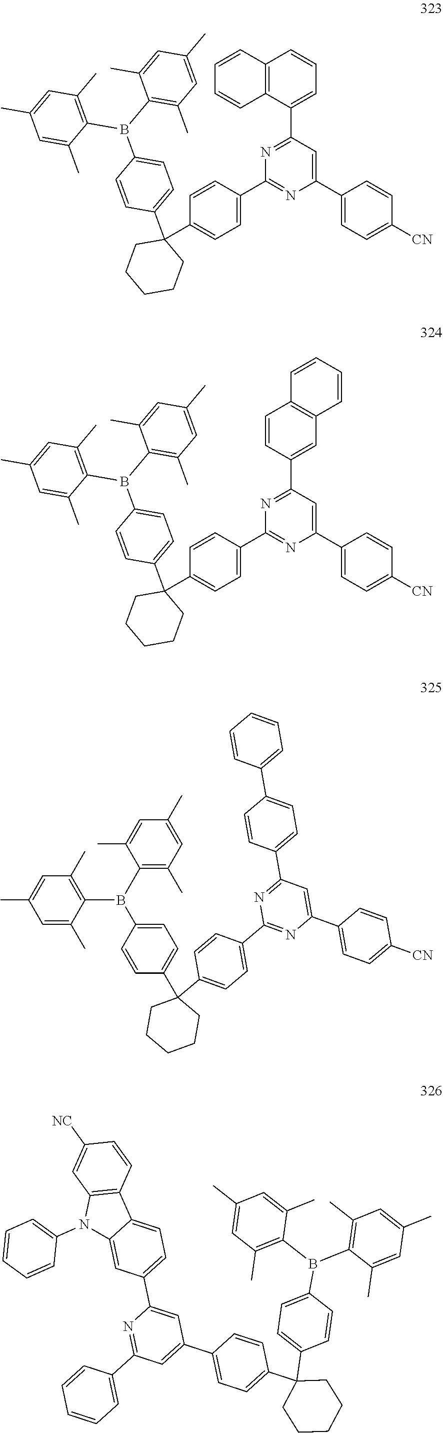 [SMILES: Cc1cc(C)c(B(c2ccc(C3(c4ccc(-c5nc(-c6ccc(C#N)cc6)cc(-c6cccc7ccccc67)n5)cc4)CCCCC3)cc2)c2c(C)cc(C)cc2C)c(C)c1 ; Cc1cc(C)c(B(c2ccc(C3(c4ccc(-c5nc(-c6ccc(C#N)cc6)cc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5nc(-c6ccc(C#N)cc6)cc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6ccc7c8ccc(C#N)cc8n(-c8ccccc8)c7c6)c5)cc4)CCCCC3)cc2)c2c(C)cc(C)cc2C)c(C)c1]

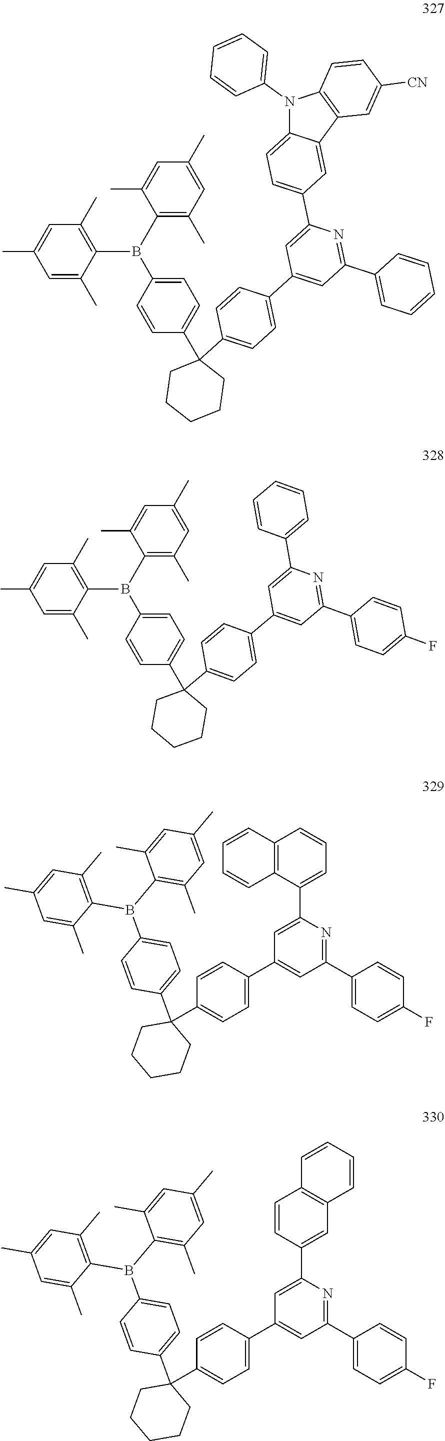 [SMILES: Cc1cc(C)c(B(c2ccc(C3(c4ccc(-c5cc(-c6ccccc6)nc(-c6ccc7c(c6)c6cc(C#N)ccc6n7-c6ccccc6)c5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6ccc(F)cc6)c5)cc4)CCCCC3)cc2)c2c(C)cc(C)cc2C)c(C)c1 ; Cc1cc(C)c(B(c2ccc(C3(c4ccc(-c5cc(-c6ccc(F)cc6)nc(-c6cccc7ccccc67)c5)cc4)CCCCC3)cc2)c2c(C)cc(C)cc2C)c(C)c1 ; Cc1cc(C)c(B(c2ccc(C3(c4ccc(-c5cc(-c6ccc(F)cc6)nc(-c6ccc7ccccc7c6)c5)cc4)CCCCC3)cc2)c2c(C)cc(C)cc2C)c(C)c1]

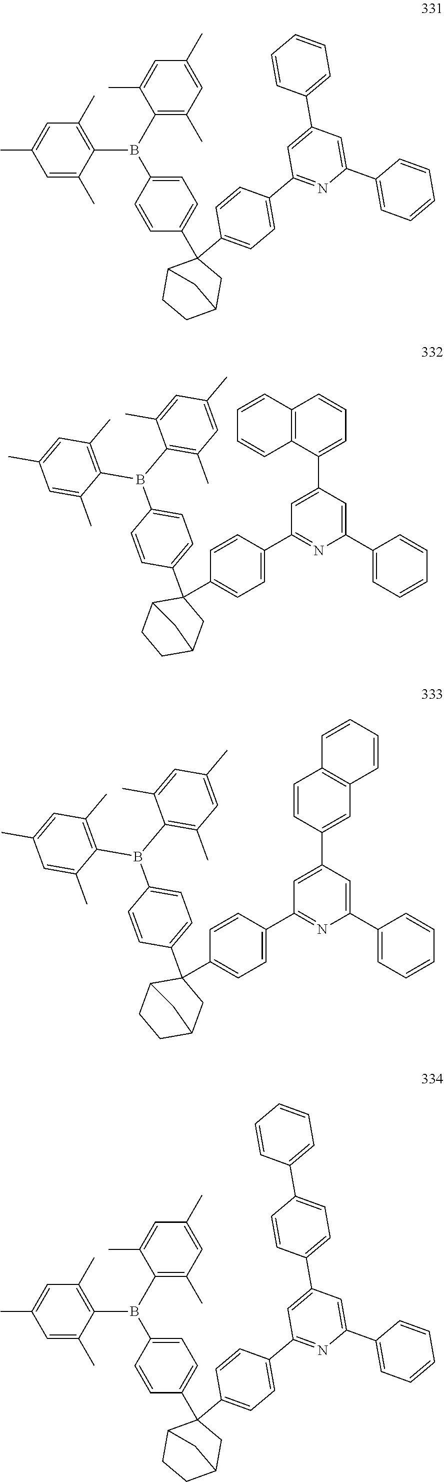 [SMILES: Cc1cc(C)c(B(c2ccc(C3(c4ccc(-c5cc(-c6ccccc6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cccc7ccccc67)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc7ccccc7c6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc(-c7ccccc7)cc6)cc(-c6ccccc6)n5)cc4)CC4CCC3C4)cc2)c2c(C)cc(C)cc2C)c(C)c1]

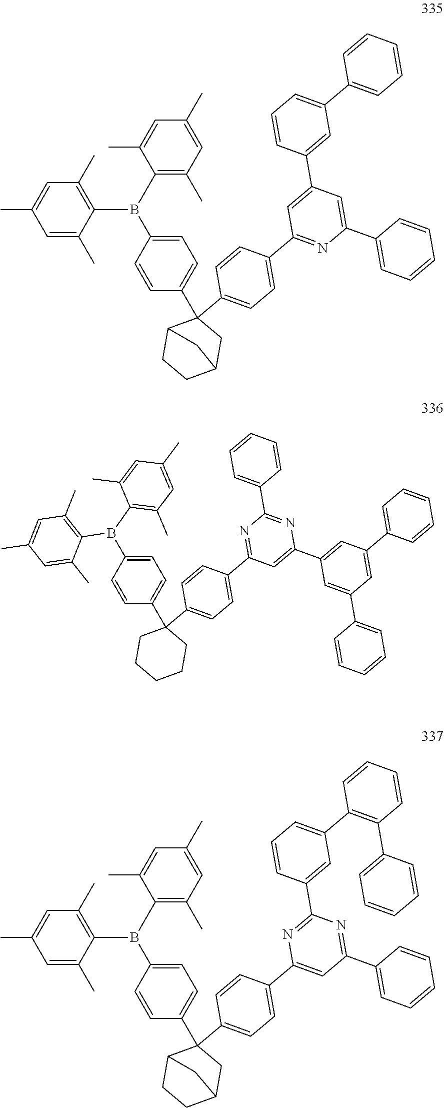 [SMILES: Cc1cc(C)c(B(c2ccc(C3(c4ccc(-c5cc(-c6cccc(-c7ccccc7)c6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cc(-c7ccccc7)cc(-c7ccccc7)c6)nc(-c6ccccc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6cccc(-c7ccccc7-c7ccccc7)c6)n5)cc4)CC4CCC3C4)cc2)c2c(C)cc(C)cc2C)c(C)c1]

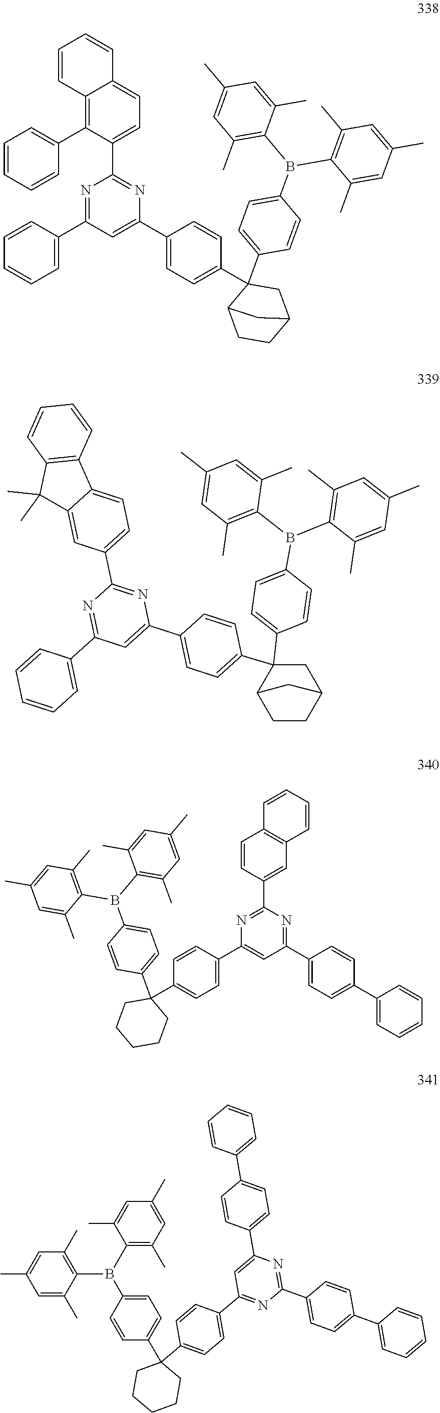

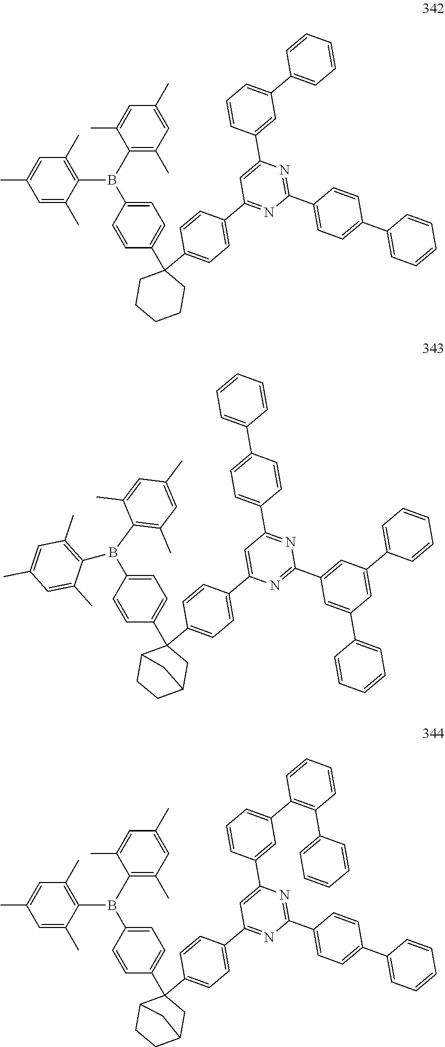 [SMILES: Cc1cc(C)c(B(c2ccc(C3(c4ccc(-c5cc(-c6cccc(-c7ccccc7)c6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5cc(-c6ccc(-c7ccccc7)cc6)nc(-c6cc(-c7ccccc7)cc(-c7ccccc7)c6)n5)cc4)CC4CCC3C4)cc2)c2c(C)cc(C)cc2C)c(C)c1 ; Cc1cc(C)c(B(c2ccc(C3(c4ccc(-c5cc(-c6cccc(-c7ccccc7-c7ccccc7)c6)nc(-c6ccc(-c7ccccc7)cc6)n5)cc4)CC4CCC3C4)cc2)c2c(C)cc(C)cc2C)c(C)c1]

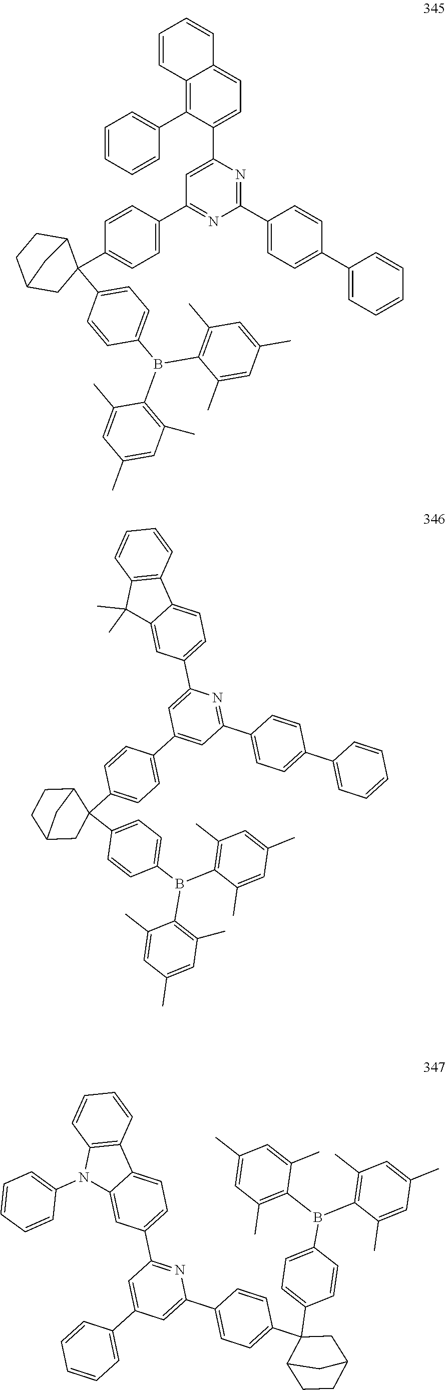 [SMILES: Cc1cc(C)c(B(c2ccc(C3(c4ccc(-c5cc(-c6ccc7ccccc7c6-c6ccccc6)nc(-c6ccc(-c7ccccc7)cc6)n5)cc4)CC4CCC3C4)cc2)c2c(C)cc(C)cc2C)c(C)c1 ; Cc1cc(C)c(B(c2ccc(C3(c4ccc(-c5cc(-c6ccc(-c7ccccc7)cc6)nc(-c6ccc7c(c6)C(C)(C)c6ccccc6-7)c5)cc4)CC4CCC3C4)cc2)c2c(C)cc(C)cc2C)c(C)c1 ; Cc1cc(C)c(B(c2ccc(C3(c4ccc(-c5cc(-c6ccccc6)cc(-c6ccc7c8ccccc8n(-c8ccccc8)c7c6)n5)cc4)CC4CCC3C4)cc2)c2c(C)cc(C)cc2C)c(C)c1]

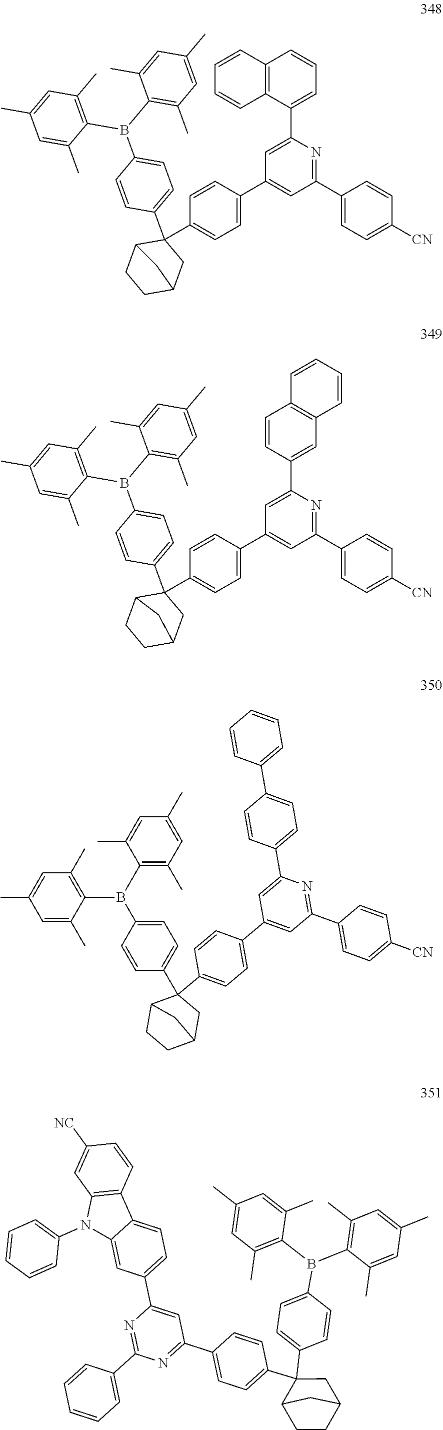 [SMILES: Cc1cc(C)c(B(c2ccc(C3(c4ccc(-c5cc(-c6ccc(C#N)cc6)nc(-c6cccc7ccccc67)c5)cc4)CC4CCC3C4)cc2)c2c(C)cc(C)cc2C)c(C)c1 ; Cc1cc(C)c(B(c2ccc(C3(c4ccc(-c5cc(-c6ccc(C#N)cc6)nc(-c6ccc7ccccc7c6)c5)cc4)CC4CCC3C4)cc2)c2c(C)cc(C)cc2C)c(C)c1 ; Cc1cc(C)c(B(c2ccc(C3(c4ccc(-c5cc(-c6ccc(C#N)cc6)nc(-c6ccc(-c7ccccc7)cc6)c5)cc4)CC4CCC3C4)cc2)c2c(C)cc(C)cc2C)c(C)c1 ; Cc1cc(C)c(B(c2ccc(C3(c4ccc(-c5cc(-c6ccc7c8ccc(C#N)cc8n(-c8ccccc8)c7c6)nc(-c6ccccc6)n5)cc4)CC4CCC3C4)cc2)c2c(C)cc(C)cc2C)c(C)c1]

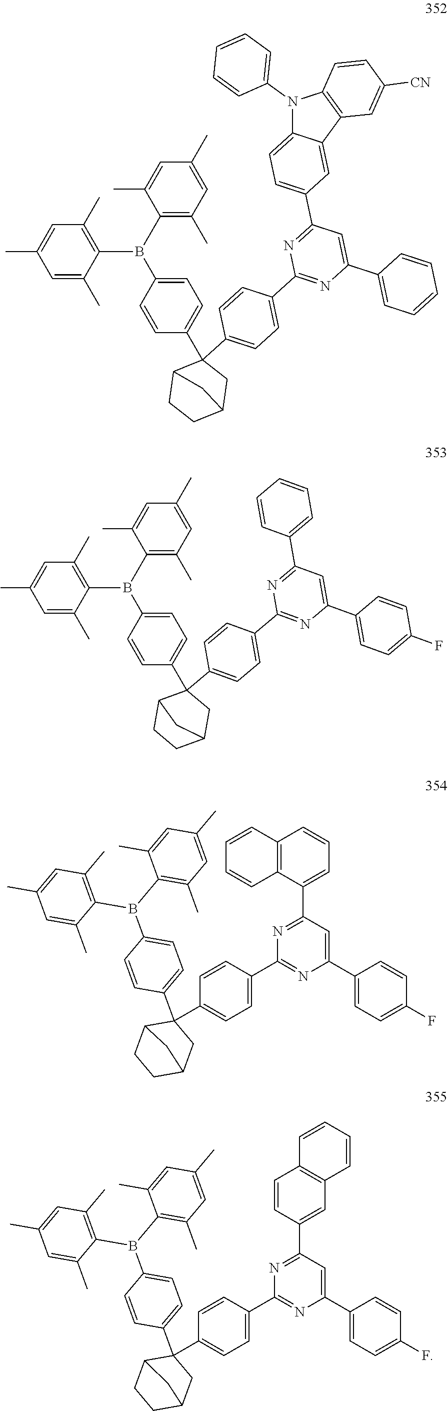 [SMILES: Cc1cc(C)c(B(c2ccc(C3(c4ccc(-c5nc(-c6ccccc6)cc(-c6ccc7c(c6)c6cc(C#N)ccc6n7-c6ccccc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)cc(-c6ccc(F)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccc(F)cc6)cc(-c6cccc7ccccc67)n5)cc4)CC4CCC3C4)cc2)c2c(C)cc(C)cc2C)c(C)c1 ; Cc1cc(C)c(B(c2ccc(C3(c4ccc(-c5nc(-c6ccc(F)cc6)cc(-c6ccc7ccccc7c6)n5)cc4)CC4CCC3C4)cc2)c2c(C)cc(C)cc2C)c(C)c1]

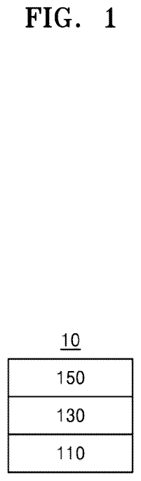

### Description of FIG. 1

FIG. 1 is a schematic cross-sectional view of a light-emitting device 10 according to one or more embodiments of the present disclosure. The light-emitting device 10 may include a first electrode 110, an interlayer 130, and a second electrode 150.

Hereinafter, a structure of the light-emitting device 10 according to one or more embodiments and a method of manufacturing the light-emitting device 10 are described in more detail with reference to FIG. 1.

### First Electrode 110

In FIG. 1, in one or more embodiments, a substrate may be additionally provided and arranged under the first electrode 110 and/or on the second electrode 150. As the substrate, a glass substrate or a plastic substrate may be utilized. In one or more embodiments, the substrate may be a flexible substrate and may include plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In one or more embodiments, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layer structure including (e.g., consisting of) a single layer or a multilayer structure including a plurality of layers. In one or more embodiments, the first electrode 110 may have a three-layer structure of ITO/Ag/ITO.

### Interlayer 130

The interlayer 130 may be arranged on the first electrode 110. The interlayer 130 may include an emission layer.

In one or more embodiments, the interlayer 130 may further include a hole transport region arranged between the first electrode 110 and the emission layer, and an electron transport region arranged between the emission layer and the second electrode 150.

In one or more embodiments, the interlayer 130 may further include, in addition to one or more suitable organic materials, a metal-containing compound such as an organometallic compound, an inorganic material such as quantum dots, and/or the like.

In one or more embodiments, the interlayer 130 may include, i) two or more emitting units sequentially stacked between the first electrode 110 and the second electrode 150, and ii) a charge generation layer between the two or more emitting units. When the interlayer 130 includes the two or more emitting units and the charge generation layer as described, the light-emitting device 10 may be a tandem light-emitting device.

### Hole Transport Region in Interlayer 130

The hole transport region may have: i) a single-layer structure including (e.g., consisting of) a single layer including (e.g., consisting of) a single material, ii) a single-layer structure including (e.g., consisting of) a single layer including (e.g., consisting of) a plurality of materials that are different from each other, or iii) a multilayer structure including a plurality of layers including a plurality of materials that are different from each other.

The hole transport region may include a hole injection layer, a hole transport layer, an emission auxiliary layer, an electron blocking layer, or any combination thereof.

In one or more embodiments, the hole transport region may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110 in the stated order.

In one or more embodiments, the hole transport region may include a compound represented by Formula 201, a compound represented by Formula 202, or any combination thereof:

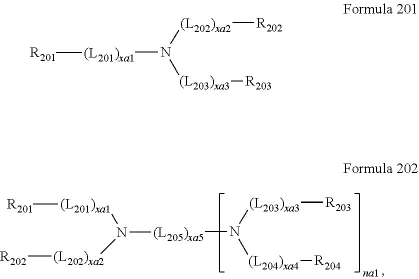

wherein, in Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀S may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group (for example, a carbazole group) that is unsubstituted or substituted with at least one R₁₀ₐ (for example, Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ, to form a C₈-C₆₀ polycyclic group that is unsubstituted or substituted with at least one R₁₀ₐ, and
na1 may be an integer from 1 to 4.

In one or more embodiments, each of Formulae 201 and 202 may include at least one selected from groups represented by Formulae CY201 to CY217:

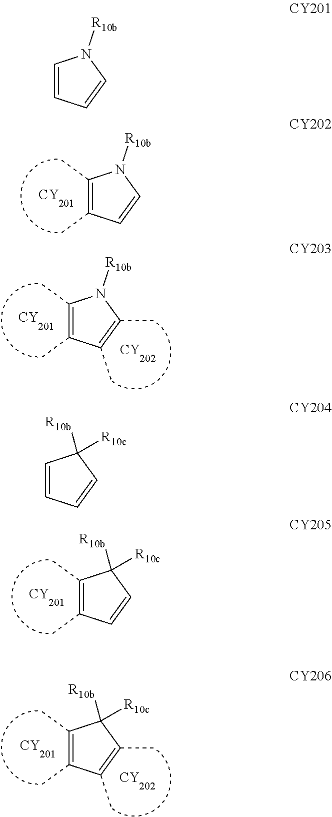

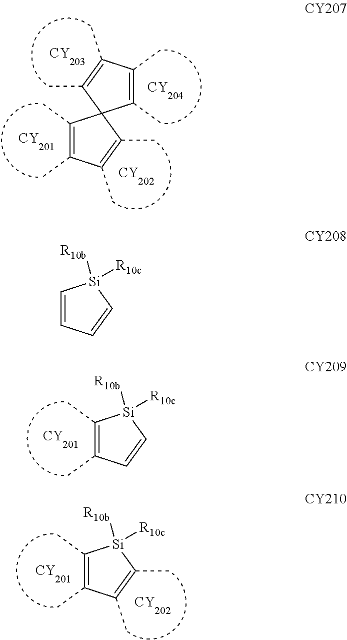

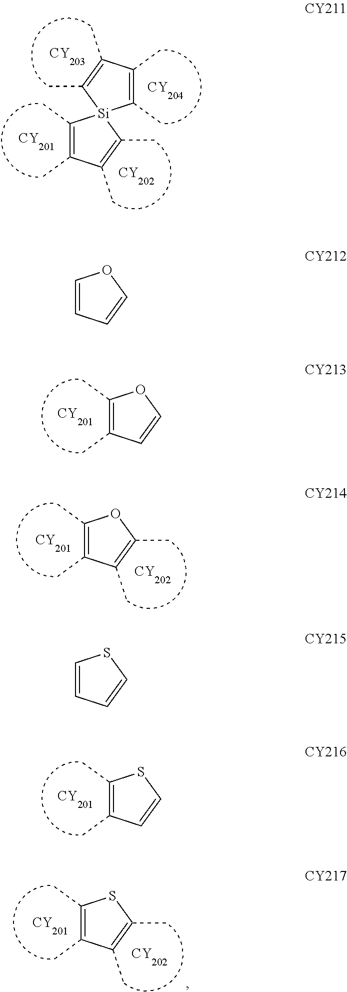

wherein, in Formulae CY201 to CY217, R_{10b} and R_{10c} may each be the same as described with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In one or more embodiments, ring CY201 to ring CY204 in Formulae CY201 to CY217 may each independently be a benzene group, a naphthalene group, a phenanthrene group, or an anthracene group.

In one or more embodiments, each of Formulae 201 and 202 may include at least one selected from groups represented by Formulae CY201 to CY203.

In one or more embodiments, Formula 201 may include at least one selected from groups represented by Formulae CY201 to CY203 and at least one selected from groups represented by Formulae CY204 to CY217.

In one or more embodiments, in Formula 201, xa1 may be 1, R₂₀₁ may be a group represented by one selected from Formulae CY201 to CY203, xa2 may be 0, and R₂₀₂ may be a group represented by one selected from Formulae CY204 to CY207.

In one or more embodiments, each of Formulae 201 and 202 may not include (e.g., may exclude) any of groups represented by Formulae CY201 to CY203.

In one or more embodiments, each of Formulae 201 and 202 may not include (e.g., may exclude) any of groups represented by Formulae CY201 to CY203 and may include at least one selected from groups represented by Formulae CY204 to CY217.

In one or more embodiments, each of Formulae 201 and 202 may not include (e.g., may exclude) any of groups represented by Formulae CY201 to CY217.

In one or more embodiments, the hole transport region may include at least one selected from among Compounds HT1 to HT46, 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), N,N′-di(naphthalen-1-yl)-N,N′-diphenyl-benzidine (NPB(NPD)), β-NPB, N,N′-bis(3-methylphenyl)-N,N′-diphenyl-[1,1′-biphenyl]-4,4′-diamine (TPD), Spiro-TPD, Spiro-NPB, methylated NPB, 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), CzSi, or any combination thereof:

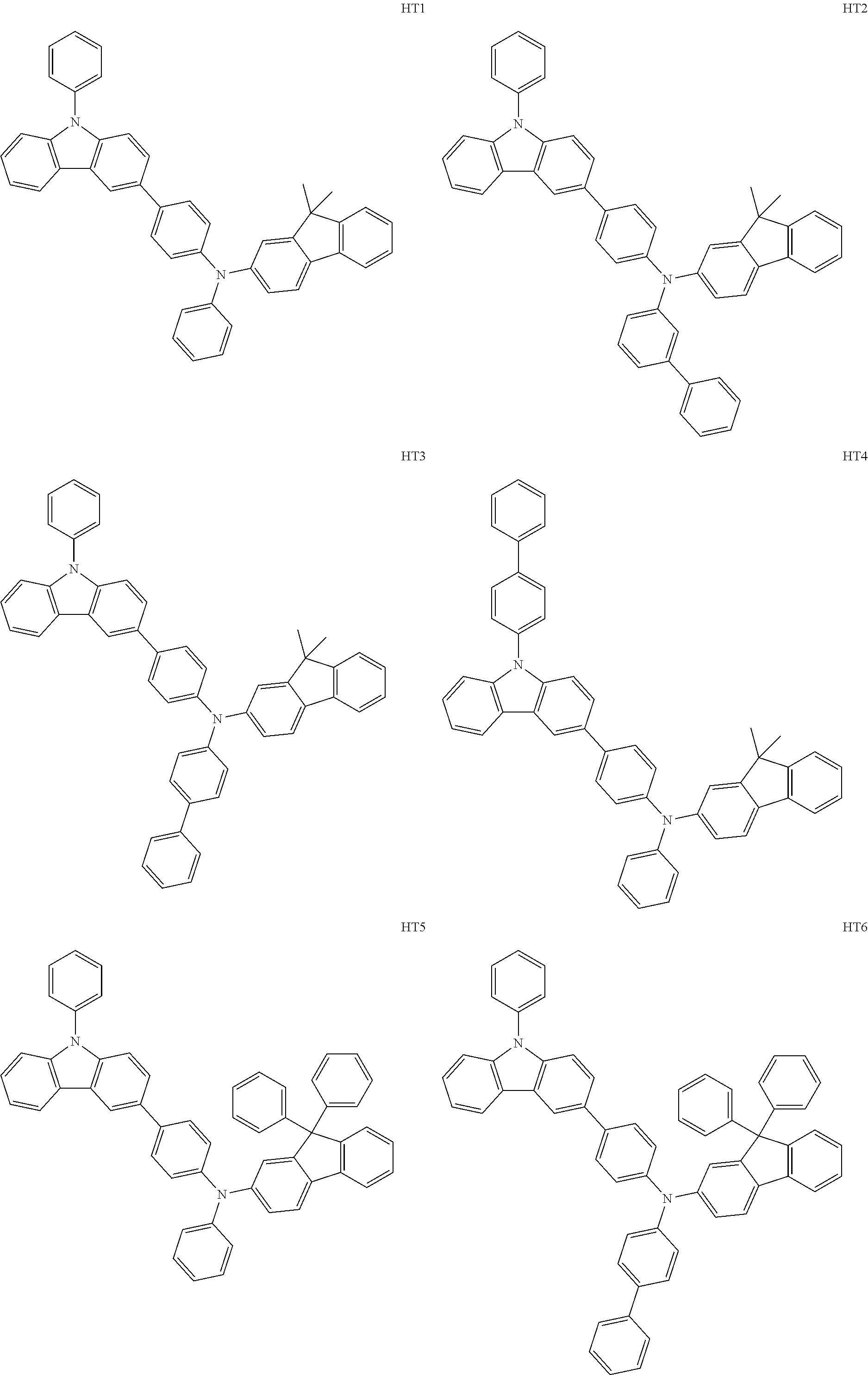

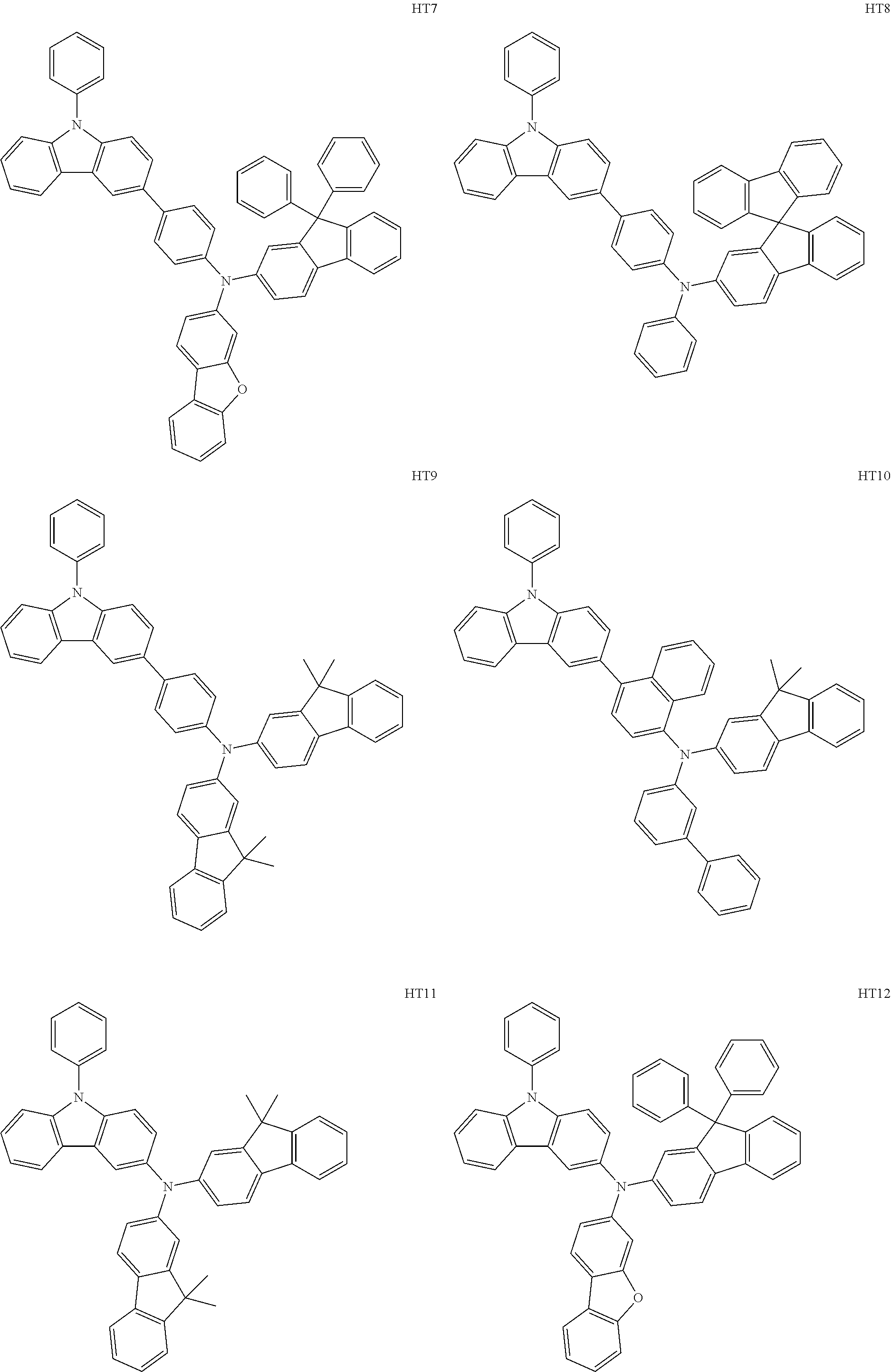

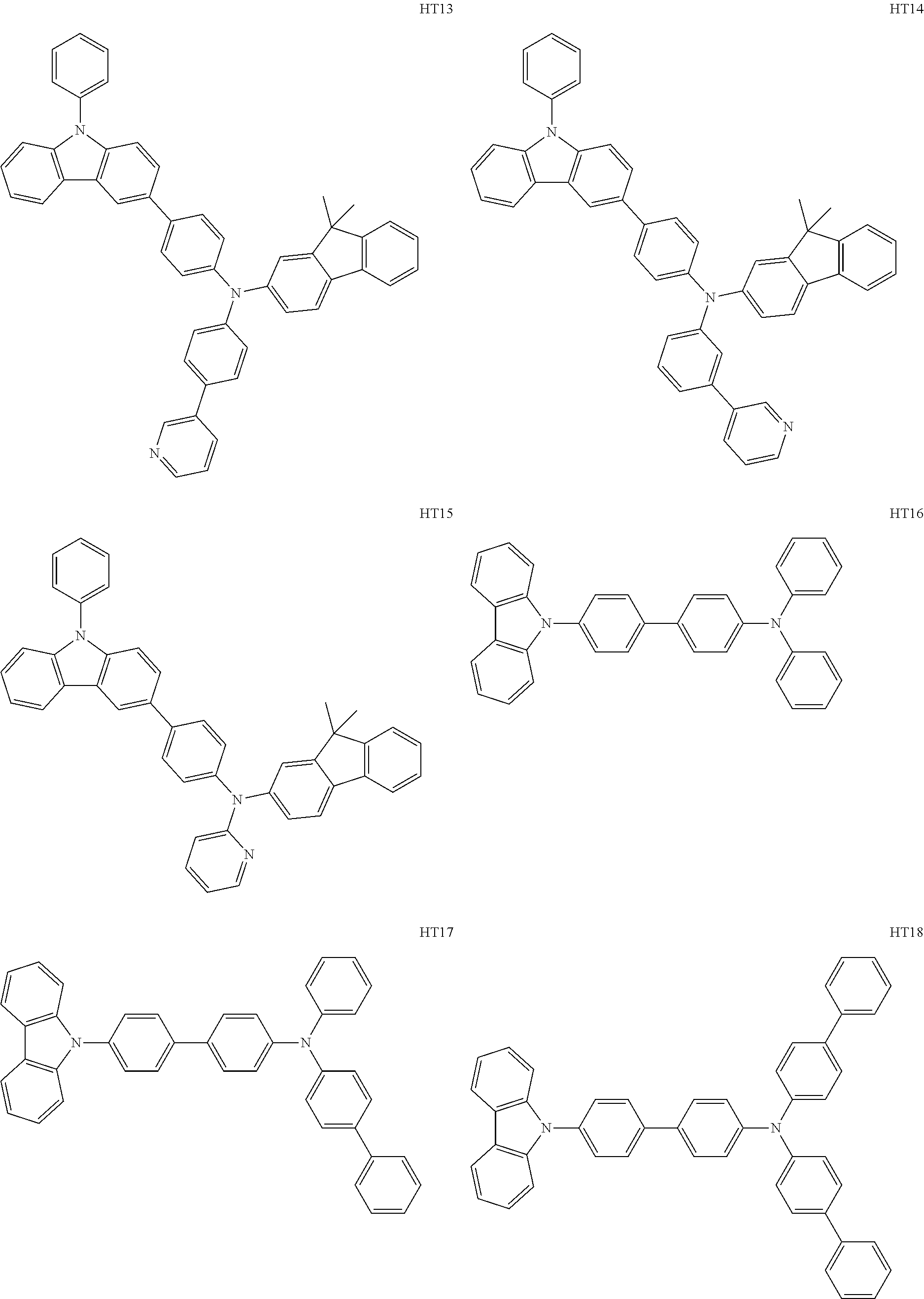 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

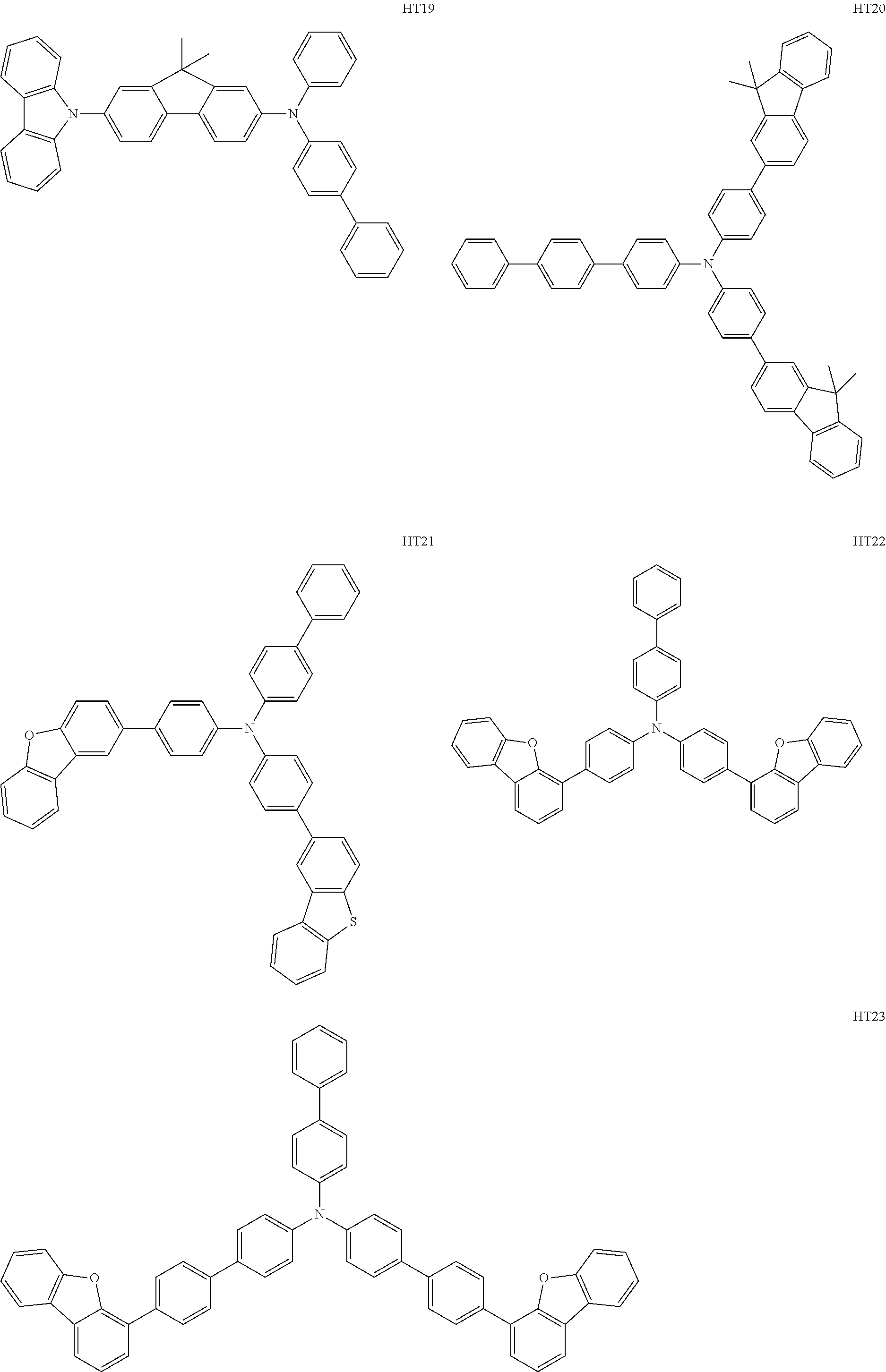 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

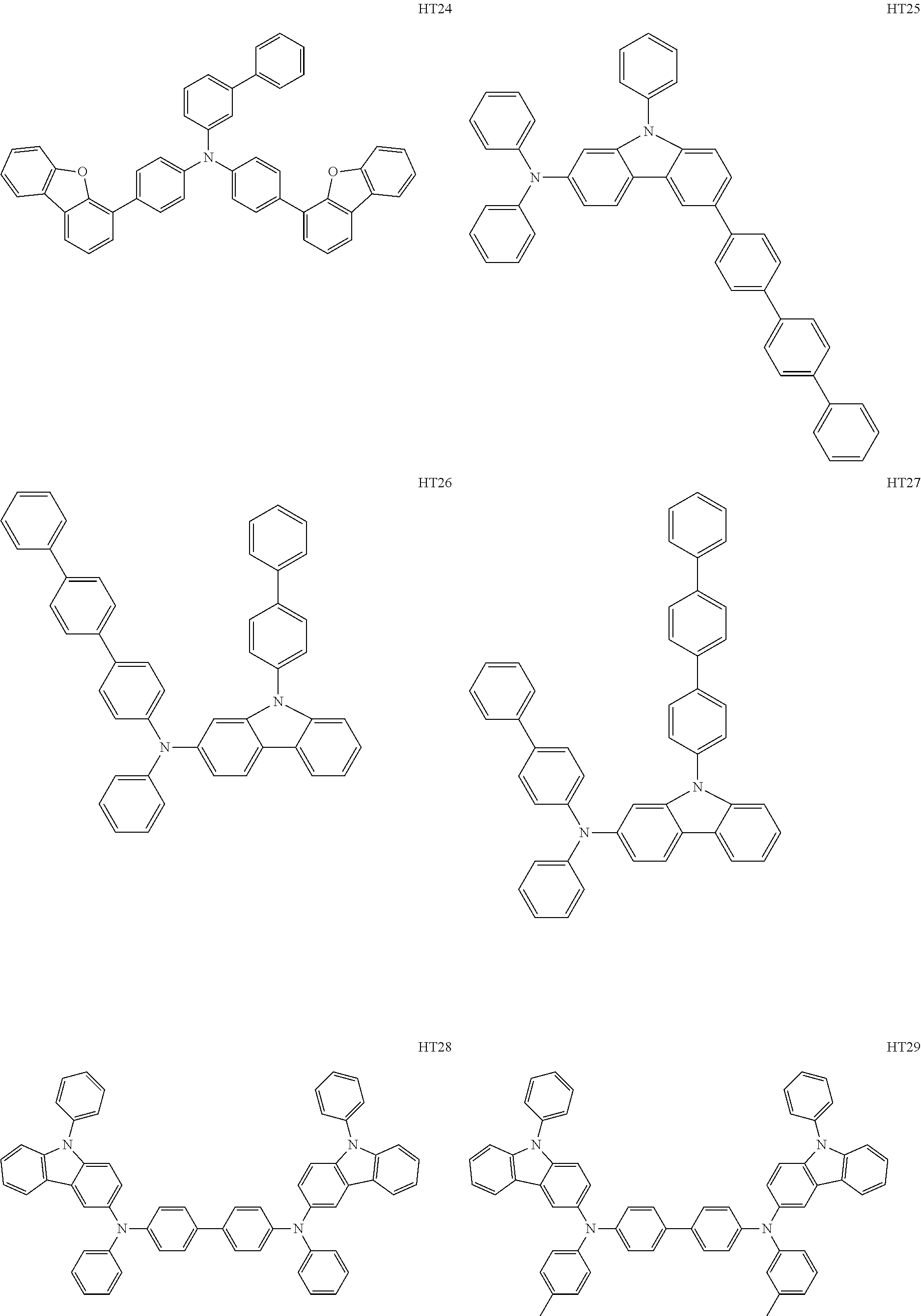

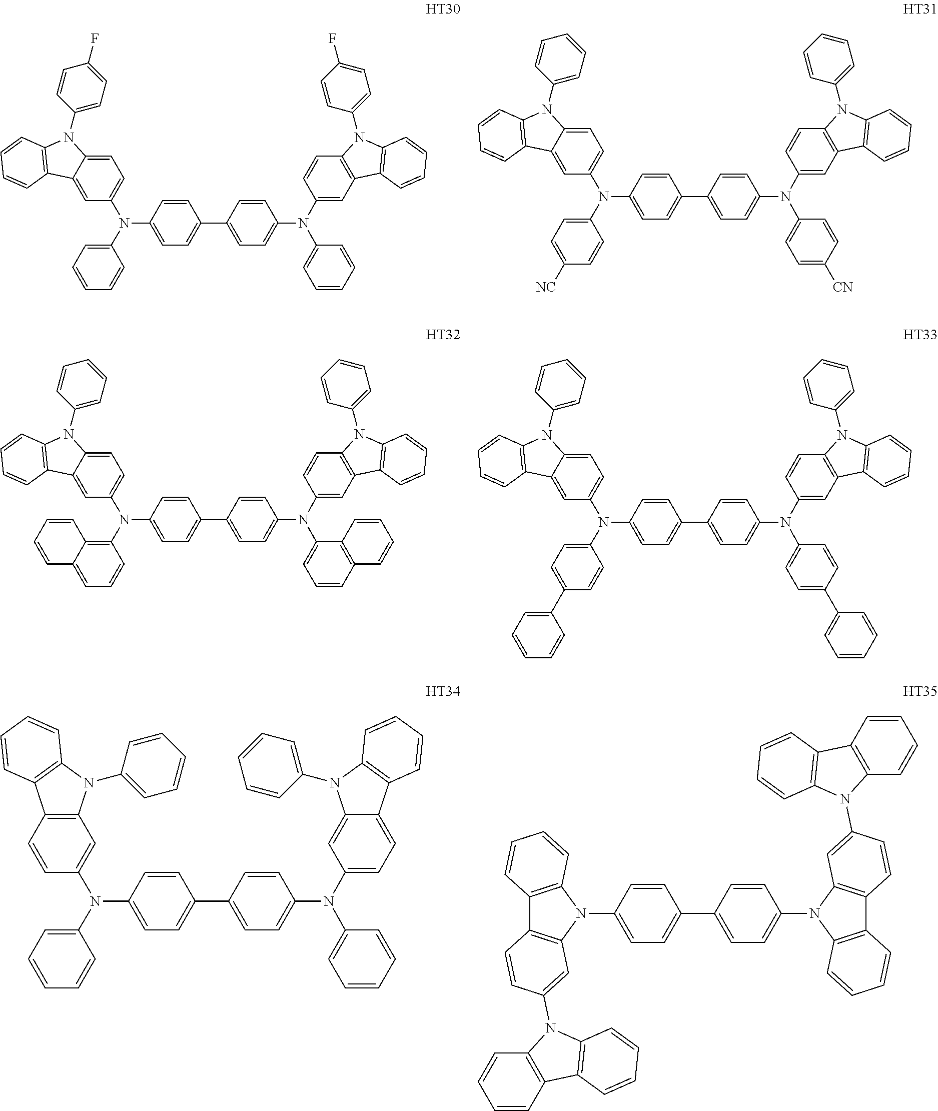

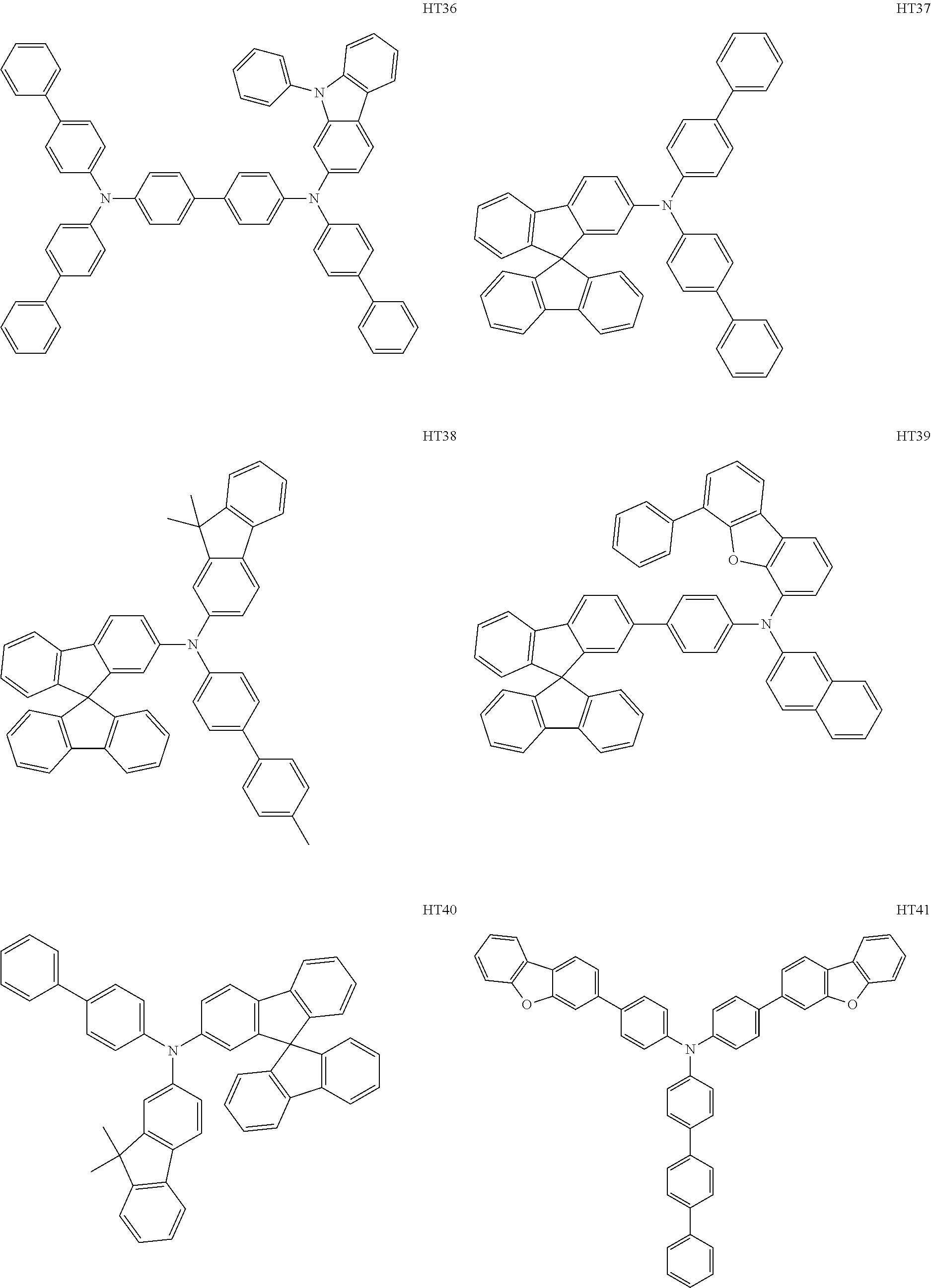

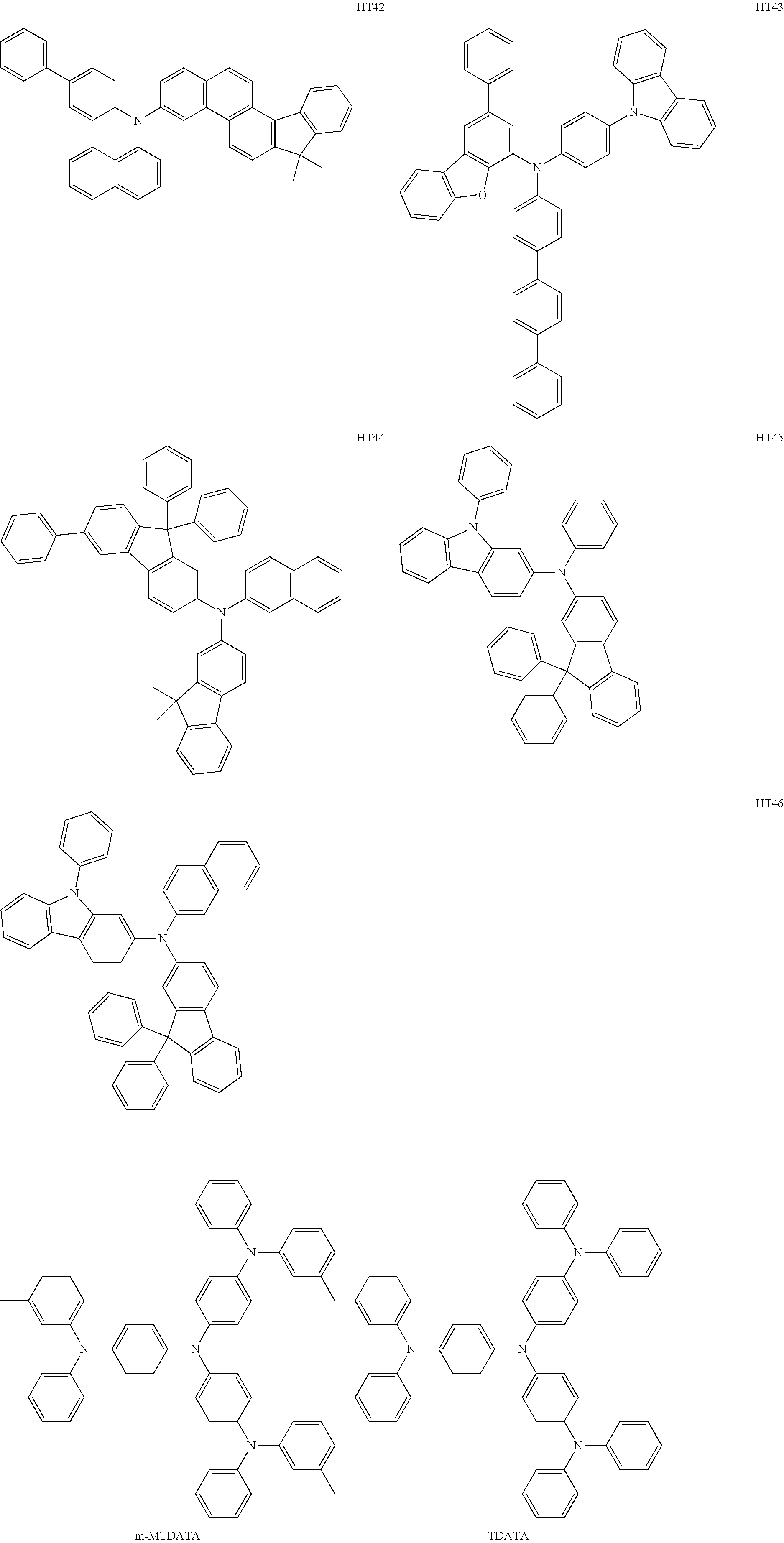

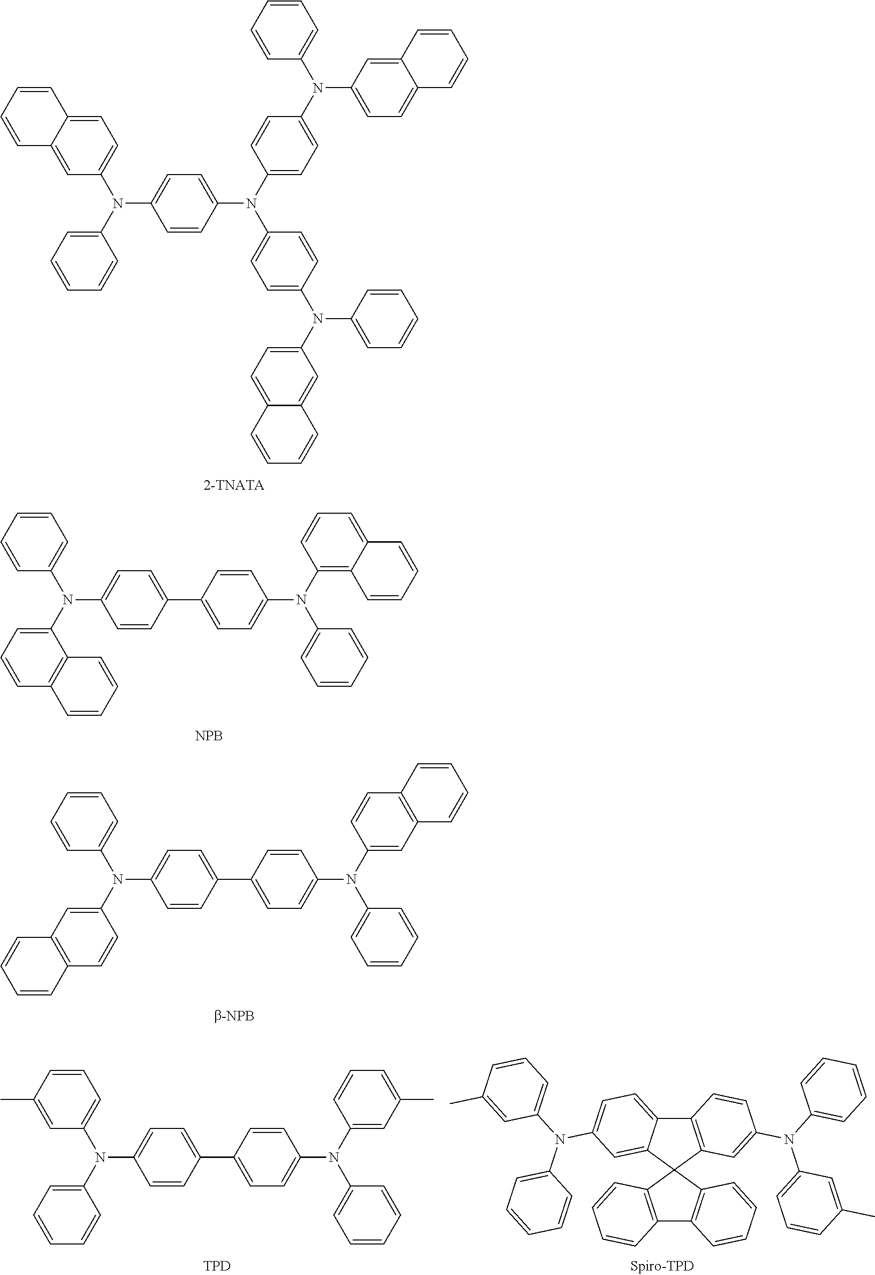

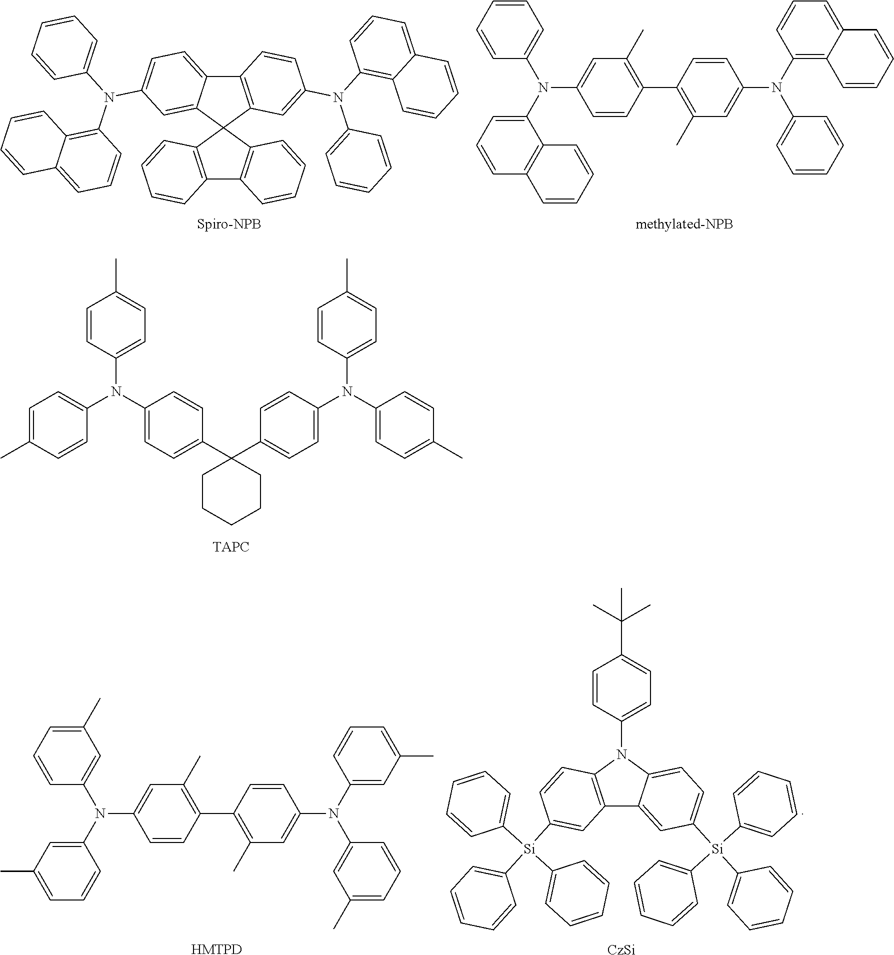

A thickness of the hole transport region may be about 50 angstrom (Å) to about 10,000 Å, for example, about 100 Å to about 4,000 Å. When the hole transport region includes a hole injection layer, a hole transport layer, or any combination thereof, a thickness of the hole injection layer may be about 100 A to about 9,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within the ranges described above, satisfactory hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region. Materials that may be included in the hole transport region may be included in the emission auxiliary layer and the electron blocking layer.

p-Dopant

The hole transport region may further include, in addition to one or more of these aforementioned materials, a charge-generation material for the improvement of conductive properties. The charge-generation material may be uniformly (e.g., substantially uniformly) or non-uniformly dispersed in the hole transport region (for example, in the form of a single layer including (e.g., consisting of) a charge-generation material).

The charge-generation material may be, for example, a p-dopant.

For example, in one or more embodiments, the LUMO energy level of the p-dopant may be less than or equal to −3.5 eV.

In one or more embodiments, the p-dopant may include a quinone derivative, a cyano group-containing compound, a compound including an element EL1 and an element EL2, or any combination thereof.

Non-limiting examples of the quinone derivative may include tetracyanoquinodimethane (TCNQ) and 2,3,5,6-tetrafluoro-7,7,8,8-tetracyanoquinodimethane (F4-TCNQ).

Non-limiting examples of the cyano group-containing compound may include dipyrazino[2,3-f:2′,3′-h]quinoxaline-2,3,6,7,10,11-hexacarbonitrile (HAT-CN) and a compound represented by Formula 221.

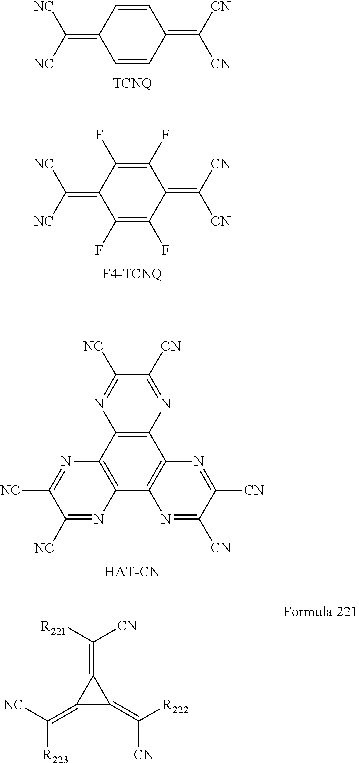

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one selected from among R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including the element EL1 and the element EL2, the element EL1 may be a metal, a metalloid, or a (e.g., any suitable) combination thereof, and the element EL2 may be a non-metal, a metalloid, or a (e.g., any suitable) combination thereof.

Non-limiting examples of the metal may include an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (for example, zinc (Zn), indium (In), tin (Sn), and/or the like); and/or a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Non-limiting examples of the metalloid may include silicon (Si), antimony (Sb), and/or tellurium (Te).

Non-limiting examples of the non-metal may include oxygen (O) and/or a halogen (for example, F, Cl, Br, I, and/or the like).

Non-limiting examples of the compound including the element EL1 and the element EL2 may include a metal oxide, a metal halide (for example, a metal fluoride, a metal chloride, a metal bromide, a metal iodide, and/or the like), a metalloid halide (for example, a metalloid fluoride, a metalloid chloride, a metalloid bromide, a metalloid iodide, and/or the like), a metal telluride, or any combination thereof.

Non-limiting examples of the metal oxide may include a tungsten oxide (for example, WO, W₂O₃, WO₂, WO₃, W₂O₅, and/or the like), a vanadium oxide (for example, VO, V₂O₃, VO₂, V₂O₅, and/or the like), a molybdenum oxide (MoO, Mo₂O₃, MoO₂, MoO₃, Mo₂O₅, and/or the like), and/or a rhenium oxide (for example, ReO₃, and/or the like).

Non-limiting examples of the metal halide may include an alkali metal halide, an alkaline earth metal halide, a transition metal halide, a post-transition metal halide, and/or a lanthanide metal halide.

Non-limiting examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Non-limiting examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, Bel₂, Mgl₂, CaI₂, SrI₂, and/or BaI₂.

Non-limiting examples of the transition metal halide may include a titanium halide (for example, TiF₄, TiCl₄, TiBr₄, TiI₄, and/or the like), a zirconium halide (for example, ZrF₄, ZrC₁₄, ZrBr₄, ZrI₄, and/or the like), a hafnium halide (for example, HfF₄, HfCl₄, HfBr₄, HfI₄, and/or the like), a vanadium halide (for example, VF₃, VCl₃, VBr₃, VI₃, and/or the like), a niobium halide (for example, NbF₃, NbCl₃, NbBr₃, NbI₃, and/or the like), a tantalum halide (for example, TaF₃, TaCl₃, TaBr₃, TaI₃, and/or the like), a chromium halide (for example, CrF₃, CrO₃, CrBr₃, CrI₃, and/or the like), a molybdenum halide (for example, MoF₃, MoCl₃, MoBr₃, MoI₃, and/or the like), a tungsten halide (for example, WF₃, WCl₃, WBr₃, WI₃, and/or the like), a manganese halide (for example, MnF₂, MnCl₂, MnBr₂, MnI₂, and/or the like), a technetium halide (for example, TcF₂, TcCl₂, TcBr₂, TcI₂, and/or the like), a rhenium halide (for example, ReF₂, ReCl₂, ReBr₂, ReI₂, and/or the like), a ferrous halide (for example, FeF₂, FeCl₂, FeBr₂, FeI₂, and/or the like), a ruthenium halide (for example, RuF₂, RuCl₂, RuBr₂, RuI₂, and/or the like), an osmium halide (for example, OsF₂, OsCl₂, OsBr₂, OsI₂, and/or the like), a cobalt halide (for example, CoF₂, CoCl₂, CoBr₂, CoI₂, and/or the like), a rhodium halide (for example, RhF₂, RhCl₂, RhBr₂, RhI₂, and/or the like), an iridium halide (for example, IrF₂, IrCl₂, IrBr₂, IrI₂, and/or the like), a nickel halide (for example, NiF₂, NiCl₂, NiBr₂, NiI₂, and/or the like), a palladium halide (for example, PdF₂, PdCl₂, PdBr₂, PdI₂, and/or the like), a platinum halide (for example, PtF₂, PtCl₂, PtBr₂, PtI₂, and/or the like), a cuprous halide (for example, CuF, CuCl, CuBr, CuI, and/or the like), a silver halide (for example, AgF, AgCl, AgBr, AgI, and/or the like), and/or a gold halide (for example, AuF, AuCl, AuBr, AuI, and/or the like).

Non-limiting examples of the post-transition metal halide may include a zinc halide (for example, ZnF₂, ZnCl₂, ZnBr₂, ZnI₂, and/or the like), an indium halide (for example, InI₃, and/or the like), and/or a tin halide (for example, SnI₂, and/or the like).

Non-limiting examples of the lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and/or SmI₃.

Non-limiting examples of the metalloid halide may include an antimony halide (for example, SbCl₅, and/or the like).

Non-limiting examples of the metal telluride may include an alkali metal telluride (for example, Li₂Te, Na₂Te, K₂Te, Rb₂Te, Cs₂Te, and/or the like), an alkaline earth metal telluride (for example, BeTe, MgTe, CaTe, SrTe, BaTe, and/or the like), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), a post-transition metal telluride (for example, ZnTe, and/or the like), and/or a lanthanide metal telluride (for example, LaTe, CeTe, PrTe, NdTe, PmTe, EuTe, GdTe, TbTe, DyTe, HoTe, ErTe, TmTe, YbTe, LuTe, and/or the like).

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers selected from a red emission layer, a green emission layer, and a blue emission layer, in which the two or more layers contact each other or are separated from each other, to emit white light (e.g., combined white light). In one or more embodiments, the emission layer may include two or more materials selected from among a red light-emitting material, a green light-emitting material, and a blue light-emitting material, in which the two or more materials are mixed with each other in a single layer, to emit white light (e.g., combined white light).

The emission layer may include a host and a dopant. The dopant may include a phosphorescent dopant, a fluorescent dopant, or any combination thereof.

An amount of the dopant in the emission layer may be from about 0.01 part by weight to about 15 parts by weight based on 100 parts by weight of the host.

In one or more embodiments, the emission layer may include a quantum dot.

In one or more embodiments, the emission layer may include a delayed fluorescence material. The delayed fluorescence material may act as a host or a dopant in the emission layer.

A thickness of the emission layer may be about 100 Å to about 1,000 Å, for example, about 200 Å to about 600 Å. When the thickness of the emission layer is within the range described above, excellent or suitable luminescence characteristics may be obtained without a substantial increase in driving voltage.

### Host

In one or more embodiments, the host may include a compound represented by Formula 301:

[Ar₃₀₁]_{xb11}-[(L₃₀₁)_{xb1}-R₃₀₁]_{xb21}, Formula 301
wherein, in Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ are each independently the same as described with respect to Q₁.

In one or more embodiments, if (e.g., when) xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

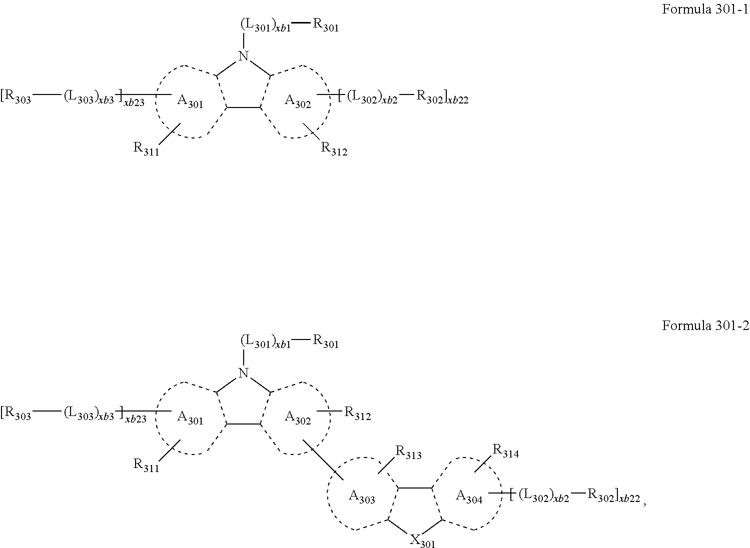

wherein, in Formula 301-1 and 301-2,
ring A₃₀₁ to ring A₃₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each the same as described in the present disclosure,
L₃₀₂ to L₃₀₄ may each independently be the same as described with respect to L₃₀₁,
xb2 to xb4 may each independently be the same as described with respect to xb1, and
R₃₀₂ to R₃₀₅ and R₃₁₁ to R₃₁₄ are each independently the same as described with respect to R₃₀₁.

In one or more embodiments, the host may include an alkaline earth metal complex, a post-transition metal complex, or any combination thereof. In one or more embodiments, the host may include a Be complex (for example, Compound H55), an Mg complex, a Zn complex, or any combination thereof.

In one or more embodiments, the host may include at least one selected from among Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di(9H-carbazol-9-yl)benzene (mOP), 1,3,5-tri(carbazol-9-yl)benzene (TCP), or any combination thereof:

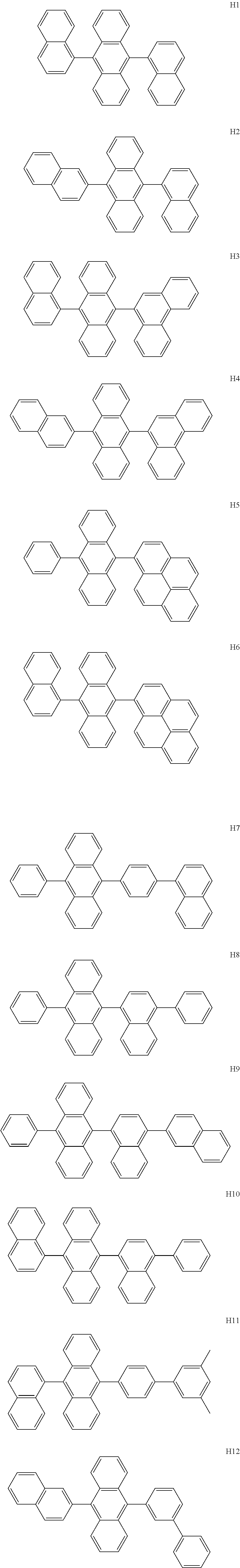

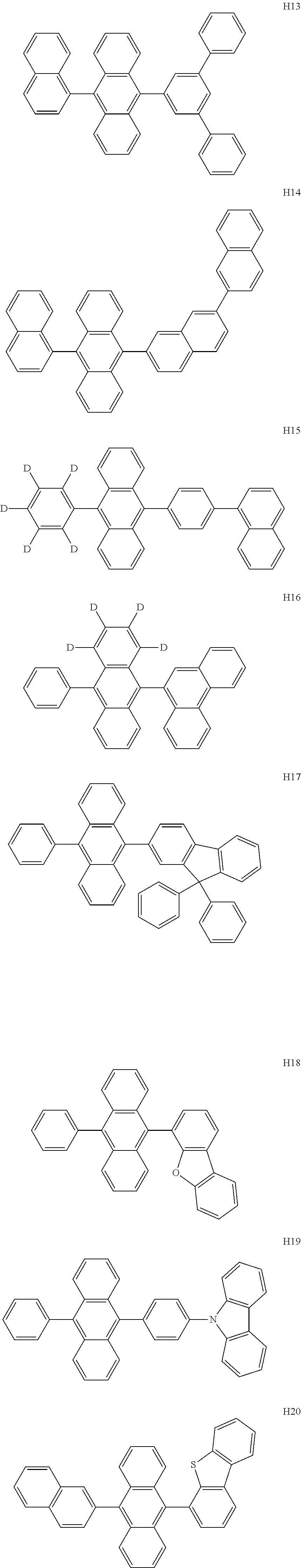

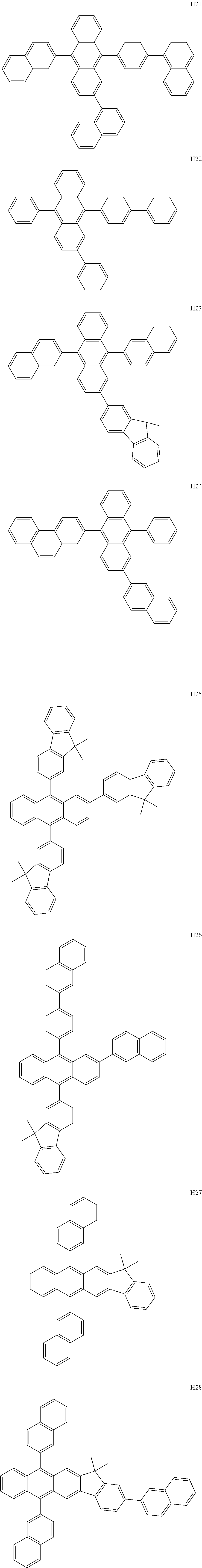

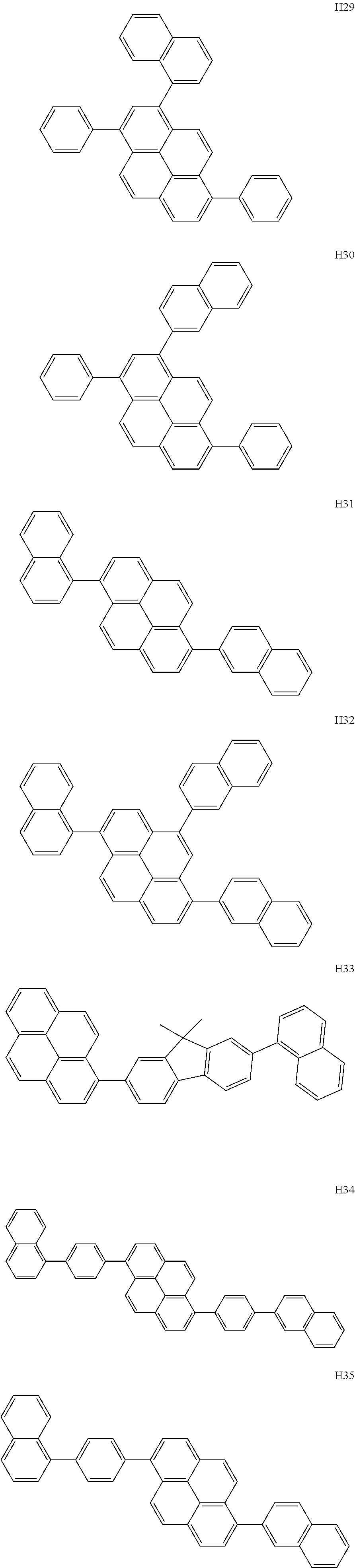

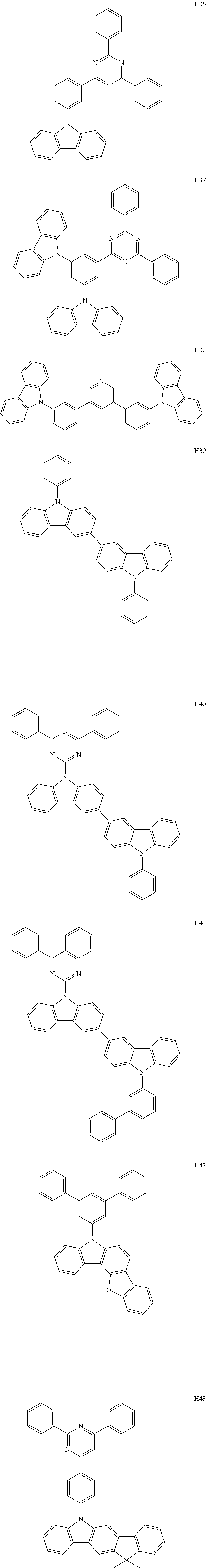

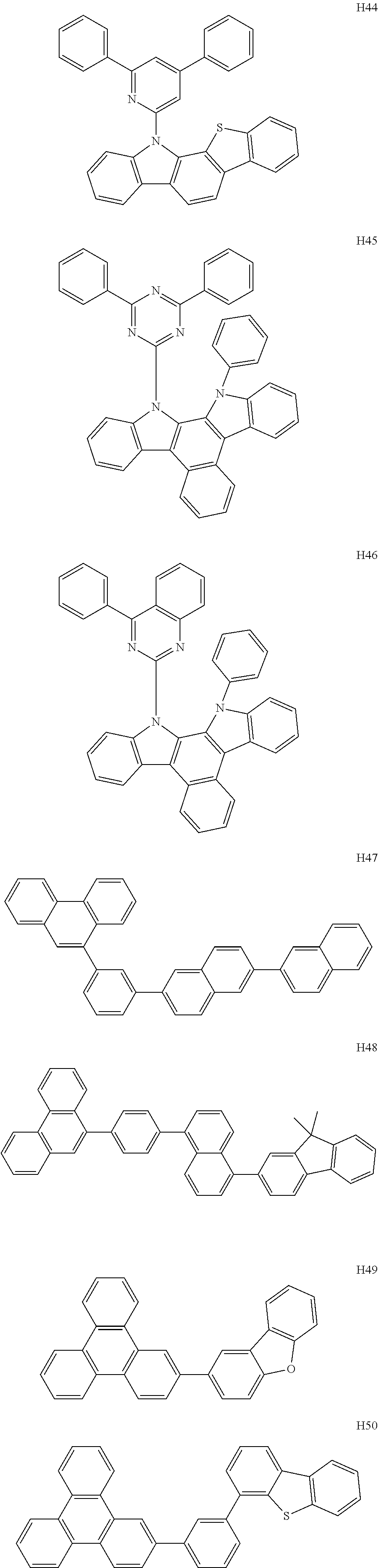

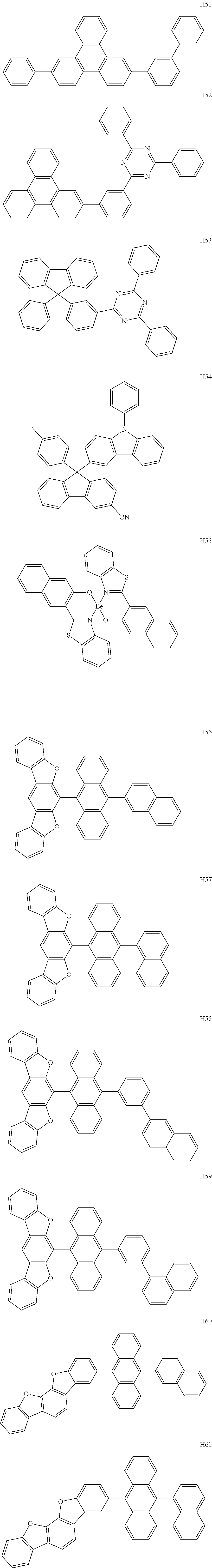

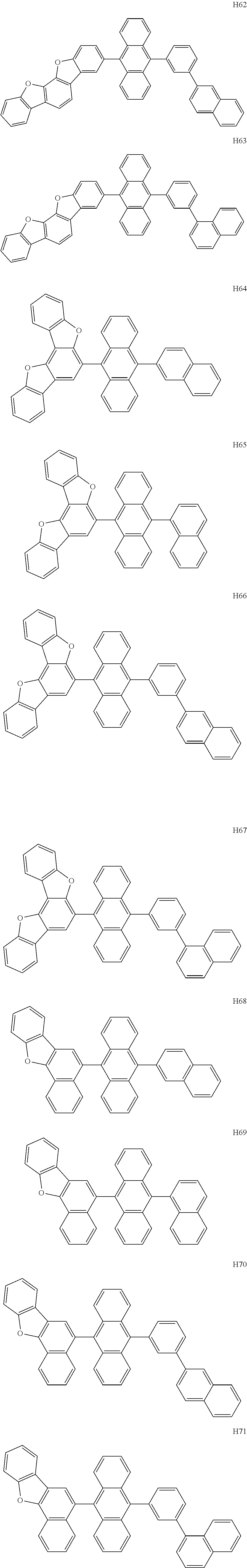

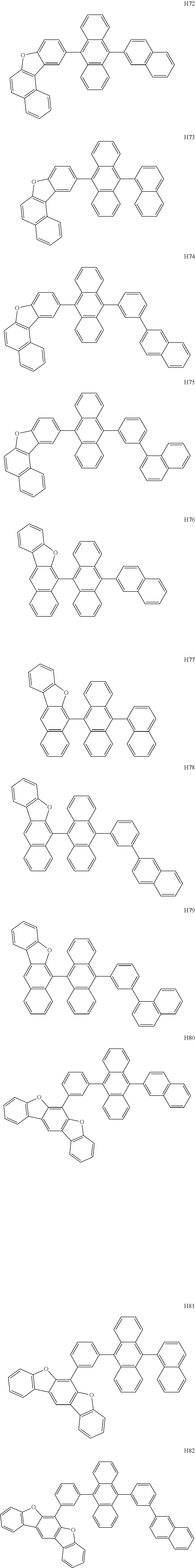

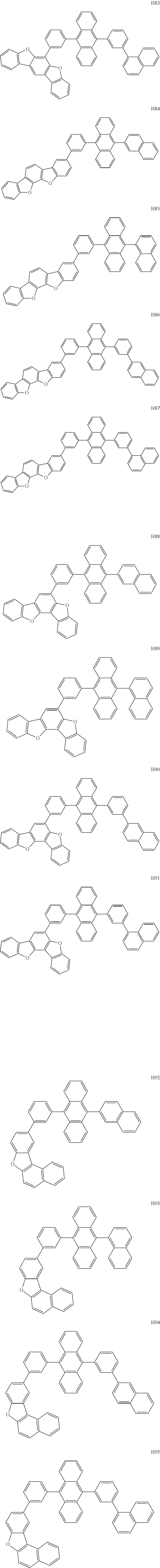

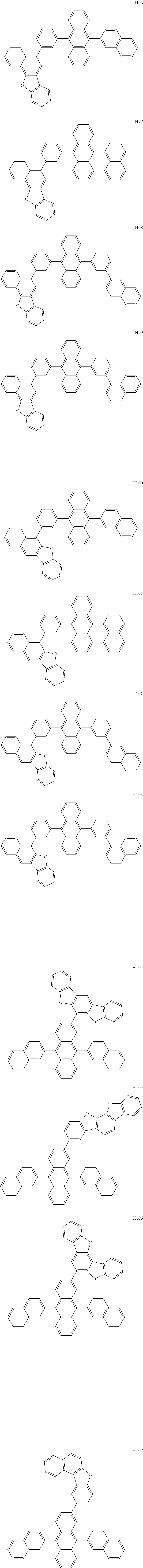

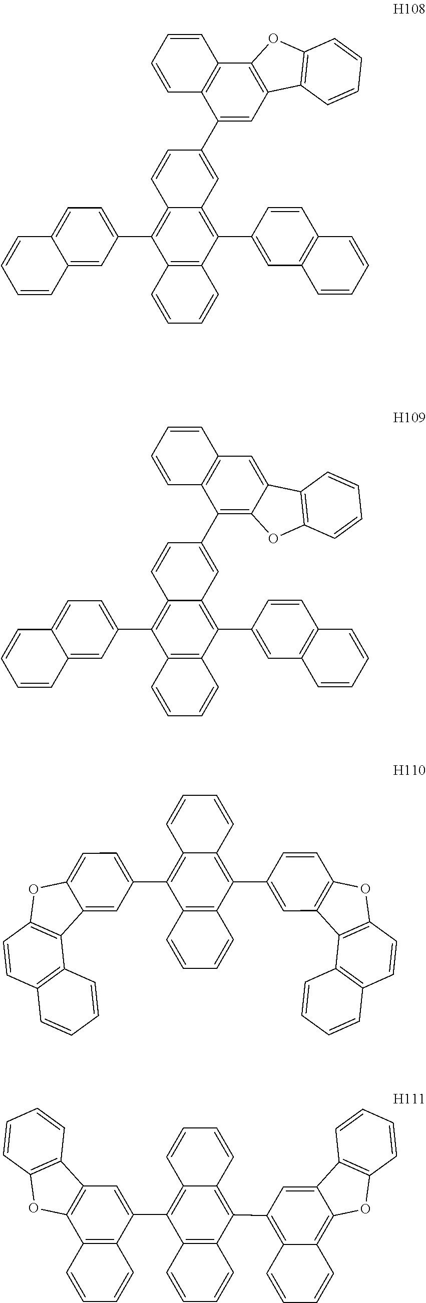 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

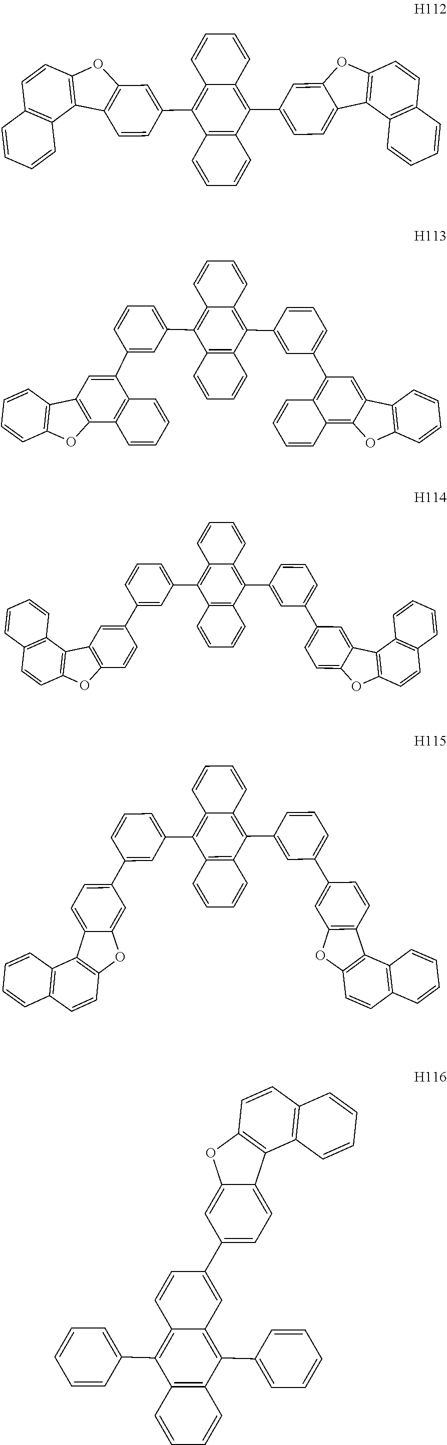 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

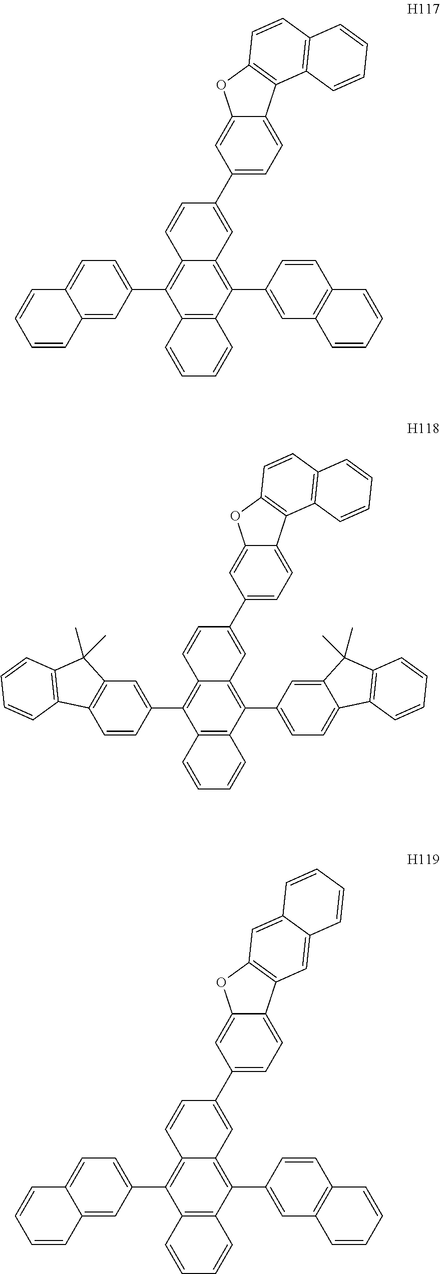 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

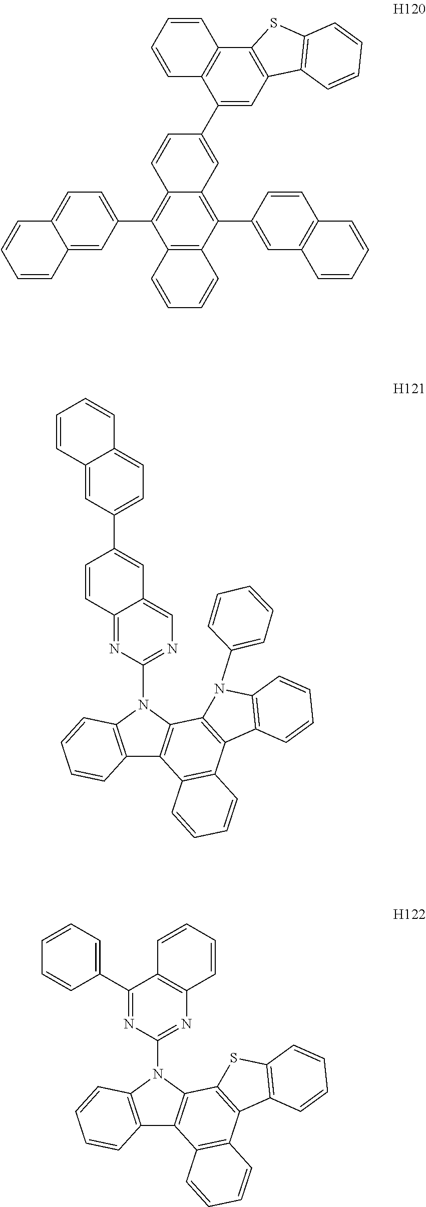 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

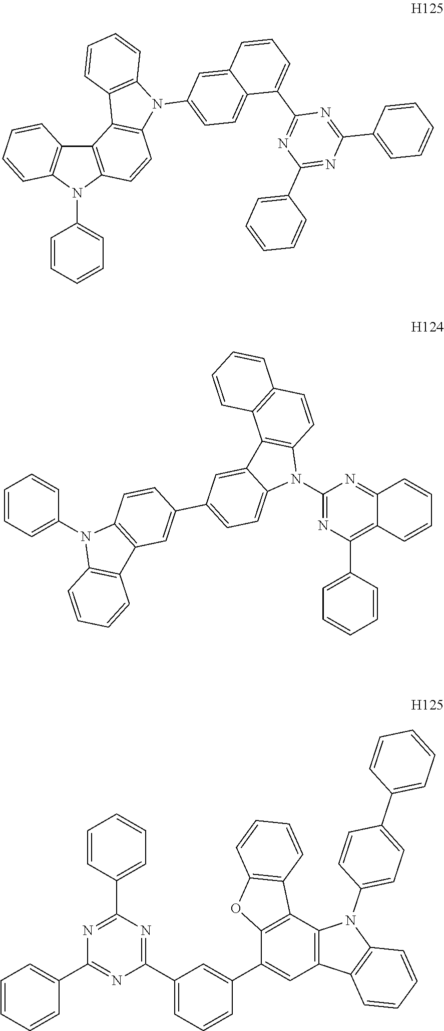 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

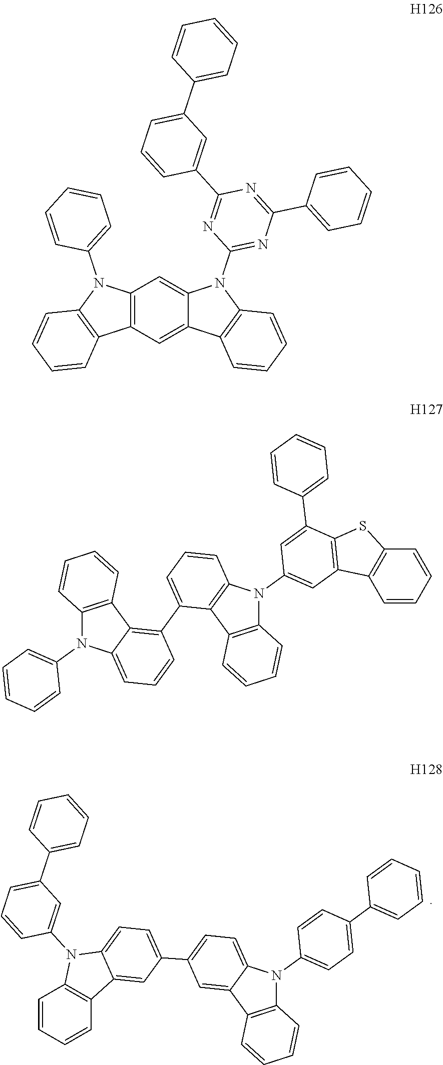 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In one or more embodiments, the phosphorescent dopant may include an organometallic compound represented by Formula 401:

M(L₄₀₁)_{xc1}(L₄₀₂)_{xc2} Formula 401

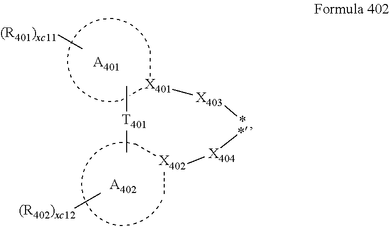

wherein, in Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 is 1, 2, or 3, wherein, if (e.g., when) xc1 is 2 or more, two or more of L₄₀₁(s) may be identical to or different from each other,
L₄₀₂ may be an organic ligand, and xc2 may be 0, 1, 2, 3, or 4, wherein, if (e.g., when) xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)═*′, or *=C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)-(Q₄₁₄),
Q₄₁₁ to Q₄₁₄ are each independently the same as described with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ are each independently the same as described with respect to Q₁,
xc11 and xc12 may each independently be an integer from 0 to 10, and
* and *′ in Formula 402 each indicate a binding site to M in Formula 401.

In one or more embodiments, in Formula 402, i) X₄₀₁ may be nitrogen, and X₄₀₂ may be carbon, or ii) each of X₄₀₁ and X₄₀₂ may be nitrogen.

In one or more embodiments, if (e.g., when) xc1 in Formula 401 is 2 or more, two ring A₄₀₁(s) among two or more of L₄₀₁ (s) may be optionally linked together via T₄₀₂, which is a linking group, and/or two ring A₄₀₂(s) may be optionally linked together via T₄₀₃, which is a linking group (see Compounds PD1 to PD4 and PD7). T₄₀₂ and T₄₀₃ are each the same as described with respect to T₄₀₁.

L₄₀₂ in Formula 401 may be an organic ligand. In one or more embodiments, L₄₀₂ may include a halogen, a diketone group (for example, an acetylacetonate group), a carboxylic acid group (for example, a picolinate group), —C(═O), an isonitrile group, a —CN group, a phosphorus-containing group (for example, a phosphine group, a phosphite group, and/or the like), or any combination thereof.

In one or more embodiments, the phosphorescent dopant may include, for example, one selected from Compounds PD1 to PD39, or any combination thereof:

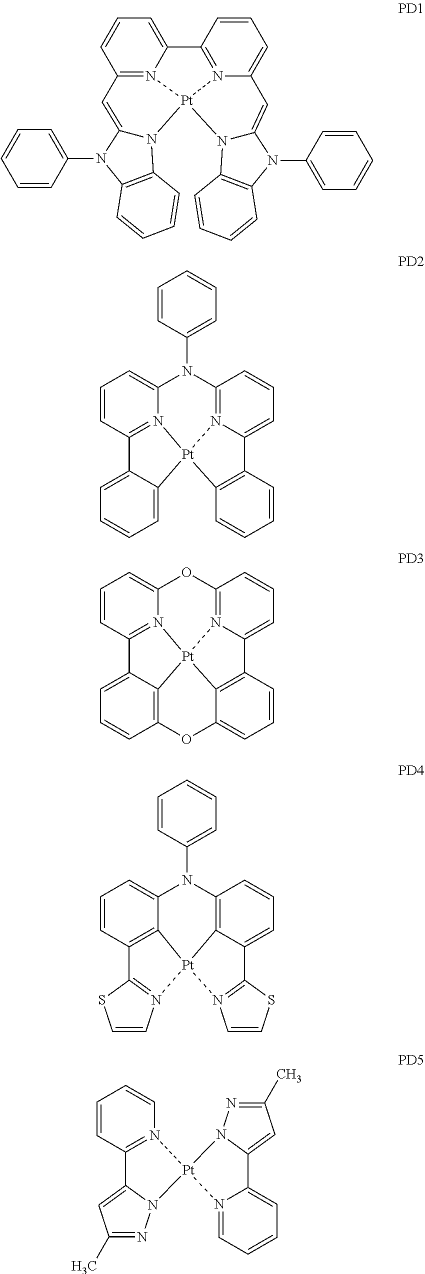

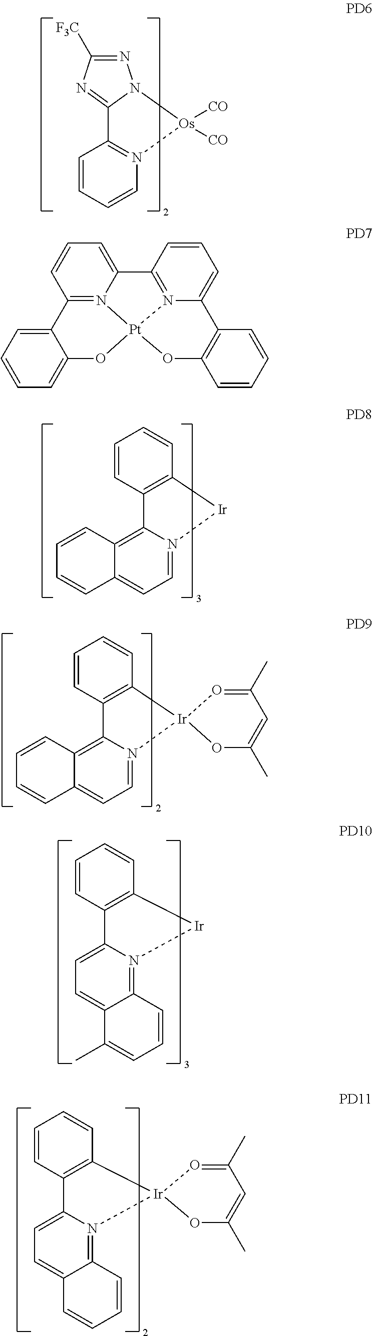

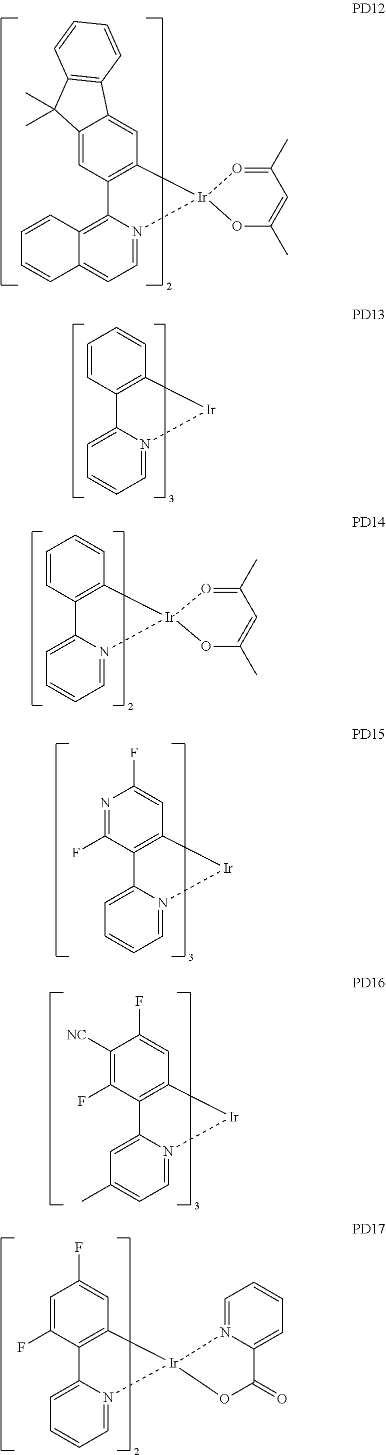

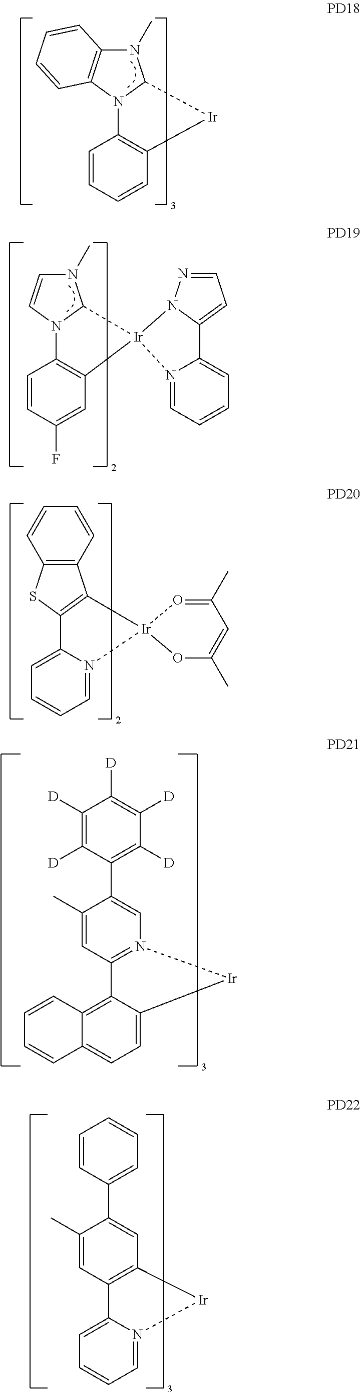

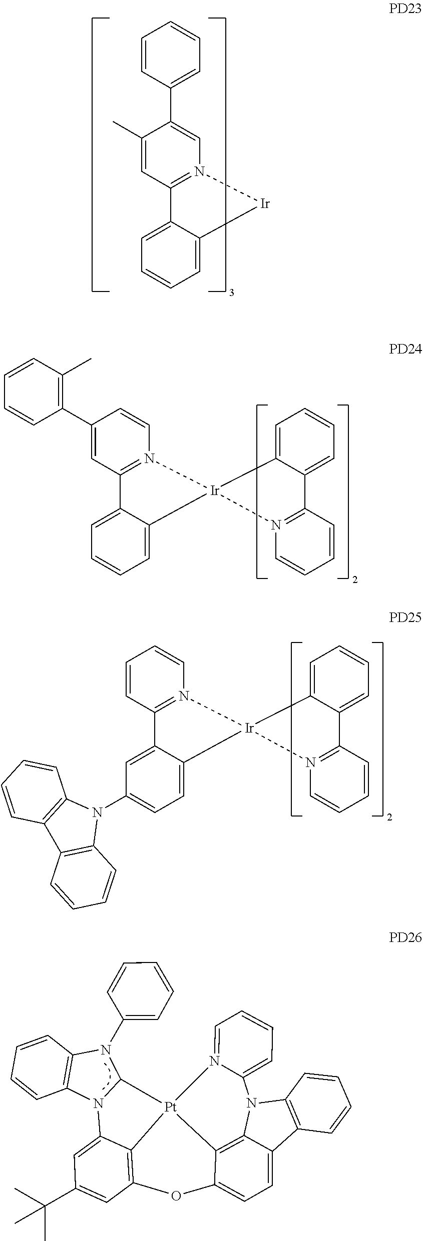

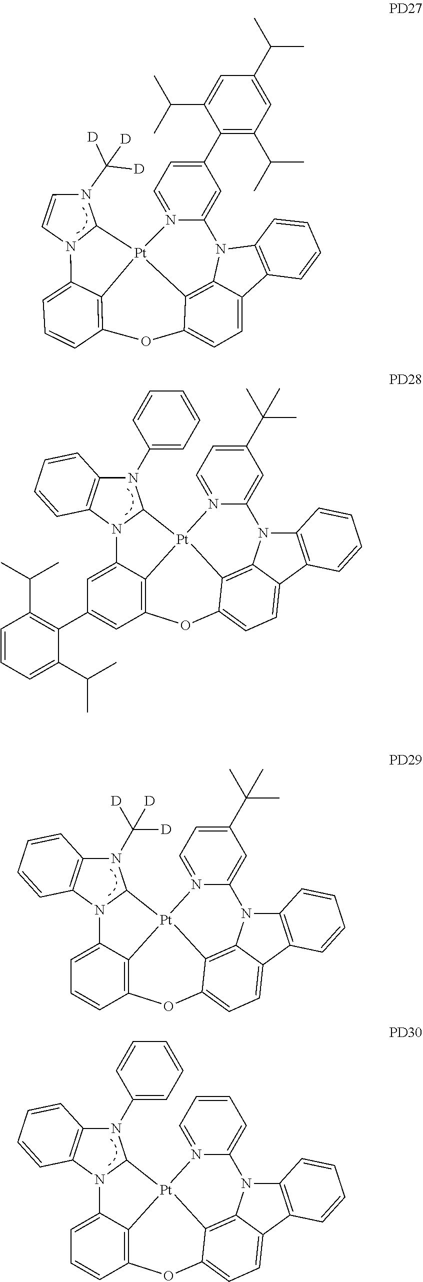

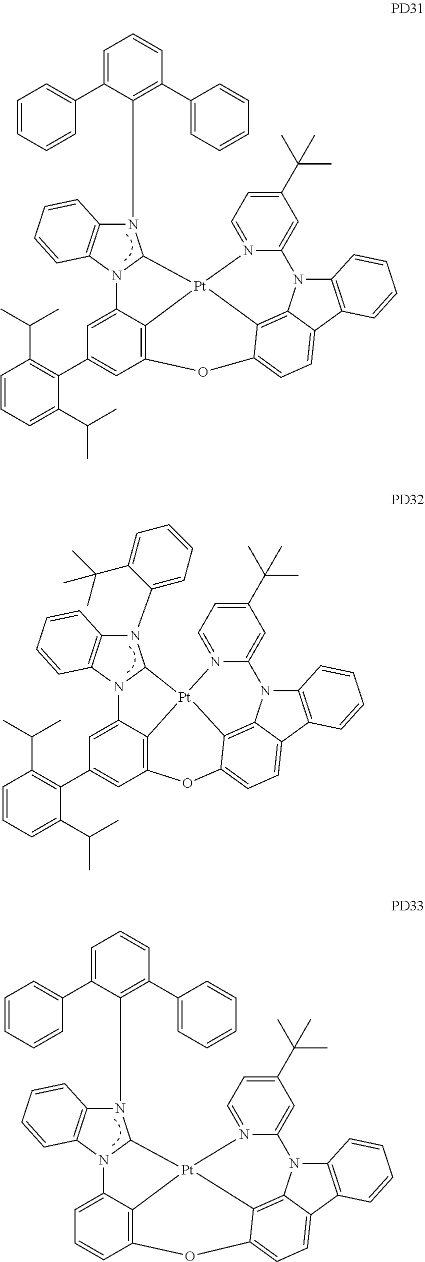

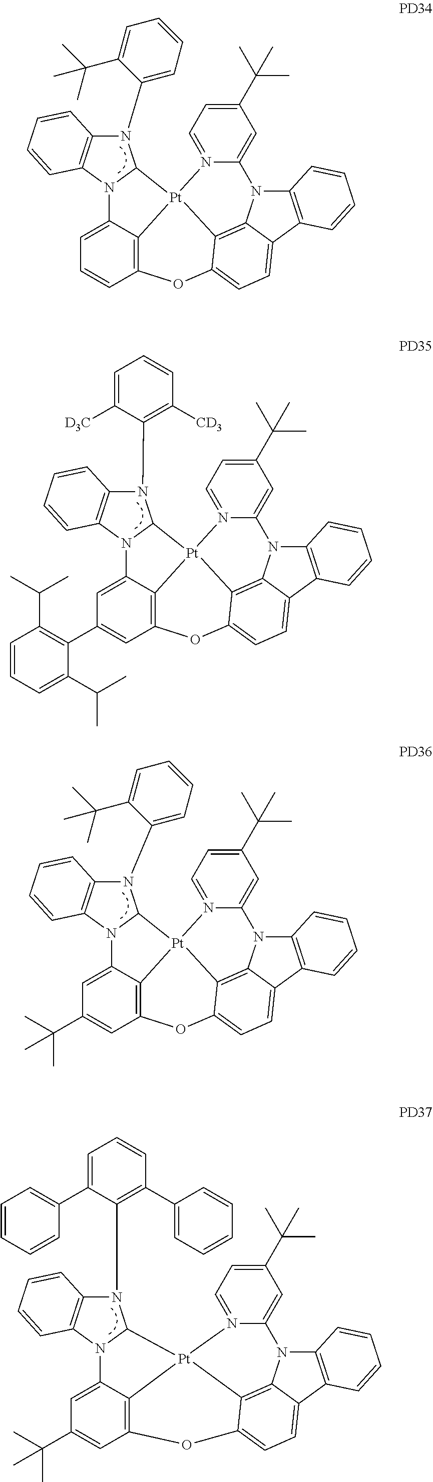

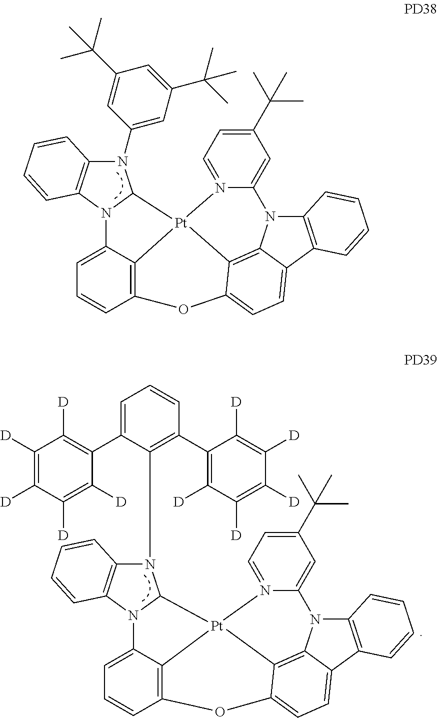

### Fluorescent Dopant

The fluorescent dopant may include an amine group-containing compound, a styryl group-containing compound, or any combination thereof.

For example, in one or more embodiments, the fluorescent dopant may include a compound represented by Formula 501:

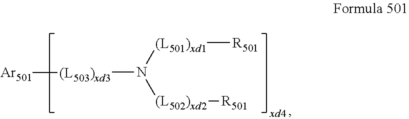

wherein, in Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be 0, 1, 2, or 3, and
xd4 may be 1, 2, 3, 4, 5, or 6.

In one or more embodiments, Ar₅₀₁ in Formula 501 may be a condensed cyclic group (for example, an anthracene group, a chrysene group, a pyrene group, and/or the like) in which three or more monocyclic groups are condensed together.

In one or more embodiments, xd4 in Formula 501 may be 2.

In one or more embodiments, the fluorescent dopant may include: at least one of Compounds FD1 to FD37; 4,4′-bis(2,2-diphenylvinyl)-1,1′-biphenyl (DPVBi); 4,4′-bis[4-(N,N-diphenylamino)styryl]biphenyl (DPAVBi); or any combination thereof:

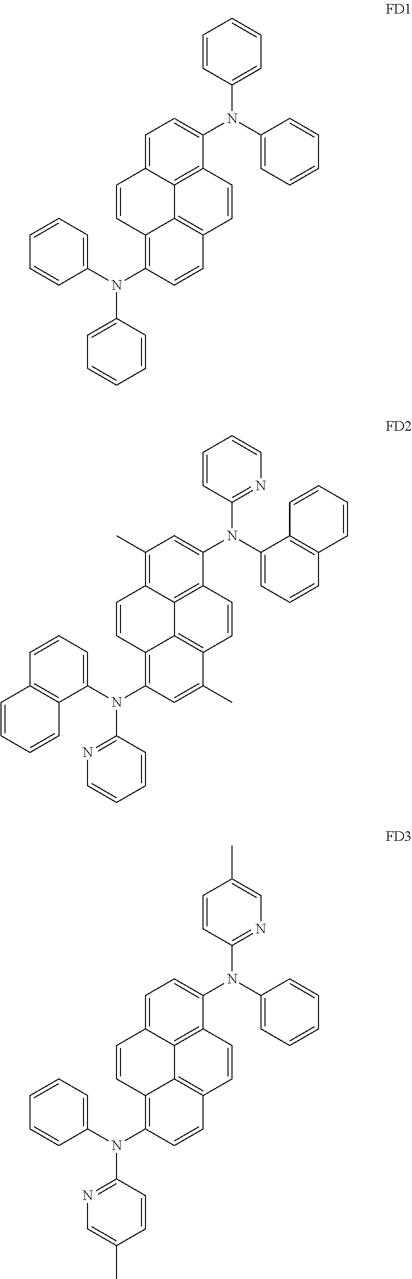 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

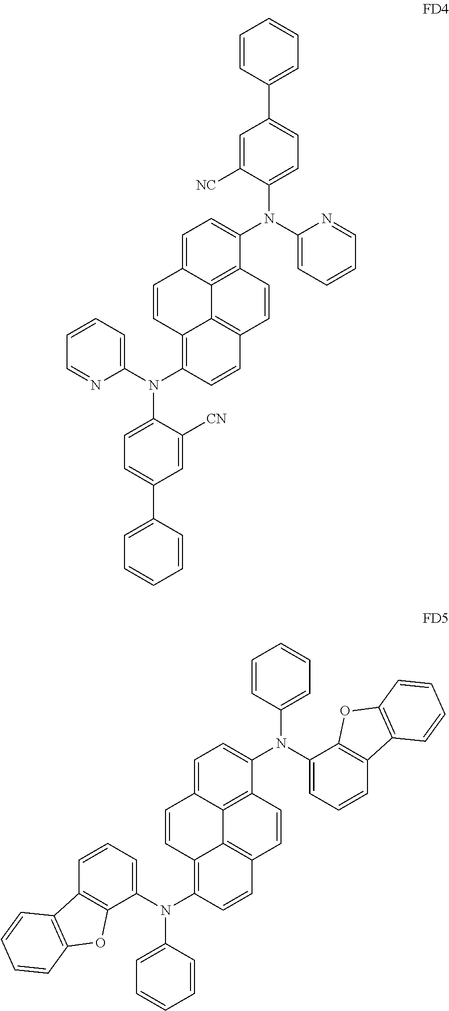 [SMILES: N#Cc1cc(-c2ccccc2)ccc1N(c1ccccn1)c1ccc2ccc3c(N(c4ccccn4)c4ccc(-c5ccccc5)cc4C#N)ccc4ccc1c2c43 ; c1ccc(N(c2ccc3ccc4c(N(c5ccccc5)c5cccc6c5oc5ccccc56)ccc5ccc2c3c54)c2cccc3c2oc2ccccc23)cc1]

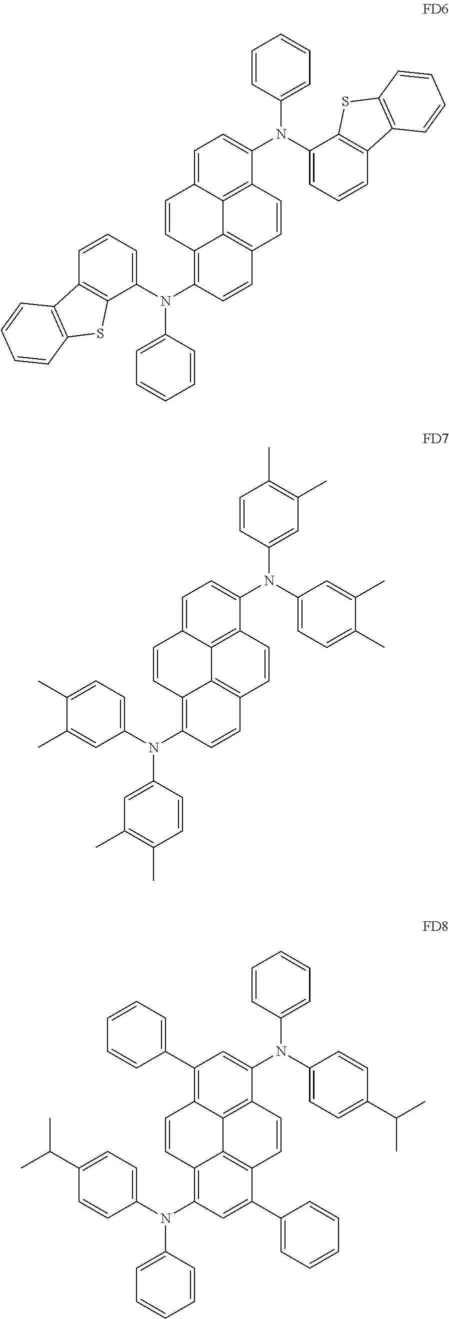

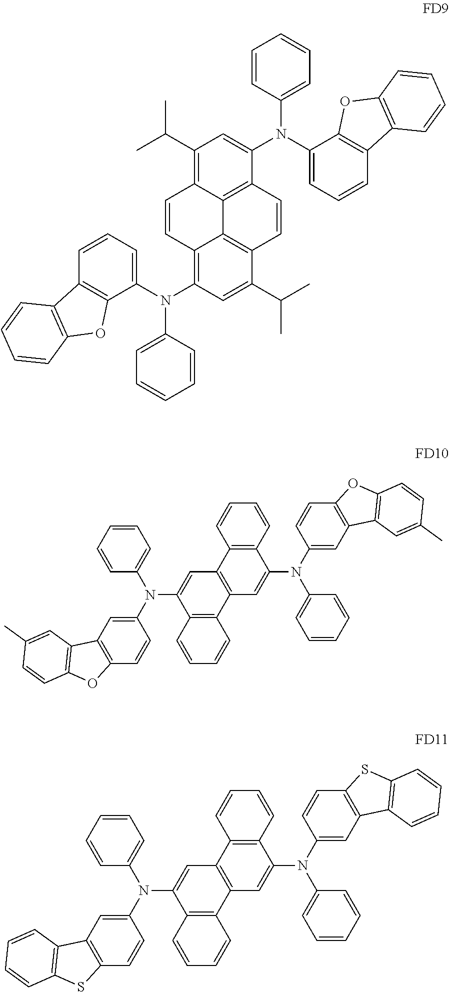

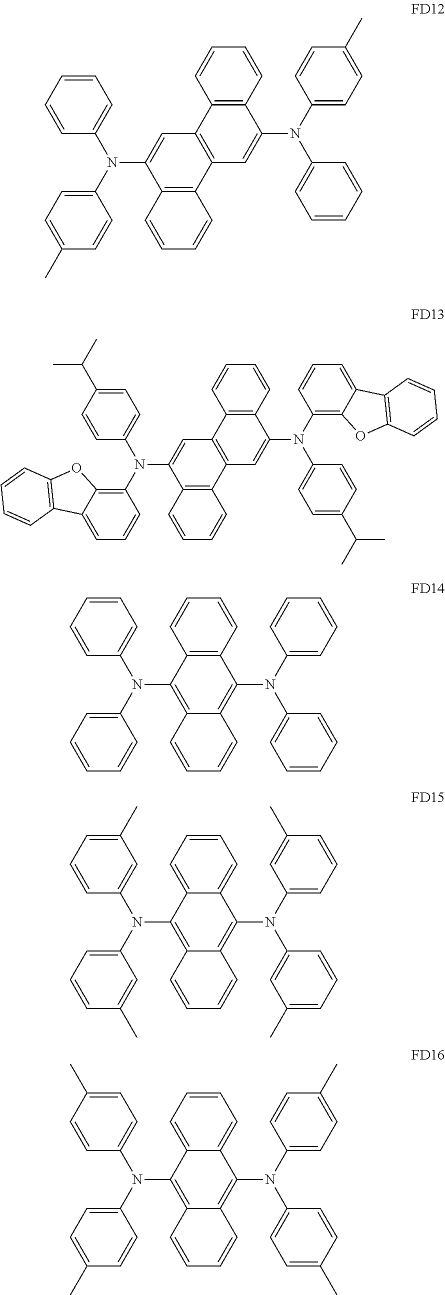

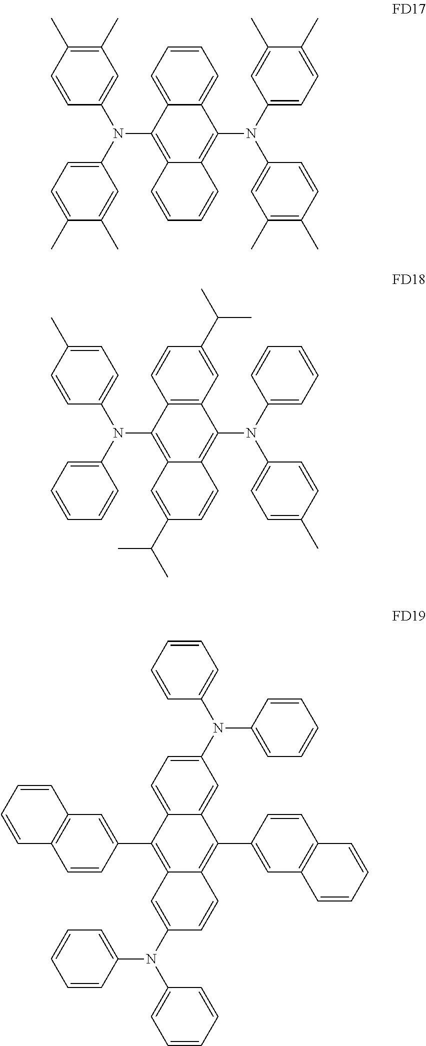 [SMILES: Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1 ; c1ccc(N(c2ccccc2)c2ccc3c(-c4ccc5ccccc5c4)c4cc(N(c5ccccc5)c5ccccc5)ccc4c(-c4ccc5ccccc5c4)c3c2)cc1]

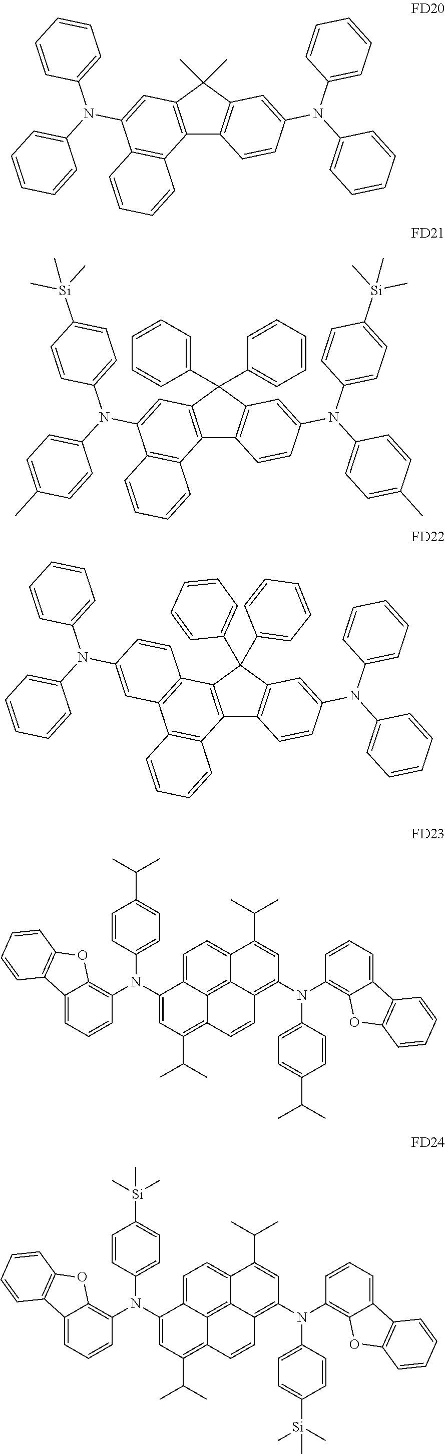

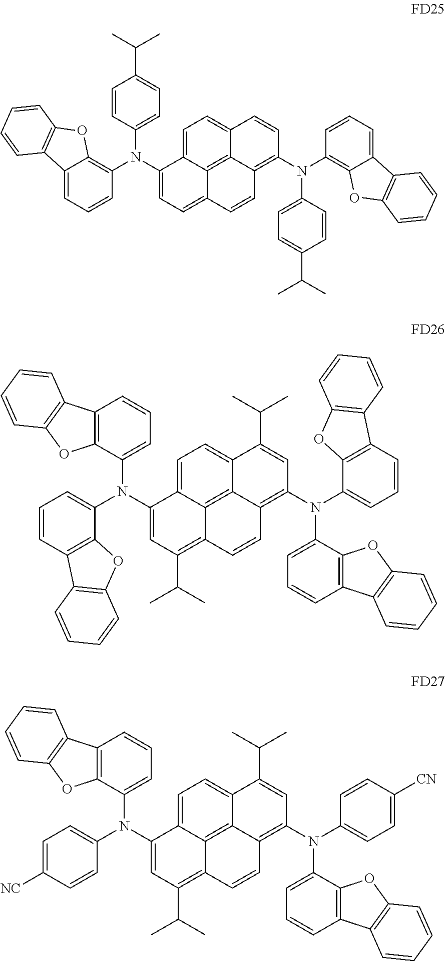 [SMILES: CC(C)c1ccc(N(c2ccc3ccc4c(N(c5ccc(C(C)C)cc5)c5cccc6c5oc5ccccc56)ccc5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34 ; CC(C)c1cc(N(c2ccc(C#N)cc2)c2cccc3c2oc2ccccc23)c2ccc3c(C(C)C)cc(N(c4ccc(C#N)cc4)c4cccc5c4oc4ccccc45)c4ccc1c2c34]

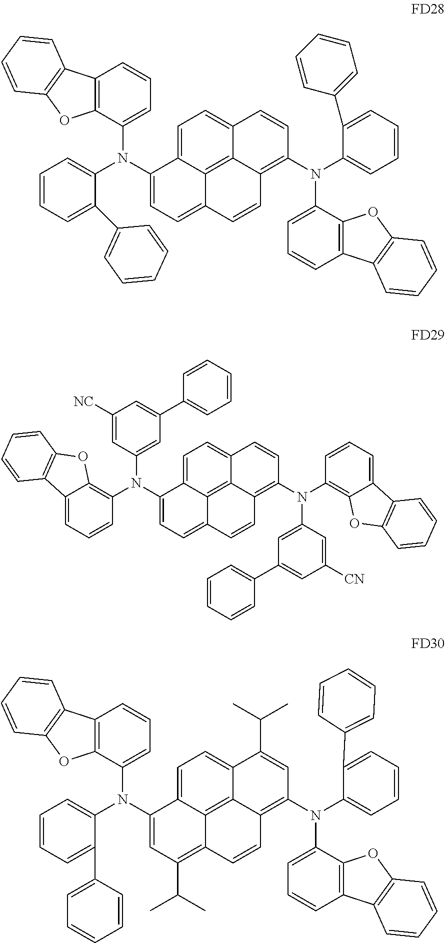 [SMILES: c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; N#Cc1cc(-c2ccccc2)cc(N(c2ccc3ccc4c(N(c5cc(C#N)cc(-c6ccccc6)c5)c5cccc6c5oc5ccccc56)ccc5ccc2c3c54)c2cccc3c2oc2ccccc23)c1 ; CC(C)c1cc(N(c2ccccc2-c2ccccc2)c2cccc3c2oc2ccccc23)c2ccc3c(C(C)C)cc(N(c4ccccc4-c4ccccc4)c4cccc5c4oc4ccccc45)c4ccc1c2c34]

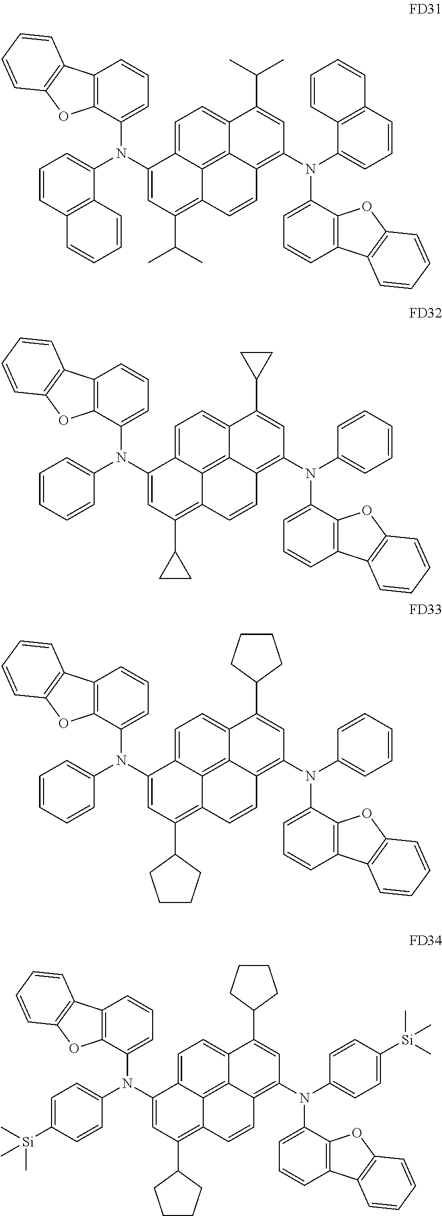

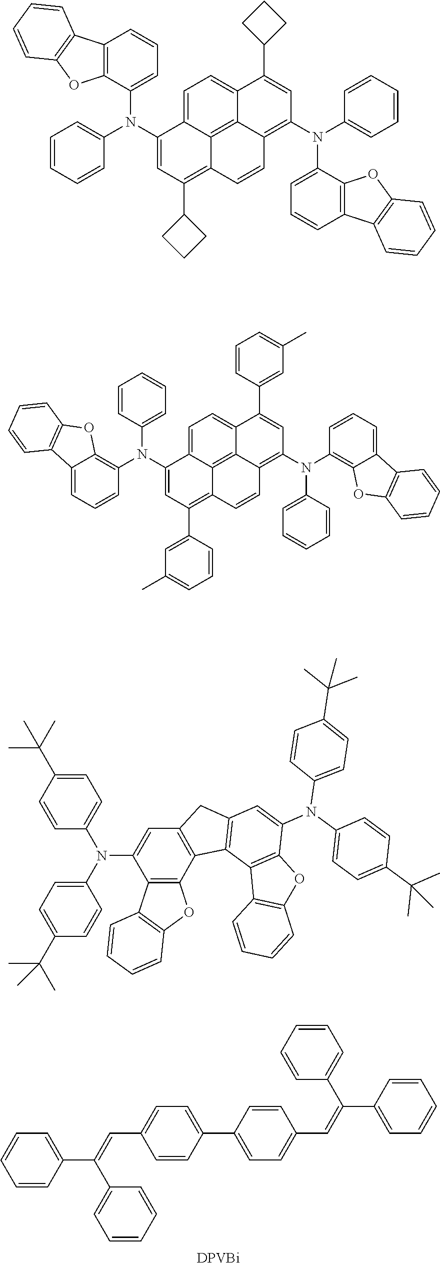

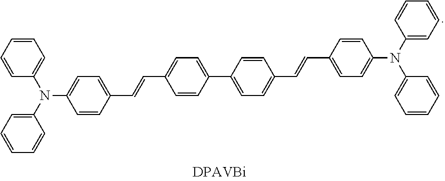 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

### Delayed Fluorescence Material

The emission layer may include a delayed fluorescence material.

Herein, the delayed fluorescence material may be selected from among compounds capable of emitting delayed fluorescence based on a delayed fluorescence emission mechanism.

The delayed fluorescence material included in the emission layer may act as a host or a dopant depending on the type or kind of other materials included in the emission layer.

In one or more embodiments, a difference between a triplet energy level (eV) of the delayed fluorescence material and a singlet energy level (eV) of the delayed fluorescence material may be at least about 0 eV and at most, e.g., not more than, about 0.5 eV. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively occur, and thus, the light-emitting device 10 may have improved luminescence efficiency.

In one or more embodiments, the delayed fluorescence material may include: i) a material including at least one electron donor (for example, a π electron-rich C₃-C₆₀ cyclic group such as a carbazole group) and at least one electron acceptor (for example, a sulfoxide group, a cyano group, a π electron-deficient nitrogen-containing C₁-C₆₀ cyclic group, and/or the like), and/or ii) a material including a C₈-C₆₀ polycyclic group including at least two cyclic groups that are condensed with each other while sharing boron (B).

Non-limiting examples of the delayed fluorescence material may include at least one selected from among Compounds DF1 to DF14:

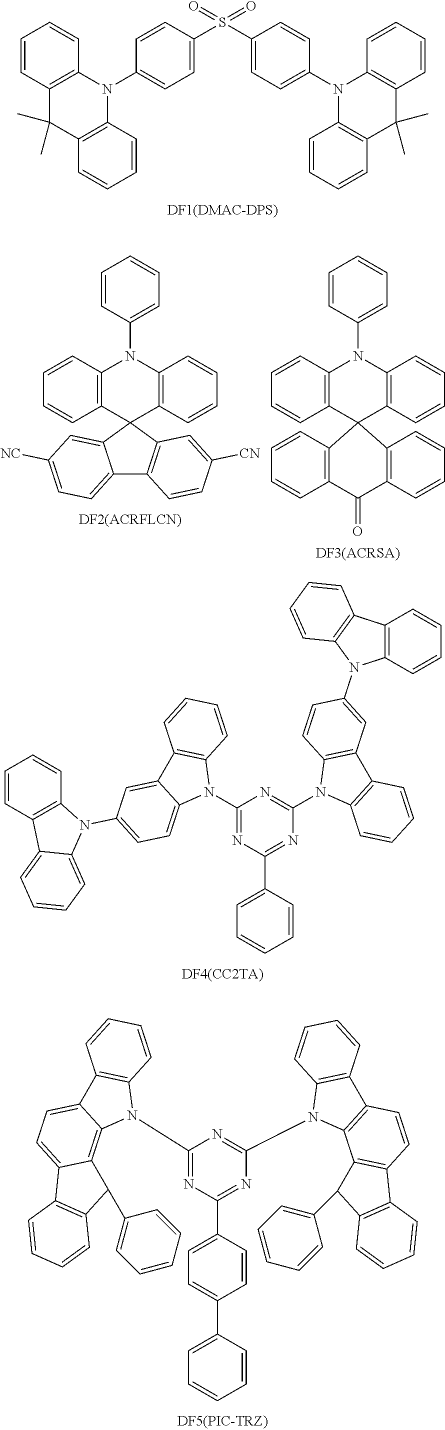

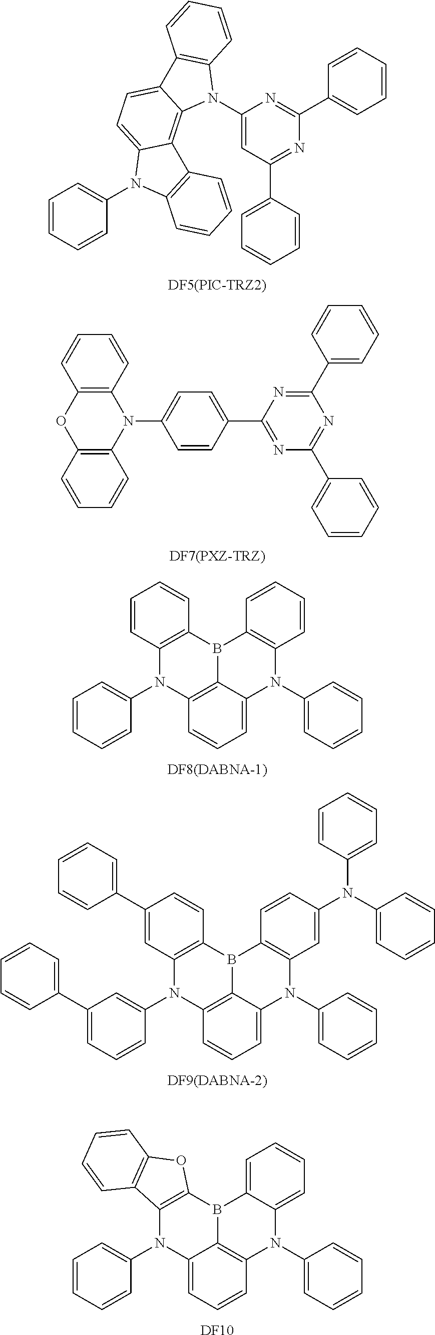

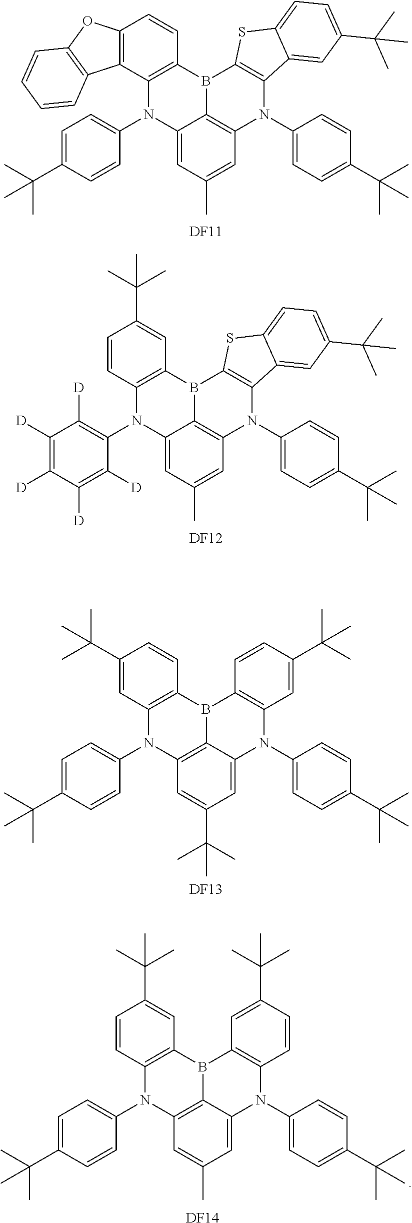

### Quantum Dot

In one or more embodiments, the emission layer may include quantum dots.

Herein, the term “quantum dot” refers to a crystal of a semiconductor compound, and may include any material capable of emitting light of one or more suitable emission wavelengths according to the size of the crystal.

A diameter of the quantum dot may be, for example, about 1 nanometer (nm) to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or any process similar thereto.

The wet chemical process is a method including mixing a precursor material of a quantum dot with an organic solvent and then growing quantum dot particle crystals. When the crystal grows, the organic solvent naturally acts as a dispersant coordinated on the surface of the quantum dot crystal and controls the growth of the crystal so that the growth of quantum dot particles may be controlled or selected through a process which costs lower, and is easier than vapor deposition methods, such as metal organic chemical vapor deposition (MOCVD) or molecular beam epitaxy (MBE).

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Non-limiting examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Non-limiting examples of the Group III-V semiconductor compound may include: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. In one or more embodiments, the Group Ill-V semiconductor compound may further include a Group II element. Non-limiting examples of the Group III-V semiconductor compound further including the Group II element may include InZnP, InGaZnP, and/or InAlZnP.

Non-limiting examples of the Group III-VI semiconductor compound may include: a binary compound, such as GaS, GaSe, Ga₂Se₃, GaTe, InS, InSe, In₂S₃, In₂Se₃, and/or InTe; a ternary compound, such as InGaS₃ and/or InGaSe₃; or any combination thereof.

Non-limiting examples of the Group I-III-VI semiconductor compound may include: a ternary compound, such as AgInS, AgInS₂, CuInS, CuInS₂, CuGaO₂, AgGaO₂, and/or AgAlO₂; or any combination thereof.

Non-limiting examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

Non-limiting examples of the Group IV element or compound may include: a single element compound, such as Si and/or Ge; a binary compound, such as SiC and/or SiGe; or any combination thereof.

Each element included in a multi-element compound, such as the binary compound, the ternary compound, and the quaternary compound, may be present at a substantially uniform concentration or non-substantially uniform concentration in a particle.

In one or more embodiments, the quantum dot may have a single structure in which the concentration of each element in the quantum dot is substantially uniform, or may have a core-shell dual structure. In one or more embodiments, a material included in the core and a material included in the shell may be different from each other.

The shell of the quantum dot may act as a protective layer which prevents chemical denaturation of the core to maintain semiconductor characteristics, and/or as a charging layer which imparts electrophoretic characteristics to the quantum dot. The shell may be a single layer or a multilayer. The interface between the core and the shell may have a concentration gradient in which the concentration of an element existing in the shell decreases toward the center of the core.

Examples of the shell of the quantum dot are an oxide of metal, metalloid, or non-metal, a semiconductor compound, and/or a (e.g., any suitable) combination thereof. Non-limiting examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Examples of the semiconductor compound may include: as described herein, a Group II-VI semiconductor compound; a Group III-V semiconductor compound; a Group III-VI semiconductor compound; a Group I-III-VI semiconductor compound; a Group IV-VI semiconductor compound; or any combination thereof. In one or more embodiments, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width at half maximum (FWHM) of the emission wavelength spectrum of less than or equal to about 45 nm, less than or equal to about 40 nm, or for example, less than or equal to about 30 nm. When the FWHM of the quantum dot is within these ranges, the quantum dot may have improved color purity or improved color reproducibility. In one or more embodiments, because light emitted through the quantum dot is emitted in all directions, the wide viewing angle may be improved.

In one or more embodiments, the quantum dot may be in the form of spherical nanoparticles, pyramidal nanoparticles, multi-arm nanoparticles, or cubic nanoparticles, nanotubes, nanowires, nanofibers, or nanoplate particles.

Because the energy band gap of the quantum dot may be adjusted by controlling the size of the quantum dot, light having one or more suitable wavelength bands may be obtained from a quantum dot emission layer. Accordingly, by utilizing quantum dots of different sizes, a light-emitting device that emits light of one or more suitable wavelengths may be implemented. For example, the size of the quantum dots may be selected to enable the quantum dots to emit red light, green light, and/or blue light. In one or more embodiments, the quantum dots with suitable sizes may be configured to emit white light by combination of light of one or more suitable colors.

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including multiple different materials, or iii) a multilayer structure including multiple layers including multiple different materials.

The electron transport region may include a buffer layer, a hole blocking layer, an electron control layer, an electron transport layer, an electron injection layer, or any combination thereof.

In one or more embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are stacked in the stated order from the emission layer.

In one or embodiments, the electron transport region may include the heterocyclic compound represented by Formula 1. The heterocyclic compound represented by Formula 1 is as described in the present disclosure.

In one or more embodiments, for example, the electron transport region (for example, a buffer layer, a hole blocking layer, an electron control layer, or an electron transport layer in the electron transport region) may include a metal-free compound including at least one π electron-deficient nitrogen-containing C₁-C₆₀ cyclic group.

In one or more embodiments, the electron transport region may include a compound represented by Formula 601.

[Ar₆₀₁]ₓₑ₁₁-[(L₆₀₁)ₓₑ₁-R₆₀₁]ₓₑ₂₁ Formula 601

In Formula 601,
Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ are each the same as described with respect to Q₁,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ cyclic group that is unsubstituted or substituted with at least one R₁₀ₐ.

In one or more embodiments, if (e.g., when) xe11 in Formula 601 is 2 or more, two or more of Ar₆₀₁(s) may be linked together via a single bond.

In one or more embodiments, Ar₆₀₁ in Formula 601 may be an anthracene group that is unsubstituted or substituted with at least one R₁₀ₐ.

In one or more embodiments, the electron transport region may include a compound represented by Formula 601-1:

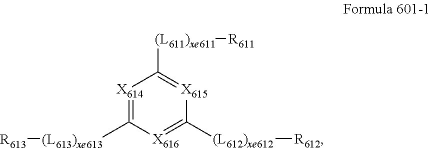

wherein, in Formula 601-1,
X₆₁₄ may be N or C(R₆₁₄), X₆₁₅ may be N or C(R₆₁₅), X₆₁₆ may be N or C(R₆₁₆), and at least one selected from among X₆₁₄ to X₆₁₆ may be N,
L₆₁₁ to L₆₁₃ are each the same as described with respect to L₆₀₁,
xe611 to xe613 are each the same as described with respect to xe1,
R₆₁₁ to R₆₁₃ are each the same as described with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In one or more embodiments, xe1 and xe611 to xe613 in Formulae 601 and 601-1 may each independently be 0, 1, or 2.

In one or more embodiments, the electron transport region may include at least one selected from among Compounds ET1 to ET45, 2,9-dimethyl-4,7-diphenyl-1,10-phenanthroline (BCP), 4,7-diphenyl-1,10-phenanthroline (Bphen), tris(8-hydroxyquinolinato)aluminum (Alq₃), bis(2-methyl-8-quinolinolato-N1,O8)-(1,1′-biphenyl-4-olato)aluminum (BAlq), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), or any combination thereof:

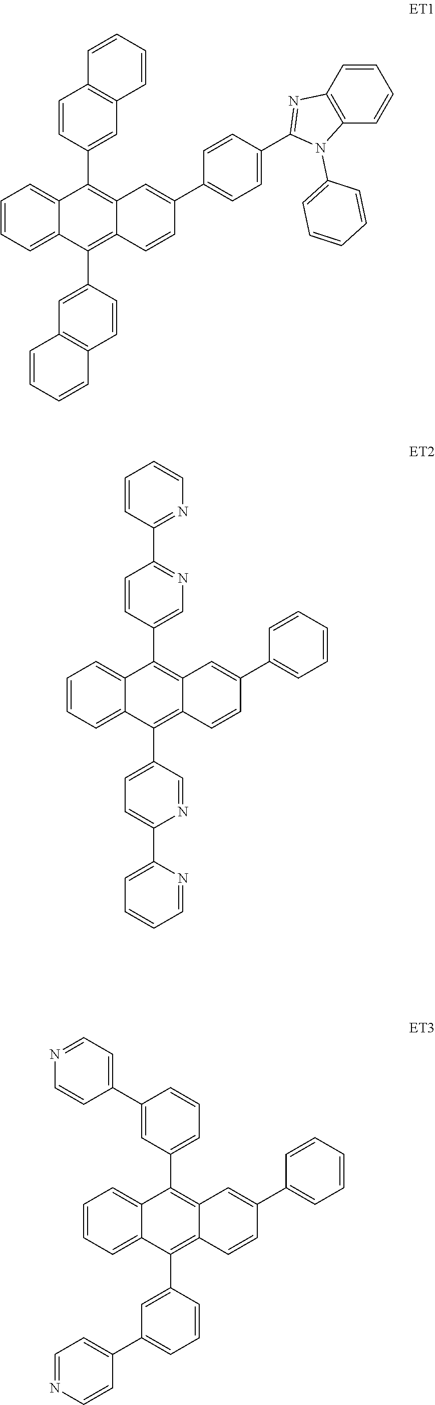 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

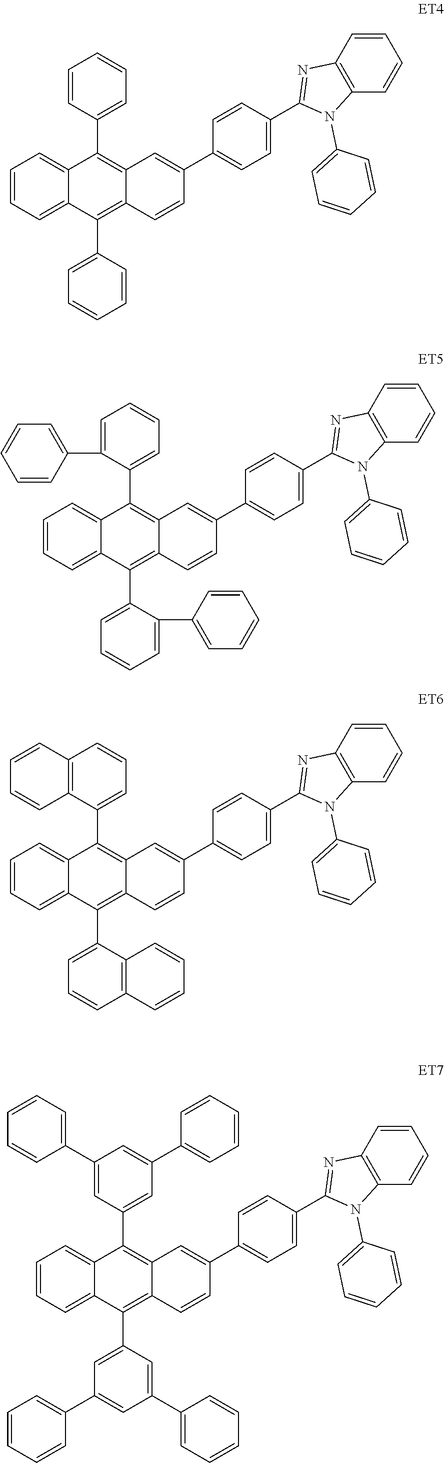 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

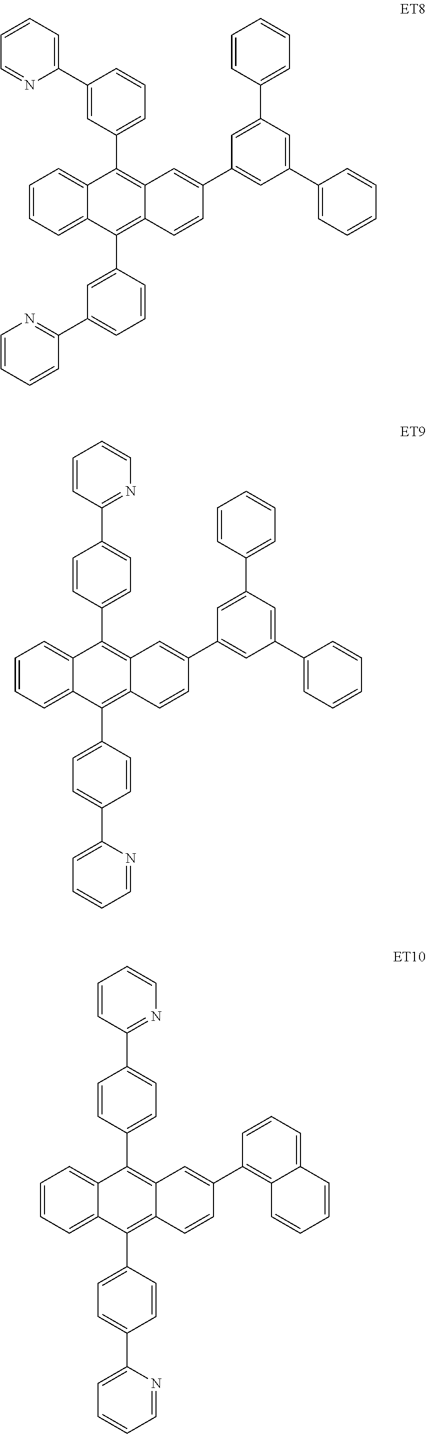 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

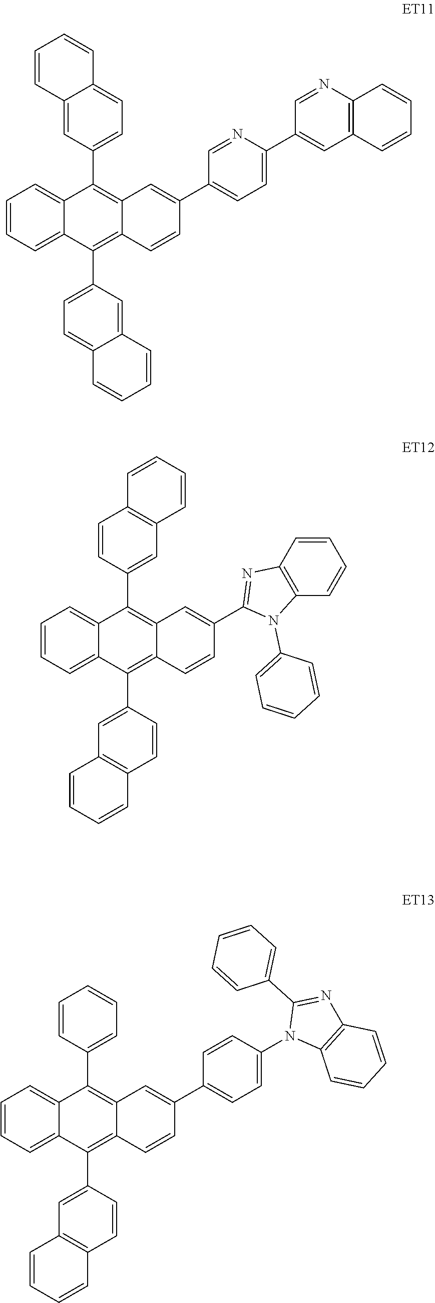 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

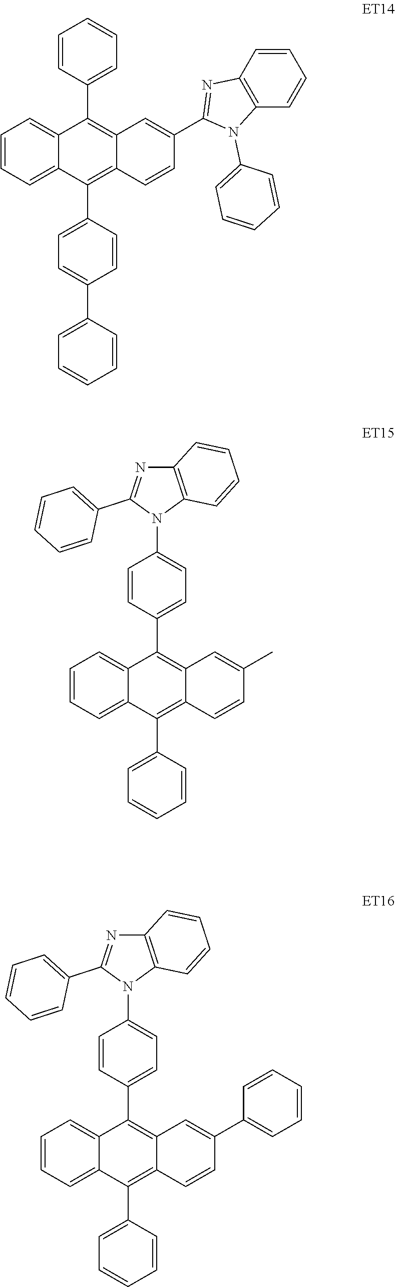 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

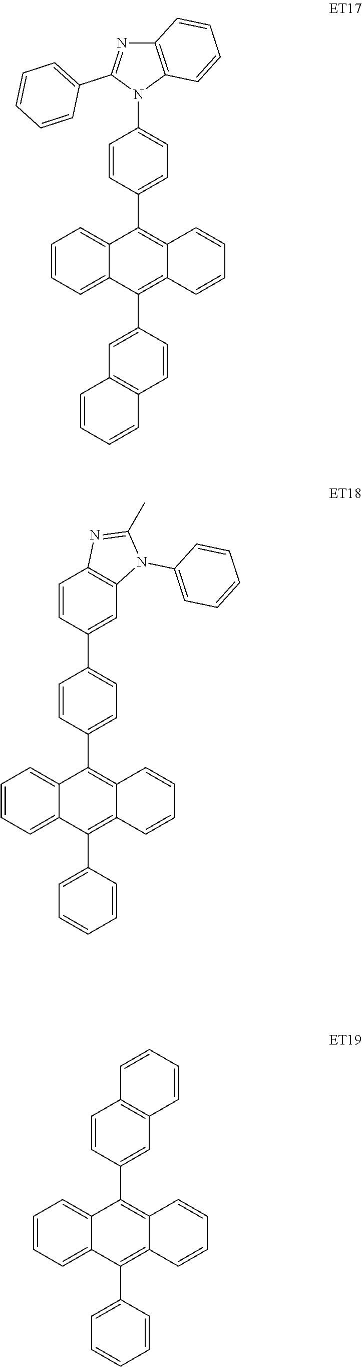

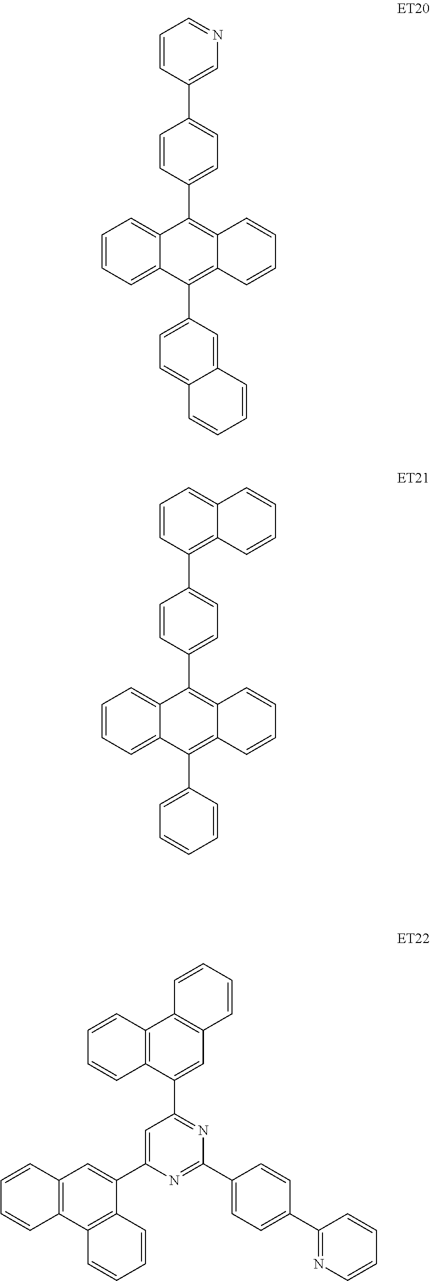

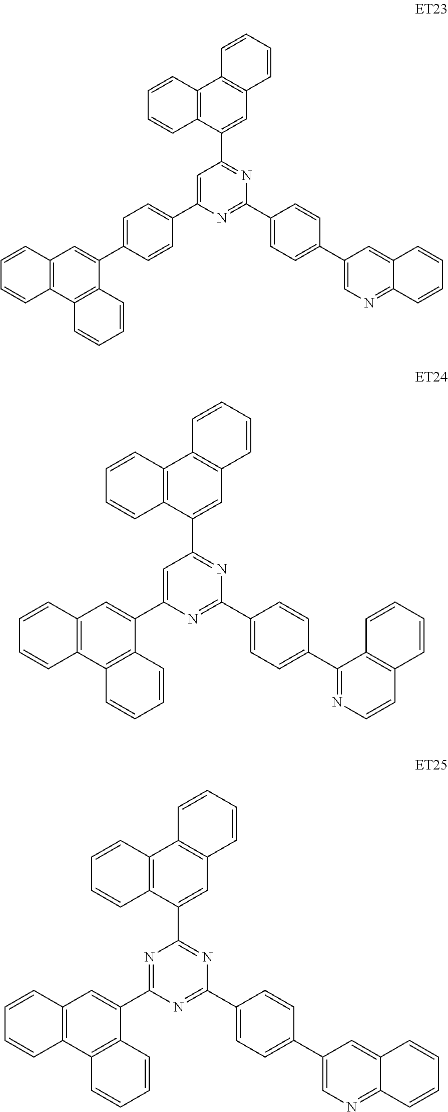 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

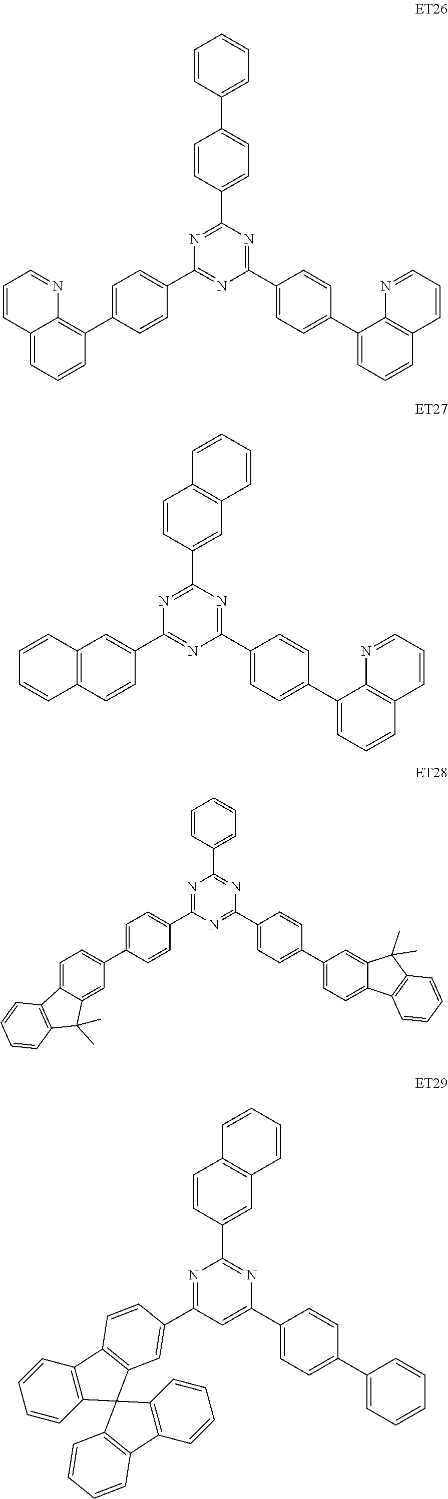 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

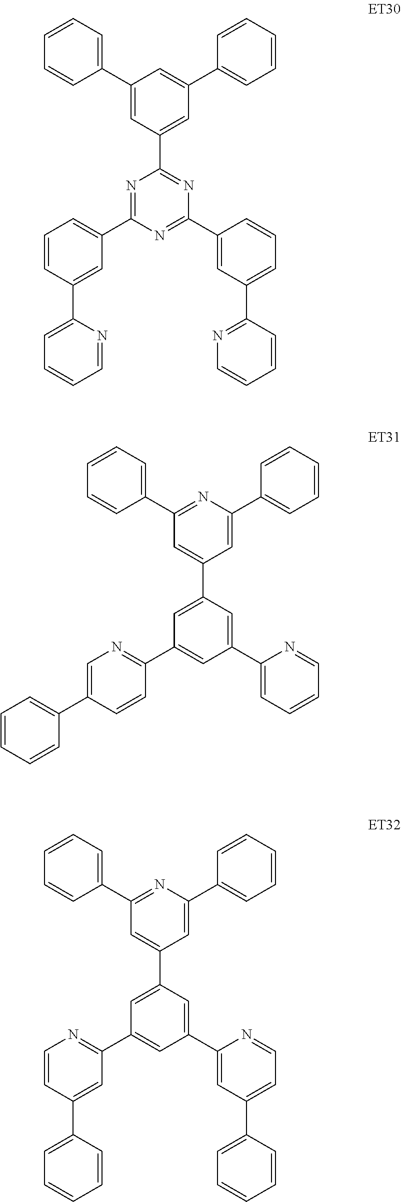 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

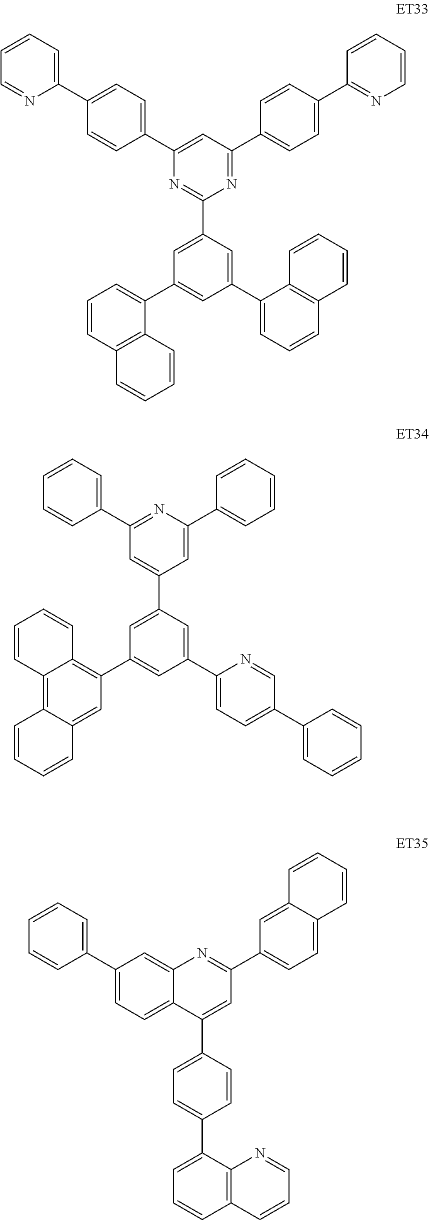 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

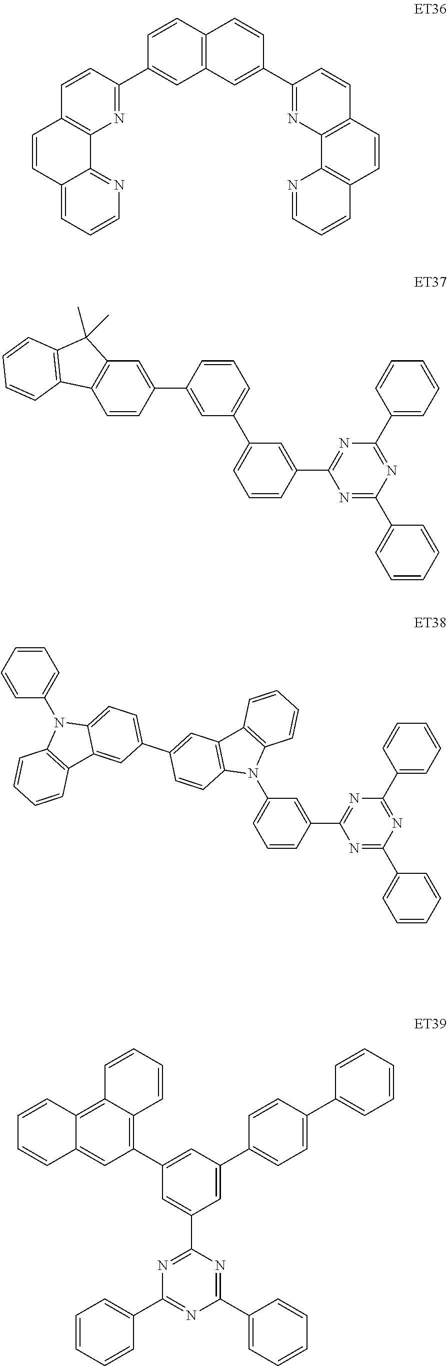 [SMILES: c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

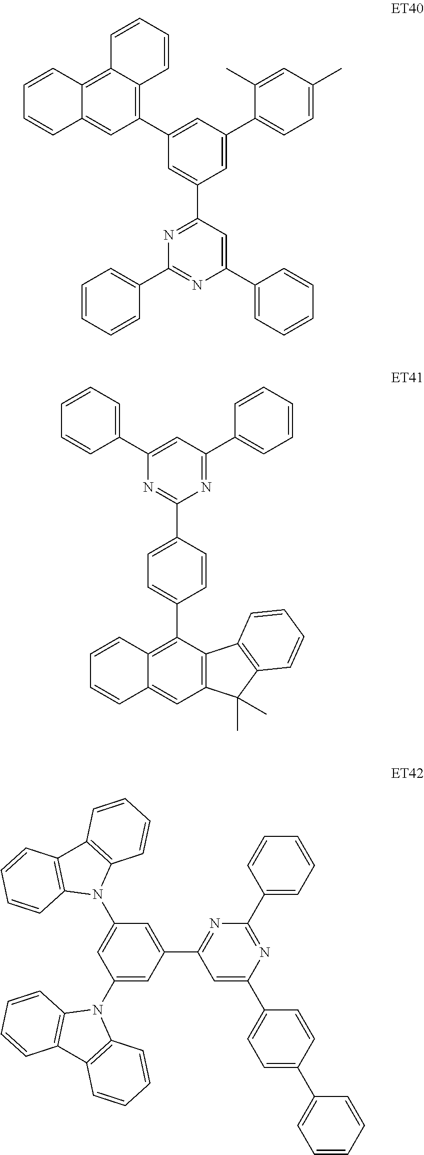 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

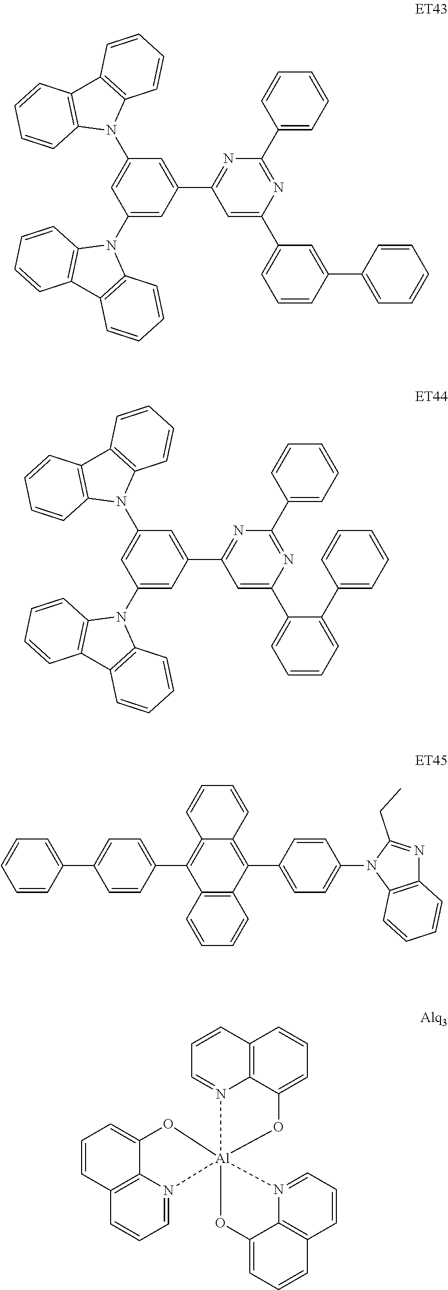

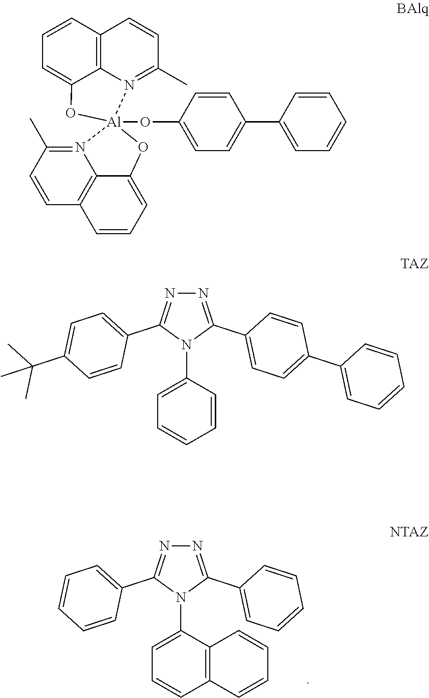

A thickness of the electron transport region may be about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may be about 20 Å to about 1,000 Å, for example, about 30 Å to about 300 Å, and a thickness of the electron transport layer may be about 100 Å to about 1,000 Å, for example, about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

In one or more embodiments, the electron transport region (for example, the electron transport layer in the electron transport region) may further include, in addition to one or more of the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the metal ion of the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In one or more embodiments, the metal-containing material may include a L₁ complex. The Li complex may include, for example, Compound ET-D1 (LiQ) or ET-D2:

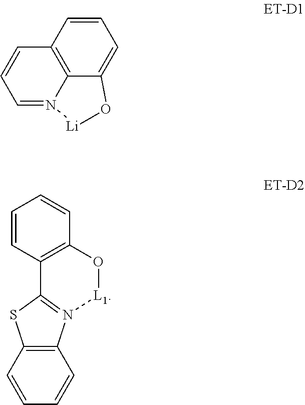

In one or more embodiments, the electron transport region may include an electron injection layer that facilitates the injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including multiple different materials, or iii) a multilayer structure including multiple layers including multiple different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include L₁, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, and/or the like), or tellurides of the alkali metal, the alkaline earth metal, and the rare earth metal, respectively, or any combination thereof.

The alkali metal-containing compound may include: alkali metal oxides, such as Li₂O, Cs₂O, and/or K₂O; alkali metal halides, such as LiF, NaF, CsF, KF, LiI, NaI, CsI, and/or KI; or any combination thereof. The alkaline earth metal-containing compound may include an alkaline earth metal compound, such as BaO, SrO, CaO, BaₓSr₁₋ₓO (x is a real number satisfying 0<x<1), and/or BaₓCa₁₋ₓO (x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rare earth metal-containing compound may include a lanthanide metal telluride. Non-limiting examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of metal ions of the alkali metal, one of metal ions of the alkaline earth metal, and one of metal ions of the rare earth metal, respectively, and ii) a ligand bonded to the respective metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, a compound represented by Formula 601).

In one or more embodiments, the electron injection layer may include (e.g., consist of) i) an alkali metal-containing compound (for example, alkali metal halide), or ii) a) an alkali metal-containing compound (for example, alkali metal halide); and b) an alkali metal, an alkaline earth metal, a rare earth metal, or any combination thereof. In one or more embodiments, the electron injection layer may be a KI:Yb co-deposited layer, an RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly (e.g., substantially uniformly) or non-uniformly dispersed in a matrix including the organic material.

A thickness of the electron injection layer may be about 1 Å to about 100 Å, and, for example, about 3 Å to about 90 Å. When the thickness of the electron injection layer is within the range as described above, satisfactory electron injection characteristics may be obtained without a substantial increase in driving voltage.

### Second Electrode 150

The second electrode 150 may be arranged on the interlayer 130. The second electrode 150 may be a cathode, which is an electron injection electrode, and as a material for forming the second electrode 150, a metal, an alloy, an electrically conductive compound, or any combination thereof, each having a low-work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layer structure or a multilayer structure including a plurality of layers.

### Capping Layer

A first capping layer may be arranged outside (e.g., on) the first electrode 110, and/or a second capping layer may be arranged outside (e.g., on) the second electrode 150. In one or more embodiments, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In one or more embodiments, light generated in the emission layer of the interlayer 130 of the light-emitting device 10 may be extracted toward the outside through the first electrode 110 which is a semi-transmissive electrode or a transmissive electrode, and the first capping layer. In one or more embodiments, light generated in the emission layer of the interlayer 130 of the light-emitting device 10 may be extracted toward the outside through the second electrode 150 which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, such that the luminescence efficiency of the light-emitting device 10 may be increased.

Each of the first capping layer and the second capping layer may include a material having a refractive index of 1.6 or more (e.g., at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may (e.g., the first capping layer and the second capping layer may each independently) include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. In one or more embodiments, at least one of the first capping layer or the second capping layer may (e.g., the first capping layer and the second capping layer may each independently) include an amine group-containing compound.

In one or more embodiments, at least one of the first capping layer or the second capping layer may (e.g., the first capping layer and the second capping layer may each independently) include a compound represented by Formula 201, a compound represented by Formula 202, or any combination thereof.

In one or more embodiments, at least one of the first capping layer or the second capping layer may (e.g., the first capping layer and the second capping layer may each independently) include at least one selected from among Compounds HT28 to HT33, at least one selected from among Compounds CP1 to CP6, β-NPB, or any combination thereof:

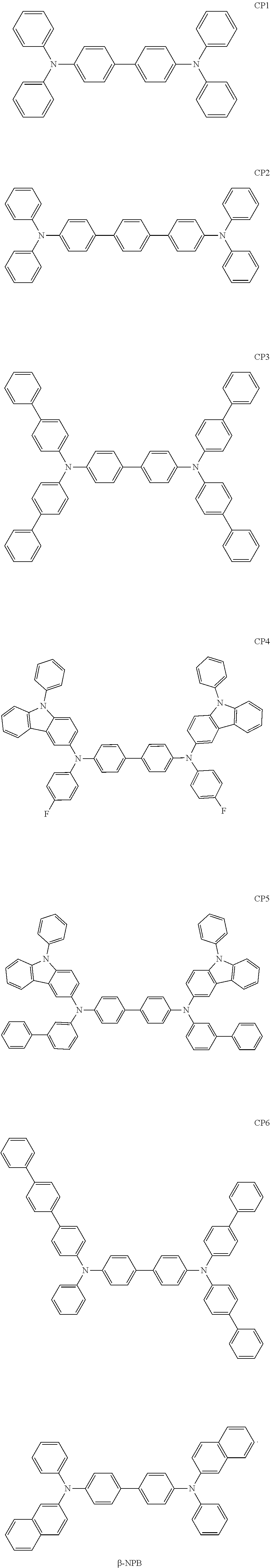

### Film

The heterocyclic compound represented by Formula 1 may be included in one or more suitable films. Accordingly, according to one or more embodiments, there may be provided a film including the heterocyclic compound represented by Formula 1. The film may be, for example, an optical member (or a light control element) (for example, a color filter, a color conversion member, a capping layer, a light extraction efficiency enhancement layer, a selective light absorbing layer, a polarizing layer, a quantum dot-containing layer, or like), a light-blocking member (for example, a light reflective layer, a light absorbing layer, and/or the like), or a protective member (for example, an insulating layer, a dielectric layer, and/or the like).

### Electronic Apparatus

The light-emitting device may be included in one or more suitable electronic apparatuses. For example, the electronic apparatus including the light-emitting device may be a light-emitting apparatus, an authentication apparatus, and/or the like.

In one or more embodiments, the electronic apparatus (for example, a light-emitting apparatus) may further include, in addition to the light-emitting device, i) a color filter, ii) a color conversion layer, or iii) a color filter and a color conversion layer. The color filter and/or the color conversion layer may be arranged in at least one travel direction of light emitted from the light-emitting device. For example, in one or more embodiments, the light emitted from the light-emitting device may be blue light or white light (e.g., combined white light). A detailed description of the light-emitting device is provided above. In one or more embodiments, the color conversion layer may include quantum dots. The quantum dots may be, for example, the quantum dots as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area configured to emit first color light, a second area configured to emit second color light, and/or a third area configured to emit third color light, wherein the first color light, the second color light, and/or the third color light may have different maximum emission wavelengths. In one or more embodiments, the first color light may be red light, the second color light may be green light, and the third color light may be blue light. In one or more embodiments, the plurality of color filter areas (or the plurality of color conversion areas) may include quantum dots. For example, the first area may include red quantum dots to emit red light, the second area may include green quantum dots to emit green light, and the third area may not include (e.g., may exclude) quantum dots. A detailed description of the quantum dots is provided herein. The first area, the second area, and/or the third area may each further include a scatter.

In one or more embodiments, the light-emitting device may be to emit first light, the first area may be to absorb the first light to emit first-first color light, the second area may be to absorb the first light to emit second-first color light, and the third area may be to absorb the first light to emit third-first color light. In this regard, the first-first color light, the second-first color light, and the third-first color light may have different maximum emission wavelengths. For example, in one or more embodiments, the first light may be blue light, the first-first color light may be red light, the second-first color light may be green light, and the third-first color light may be blue light.

In one or more embodiments, the electronic apparatus may further include a thin-film transistor, in addition to the light-emitting device as described above. The thin-film transistor may include a source electrode, a drain electrode, and an activation layer, wherein one selected from the source electrode and the drain electrode may be electrically connected to the first electrode or the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

In one or more embodiments, the electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and concurrently (e.g., simultaneously) prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally arranged on the sealing portion, in addition to the color filter and/or the color conversion layer, according to the utilization of the electronic apparatus. Non-limiting examples of the functional layers may include a touch screen layer and a polarizing layer. The touch screen layer may be a pressure-sensitive touch screen layer, a capacitive touch screen layer, or an infrared touch screen layer.

The authentication apparatus may be, for example, a biometric authentication apparatus that authenticates an individual by utilizing biometric information of a living body (for example, fingertips, pupils, and/or the like). The authentication apparatus may further include, in addition to the light-emitting device as described above, a biometric information collector.

The electronic apparatus may be applied to one or more of displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

### Electronic Equipment

The light-emitting device may be included in one or more suitable electronic equipment.

For example, electronic equipment including the light-emitting device may be at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.

Because the light-emitting device has excellent or suitable effects in terms of luminescence efficiency long lifespan, the electronic equipment including the light-emitting device may have characteristics with relatively high luminance, relatively high resolution, and relatively low power consumption.

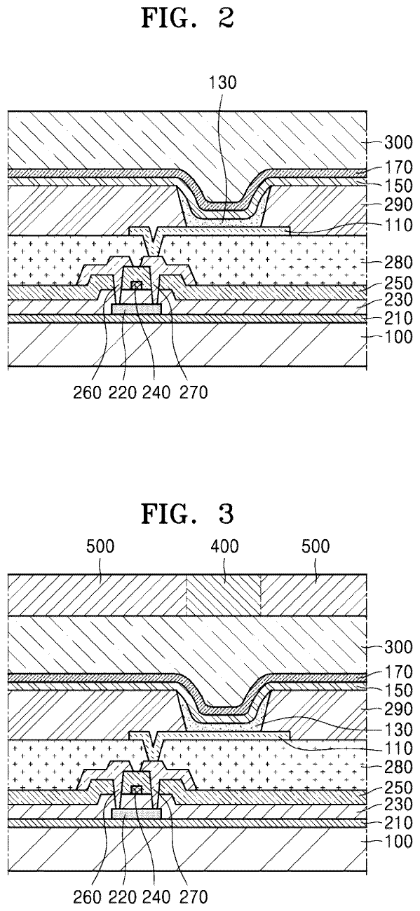

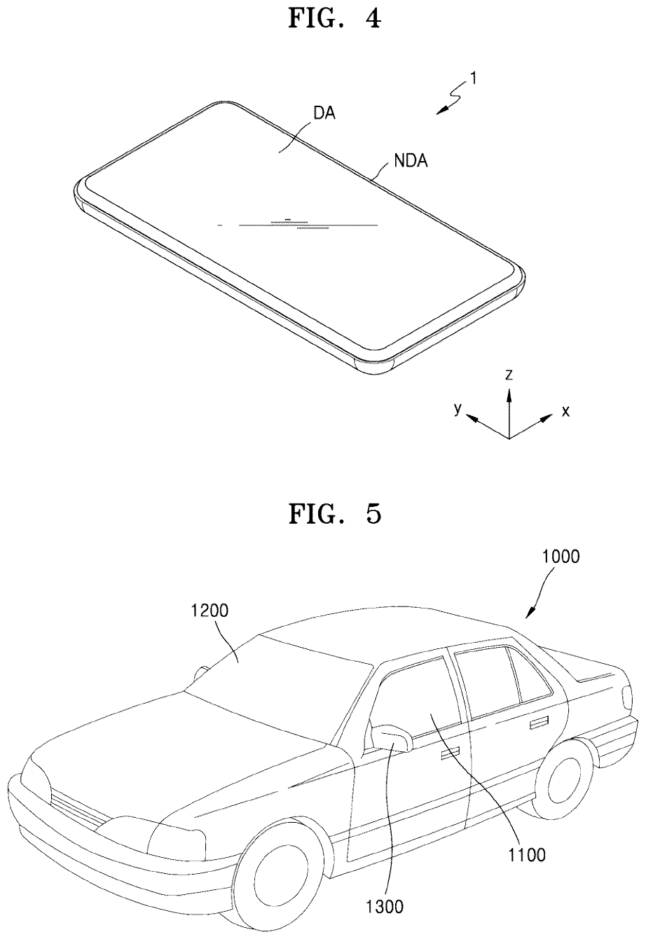

### Descriptions of FIG. 2 and FIG. 3

FIG. 2 is a cross-sectional view of a light-emitting apparatus according to one or more embodiments.

The light-emitting apparatus of FIG. 2 may include a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be on the substrate 100. The buffer layer 210 may prevent or reduce penetration of impurities through the substrate 100 and may provide a flat surface on the substrate 100.

The TFT may be on the buffer layer 210. The TFT may include an activation layer 220, a gate electrode 240, a source electrode 260, and a drain electrode 270.

The activation layer 220 may include an inorganic semiconductor, such as silicon or polysilicon, an organic semiconductor, or an oxide semiconductor, and may include a source region, a drain region, and a channel region.

A gate insulating film 230 for insulating the activation layer 220 from the gate electrode 240 may be on the activation layer 220, and the gate electrode 240 may be on the gate insulating film 230.

An interlayer insulating film 250 may be on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220, respectively.

The TFT may be electrically connected to a light-emitting device to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device may include a first electrode 110, an interlayer 130, and a second electrode 150.

The first electrode 110 may be on the passivation layer 280. The passivation layer 280 may be arranged to expose a portion of the drain electrode 270, not fully covering the drain electrode 270, and the first electrode 110 may be arranged to be connected to the exposed portion of the drain electrode 270.

A pixel-defining film 290 including an insulating material may be on the first electrode 110. The pixel-defining film 290 may expose a certain region of the first electrode 110, and the interlayer 130 may be formed in the exposed region of the first electrode 110. The pixel-defining film 290 may be a polyimide-based organic film or a polyacrylic organic film. In one or more embodiments, at least some layers of the interlayer 130 may extend beyond the upper portion of the pixel-defining film 290 to be arranged in the form of a common layer.

The second electrode 150 may be on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be arranged on the light-emitting device to protect the light-emitting device from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or any combination thereof; and/or a (e.g., any suitable) combination of the inorganic film and the organic film.

FIG. 3 is a cross-sectional view of a light-emitting apparatus according to one or more embodiments of the present disclosure.

The light-emitting apparatus of FIG. 3 is substantially the same as the light-emitting apparatus of FIG. 2, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

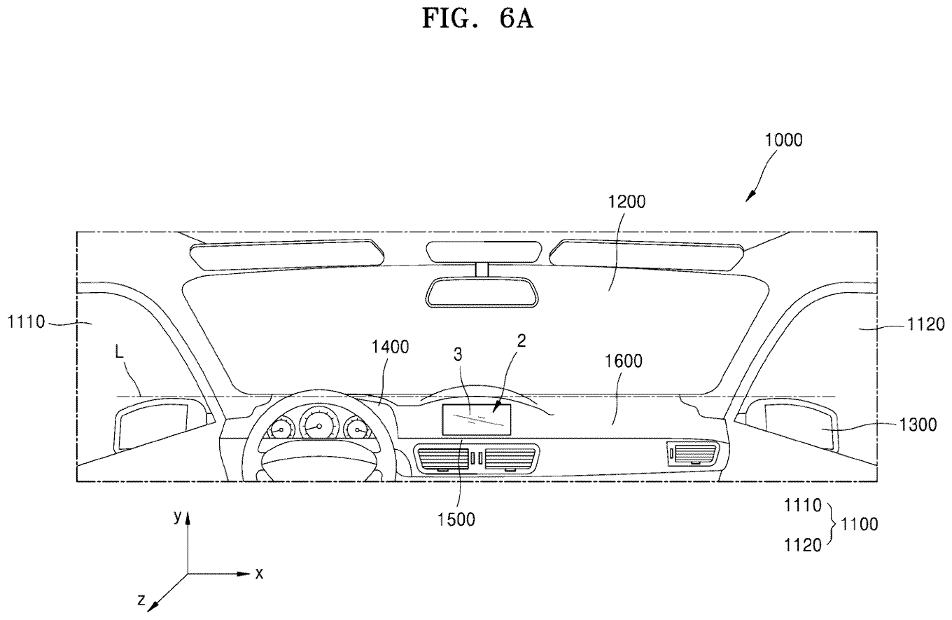

### Description of FIG. 4

FIG. 4 is a schematic perspective view of electronic equipment 1 including a light-emitting device according to one or more embodiments. The electronic equipment 1 may be, as an apparatus that displays a moving image or a still image, a portable electronic device, such as a mobile phone, a smartphone, a tablet personal computer (PC), a mobile communication terminal, an electronic notebook, an electronic book, a portable multimedia player (PMP), a navigation, or a ultra-mobile PC (UMPC), as well as one or more suitable products, such as a television, a laptop, a monitor, a billboard, or an Internet of things (IoT). The electronic equipment 1 may be such a product above or a part thereof. In one or more embodiments, the electronic equipment 1 may be a wearable device, such as a smart watch, a watch phone, a glasses-type or kind display, or a head mounted display (HMD), or a part of the wearable device. However, embodiments of the present disclosure are not limited thereto. In one or more embodiments, the electronic equipment 1 may be a dashboard of a vehicle, a center information display (CID) arranged on a center fascia or dashboard of a vehicle, a room mirror display instead of a side-view mirror of a vehicle, an entertainment for the back seat of a vehicle, or a display arranged on the back of a front seat of a vehicle, a head up display (HUD) installed on the front of a vehicle or projected on a front window glass, or a computer generated hologram augmented reality head up display (CGH AR HUD). FIG. 4 illustrates an embodiment in which the electronic equipment 1 is a smartphone for convenience of explanation.

The electronic equipment 1 may include a display area DA and a non-display area NDA outside the display area DA. A display apparatus of the electronic equipment 1 may implement an image through an array of a plurality of pixels that are two-dimensionally arranged in the display area DA.

The non-display area NDA is an area that does not display an image, and may entirely be around (e.g., surround) the display area DA. On the non-display area NDA, a driver for providing electrical signals or power to display devices arranged on the display area DA may be arranged. On the non-display area NDA, a pad, which is an area to which an electronic element or a printed circuit board, may be electrically connected may be arranged.

In the electronic equipment 1, a length in an x-axis direction and a length (e.g., a width) in a y-axis direction may be different from each other. In one or more embodiments, as shown in FIG. 4, the length in the x-axis direction may be less than the length (e.g., the width) in the y-axis direction. In one or more embodiments, the length in the x-axis direction may be substantially the same as the length (e.g., the width) in the y-axis direction. In one or more embodiments, the length in the x-axis direction may be greater than the length (e.g., the width) in the y-axis direction.

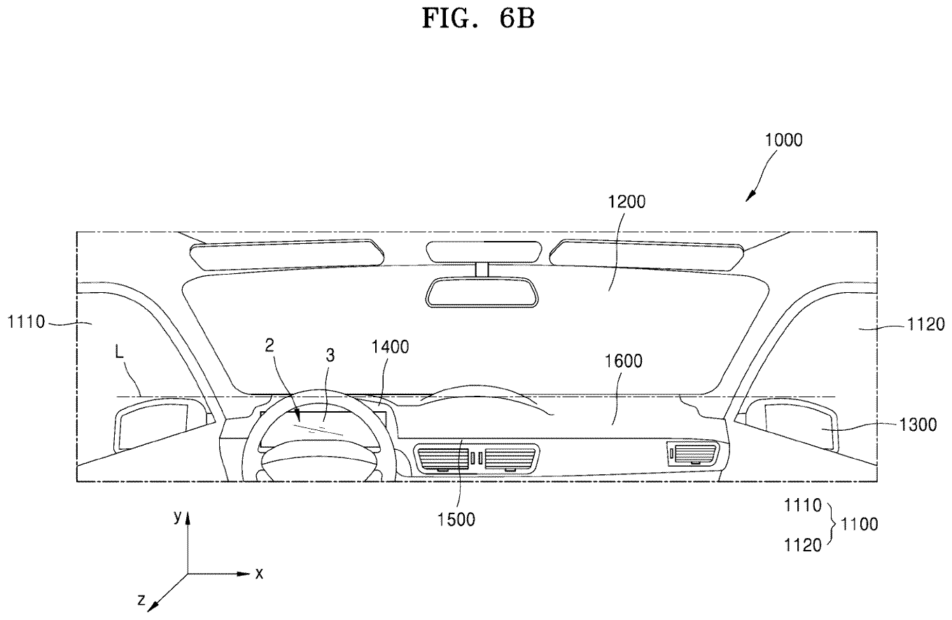

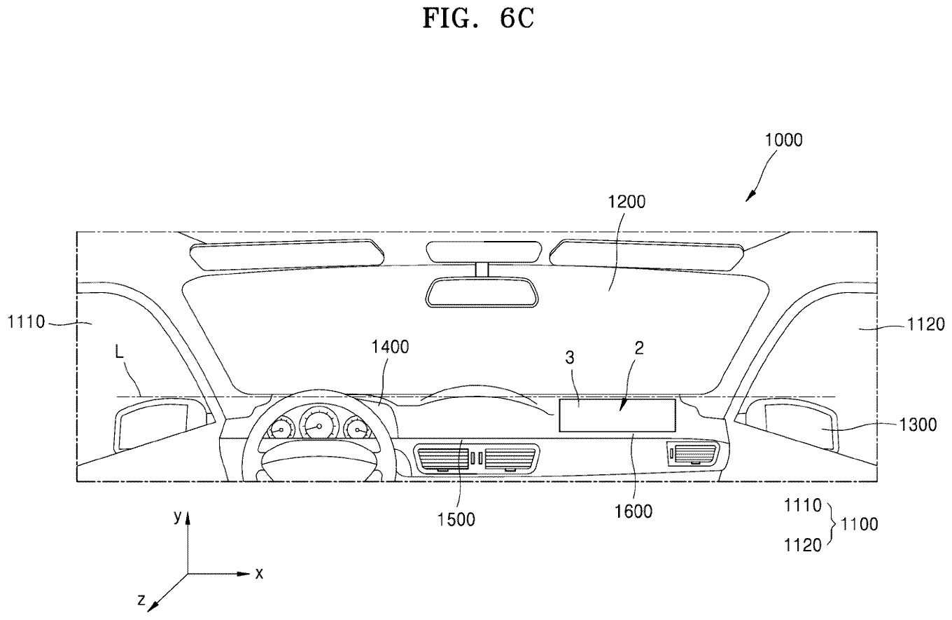

### Descriptions of FIGS. 5 and 6A to 6C

FIG. 5 is a schematic view of an exterior of a vehicle 1000 as electronic equipment including a light-emitting device, according to one or more embodiments. FIGS. 6A to 6C are each a schematic view of an interior of the vehicle 1000 according to one or more embodiments.

Referring to FIGS. 5, 6A, 6B, and 6C, the vehicle 1000 may refer to one or more suitable apparatuses for moving an object to be transported, such as a human, an object, or an animal, from a departure point to a destination point. The vehicle 1000 may include a vehicle traveling on a road or a track, a vessel moving over the sea or a river, an airplane flying in the sky utilizing the action of air, and/or the like.

In one or more embodiments, the vehicle 1000 may travel on a road or a track. The vehicle 1000 may move in a certain direction according to rotation of at least one wheel thereof. In one or more embodiments, the vehicle 1000 may include a three-wheeled or four-wheeled vehicle, a construction machine, a two-wheeled vehicle, a prime mover device, a bicycle, or a train running on a track.

The vehicle 1000 may include a vehicle body having an interior and an exterior, and a chassis in which mechanical apparatuses necessary for driving are installed as other parts except for the vehicle body. The exterior of the vehicle body may include a front panel, a bonnet, a roof panel, a rear panel, a trunk, a pillar provided at a boundary between doors, and/or the like. The chassis of the vehicle 1000 may include a power generating device, a power transmitting device, a driving device, a steering device, a braking device, a suspension device, a transmission device, a fuel device, front and rear wheels, left and right wheels, and/or the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In one or more embodiments, the side window glass 1100 may be installed on a door of the vehicle 1000. A plurality of side window glasses 1100 may be provided and may face each other. In one or more embodiments, the side window glass 1100 may include a first side window glass 1110 and a second side window glass 1120. In one or more embodiments, the first side window glass 1110 may be arranged adjacent to the cluster 1400. The second side window glass 1120 may be arranged adjacent to the passenger seat dashboard 1600.

In one or more embodiments, the side window glasses 1100 may be spaced and/or apart (e.g., spaced apart or separated) from each other in an x direction or a −x direction (the direction opposite the x-direction). In one or more embodiments, the first side window glass 1110 and the second side window glass 1120 may be spaced and/or apart (e.g., spaced apart or separated) from each other in the x direction or the −x direction. For example, an imaginary straight line L connecting the side window glasses 1100 may extend in the x direction or the −x direction. In one or more embodiments, an imaginary straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior of the vehicle body. In one or more embodiments, a plurality of side-view mirrors 1300 may be provided. Any one of the plurality of side-view mirrors 1300 may be arranged outside the first side window glass 1110. The other one of the plurality of side-view mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning light, a seat belt warning light, an odometer, a tachograph, an automatic shift selector indicator, a door open warning light, an engine oil warning light, and/or a low fuel warning light.

The center fascia 1500 may include a control panel on which a plurality of buttons for adjusting an audio device, an air conditioning device, and a heater of a seat are arranged. The center fascia 1500 may be arranged on one side of the cluster 1400.

The passenger seat dashboard 1600 may be spaced and/or apart (e.g., spaced apart or separated) from the cluster 1400 with the center fascia 1500 arranged therebetween. In one or more embodiments, the cluster 1400 may be arranged to correspond to a driver seat, and the passenger seat dashboard 1600 may be arranged to correspond to a passenger seat. In one or more embodiments, the cluster 1400 may be adjacent to the first side window glass 1110, and the passenger seat dashboard 1600 may be adjacent to the second side window glass 1120.

In one or more embodiments, the display apparatus 2 may include a display panel 3, and the display panel 3 may display an image. The display apparatus 2 may be arranged inside the vehicle 1000. In one or more embodiments, the display apparatus 2 may be arranged between the side window glasses 1100 facing each other. The display apparatus 2 may be arranged on at least one of the cluster 1400, the center fascia 1500, or the passenger seat dashboard 1600.

The display apparatus 2 may include an organic light-emitting display, an inorganic electroluminescent display, a quantum dot display, and/or the like. Hereinafter, as the display apparatus 2 according to one or more embodiments, an organic light-emitting display apparatus including the light-emitting device will be described as an example, but one or more suitable types (kinds) of display apparatuses as described above may be utilized in embodiments.

Referring to FIG. 6A, in one or more embodiments, the display apparatus 2 may be arranged on the center fascia 1500. In one or more embodiments, the display apparatus 2 may display navigation information. In one or more embodiments, the display apparatus 2 may display audio, video, or information regarding vehicle settings.

Referring to FIG. 6B, in one or more embodiments, the display apparatus 2 may be arranged on the cluster 1400. In these embodiments, the cluster 1400 may display driving information and/or the like through the display apparatus 2. For example, the cluster 1400 may be implemented digitally. The digital cluster 1400 may display vehicle information and driving information as images. In one or more embodiments, a needle and a gauge of a tachometer and one or more suitable warning light icons may be displayed by a digital signal.

Referring to FIG. 6C, in one or more embodiments, the display apparatus 2 may be arranged on the passenger seat dashboard 1600. The display apparatus 2 may be embedded in the passenger seat dashboard 1600 or arranged on the passenger seat dashboard 1600. In one or more embodiments, the display apparatus 2 arranged on the passenger seat dashboard 1600 may display an image related to information displayed on the cluster 1400 and/or information displayed on the center fascia 1500. In one or more embodiments, the display apparatus 2 arranged on the passenger seat dashboard 1600 may display information different from information displayed on the cluster 1400 and/or information displayed on the center fascia 1500.

### Manufacturing Method

The layers constituting the hole transport region, the emission layer, and the layers constituting the electron transport region may be formed in a certain region by utilizing one or more suitable methods such as vacuum deposition, spin coating, casting, Langmuir-Blodgett (LB) deposition, ink-jet printing, laser-printing, laser-induced thermal imaging, and/or the like.

When the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definition of Terms

The term “C₃-C₆₀ carbocyclic group” as utilized herein refers to a cyclic group including (e.g., consisting of) carbon only as a ring-forming atom and having three to sixty carbon atoms, and the term “C₁-C₆₀ heterocyclic group” as utilized herein refers to a cyclic group that has one to sixty carbon atoms and further includes, in addition to the carbon atoms, a heteroatom as a ring-forming atom. The C₃-C₆₀ carbocyclic group and the C₁-C₆₀ heterocyclic group may each be a monocyclic group including (e.g., consisting of) one (e.g., exactly one) ring or a polycyclic group in which two or more rings are condensed with each other. In one or more embodiments, the number of ring-forming atoms of the C₁-C₆₀ heterocyclic group may be 3 to 61.

The “cyclic group” as utilized herein may include both (e.g., simultaneously) the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π electron-deficient nitrogen-containing C₁-C₆₀ cyclic group” as utilized herein refers to a heterocyclic group that has one to sixty carbon atoms and includes *—N═*′ as a ring-forming moiety.

In one or more embodiments, the C₃-C₆₀ carbocyclic group may be i) Group T1 or ii) a condensed cyclic group in which two or more of Group T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) Group T2, ii) a condensed cyclic group in which two or more of Group T2 are condensed with each other, or iii) a condensed cyclic group in which at least one Group T2 and at least one Group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) Group T1, ii) a condensed cyclic group in which two or more of Group T1 are condensed with each other, iii) Group T3, iv) a condensed cyclic group in which two or more of Group T3 are condensed with each other, or v) a condensed cyclic group in which at least one Group T3 and at least one Group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),
the π electron-deficient nitrogen-containing C₁-C₆₀ cyclic group may be i) Group T4, ii) a condensed cyclic group in which two or more of Group T4 are condensed with each other, iii) a condensed cyclic group in which at least one Group T4 and at least one Group T1 are condensed with each other, iv) a condensed cyclic group in which at least one Group T4 and at least one Group T3 are condensed with each other, or v) a condensed cyclic group in which at least one Group T4, at least one Group T1, and at least one Group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
Group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
Group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
Group T3 may be a furan group, a thiophene group, a 1H-pyrrole group, a silole group, or a borole group, and
Group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group,” “the C₃-C₆₀ carbocyclic group,” “the C₁-C₆₀ heterocyclic group,” “the π electron-rich C₃-C₆₀ cyclic group,” or “the π electron-deficient nitrogen-containing C₁-C₆₀ cyclic group,” as used herein, refer to a monovalent or polyvalent group (for example, a divalent group, a trivalent group, a tetravalent group, or the like) that is condensed with (e.g., combined together with) a cyclic group according to the structure of a formula for which the corresponding term is utilized. In one or more embodiments, the “benzene group” may be a benzo group, a phenyl group, a phenylene group, and/or the like, which may be easily understood by those of ordinary skill in the art according to the structure of a formula including the “benzene group.”

Depending on context, in the present disclosure, a divalent group may refer or be a polyvalent group (e.g., trivalent, tetravalent, etc., and not just divalent) per, e.g., the structure of a formula in connection with which of the terms are utilized.

In one or more embodiments, non-limiting examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and non-limiting examples of the divalent C₃-C₆₀ carbocyclic group and the divalent C₁-C₆₀ heterocyclic group may include a C₃-C₁ cycloalkylene group, a C₁-C₁₀ heterocycloalkylene group, a C₃-C₁ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as utilized herein refers to a linear or branched aliphatic hydrocarbon monovalent group that has one to sixty carbon atoms, and non-limiting examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having substantially the same structure as the C₁-C₆₀ alkyl group.

The term “C₂-C₆₀ alkenyl group” as utilized herein refers to a monovalent hydrocarbon group having at least one carbon-carbon double bond in the middle or at the terminus of a C₂-C₆₀ alkyl group, and non-limiting examples thereof include an ethenyl group, a propenyl group, and a butenyl group. The term “C₂-C₆₀ alkenylene group” as utilized herein refers to a divalent group having substantially the same structure as the C₂-C₆₀ alkenyl group.

The term “C₂-C₆₀ alkynyl group” as utilized herein refers to a monovalent hydrocarbon group having at least one carbon-carbon triple bond in the middle or at the terminus of a C₂-C₆₀ alkyl group, and non-limiting examples thereof include an ethynyl group and a propynyl group. The term “C₂-C₆₀ alkynylene group” as utilized herein refers to a divalent group having substantially the same structure as the C₂-C₆₀ alkynyl group.

The term “C₁-C₆₀ alkoxy group” as utilized herein refers to a monovalent group represented by —OA₁₀₁ (wherein A₁₀₁ is a C₁-C₆₀ alkyl group), and non-limiting examples thereof include a methoxy group, an ethoxy group, and an isopropyloxy group.

The term “C₃-C₁₀ cycloalkyl group” as utilized herein refers to a monovalent saturated hydrocarbon cyclic group having three to ten carbon atoms, and non-limiting examples thereof include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as utilized herein refers to a divalent group having substantially the same structure as the C₃-C₁₀ cycloalkyl group.

The term “C₁-C₁₀ heterocycloalkyl group” as utilized herein refers to a monovalent cyclic group that has one to ten carbon atoms and further includes, in addition to the carbon atoms, at least one heteroatom as a ring-forming atom, and non-limiting examples thereof include a 1,2,3,4-oxatriazolidinyl group, a tetrahydrofuranyl group, and a tetrahydrothiophenyl group. The term “C₁-C₁₀ heterocycloalkylene group” as utilized herein refers to a divalent group having substantially the same structure as the C₁-C₁₀ heterocycloalkyl group.

The term “C₃-C₁₀ cycloalkenyl group” as utilized herein refers to a monovalent cyclic group that has three to ten carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as utilized herein refers to a divalent group having substantially the same structure as the C₃-C₁₀ cycloalkenyl group.

The term “C₁-C₁₀ heterocycloalkenyl group” as utilized herein refers to a monovalent cyclic group that has one to ten carbon atoms, further includes, in addition to the carbon atoms, at least one heteroatom as a ring-forming atom, and has at least one double bond in the ring thereof. Non-limiting examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as utilized herein refers to a divalent group having substantially the same structure as the C₁-C₁₀ heterocycloalkenyl group.

The term “C₆-C₆₀ aryl group” as utilized herein refers to a monovalent group having a carbocyclic aromatic system of six to sixty carbon atoms, and the term “C₆-C₆₀ arylene group” as utilized herein refers to a divalent group having a carbocyclic aromatic system of six to sixty carbon atoms. Non-limiting examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the two or more rings may be condensed with each other.

The term “C₁-C₆₀ heteroaryl group” as utilized herein refers to a monovalent group having a heterocyclic aromatic system that has one to sixty carbon atoms and further includes, in addition to the carbon atoms, at least one heteroatom as a ring-forming atom. The term “C₁-C₆₀ heteroarylene group” as utilized herein refers to a divalent group having a heterocyclic aromatic system that has one to sixty carbon atoms and further includes, in addition to the carbon atoms, at least one heteroatom as a ring-forming atom. non-limiting examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as utilized herein refers to a monovalent group having two or more rings condensed with each other, only carbon atoms (for example, eight to sixty carbon atoms) as ring-forming atoms, and no aromaticity in its molecular structure when considered as a whole. Non-limiting examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as utilized herein refers to a divalent group having substantially the same structure as the monovalent non-aromatic condensed polycyclic group.

The term “monovalent non-aromatic condensed heteropolycyclic group” as utilized herein refers to a monovalent group that has two or more rings condensed with each other, further includes, in addition to carbon atoms (for example, one to sixty carbon atoms), at least one heteroatom as a ring-forming atom, and has no aromaticity in its molecular structure when considered as a whole. Non-limiting examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as utilized herein refers to a divalent group having substantially the same structure as the monovalent non-aromatic condensed heteropolycyclic group.

The term “C₆-C₆₀ aryloxy group” as utilized herein refers to —OA₁₀₂ (wherein A₁₀₂ is a C₆-C₆₀ aryl group), and the term “C₆-C₆₀ arylthio group” as utilized herein refers to —SA₁₀₃ (wherein A₁₀₃ is a C₆-C₆₀ aryl group).

The term “C₇-C₆₀ arylalkyl group” as utilized herein refers to -A₁₀₄A₁₀₅ (wherein A₁₀₄ is a C₁-C₅₄ alkylene group, and A₁₀₅ is a C₆-C₅₉ aryl group), and the term “C₂-C₆₀ heteroarylalkyl group” as utilized herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as utilized herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ as utilized herein may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as utilized herein refers to any atom other than a carbon atom and a hydrogen atom. Non-limiting examples of the heteroatom include 0, S, N, P, Si, B, Ge, Se, or any combination thereof.

The term “transition metal” as utilized herein includes hafnium (Hf), tantalum (Ta), tungsten (W), rhenium (Re), osmium (Os), iridium (Ir), platinum (Pt), and gold (Au).

The term “Ph” as utilized herein refers to a phenyl group, the term “Me” as utilized herein refers to a methyl group, the term “Et” as utilized herein refers to an ethyl group, the term “tert-Bu” or “Bu^{t}” as utilized herein refers to a tert-butyl group, and the term “OMe” as utilized herein refers to a methoxy group.

The term “biphenyl group” as utilized herein refers to “a phenyl group that is substituted with a phenyl group.” For example, the “biphenyl group” may be a substituted phenyl group having a C₆-C₆₀ aryl group as a substituent.

The term “terphenyl group” as utilized herein refers to “a phenyl group substituted with a biphenyl group.” The “terphenyl group” is a substituted phenyl group having, as a substituent, a C₆-C₆₀ aryl group substituted with a C₆-C₆₀ aryl group.

* and *′ as utilized herein, unless defined otherwise, each refer to a binding site to a neighboring atom in a corresponding formula or moiety.

Herein, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

Hereinafter, compounds according to one or more embodiments and light-emitting devices according to one or more embodiments will be described in more detail with reference to the following Synthesis Examples and Examples. The wording “B was utilized instead of A” utilized in describing Synthesis Examples refers to that an substantially identical molar equivalent of B was utilized in place of A.

### EXAMPLES

### Synthesis Example 1: Synthesis of Compound 1

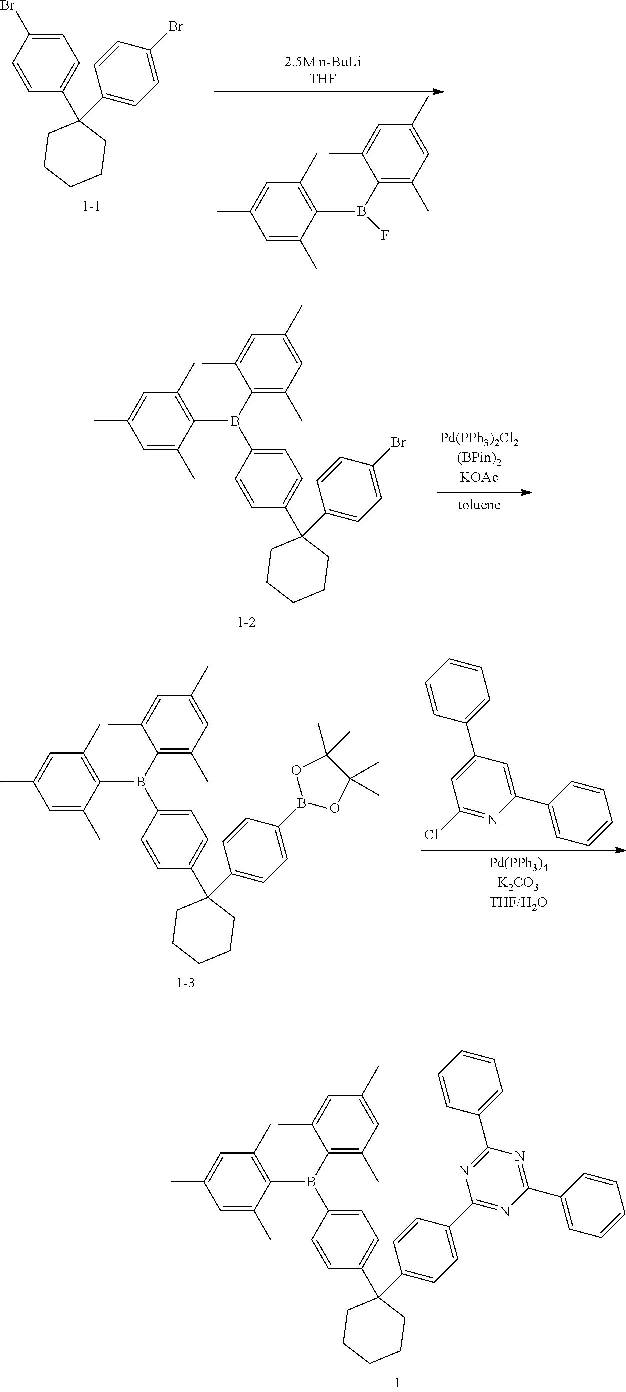

### Synthesis of Intermediate 1-2

A solution, in which Intermediate 1-1 (3.94 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodimesitylborane (2.68 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 1-2 (3.04 g, yield: 54%).

### Synthesis of Intermediate 1-3

Intermediate 1-2 (5.63 g), Pd(PPh₃)₂Cl₂ (0.35 g), bis(pinacolato)diboron ((BPin)₂, 2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 1-3 (3.90 g, yield: 64%).

### Synthesis of Compound 1

Intermediate 1-3 (6.10 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 1 (5.00 g, yield: 70%).

### Synthesis Example 2: Synthesis of Compound 26

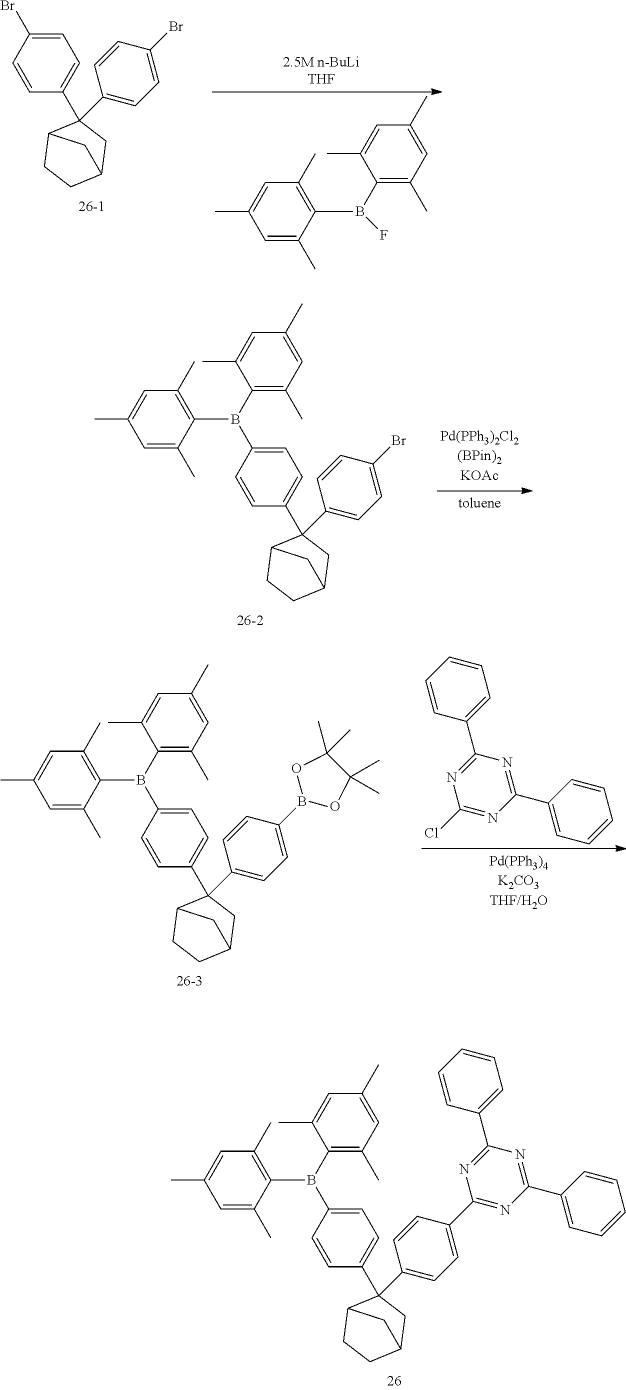

### Synthesis of Intermediate 26-2

A solution, in which Intermediate 26-1 (4.06 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodimesitylborane (2.68 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 26-2 (3.22 g, yield: 56%).

### Synthesis of Intermediate 26-3

Intermediate 26-2 (5.74 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 26-3 (3.73 g, yield: 60%).

### Synthesis of Compound 26

Intermediate 26-3 (6.10 g), Pd(PPh₃)₄ (0.56 g), K₂CO₃ (3.45 g), and 2-chloro-4,6-diphenyl-1,3,5-triazine (2.67 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 26 (5.08 g, yield: 70%).

### Synthesis Example 3: Synthesis of Compound 64

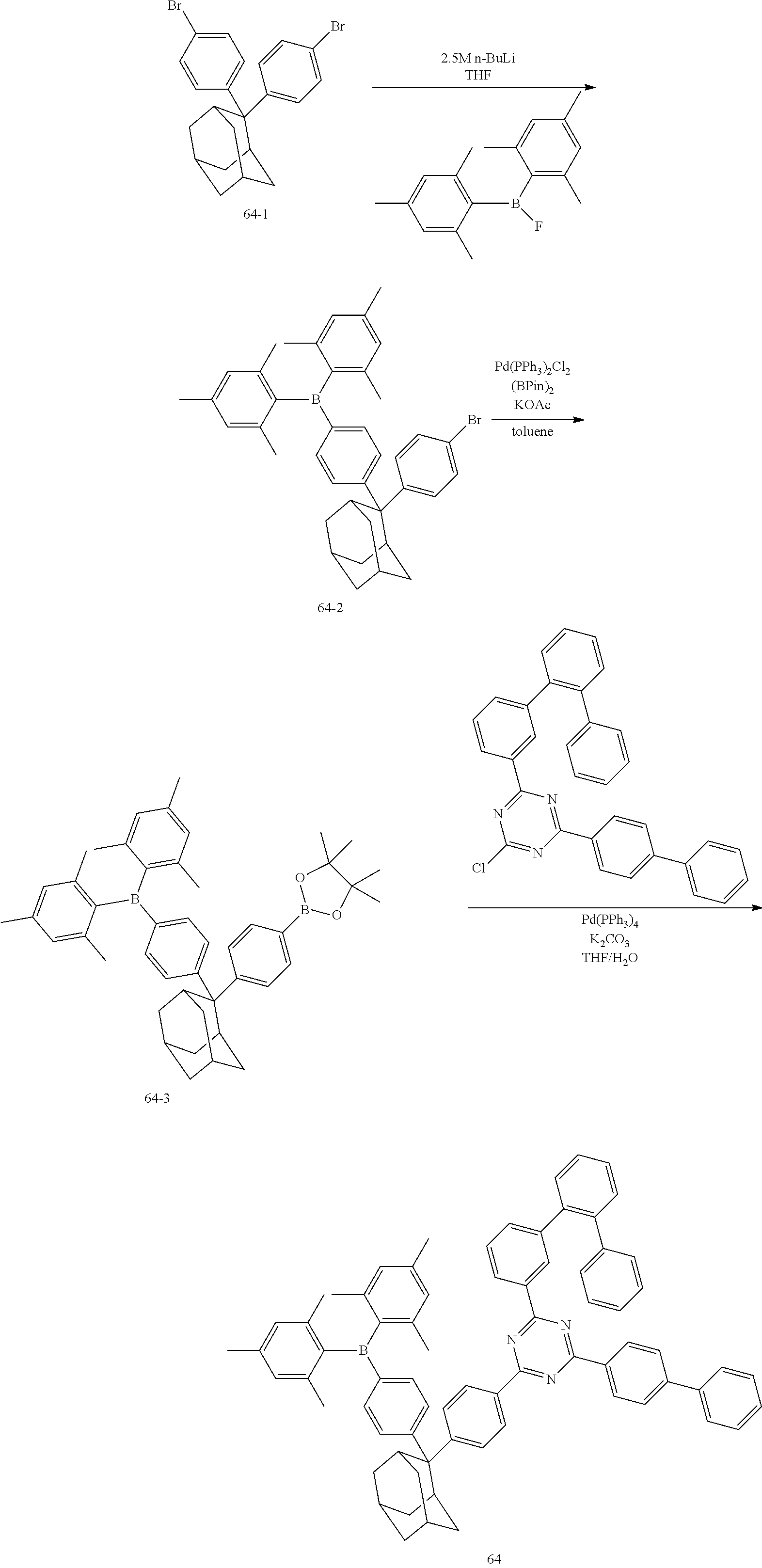

### Synthesis of Intermediate 64-2

A solution, in which Intermediate 64-1 (4.46 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodimesitylborane (2.68 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 64-2 (3.44 g, yield: 56%).

### Synthesis of Intermediate 64-3

Intermediate 64-2 (6.15 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 64-3 (4.10 g, yield: 62%).

### Synthesis of Compound 64

Intermediate 64-3 (6.10 g), Pd(PPh₃)₄ (0.56 g), K₂CO₃ (3.45 g), and 2-([1,1′-biphenyl]-4-yl)-4-([1,1′:2′,1″-terphenyl]-3-yl)-6-chloro-1,3,5-triazine (4.96 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 64 (6.57 g, yield: 66%).

### Synthesis Example 4: Synthesis of Compound 134

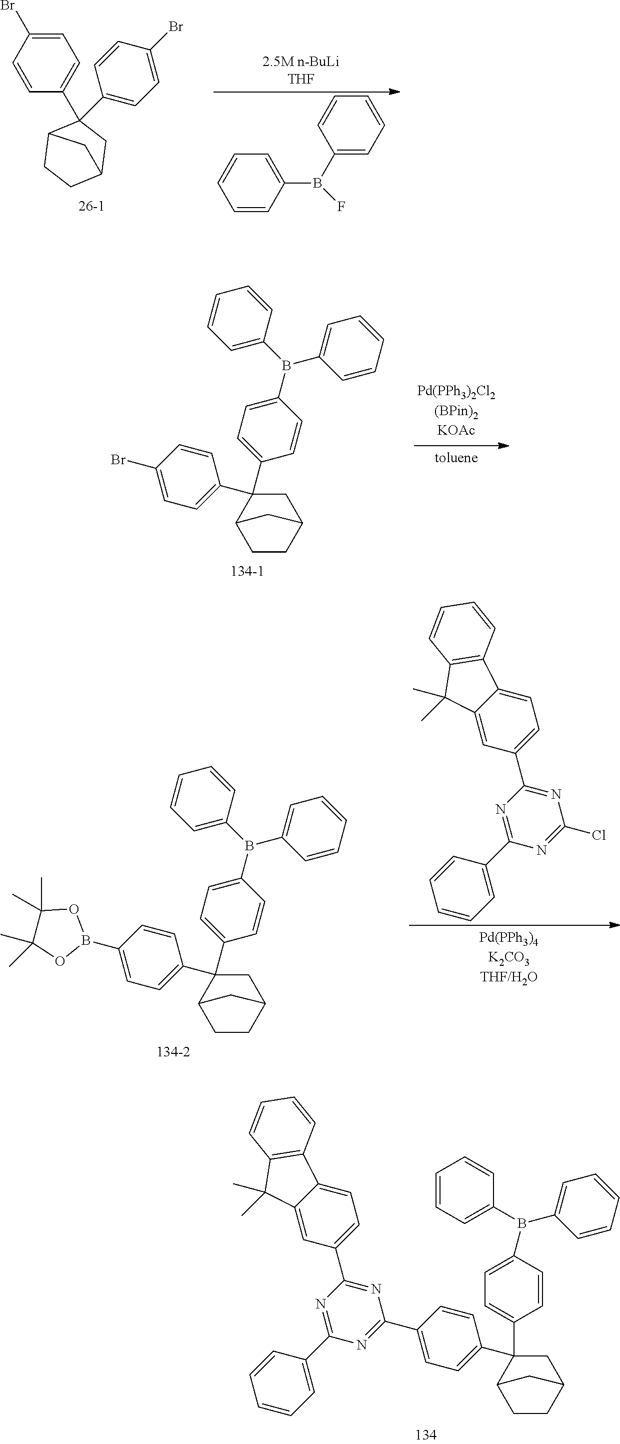 [SMILES: Brc1ccc(C2(c3ccc(Br)cc3)CC3CCC2C3)cc1 ; FB(c1ccccc1)c1ccccc1 ; Brc1ccc(C2(c3ccc(B(c4ccccc4)c4ccccc4)cc3)CC3CCC2C3)cc1 ; CC1(C)OB(c2ccc(C3(c4ccc(B(c5ccccc5)c5ccccc5)cc4)CC4CCC3C4)cc2)OC1(C)C ; CC1(C)c2ccccc2-c2ccc(-c3nc(Cl)nc(-c4ccccc4)n3)cc21 ; CC1(C)c2ccccc2-c2ccc(-c3nc(-c4ccccc4)nc(-c4ccc(C5(c6ccc(B(c7ccccc7)c7ccccc7)cc6)CC6CCC5C6)cc4)n3)cc21]

### Synthesis of Intermediate 134-1

A solution, in which Intermediate 26-1 (4.06 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodiphenylborane (1.84 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 134-1 (2.74 g, yield: 56%).

### Synthesis of Intermediate 134-2

Intermediate 134-1 (4.91 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 134-2 (2.90 g, yield: 54%).

### Synthesis of Compound 134

Intermediate 134-2 (5.38 g), Pd(PPh₃)₄ (0.56 g), K₂CO₃ (3.45 g), and 2-chloro-4-(9,9-dimethyl-9H-fluoren-2-yl)-6-phenyl-1,3,5-triazine (3.83 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 134 (4.40 g, yield: 58%).

### Synthesis Example 5: Synthesis of Compound 165

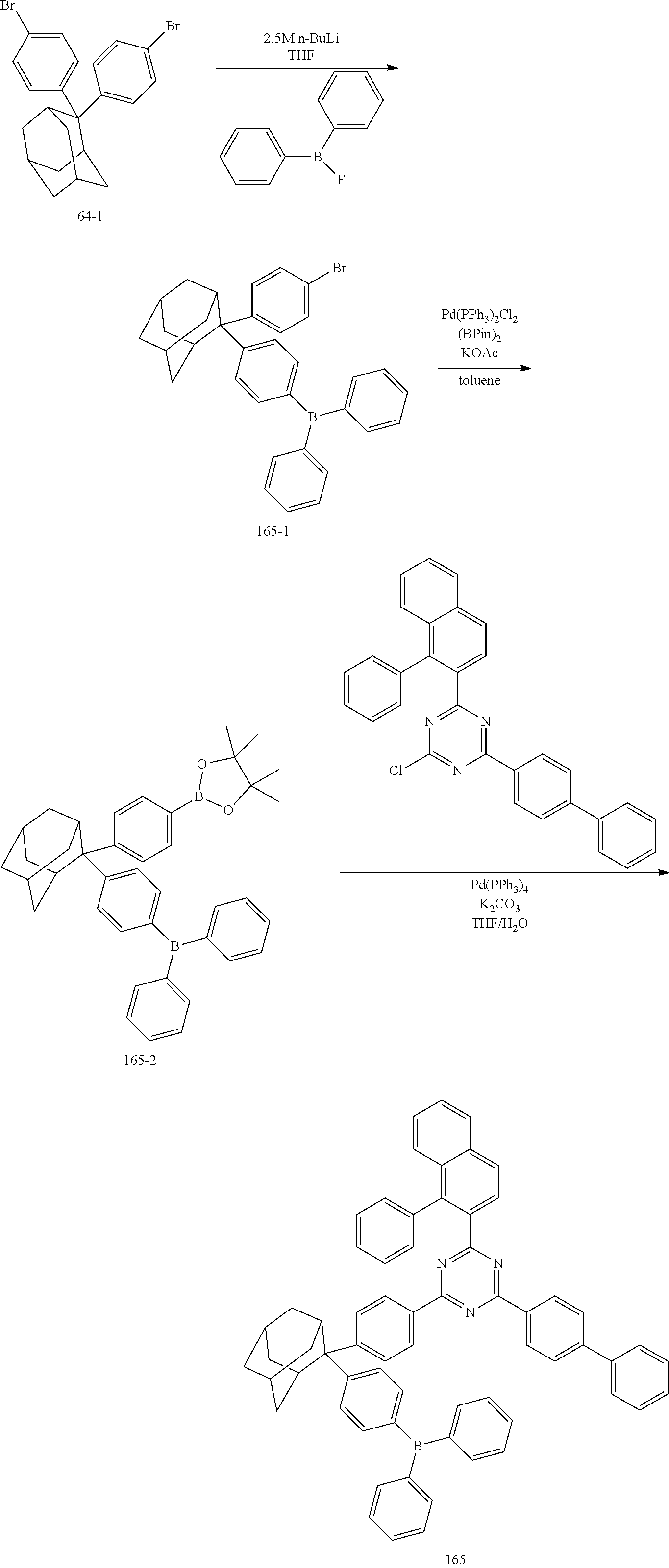 [SMILES: Brc1ccc(C2(c3ccc(Br)cc3)C3CC4CC(C3)CC2C4)cc1 ; FB(c1ccccc1)c1ccccc1 ; Brc1ccc(C2(c3ccc(B(c4ccccc4)c4ccccc4)cc3)C3CC4CC(C3)CC2C4)cc1 ; CC1(C)OB(c2ccc(C3(c4ccc(B(c5ccccc5)c5ccccc5)cc4)C4CC5CC(C4)CC3C5)cc2)OC1(C)C ; Clc1nc(-c2ccc(-c3ccccc3)cc2)nc(-c2ccc3ccccc3c2-c2ccccc2)n1 ; c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)C4CC5CC(C4)CC3C5)cc2)cc1]

### Synthesis of Intermediate 165-1

A solution, in which Intermediate 64-1 (4.46 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodiphenylborane (1.84 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 165-1 (2.65 g, yield: 50%).

### Synthesis of Intermediate 165-2

Intermediate 165-1 (5.31 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 165-2 (3.46 g, yield: 60%).

### Synthesis of Compound 165

Intermediate 165-2 (5.38 g), Pd(PPh₃)₄ (0.56 g), K₂CO₃ (3.45 g), and 2-([1,1′-biphenyl]-4-yl)-4-chloro-6-(1-phenylnaphthalen-2-yl)-1,3,5-triazine (4.69 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 165 (5.66 g, yield: 64%).

### Synthesis Example 6: Synthesis of Compound 188

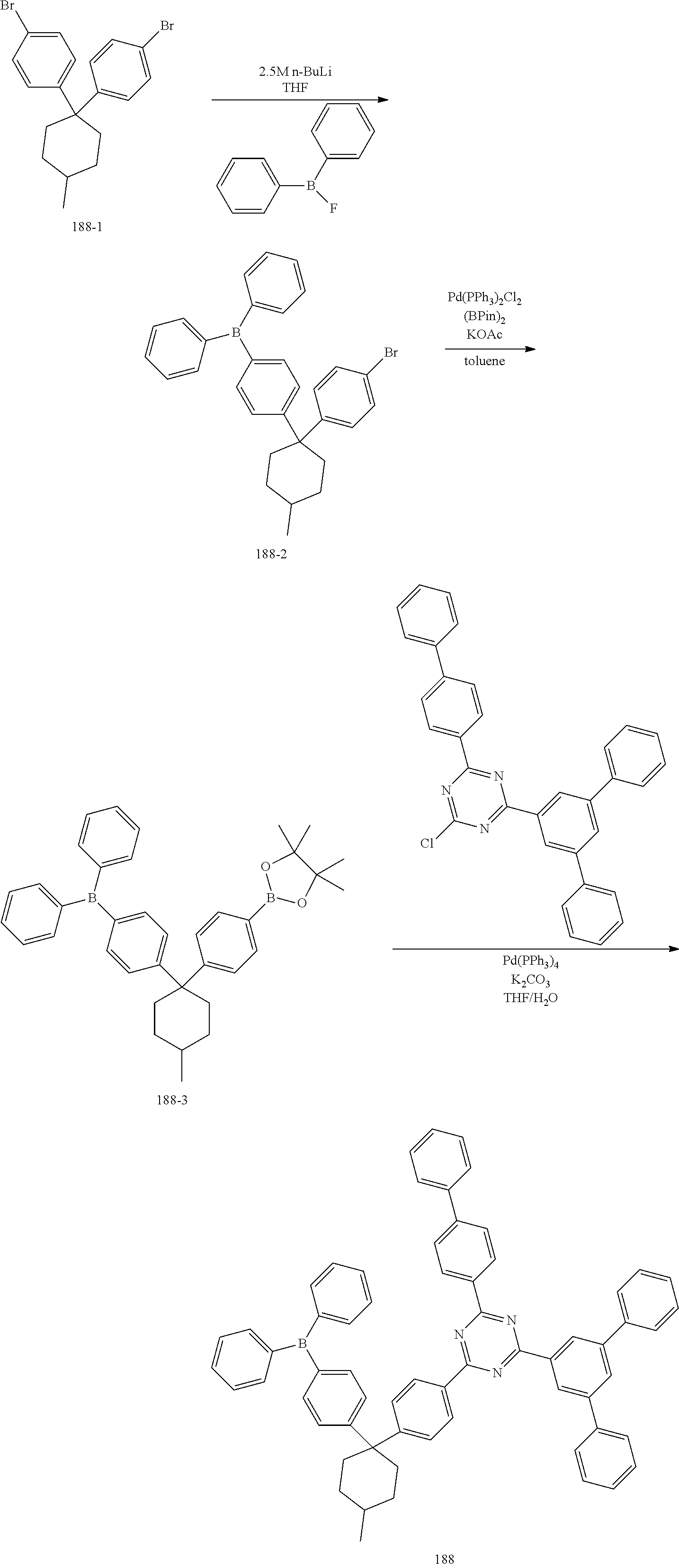

### Synthesis of Intermediate 188-2

A solution, in which Intermediate 188-1 (4.08 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodiphenylborane (1.84 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 188-2 (2.95 g, yield: 60%).

### Synthesis of Intermediate 188-3

Intermediate 188-2 (4.93 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 188-3 (3.29 g, yield: 61%).

### Synthesis of Compound 188

Intermediate 188-3 (5.40 g), Pd(PPh₃)₄ (0.56 g), K₂CO₃ (3.45 g), and 2-([1,1′-biphenyl]-4-yl)-4-([1,1′:3′,1″-terphenyl]-5′-yl)-6-chloro-1,3,5-triazine (4.96 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 188 (4.97 g, yield: 57%).

### Synthesis Example 7: Synthesis of Compound 235

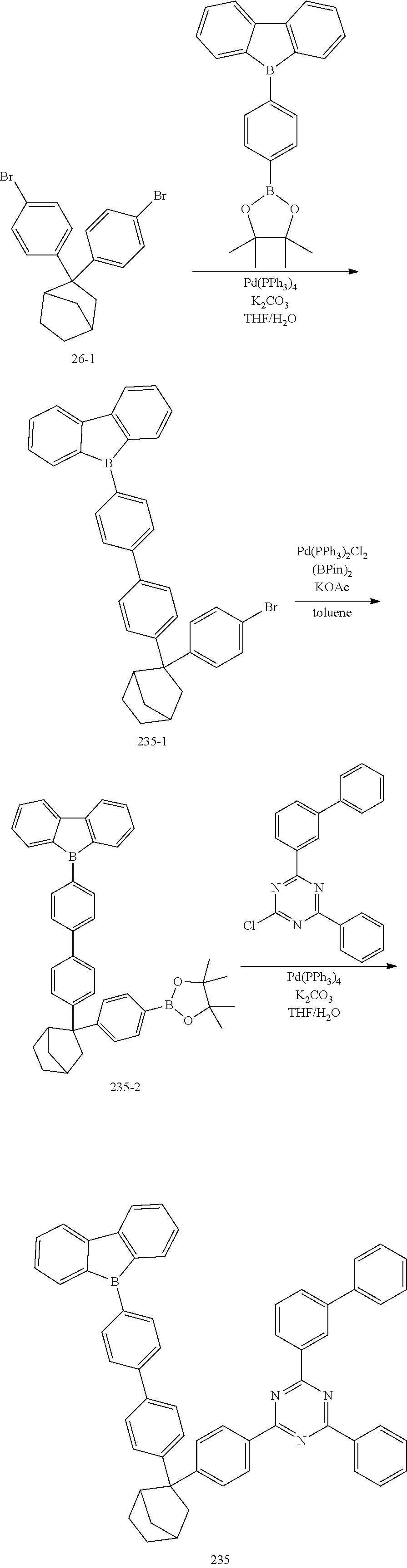 [SMILES: Brc1ccc(C2(c3ccc(Br)cc3)CC3CCC2C3)cc1 ; CC1(C)OB(c2ccc(B3c4ccccc4-c4ccccc43)cc2)OC1(C)C ; Brc1ccc(C2(c3ccc(-c4ccc(B5c6ccccc6-c6ccccc65)cc4)cc3)CC3CCC2C3)cc1 ; CC1(C)OB(c2ccc(C3(c4ccc(-c5ccc(B6c7ccccc7-c7ccccc76)cc5)cc4)CC4CCC3C4)cc2)OC1(C)C ; Clc1nc(-c2ccccc2)nc(-c2cccc(-c3ccccc3)c2)n1 ; c1ccc(-c2cccc(-c3nc(-c4ccccc4)nc(-c4ccc(C5(c6ccc(-c7ccc(B8c9ccccc9-c9ccccc98)cc7)cc6)CC6CCC5C6)cc4)n3)c2)cc1]

### Synthesis of Intermediate 235-1

Intermediate 26-1 (4.06 g), Pd(PPh₃)₄ (0.56 g), K₂CO₃ (3.45 g), and 2-(4-(5H-dibenzo[b,d]borol-5-yl)phenyl)-4,4,5,5-tetramethyl-1,3,2-dioxaborolane (3.66 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 235-1 (3.22 g, yield: 57%).

### Synthesis of Intermediate 235-2

Intermediate 235-1 (5.65 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 235-2 (3.67 g, yield: 60%).

### Synthesis of Compound 235

Intermediate 235-2 (6.70 g), Pd(PPh₃)₄ (0.56 g), K₂CO₃ (3.45 g), and 2-([1,1′-biphenyl]-3-yl)-4-chloro-6-phenyl-1,3,5-triazine (3.43 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 235 (3.40 g, yield: 43%).

### Synthesis Example 8: Synthesis of Compound 294

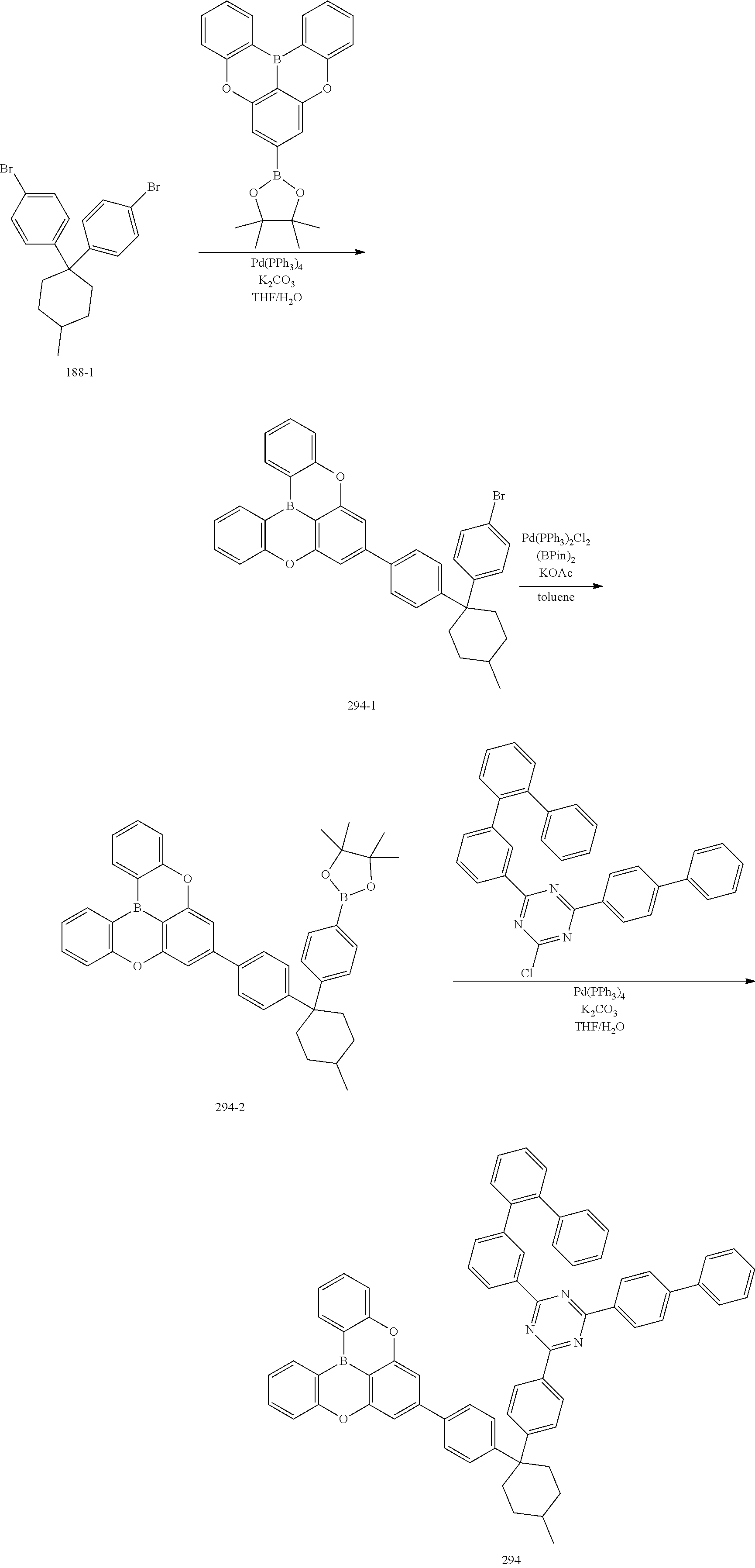 [SMILES: CC1CCC(c2ccc(Br)cc2)(c2ccc(Br)cc2)CC1 ; CC1(C)OB(c2cc3c4c(c2)Oc2ccccc2B4c2ccccc2O3)OC1(C)C ; CC1CCC(c2ccc(Br)cc2)(c2ccc(-c3cc4c5c(c3)Oc3ccccc3B5c3ccccc3O4)cc2)CC1 ; CC1CCC(c2ccc(B3OC(C)(C)C(C)(C)O3)cc2)(c2ccc(-c3cc4c5c(c3)Oc3ccccc3B5c3ccccc3O4)cc2)CC1 ; Clc1nc(-c2ccc(-c3ccccc3)cc2)nc(-c2cccc(-c3ccccc3-c3ccccc3)c2)n1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5-c5ccccc5)c4)n3)cc2)CC1]

### Synthesis of Intermediate 294-1

Intermediate 188-1 (4.08 g), Pd(PPh₃)₄ (0.56 g), K₂CO₃ (3.45 g), and 7-(4,4,5,5-tetramethyl-1,3,2-dioxaborolan-2-yl)-5,9-dioxa-13b-boranaphtho[3,2,1-de]anthracene (3.96 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 294-1 (3.40 g, yield: 57%).

### Synthesis of Intermediate 294-2

Intermediate 294-1 (5.97 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 294-2 (4.05 g, yield: 63%).

### Synthesis of Compound 294

Intermediate 294-2 (6.44 g), Pd(PPh₃)₄ (0.56 g), K₂CO₃ (3.45 g), and 2-([1,1′-biphenyl]-4-yl)-4-([1,1′:2′,1″-terphenyl]-3-yl)-6-chloro-1,3,5-triazine (3.43 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 294 (6.45 g, yield: 66%).

### Synthesis Example 9: Synthesis of Compound 331

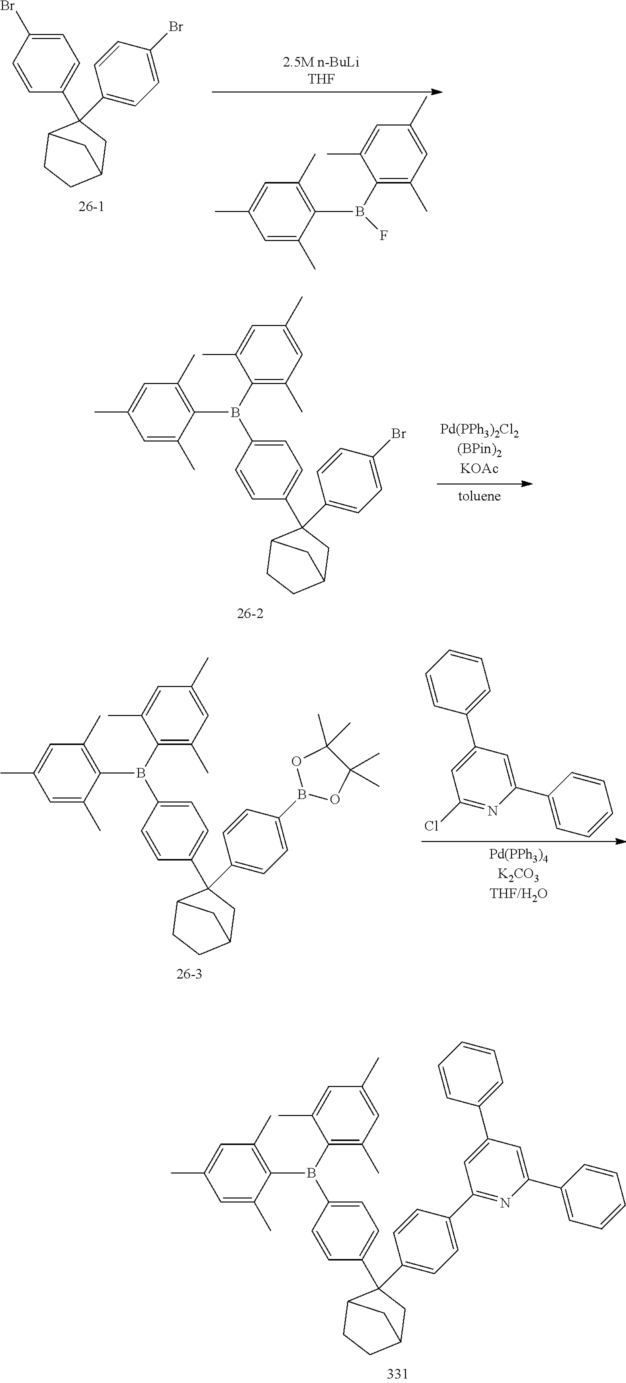

### Synthesis of Intermediate 26-2

A solution, in which Intermediate 26-1 (4.06 g) was dissolved in tetrahydrofuran (THF, 50 mL), was stirred at −78° C., and then 4 mL of n-BuLi (2.5 M in hexane) was slowly added dropwise thereto at −78° C. To this solution, a solution, in which fluorodimesitylborane (2.68 g) was dissolved in THE (50 mL), was slowly added dropwise at −78° C. This solution was stirred at room temperature for 12 hours. The reaction was terminated by utilizing water, and an extraction process was performed on the reaction solution three times by utilizing ethylether. An organic layer thus separated therefrom was dried by utilizing anhydrous magnesium sulfate and distilled under reduced pressure, and a residue thus obtained was separated and purified by column chromatography to obtain Intermediate 26-2 (3.85 g, yield: 67%).

### Synthesis of Intermediate 26-3

Intermediate 26-2 (5.65 g), Pd(PPh₃)₂Cl₂ (0.35 g), bis(pinacolato)diboron (2.53 g), and KOAc (2.45 g) were dissolved in toluene (50 mL) and then stirred at 100° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Intermediate 26-3 (4.29 g, yield: 69%).

### Synthesis of Compound 331

Intermediate 26-3 (6.22 g), Pd(PPh₃)₄ (0.56 g), K₂CO₃ (3.45 g), and 2-chloro-4,6-diphenylpyridine (2.65 g) were dissolved in THF/H₂O (100 mL/25 mL) and then stirred at 60° C. for 12 hours. The reaction temperature was lowered to room temperature, and the reaction was terminated by utilizing water. Then, an extraction process was performed thereon three times by utilizing ethylether. An organic layer thus separated therefrom was dried by utilizing anhydrous magnesium sulfate and distilled under reduced pressure, and a residue thus obtained was separated and purified by column chromatography to obtain Compound 331 (4.35 g, yield: 60%).

Synthesis methods of other compounds in addition to the compound synthesized in Synthesis Examples may be easily recognized by those skilled in the art by referring to the synthesis paths and source materials.

### Example 1

As an anode, a glass substrate (product of Corning Inc.) with a 15 Ω/cm² (1,200 Å) ITO electrode formed thereon was cut to a size of 50 mm×50 mm×0.7 mm, sonicated with isopropyl alcohol and then pure water each for 5 minutes, cleaned by irradiation of ultraviolet rays and exposure of ozone thereto for 30 minutes, and then mounted on a vacuum deposition apparatus. NPD was deposited on the anode to form a hole injection layer having a thickness of 300 Å, HT3 was deposited on the hole injection layer to form a hole transport layer having a thickness of 200 Å, and CzSi was deposited on the hole transport layer to form an emission auxiliary layer having a thickness of 100 Å.

HT-3 and ET-2 (exciplex host), PS-2 (phosphorescent sensitizer), and t-DABNA (boron dopant) were co-deposited on the emission auxiliary layer at a weight ratio of 42:42:15:1 to form an emission layer having a thickness of 200 Å.

Next, TSPO1 was deposited on the emission layer to form a hole blocking layer having a thickness of 200 Å, Compound 1 was deposited on the hole blocking layer to form an electron transport layer having a thickness of 300 Å, LiF was deposited on the electron transport layer to form an electron injection layer having a thickness of 10 Å, and Al was deposited on the electron injection layer to form a cathode having a thickness of 3,000 Å, thereby completing manufacture of a light-emitting device.

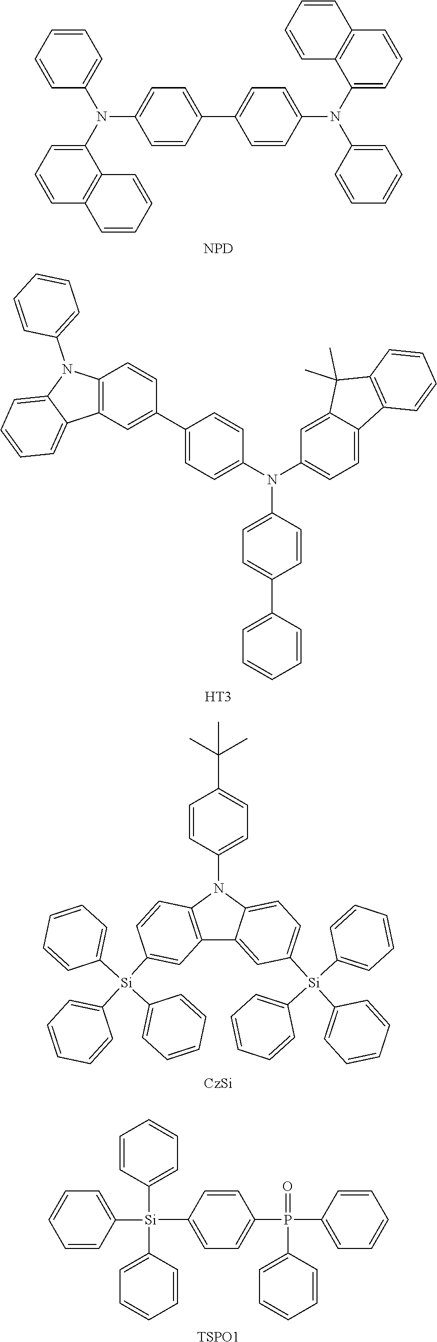

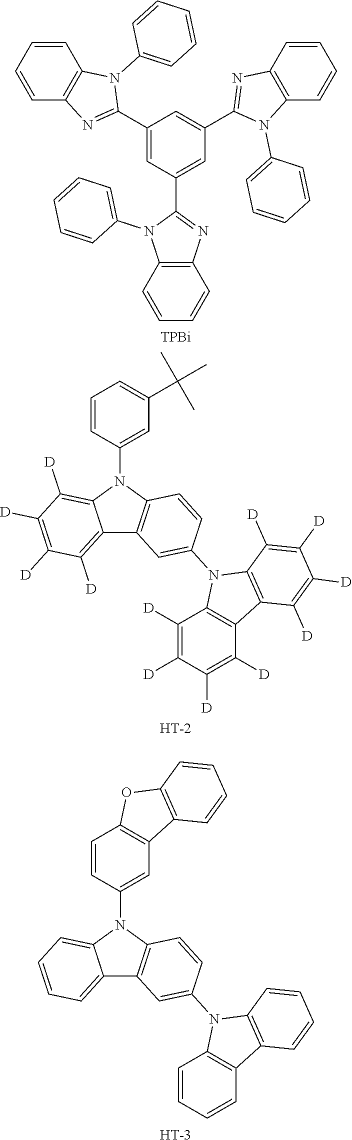

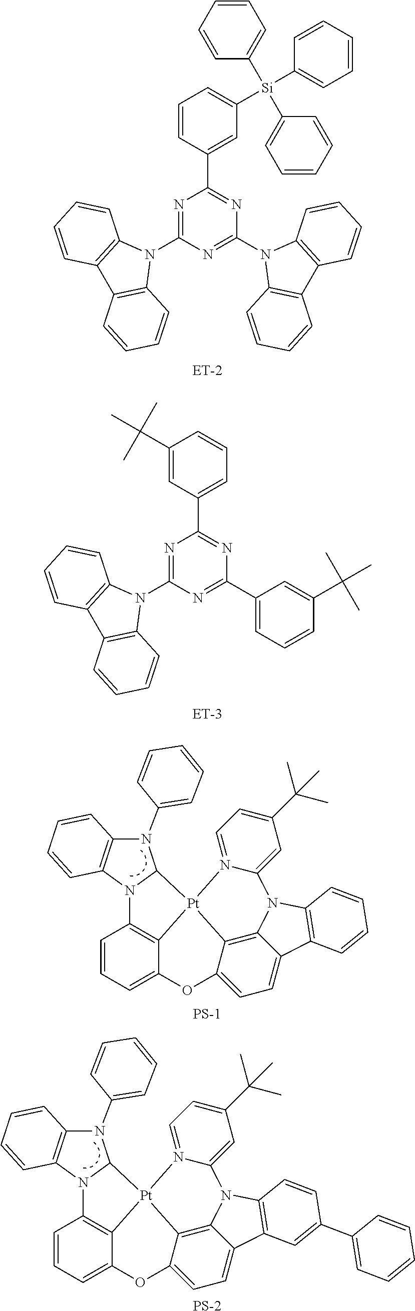

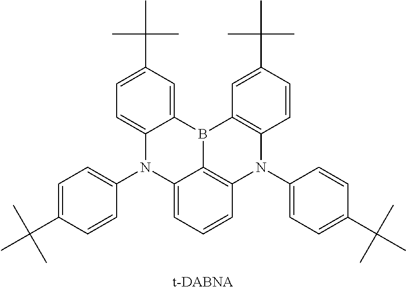 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

### Examples 2 to 9 and Comparative Examples 1 to 3

Light-emitting devices were manufactured in substantially the same manner as in Example 1, except that materials were changed as shown in Table 1 when the emission layer and the electron transport layer were formed.

### Evaluation Example 1

Driving voltage (V) at 1,000 cd/m² luminance, luminescence efficiency (cd/A), and lifespan ratio (T₉₅) of the each of light-emitting devices manufactured in Examples 1 to 9 and Comparative Examples 1 to 3 were measured by utilizing Keithley SMU 236 and a luminance meter PR650, and results thereof are shown in Table 1. The lifespan ratio (T₉₅) in Table 1 is a measure of time (device lifespan, hr) taken for the luminance to reach 95% relative to the initial luminance of each of Examples and Comparative Examples, and represents the ratio of each of Examples and Comparative Examples when the device lifespan of Comparative Example 1 is set to 1.

TABLE 1

| | HTL | Exciplex | | | ETL | | | |
|---|---|---|---|---|---|---|---|---|
| | (Hole | host | Phospho- | | (Electron | Driving | Luminescence | Lifespan |
| | transport | (HT:ET = | rescent | Boron | transport | voltage | Efficiency | ratio |
| | layer) | 5:5) | sensitizer | dopant | layer) | (V) | (cd/A) | (T₉₅) |
| Example | HT3 | HT-3/ET-2 | PS-2 | t-DABNA | Compound 1 | 3.94 | 25.8 | 5.4 |
| 1 | | | | | | | | |
| Example | HT3 | HT-3/ET-2 | PS-2 | t-DABNA | Compound 26 | 4.09 | 25.3 | 4.9 |
| 2 | | | | | | | | |
| Example | HT3 | HT-3/ET-2 | PS-2 | t-DABNA | Compound 64 | 3.96 | 26.3 | 5.2 |
| 3 | | | | | | | | |
| Example | HT3 | HT-3/ET-2 | PS-2 | t-DABNA | Compound 134 | 4.11 | 24.2 | 5.4 |
| 4 | | | | | | | | |
| Example | HT3 | HT-3/ET-2 | PS-2 | t-DABNA | Compound 165 | 4.23 | 24.9 | 5.5 |
| 5 | | | | | | | | |
| Example | HT3 | HT-3/ET-2 | PS-2 | t-DABNA | Compound 188 | 4.34 | 25.7 | 5.7 |
| 6 | | | | | | | | |
| Example | HT3 | HT-3/ET-2 | PS-2 | t-DABNA | Compound 235 | 4.21 | 25.9 | 4.5 |
| 7 | | | | | | | | |
| Example | HT3 | HT-3/ET-2 | PS-1 | t-DABNA | Compound 294 | 4.03 | 24.4 | 4.4 |
| 8 | | | | | | | | |
| Example | HT3 | HT-3/ET-2 | PS-1 | t-DABNA | Compound 331 | 4.19 | 26.0 | 4.8 |
| 9 | | | | | | | | |
| Comparative | HT3 | HT-3/ET-2 | PS-2 | t-DABNA | TPBI | 5.6 | 18.8 | 1 |
| Example | | | | | | | | |
| 1 | | | | | | | | |
| Comparative | HT3 | HT-3/ET-2 | PS-2 | t-DABNA | CE1 | 4.53 | 20.3 | 3.1 |
| Example | | | | | | | | |
| 2 | | | | | | | | |
| Comparative | HT3 | HT-3/ET-2 | PS-2 | t-DABNA | CE2 | 4.44 | 22.4 | 2.7 |
| Example | | | | | | | | |
| 3 | | | | | | | | |

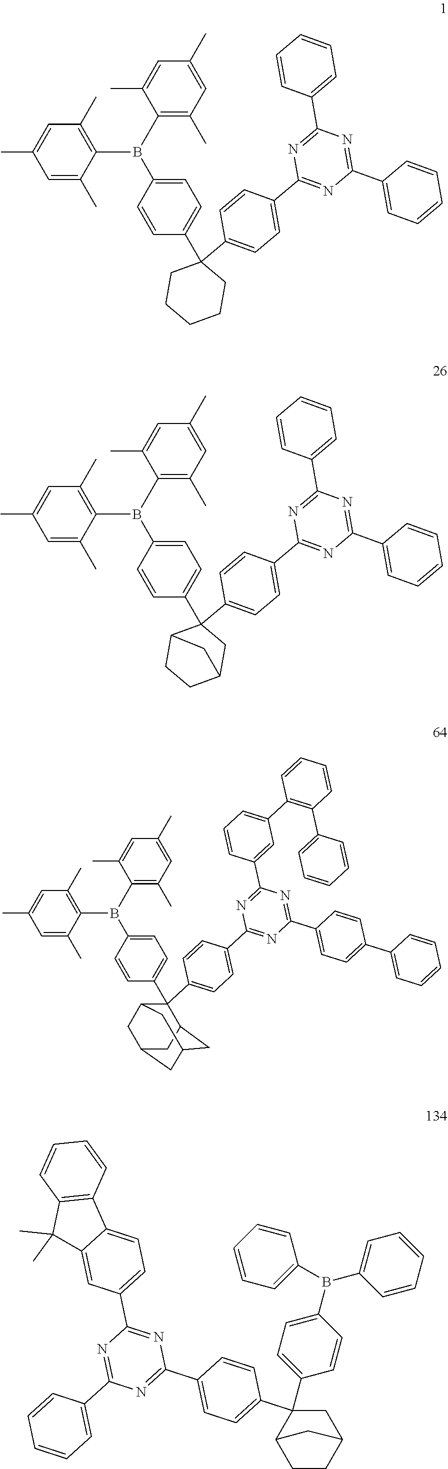 [SMILES: Cc1cc(C)c(B(c2ccc(C3(c4ccc(-c5nc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccccc6)nc(-c6ccccc6)n5)cc4)CC4CCC3C4)cc2)c2c(C)cc(C)cc2C)c(C)c1 ; Cc1cc(C)c(B(c2ccc(C3(c4ccc(-c5nc(-c6ccc(-c7ccccc7)cc6)nc(-c6cccc(-c7ccccc7-c7ccccc7)c6)n5)cc4)C4CC5CC(C4)CC3C5)cc2)c2c(C)cc(C)cc2C)c(C)c1 ; CC1(C)c2ccccc2-c2ccc(-c3nc(-c4ccccc4)nc(-c4ccc(C5(c6ccc(B(c7ccccc7)c7ccccc7)cc6)CC6CCC5C6)cc4)n3)cc21]

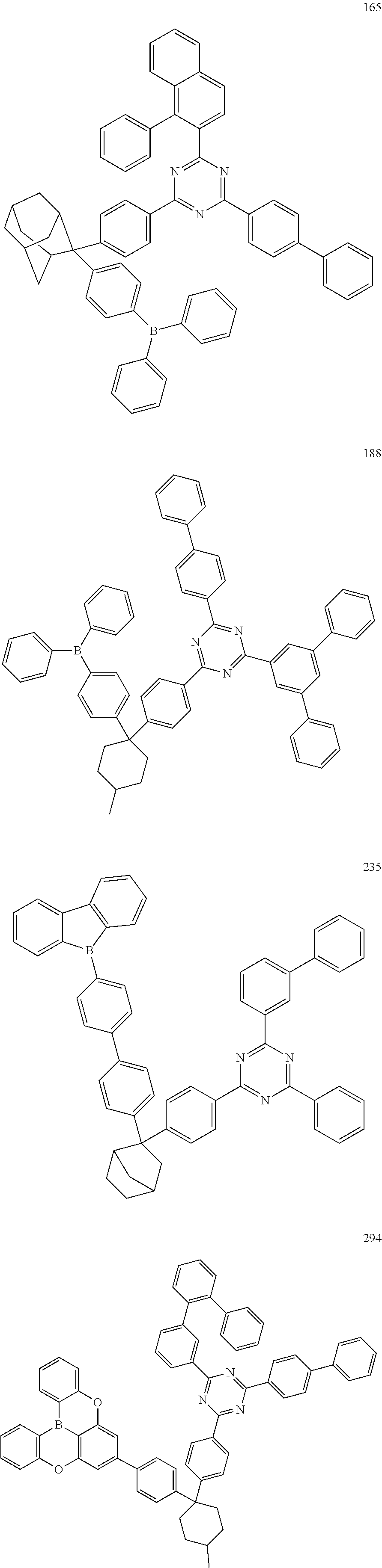 [SMILES: c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)C4CC5CC(C4)CC3C5)cc2)cc1 ; CC1CCC(c2ccc(B(c3ccccc3)c3ccccc3)cc2)(c2ccc(-c3nc(-c4ccc(-c5ccccc5)cc4)nc(-c4cc(-c5ccccc5)cc(-c5ccccc5)c4)n3)cc2)CC1 ; c1ccc(-c2cccc(-c3nc(-c4ccccc4)nc(-c4ccc(C5(c6ccc(-c7ccc(B8c9ccccc9-c9ccccc98)cc7)cc6)CC6CCC5C6)cc4)n3)c2)cc1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5-c5ccccc5)c4)n3)cc2)CC1]

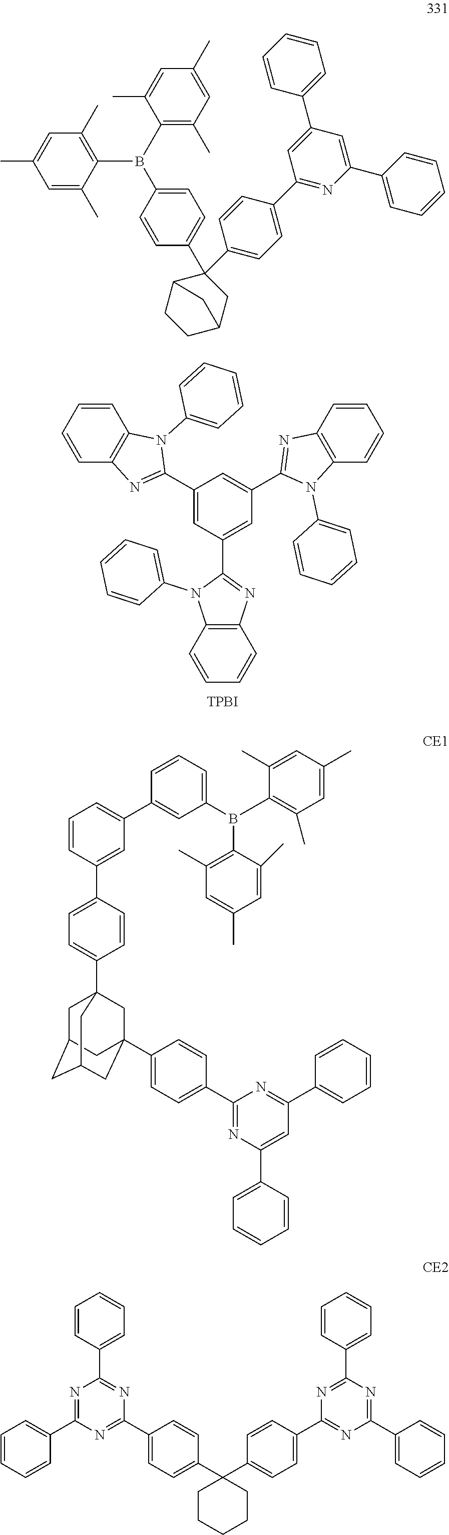

From Table 1, it could be confirmed that the light-emitting devices according to Examples 1 to 9 each had better driving voltage, better luminescence efficiency, and better device lifespan than that of the light-emitting devices according to Comparative Examples 1 to 3.

By utilizing the heterocyclic compound of the present disclosure, a light-emitting device with reduced driving voltage, improved color purity, improved luminescence efficiency, and increased lifespan and a high-quality electronic apparatus including the light-emitting device may be manufactured.

In the present disclosure, it will be understood that the term “comprise(s),” “include(s),” or “have/has” specifies the presence of stated features, integers, steps, operations, elements, and/or components, but do not preclude the presence or addition of one or more other features, integers, steps, operations, elements, components, and/or groups thereof.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light-emitting device, the light-emitting apparatus, the display device, the electronic apparatus, the electronic device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A light-emitting device comprising:
a first electrode;
a second electrode facing the first electrode; and
an interlayer between the first electrode and the second electrode and comprising an emission layer,
wherein:
the first electrode is an anode,
the second electrode is a cathode,
the interlayer further comprises a hole transport region between the first electrode and the emission layer and an electron transport region between the emission layer and the second electrode, and
the electron transport region comprises a heterocyclic compound represented by Formula 1: 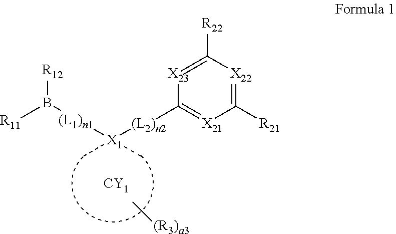
wherein, in Formula 1,
X₁ is carbon, and X₁ is bonded to another carbon or nitrogen atom in one of four directions of X₁,
ring CY1 is a C₃-C₂₀ cycloalkyl group,
X₂₁ is C(Y₂₁) or N, X₂₂ is C(Y₂₂) or N, X₂₃ is C(Y₂₃) or N, and the number of N(s) among X₂₁ to X₂₃ is one or more,
R₁₁, R₁₂, R₂₁, R₂₂, R₃, and Y₂₁ to Y₂₃ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a3 is an integer from 1 to 20,
L₁ and L₂ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
n1 and n2 are each independently an integer from 1 to 5,
R₁₁ and L₁ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and L₁ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₁ and R₁₂ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
two or more neighboring groups selected from among R₂₁, R₂₂, and Y₂₁ to Y₂₃ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein the hole transport region comprises a hole injection layer, a hole transport layer, an emission auxiliary layer, an electron blocking layer, or any combination thereof, and
the electron transport region comprises a buffer layer, a hole blocking layer, an electron control layer, an electron transport layer, an electron injection layer, or any combination thereof.

3. The light-emitting device of claim 1, wherein the electron transport region comprises an electron transport layer, and
the electron transport layer comprises the heterocyclic compound.

4. The light-emitting device of claim 1, wherein the emission layer comprises a first compound that is a transition metal-containing compound, a second compound comprising at least one π electron-deficient nitrogen-containing C₁-C₆₀ heterocyclic group, a third compound comprising a group represented by Formula 3, a fourth compound capable of emitting delayed fluorescence, or any combination thereof, and
the first compound, the second compound, the third compound, and the fourth compound are different from each other: 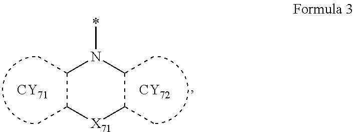
in Formula 3,
ring CY71 and ring CY72 being each independently a π electron-rich C₃-C₆₀ cyclic group or a pyridine group,
X₇₁ being a single bond or a linking group comprising O, S, N, B, C, Si, or any combination thereof, and
* indicating a binding site to any atom included in a remaining part other than the group presented by Formula 3 in the third compound.

5. The light-emitting device of claim 1, wherein the emission layer is to emit blue light.

6. An electronic apparatus comprising the light-emitting device of claim 1.

7. The electronic apparatus of claim 6, further comprising a thin-film transistor,
wherein the thin-film transistor comprises a source electrode and a drain electrode, and
the first electrode of the light-emitting device is electrically connected to the source electrode or the drain electrode of the thin-film transistor.

8. The electronic apparatus of claim 6, further comprising a color filter, a color conversion layer, a touch screen layer, a polarizing layer, or any combination thereof.

9. An electronic equipment comprising the light-emitting device of claim 1.

10. The electronic equipment of claim 9, wherein the electronic equipment is at least one of a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, or a signboard.

11. A heterocyclic compound represented by Formula 1: 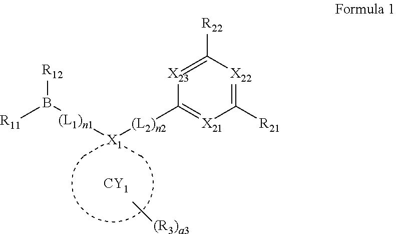
wherein, in Formula 1,
X₁ is carbon (C), and X₁ is bonded to another carbon or nitrogen atom in one of four directions of X₁,
ring CY1 is a C₃-C₂₀ cycloalkyl group,
X₂₁ is C(Y₂₁) or N, X₂₂ is C(Y₂₂) or N, X₂₃ is C(Y₂₃) or N, and the number of N(s) among X₂₁ to X₂₃ is one or more,
R₁₁, R₁₂, R₂₁, R₂₂, R₃, and Y₂₁ to Y₂₃ are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₁-C₆₀ alkylthio group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, a C₆-C₆₀ aryloxy group that is unsubstituted or substituted with at least one R₁₀ₐ, a C₆-C₆₀ arylthio group that is unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a3 is an integer from 1 to 20,
L₁ and L₂ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
n1 and n2 are each independently an integer from 1 to 5,
R₁₁ and L₁ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₂ and L₁ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₁ and R₁₂ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
two or more neighboring groups selected from among R₂₁, R₂₂, and Y₂₁ to Y₂₃ are optionally bonded together to form a C₃-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

12. The heterocyclic compound of claim 11, wherein ring CY1 is a cyclopropane group, a cyclobutane group, a cyclopentane group, a cyclohexane group, a cycloheptane group, a cyclooctane group, an adamantane group, a bicyclo[1.1.1]pentane group, a bicyclo[2.1.1]hexane group, a bicyclo[2.2.1]heptane group, a bicyclo[2.2.2]octane group, a bicyclo[3.2.1]octane group, a bicyclo[3.2.2]nonane group, a bicyclo[3.3.1]nonane group, a tricyclo[3.1.1.0(3,6)]heptane group, or a tricyclo[4.1.1.0(3,7)]octane group.

13. The heterocyclic compound of claim 11, wherein a group represented by 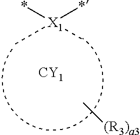
in Formula 1 is a group represented by one selected from Formulae CY(1) to CY(11): 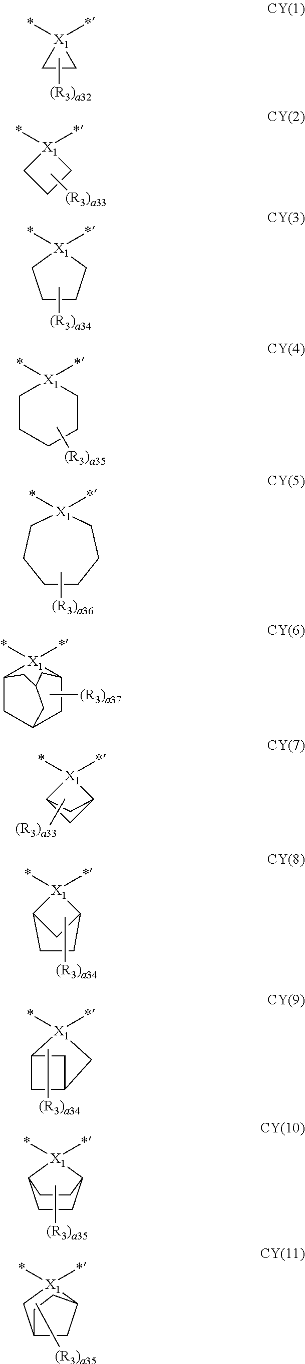
in Formulae CY(1) to CY(11),
X₁ and R₃ being each the same as described in Formula 1,
a32 being an integer from 1 to 4,
a33 being an integer from 1 to 6,
a34 being an integer from 1 to 8,
a35 being an integer from 1 to 10,
a36 being an integer from 1 to 12,
a37 being an integer from 1 to 14,
* indicating a binding site to L₁ in Formula 1, and
*′ indicating a binding site to L₂ in Formula 1.

14. The heterocyclic compound of claim 11, wherein Y₂₁ to Y₂₃ are each independently:
hydrogen, deuterium, —F, —Cl, —Br, —I, a hydroxyl group, a cyano group, a nitro group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

15. The heterocyclic compound of claim 11, wherein R₁₁, R₁₂, R₂₁, R₂₂, and R₃ are each independently:
hydrogen, deuterium, —F, —Cl, —Br, —I, a hydroxyl group, a cyano group, a nitro group, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CDs, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a (C₁-C₁₀ alkyl)phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a phthalazinyl group, a carbazolyl group, a phenanthrolinyl group, a benzimidazolyl group, a benzofuranyl group, a benzothiophenyl group, a benzothiazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or
—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
Q₁ to Q₃ and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a C₁-C₆₀ alkylthio group, a phenyl group, a biphenyl group, or any combination thereof.

16. The heterocyclic compound of claim 11, wherein L₁ and L₂ are each independently a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phthalazine group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzoxasiline group, a dibenzothiasiline group, a dibenzodihydroazasiline group, a dibenzodihydrodihydrodisiline group, a dibenzodihydrosiline group, a dibenzodioxin group, a dibenzoxathiin group, a dibenzoxazine group, a dibenzopyran group, a dibenzodithiin group, a dibenzothiazine group, a dibenzothiopyran group, a dibenzocyclohexadiene group, a dibenzodihydropyridine group, or a dibenzodihydropyrazine group, each unsubstituted or substituted with at least one R₁₀ₐ.

17. The heterocyclic compound of claim 11, wherein L₁ and L₂ are each independently a group represented by one selected from among Formulae L(1) to L(24): 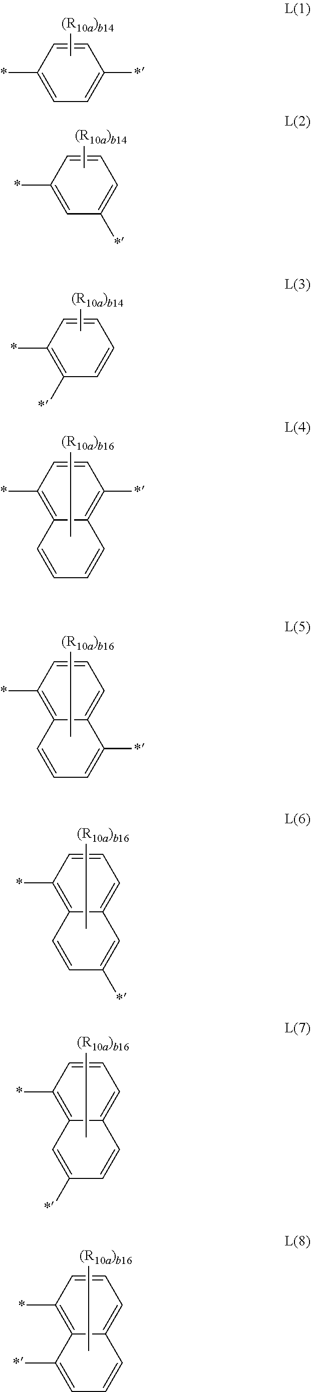 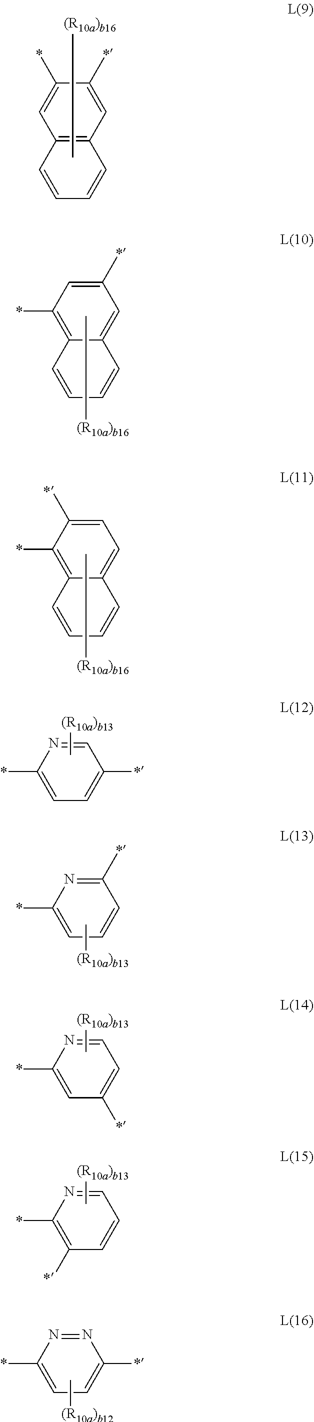 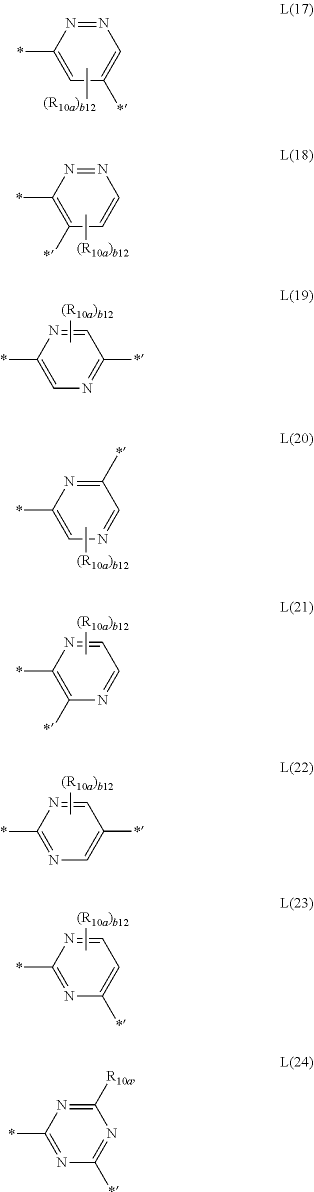
in Formulae L(1) to L(24),
R₁₀ₐ is the same as described in Formula 1,
b12 being an integer from 1 to 2,
b13 being an integer from 1 to 3,
b14 being an integer from 1 to 4,
b16 being an integer from 1 to 6, and
* and *′ each indicating a binding site to a neighboring atom.

18. The heterocyclic compound of claim 11, wherein:
n1 is 1 or 2, and
n2 is 1.

19. The heterocyclic compound of claim 11, wherein a group represented by 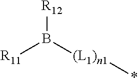
in Formula 1 is a group represented by one selected from among Formulae B(1) to B(3): 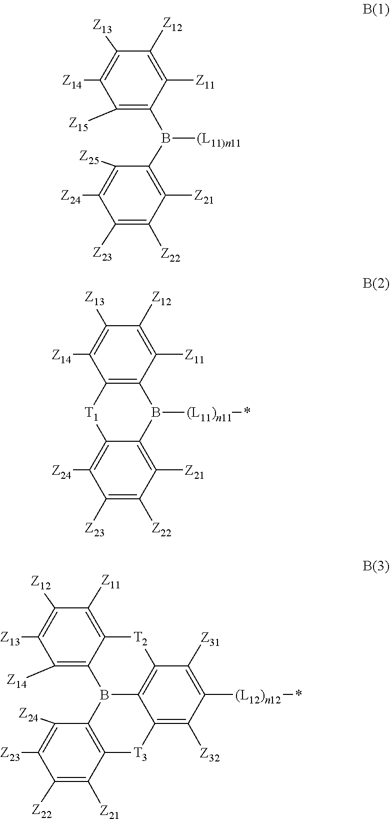
in Formulae B(1) to B(3),
L₁₁ and L₁₂ being each independently the same as described with respect to L₁ in Formula 1,
n11 being an integer from 1 to 5, and n12 being an integer from 1 to 4,
T₁ to T₃ being each independently a single bond, *—O—*′, *—S—*′, *—Se—*′, *—N(R′)—*′, *—B(R′)—*′, *—C(R′)(R″)—*′, or *—Si(R′)(R″)—*,
Z₁₁ to Z₁₅, Z₂₁ to Z₂₅, Z₃₁, Z₃₂, R′, and R″ being each independently the same as described with respect to R₁₀ₐ in Formula 1, and
* and *′ each independently indicating a binding site to a neighboring atom.

20. The heterocyclic compound of claim 11, wherein the heterocyclic compound is any one selected from among Compounds 1 to 355: 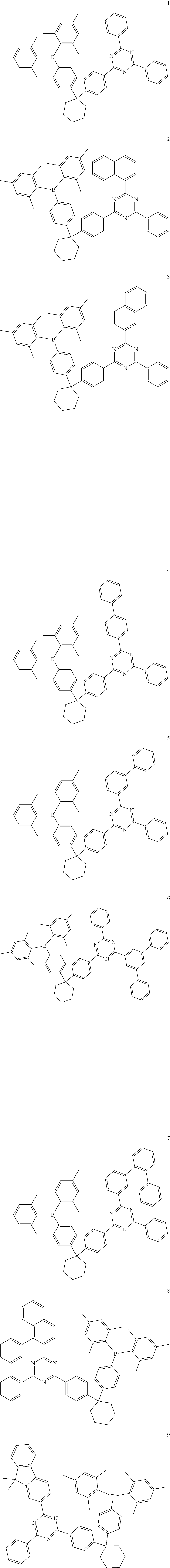 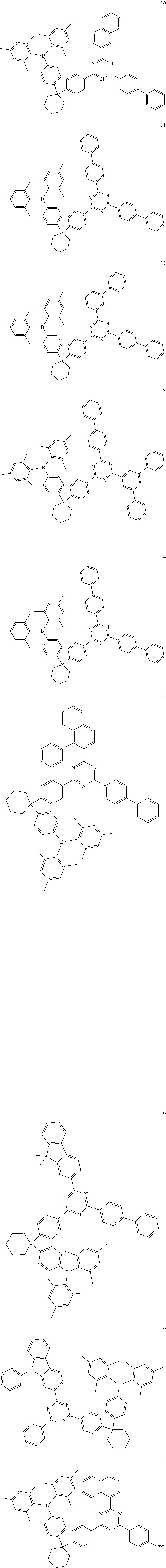 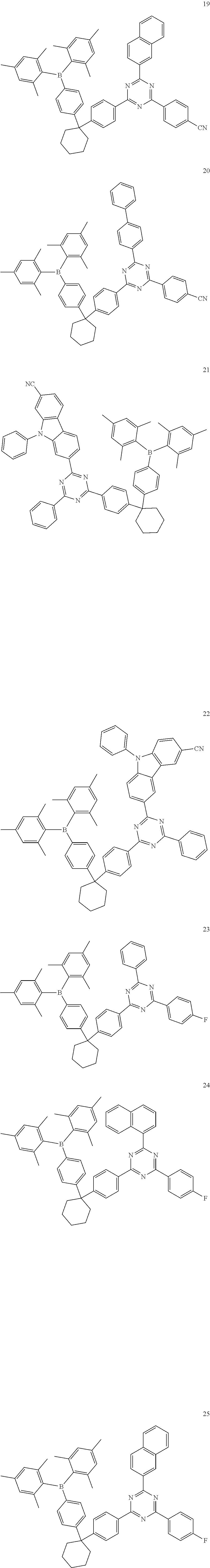 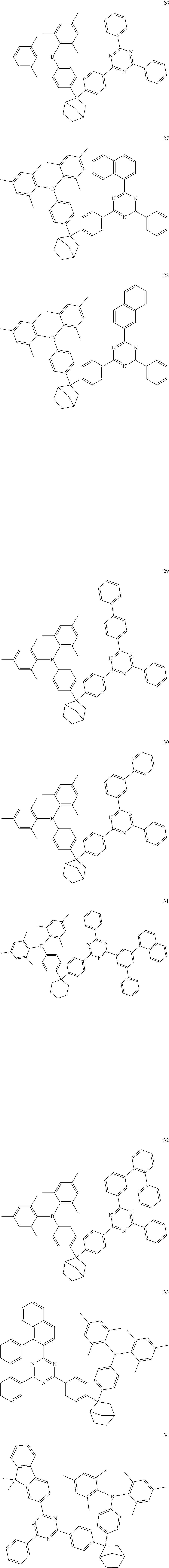 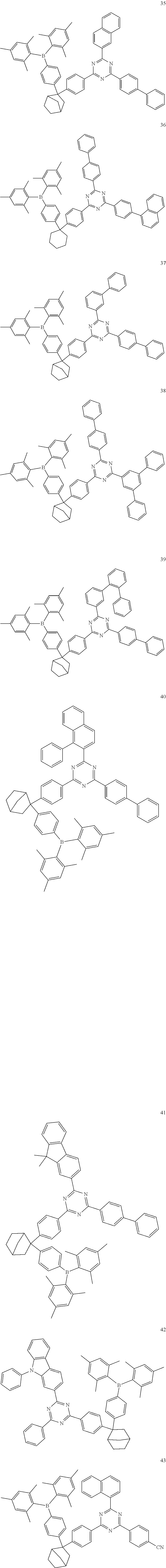 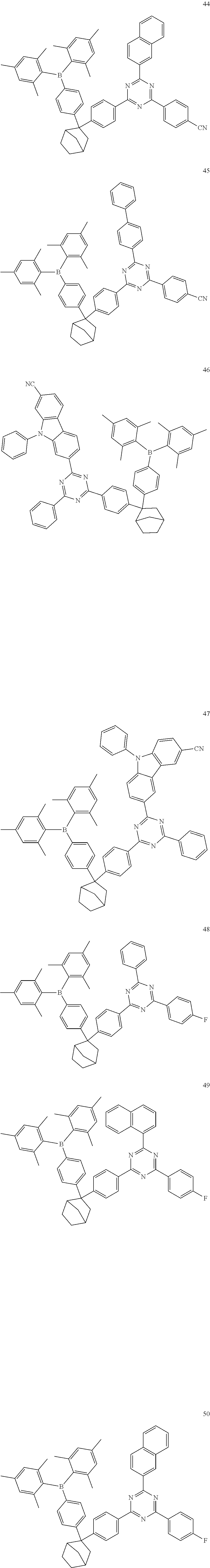 [chemical structure] [chemical structure] 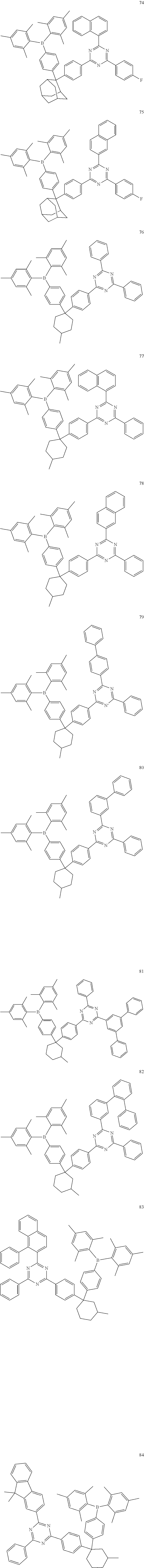 [chemical structure] [chemical structure] [chemical structure] 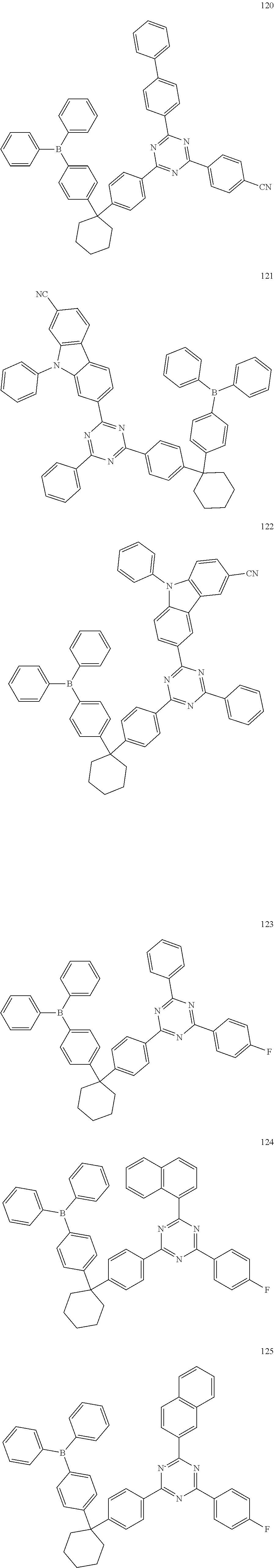 [chemical structure] 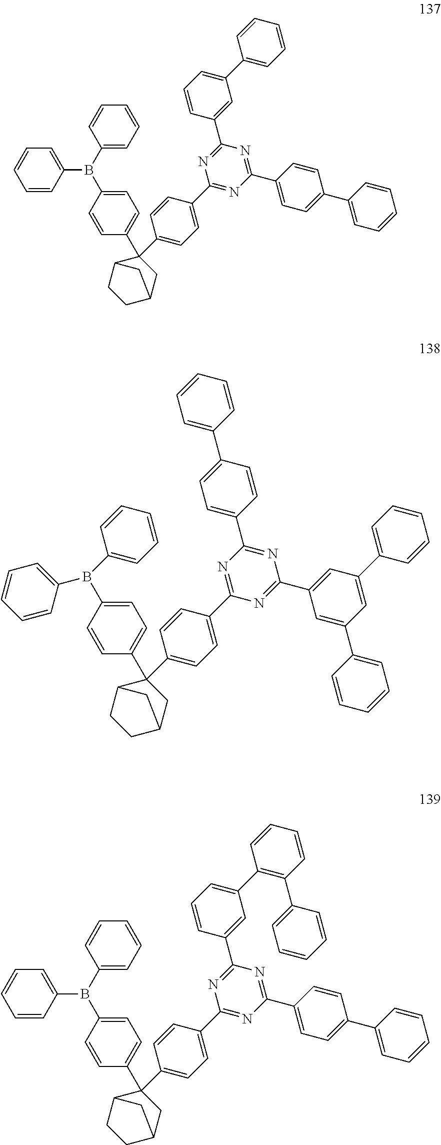 [SMILES: c1ccc(B(c2ccccc2)c2ccc(C3(c4ccc(-c5nc(-c6ccc(-c7ccccc7)cc6)nc(-c6cccc(-c7ccccc7)c6)n5)cc4)CC4CCC3C4)cc2)cc1 ; c1ccc(B(c2ccccc2)c2ccc(C3(c4ccc(-c5nc(-c6ccc(-c7ccccc7)cc6)nc(-c6cc(-c7ccccc7)cc(-c7ccccc7)c6)n5)cc4)CC4CCC3C4)cc2)cc1 ; c1ccc(B(c2ccccc2)c2ccc(C3(c4ccc(-c5nc(-c6ccc(-c7ccccc7)cc6)nc(-c6cccc(-c7ccccc7-c7ccccc7)c6)n5)cc4)CC4CCC3C4)cc2)cc1] 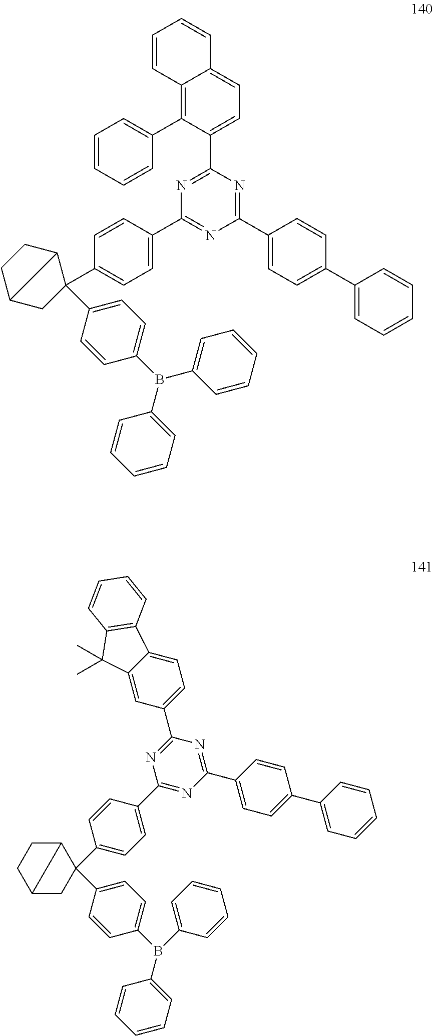 [SMILES: c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)CC4CCC3C4)cc2)cc1 ; CC1(C)c2ccccc2-c2ccc(-c3nc(-c4ccc(-c5ccccc5)cc4)nc(-c4ccc(C5(c6ccc(B(c7ccccc7)c7ccccc7)cc6)CC6CCC65)cc4)n3)cc21] 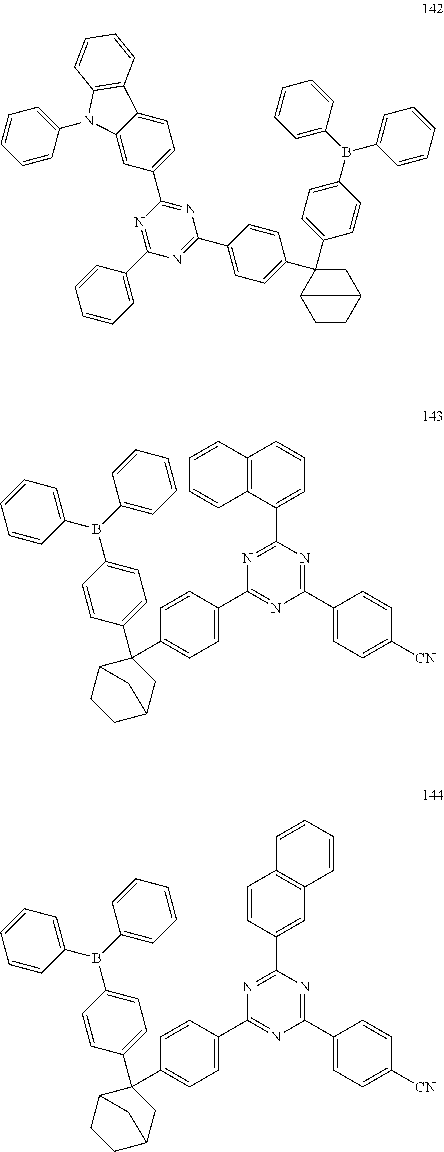 [SMILES: c1ccc(B(c2ccccc2)c2ccc(C3(c4ccc(-c5nc(-c6ccccc6)nc(-c6ccc7c8ccccc8n(-c8ccccc8)c7c6)n5)cc4)CC4CCC43)cc2)cc1 ; N#Cc1ccc(-c2nc(-c3ccc(C4(c5ccc(B(c6ccccc6)c6ccccc6)cc5)CC5CCC4C5)cc3)nc(-c3cccc4ccccc34)n2)cc1 ; N#Cc1ccc(-c2nc(-c3ccc(C4(c5ccc(B(c6ccccc6)c6ccccc6)cc5)CC5CCC4C5)cc3)nc(-c3ccc4ccccc4c3)n2)cc1] 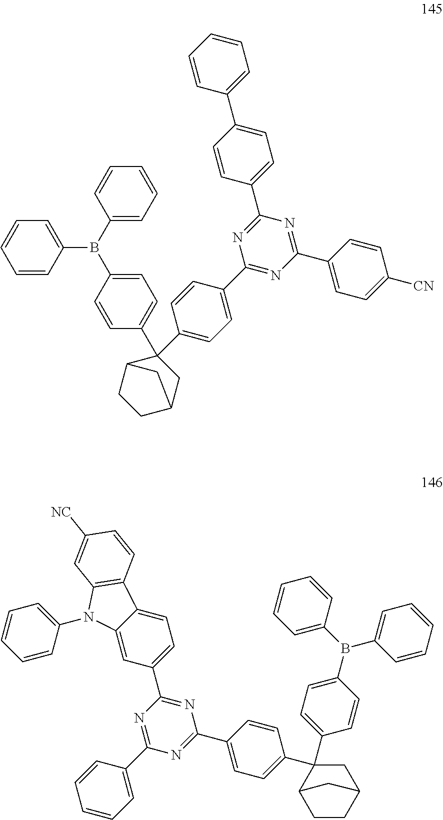 [SMILES: N#Cc1ccc(-c2nc(-c3ccc(-c4ccccc4)cc3)nc(-c3ccc(C4(c5ccc(B(c6ccccc6)c6ccccc6)cc5)CC5CCC4C5)cc3)n2)cc1 ; N#Cc1ccc2c3ccc(-c4nc(-c5ccccc5)nc(-c5ccc(C6(c7ccc(B(c8ccccc8)c8ccccc8)cc7)CC7CCC6C7)cc5)n4)cc3n(-c3ccccc3)c2c1] 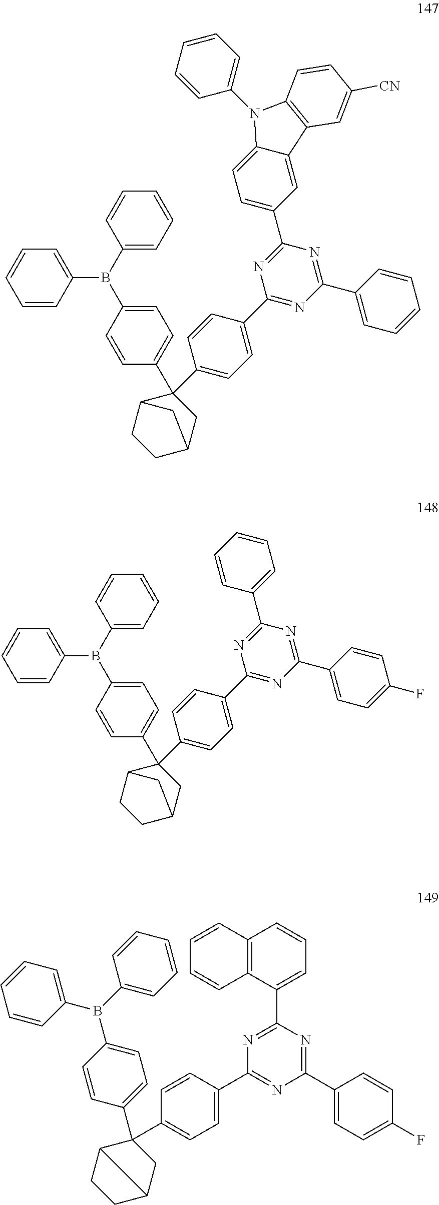 [SMILES: N#Cc1ccc2c(c1)c1cc(-c3nc(-c4ccccc4)nc(-c4ccc(C5(c6ccc(B(c7ccccc7)c7ccccc7)cc6)CC6CCC5C6)cc4)n3)ccc1n2-c1ccccc1 ; Fc1ccc(-c2nc(-c3ccccc3)nc(-c3ccc(C4(c5ccc(B(c6ccccc6)c6ccccc6)cc5)CC5CCC4C5)cc3)n2)cc1 ; Fc1ccc(-c2nc(-c3ccc(C4(c5ccc(B(c6ccccc6)c6ccccc6)cc5)CC5CCC54)cc3)nc(-c3cccc4ccccc34)n2)cc1] 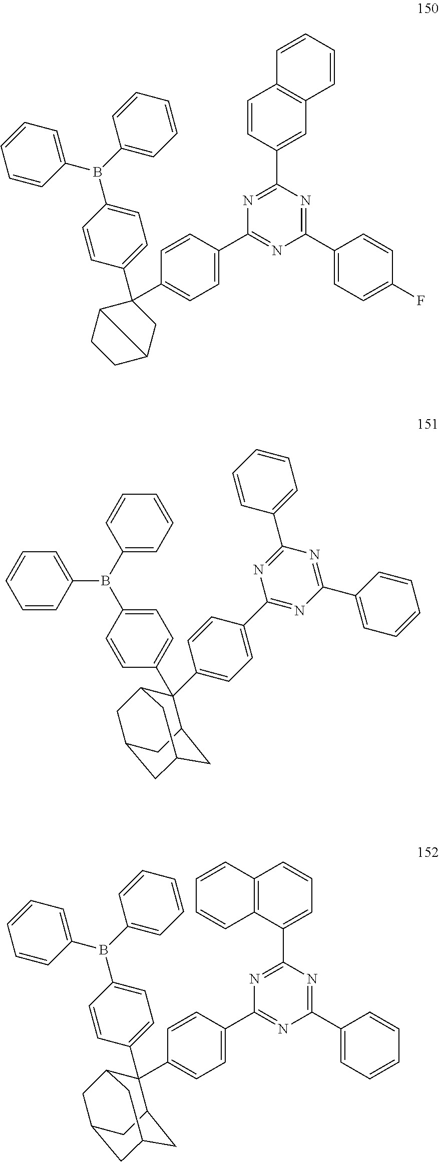 [SMILES: Fc1ccc(-c2nc(-c3ccc(C4(c5ccc(B(c6ccccc6)c6ccccc6)cc5)CC5CCC54)cc3)nc(-c3ccc4ccccc4c3)n2)cc1 ; c1ccc(B(c2ccccc2)c2ccc(C3(c4ccc(-c5nc(-c6ccccc6)nc(-c6ccccc6)n5)cc4)C4CC5CC(C4)CC3C5)cc2)cc1 ; c1ccc(B(c2ccccc2)c2ccc(C3(c4ccc(-c5nc(-c6ccccc6)nc(-c6cccc7ccccc67)n5)cc4)C4CC5CC(C4)CC3C5)cc2)cc1] 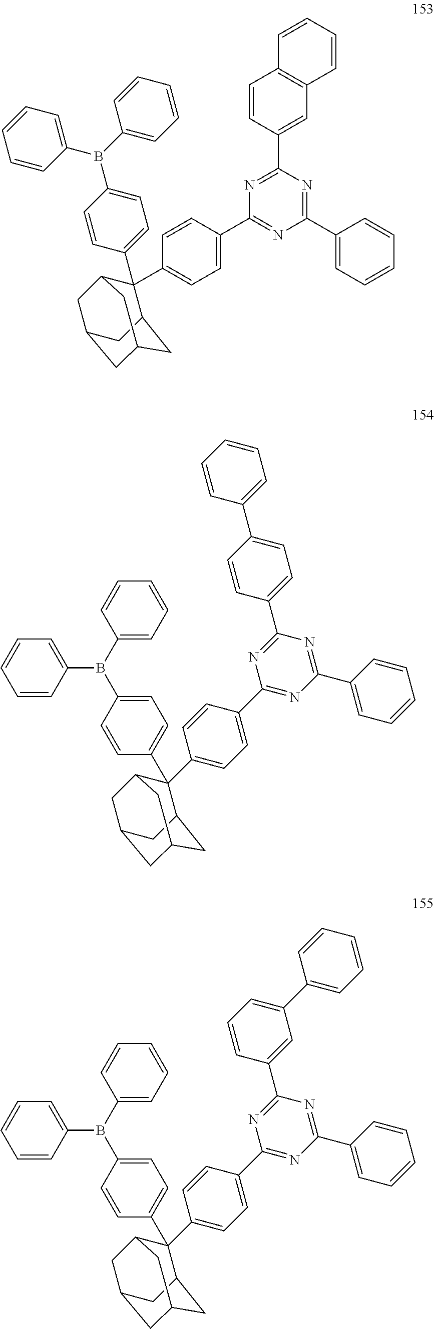 [SMILES: c1ccc(B(c2ccccc2)c2ccc(C3(c4ccc(-c5nc(-c6ccccc6)nc(-c6ccc7ccccc7c6)n5)cc4)C4CC5CC(C4)CC3C5)cc2)cc1 ; c1ccc(B(c2ccccc2)c2ccc(C3(c4ccc(-c5nc(-c6ccccc6)nc(-c6ccc(-c7ccccc7)cc6)n5)cc4)C4CC5CC(C4)CC3C5)cc2)cc1 ; c1ccc(B(c2ccccc2)c2ccc(C3(c4ccc(-c5nc(-c6ccccc6)nc(-c6cccc(-c7ccccc7)c6)n5)cc4)C4CC5CC(C4)CC3C5)cc2)cc1] 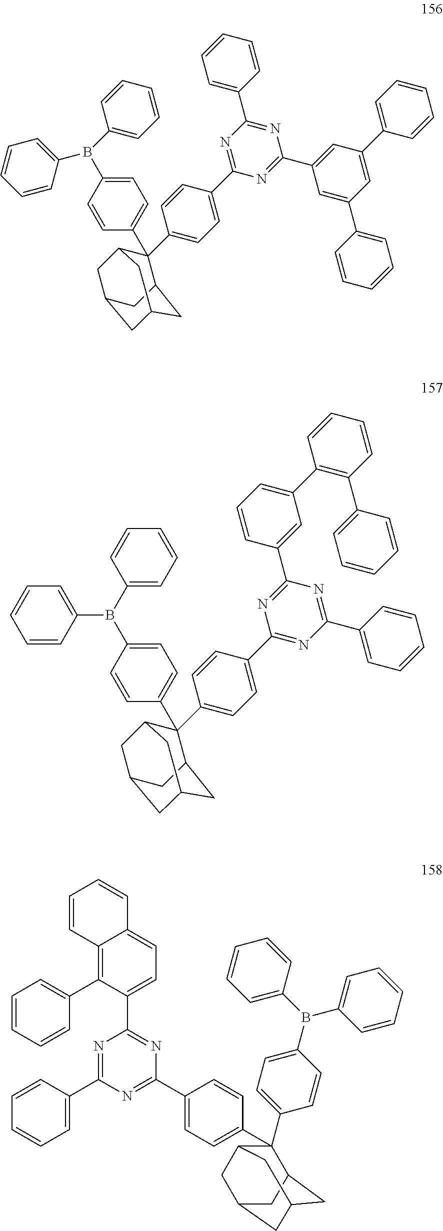 [SMILES: c1ccc(B(c2ccccc2)c2ccc(C3(c4ccc(-c5nc(-c6ccccc6)nc(-c6cc(-c7ccccc7)cc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccccc6)nc(-c6cccc(-c7ccccc7-c7ccccc7)c6)n5)cc4)C4CC5CC(C4)CC3C5)cc2)cc1 ; c1ccc(B(c2ccccc2)c2ccc(C3(c4ccc(-c5nc(-c6ccccc6)nc(-c6ccc7ccccc7c6-c6ccccc6)n5)cc4)C4CC5CC(C4)CC3C5)cc2)cc1] 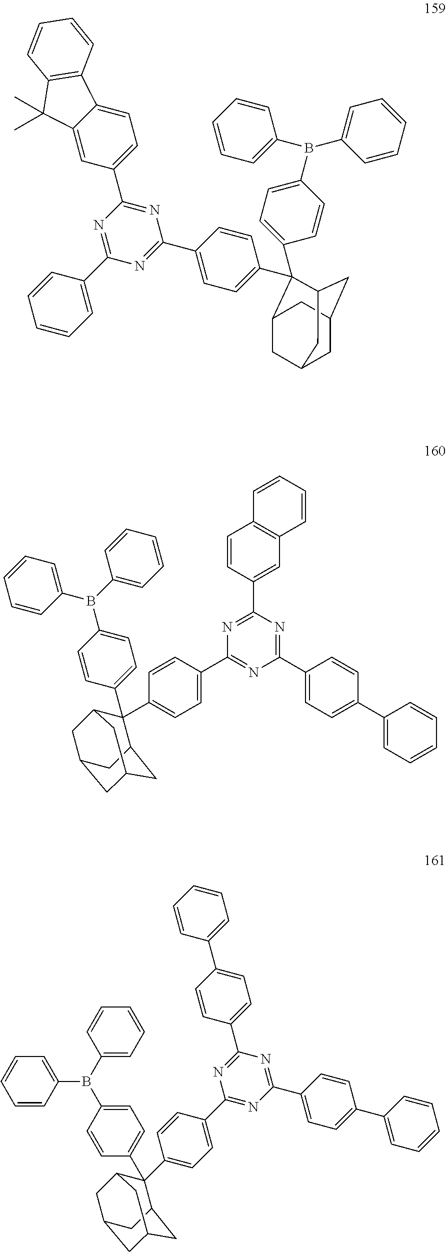 [SMILES: CC1(C)c2ccccc2-c2ccc(-c3nc(-c4ccccc4)nc(-c4ccc(C5(c6ccc(B(c7ccccc7)c7ccccc7)cc6)C6CC7CC(C6)CC5C7)cc4)n3)cc21 ; c1ccc(B(c2ccccc2)c2ccc(C3(c4ccc(-c5nc(-c6ccc(-c7ccccc7)cc6)nc(-c6ccc7ccccc7c6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6ccc(-c7ccccc7)cc6)n5)cc4)C4CC5CC(C4)CC3C5)cc2)cc1] 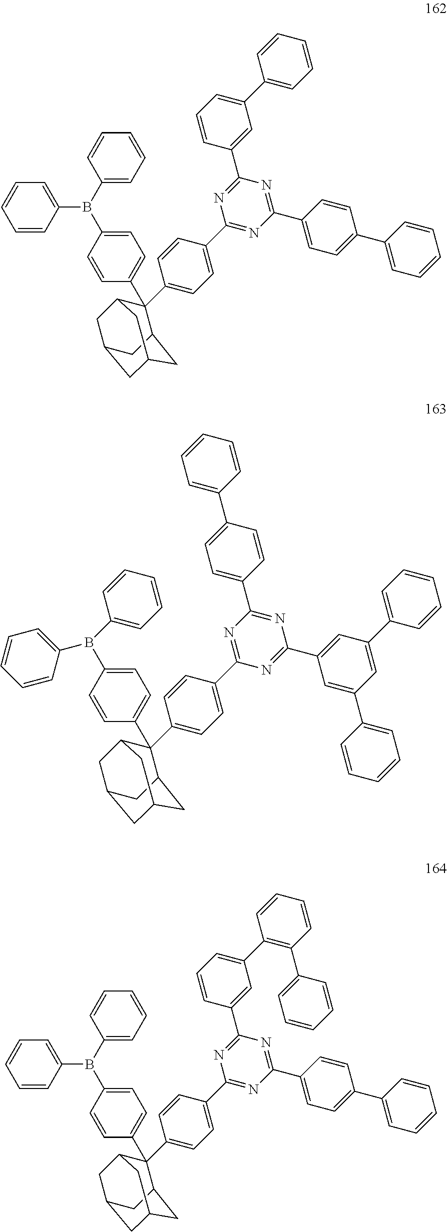 [SMILES: c1ccc(B(c2ccccc2)c2ccc(C3(c4ccc(-c5nc(-c6ccc(-c7ccccc7)cc6)nc(-c6cccc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6cc(-c7ccccc7)cc(-c7ccccc7)c6)n5)cc4)C4CC5CC(C4)CC3C5)cc2)cc1 ; c1ccc(B(c2ccccc2)c2ccc(C3(c4ccc(-c5nc(-c6ccc(-c7ccccc7)cc6)nc(-c6cccc(-c7ccccc7-c7ccccc7)c6)n5)cc4)C4CC5CC(C4)CC3C5)cc2)cc1] 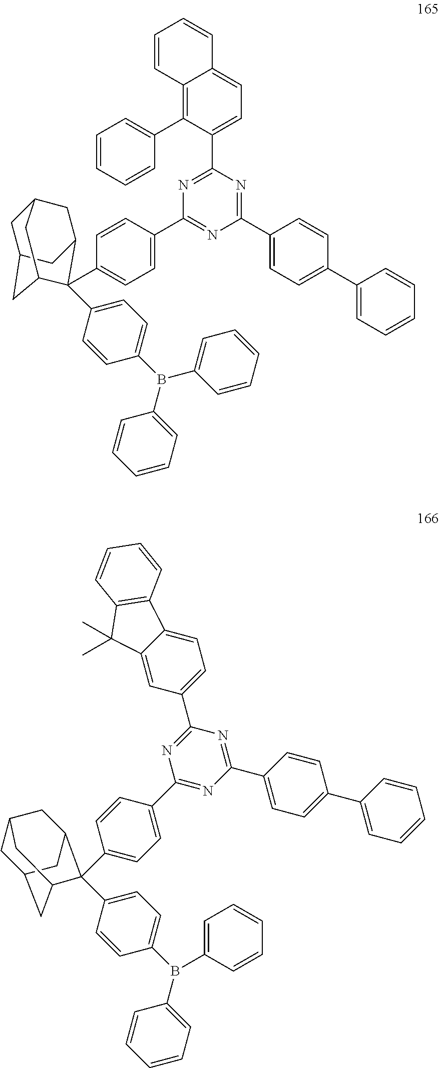 [SMILES: c1ccc(B(c2ccccc2)c2ccc(C3(c4ccc(-c5nc(-c6ccc(-c7ccccc7)cc6)nc(-c6ccc7ccccc7c6-c6ccccc6)n5)cc4)C4CC5CC(C4)CC3C5)cc2)cc1 ; CC1(C)c2ccccc2-c2ccc(-c3nc(-c4ccc(-c5ccccc5)cc4)nc(-c4ccc(C5(c6ccc(B(c7ccccc7)c7ccccc7)cc6)C6CC7CC(C6)CC5C7)cc4)n3)cc21] 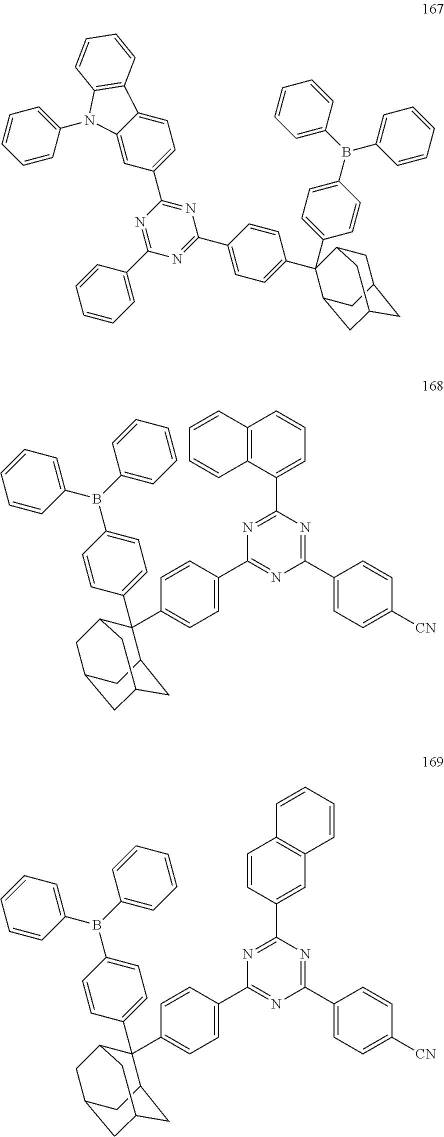 [SMILES: c1ccc(B(c2ccccc2)c2ccc(C3(c4ccc(-c5nc(-c6ccccc6)nc(-c6ccc7c8ccccc8n(-c8ccccc8)c7c6)n5)cc4)C4CC5CC(C4)CC3C5)cc2)cc1 ; N#Cc1ccc(-c2nc(-c3ccc(C4(c5ccc(B(c6ccccc6)c6ccccc6)cc5)C5CC6CC(C5)CC4C6)cc3)nc(-c3cccc4ccccc34)n2)cc1 ; N#Cc1ccc(-c2nc(-c3ccc(C4(c5ccc(B(c6ccccc6)c6ccccc6)cc5)C5CC6CC(C5)CC4C6)cc3)nc(-c3ccc4ccccc4c3)n2)cc1] 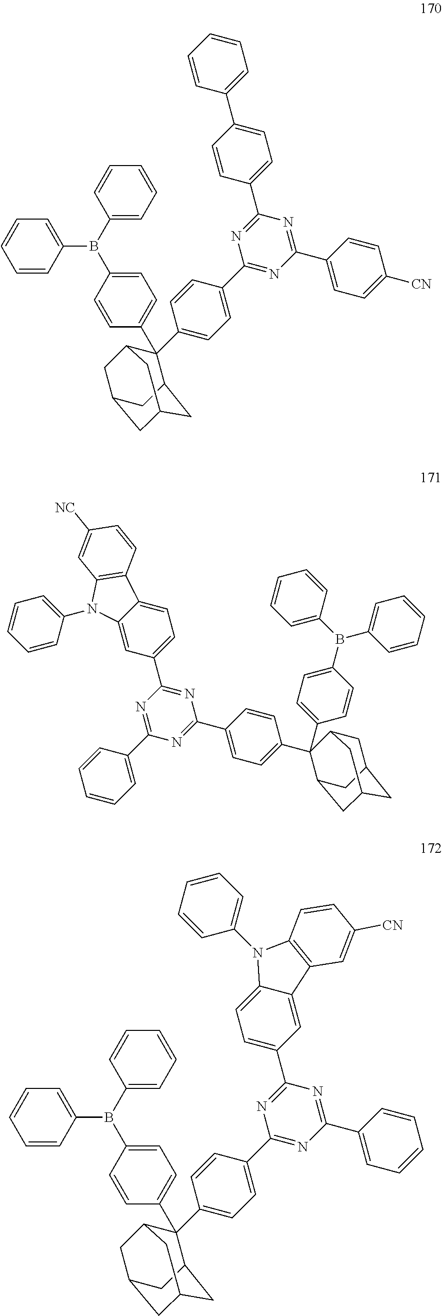 [SMILES: N#Cc1ccc(-c2nc(-c3ccc(-c4ccccc4)cc3)nc(-c3ccc(C4(c5ccc(B(c6ccccc6)c6ccccc6)cc5)C5CC6CC(C5)CC4C6)cc3)n2)cc1 ; N#Cc1ccc2c3ccc(-c4nc(-c5ccccc5)nc(-c5ccc(C6(c7ccc(B(c8ccccc8)c8ccccc8)cc7)C7CC8CC(C7)CC6C8)cc5)n4)cc3n(-c3ccccc3)c2c1 ; N#Cc1ccc2c(c1)c1cc(-c3nc(-c4ccccc4)nc(-c4ccc(C5(c6ccc(B(c7ccccc7)c7ccccc7)cc6)C6CC7CC(C6)CC5C7)cc4)n3)ccc1n2-c1ccccc1] 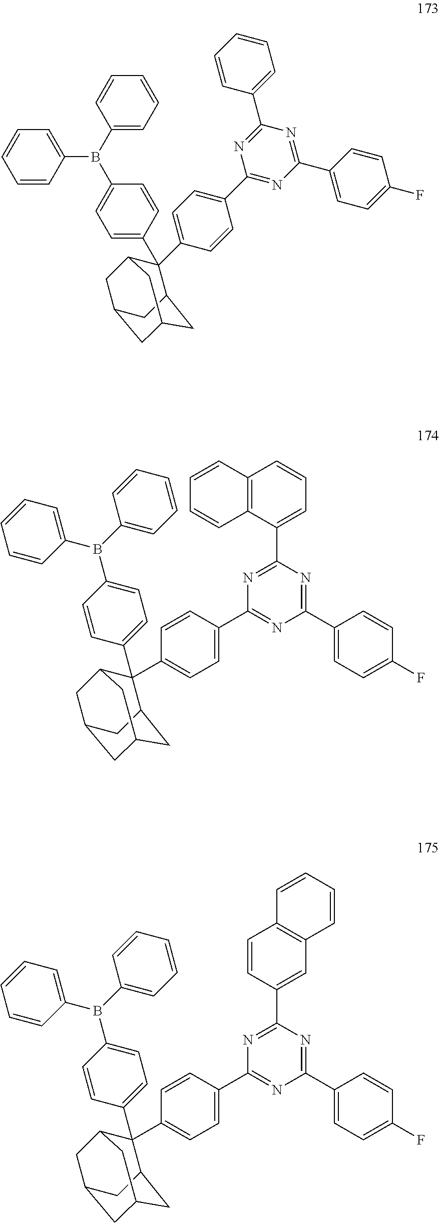 [SMILES: Fc1ccc(-c2nc(-c3ccccc3)nc(-c3ccc(C4(c5ccc(B(c6ccccc6)c6ccccc6)cc5)C5CC6CC(C5)CC4C6)cc3)n2)cc1 ; Fc1ccc(-c2nc(-c3ccc(C4(c5ccc(B(c6ccccc6)c6ccccc6)cc5)C5CC6CC(C5)CC4C6)cc3)nc(-c3cccc4ccccc34)n2)cc1 ; Fc1ccc(-c2nc(-c3ccc(C4(c5ccc(B(c6ccccc6)c6ccccc6)cc5)C5CC6CC(C5)CC4C6)cc3)nc(-c3ccc4ccccc4c3)n2)cc1] 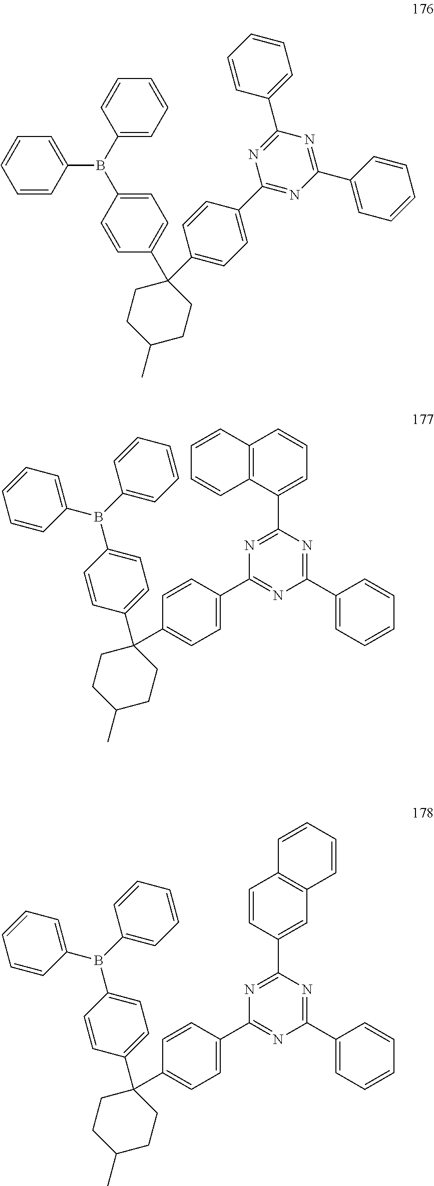 [SMILES: CC1CCC(c2ccc(B(c3ccccc3)c3ccccc3)cc2)(c2ccc(-c3nc(-c4ccccc4)nc(-c4ccccc4)n3)cc2)CC1 ; CC1CCC(c2ccc(B(c3ccccc3)c3ccccc3)cc2)(c2ccc(-c3nc(-c4ccccc4)nc(-c4cccc5ccccc45)n3)cc2)CC1 ; CC1CCC(c2ccc(B(c3ccccc3)c3ccccc3)cc2)(c2ccc(-c3nc(-c4ccccc4)nc(-c4ccc5ccccc5c4)n3)cc2)CC1] 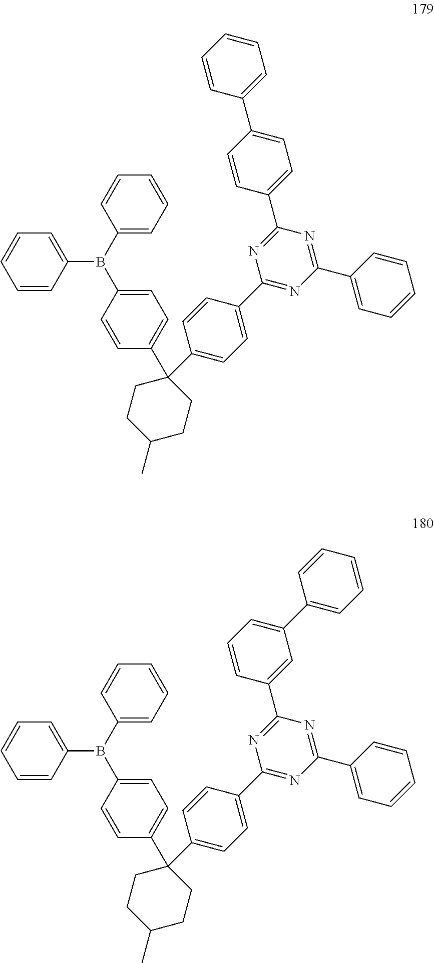 [SMILES: CC1CCC(c2ccc(B(c3ccccc3)c3ccccc3)cc2)(c2ccc(-c3nc(-c4ccccc4)nc(-c4ccc(-c5ccccc5)cc4)n3)cc2)CC1 ; CC1CCC(c2ccc(B(c3ccccc3)c3ccccc3)cc2)(c2ccc(-c3nc(-c4ccccc4)nc(-c4cccc(-c5ccccc5)c4)n3)cc2)CC1] 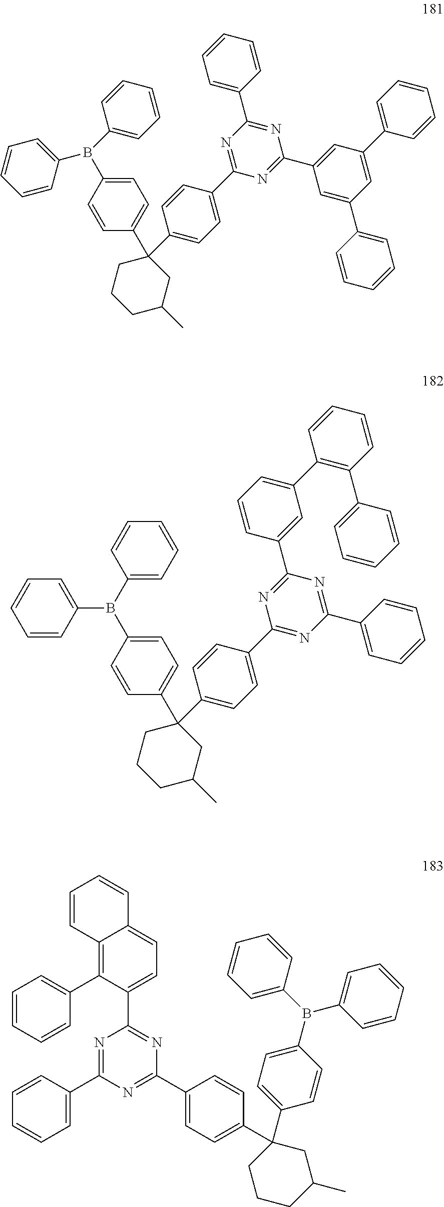 [SMILES: CC1CCCC(c2ccc(B(c3ccccc3)c3ccccc3)cc2)(c2ccc(-c3nc(-c4ccccc4)nc(-c4cc(-c5ccccc5)cc(-c5ccccc5)c4)n3)cc2)C1 ; CC1CCCC(c2ccc(B(c3ccccc3)c3ccccc3)cc2)(c2ccc(-c3nc(-c4ccccc4)nc(-c4cccc(-c5ccccc5-c5ccccc5)c4)n3)cc2)C1 ; CC1CCCC(c2ccc(B(c3ccccc3)c3ccccc3)cc2)(c2ccc(-c3nc(-c4ccccc4)nc(-c4ccc5ccccc5c4-c4ccccc4)n3)cc2)C1] 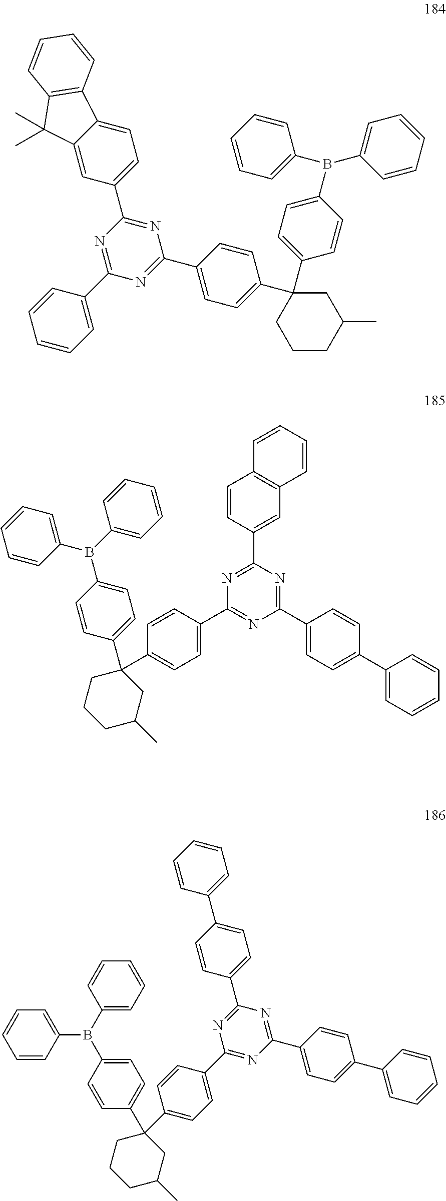 [SMILES: CC1CCCC(c2ccc(B(c3ccccc3)c3ccccc3)cc2)(c2ccc(-c3nc(-c4ccccc4)nc(-c4ccc5c(c4)C(C)(C)c4ccccc4-5)n3)cc2)C1 ; CC1CCCC(c2ccc(B(c3ccccc3)c3ccccc3)cc2)(c2ccc(-c3nc(-c4ccc(-c5ccccc5)cc4)nc(-c4ccc5ccccc5c4)n3)cc2)C1 ; CC1CCCC(c2ccc(B(c3ccccc3)c3ccccc3)cc2)(c2ccc(-c3nc(-c4ccc(-c5ccccc5)cc4)nc(-c4ccc(-c5ccccc5)cc4)n3)cc2)C1] 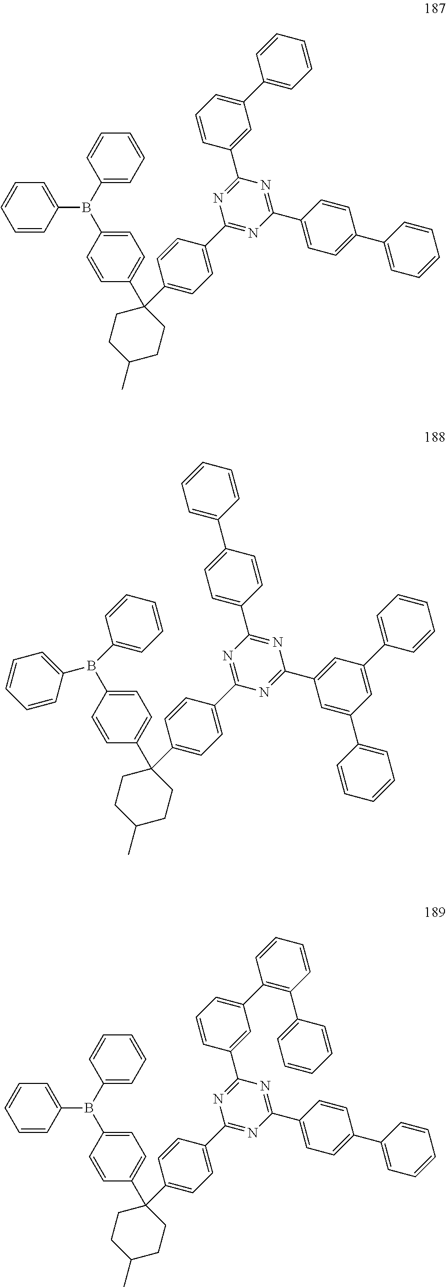 [SMILES: CC1CCC(c2ccc(B(c3ccccc3)c3ccccc3)cc2)(c2ccc(-c3nc(-c4ccc(-c5ccccc5)cc4)nc(-c4cccc(-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4cc(-c5ccccc5)cc(-c5ccccc5)c4)n3)cc2)CC1 ; CC1CCC(c2ccc(B(c3ccccc3)c3ccccc3)cc2)(c2ccc(-c3nc(-c4ccc(-c5ccccc5)cc4)nc(-c4cccc(-c5ccccc5-c5ccccc5)c4)n3)cc2)CC1] 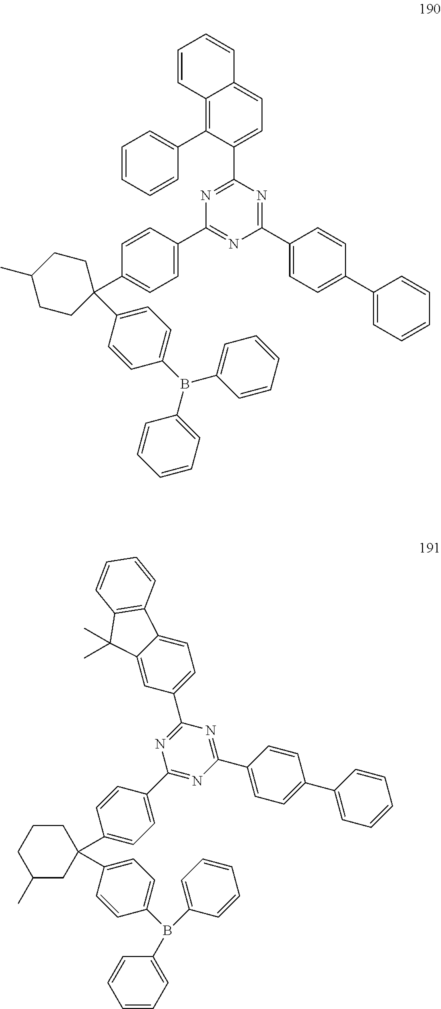 [SMILES: CC1CCC(c2ccc(B(c3ccccc3)c3ccccc3)cc2)(c2ccc(-c3nc(-c4ccc(-c5ccccc5)cc4)nc(-c4ccc5ccccc5c4-c4ccccc4)n3)cc2)CC1 ; CC1CCCC(c2ccc(B(c3ccccc3)c3ccccc3)cc2)(c2ccc(-c3nc(-c4ccc(-c5ccccc5)cc4)nc(-c4ccc5c(c4)C(C)(C)c4ccccc4-5)n3)cc2)C1] 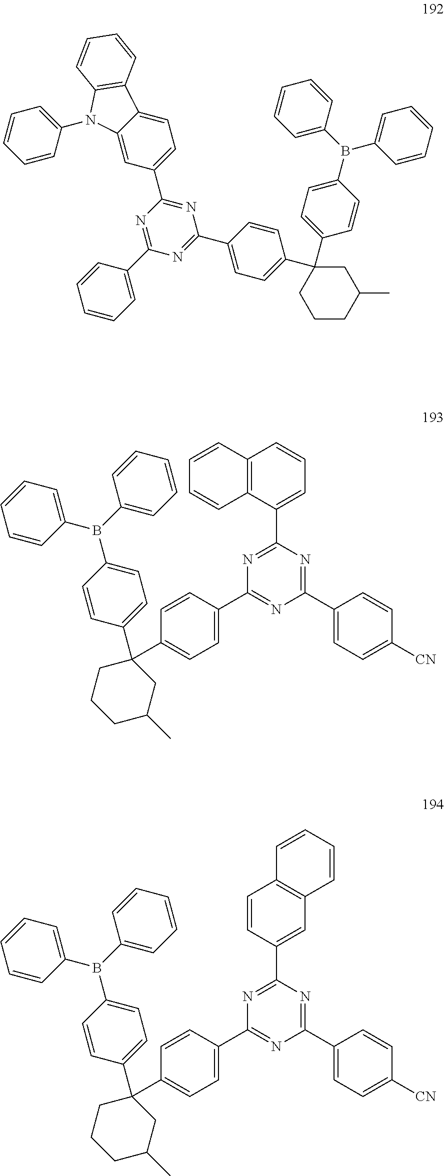 [SMILES: CC1CCCC(c2ccc(B(c3ccccc3)c3ccccc3)cc2)(c2ccc(-c3nc(-c4ccccc4)nc(-c4ccc5c6ccccc6n(-c6ccccc6)c5c4)n3)cc2)C1 ; CC1CCCC(c2ccc(B(c3ccccc3)c3ccccc3)cc2)(c2ccc(-c3nc(-c4ccc(C#N)cc4)nc(-c4cccc5ccccc45)n3)cc2)C1 ; CC1CCCC(c2ccc(B(c3ccccc3)c3ccccc3)cc2)(c2ccc(-c3nc(-c4ccc(C#N)cc4)nc(-c4ccc5ccccc5c4)n3)cc2)C1] 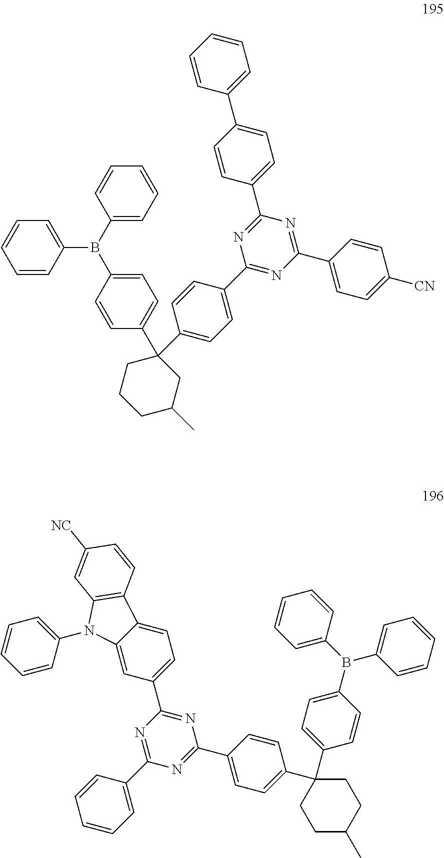 [SMILES: CC1CCCC(c2ccc(B(c3ccccc3)c3ccccc3)cc2)(c2ccc(-c3nc(-c4ccc(C#N)cc4)nc(-c4ccc(-c5ccccc5)cc4)n3)cc2)C1 ; CC1CCC(c2ccc(B(c3ccccc3)c3ccccc3)cc2)(c2ccc(-c3nc(-c4ccccc4)nc(-c4ccc5c6ccc(C#N)cc6n(-c6ccccc6)c5c4)n3)cc2)CC1] 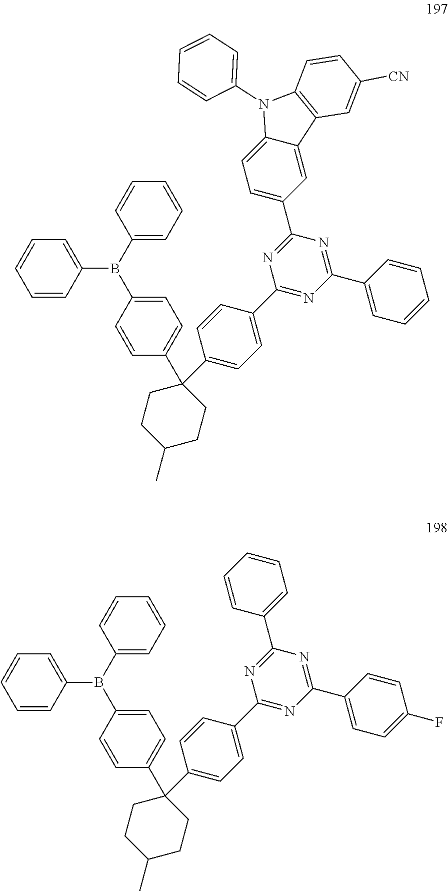 [SMILES: CC1CCC(c2ccc(B(c3ccccc3)c3ccccc3)cc2)(c2ccc(-c3nc(-c4ccccc4)nc(-c4ccc5c(c4)c4cc(C#N)ccc4n5-c4ccccc4)n3)cc2)CC1 ; CC1CCC(c2ccc(B(c3ccccc3)c3ccccc3)cc2)(c2ccc(-c3nc(-c4ccccc4)nc(-c4ccc(F)cc4)n3)cc2)CC1] 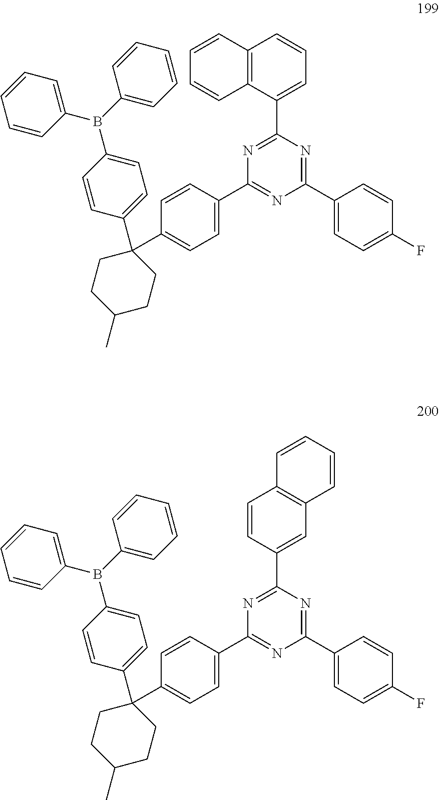 [SMILES: CC1CCC(c2ccc(B(c3ccccc3)c3ccccc3)cc2)(c2ccc(-c3nc(-c4ccc(F)cc4)nc(-c4cccc5ccccc45)n3)cc2)CC1 ; CC1CCC(c2ccc(B(c3ccccc3)c3ccccc3)cc2)(c2ccc(-c3nc(-c4ccc(F)cc4)nc(-c4ccc5ccccc5c4)n3)cc2)CC1] 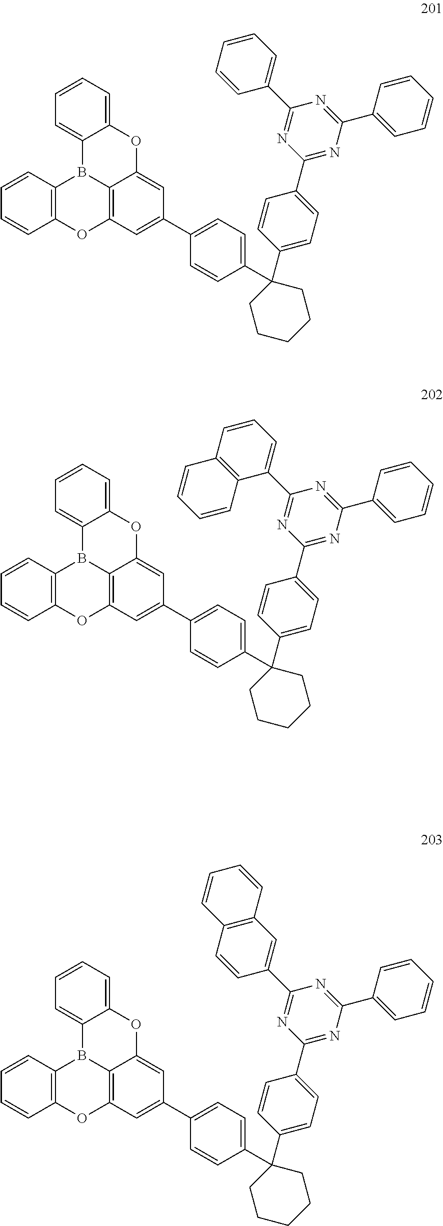 [SMILES: c1ccc(-c2nc(-c3ccccc3)nc(-c3ccc(C4(c5ccc(-c6cc7c8c(c6)Oc6ccccc6B8c6ccccc6O7)cc5)CCCCC4)cc3)n2)cc1 ; c1ccc(-c2nc(-c3ccc(C4(c5ccc(-c6cc7c8c(c6)Oc6ccccc6B8c6ccccc6O7)cc5)CCCCC4)cc3)nc(-c3cccc4ccccc34)n2)cc1 ; c1ccc(-c2nc(-c3ccc(C4(c5ccc(-c6cc7c8c(c6)Oc6ccccc6B8c6ccccc6O7)cc5)CCCCC4)cc3)nc(-c3ccc4ccccc4c3)n2)cc1] 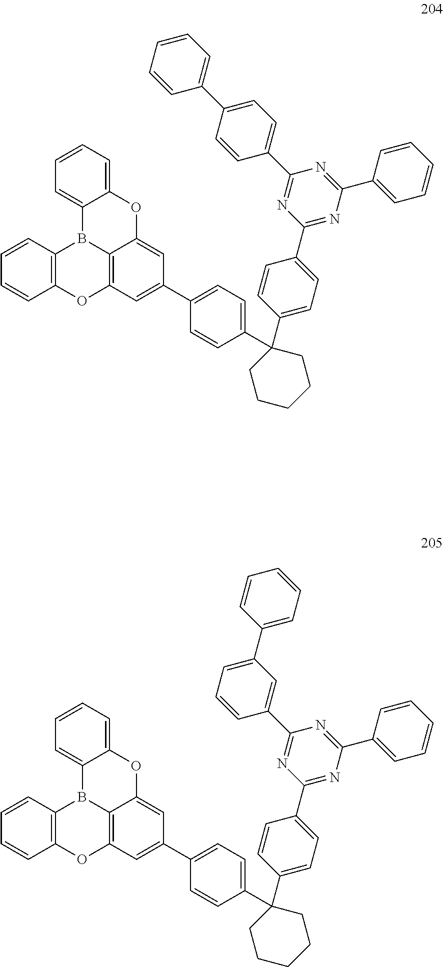 [SMILES: c1ccc(-c2ccc(-c3nc(-c4ccccc4)nc(-c4ccc(C5(c6ccc(-c7cc8c9c(c7)Oc7ccccc7B9c7ccccc7O8)cc6)CCCCC5)cc4)n3)cc2)cc1 ; c1ccc(-c2cccc(-c3nc(-c4ccccc4)nc(-c4ccc(C5(c6ccc(-c7cc8c9c(c7)Oc7ccccc7B9c7ccccc7O8)cc6)CCCCC5)cc4)n3)c2)cc1] 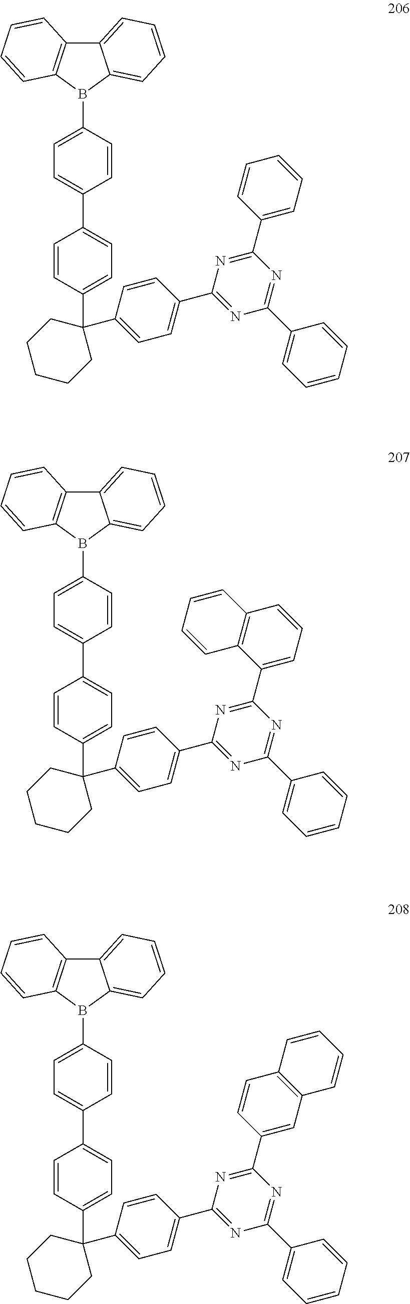 [SMILES: c1ccc(-c2nc(-c3ccccc3)nc(-c3ccc(C4(c5ccc(-c6ccc(B7c8ccccc8-c8ccccc87)cc6)cc5)CCCCC4)cc3)n2)cc1 ; c1ccc(-c2nc(-c3ccc(C4(c5ccc(-c6ccc(B7c8ccccc8-c8ccccc87)cc6)cc5)CCCCC4)cc3)nc(-c3cccc4ccccc34)n2)cc1 ; c1ccc(-c2nc(-c3ccc(C4(c5ccc(-c6ccc(B7c8ccccc8-c8ccccc87)cc6)cc5)CCCCC4)cc3)nc(-c3ccc4ccccc4c3)n2)cc1] 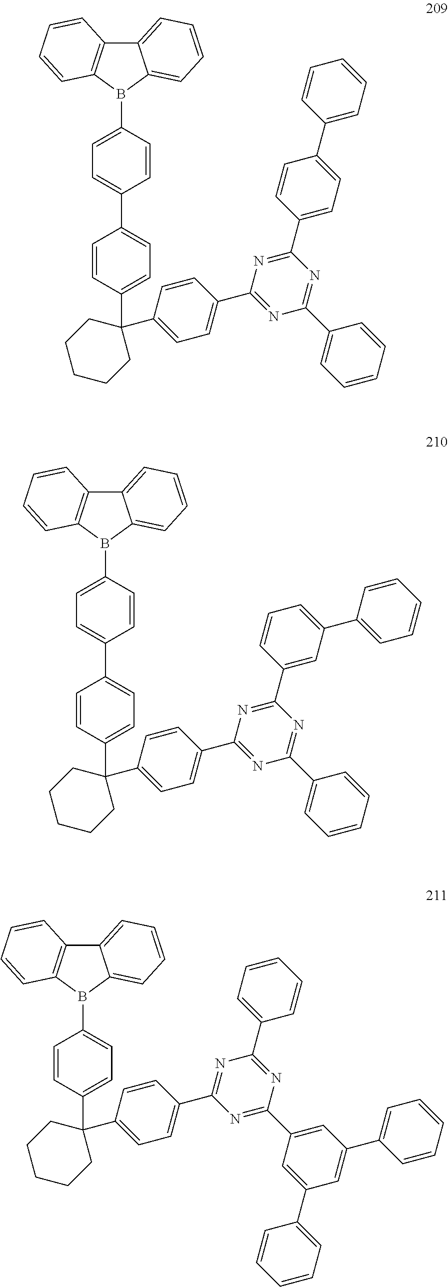 [SMILES: c1ccc(-c2ccc(-c3nc(-c4ccccc4)nc(-c4ccc(C5(c6ccc(-c7ccc(B8c9ccccc9-c9ccccc98)cc7)cc6)CCCCC5)cc4)n3)cc2)cc1 ; c1ccc(-c2cccc(-c3nc(-c4ccccc4)nc(-c4ccc(C5(c6ccc(-c7ccc(B8c9ccccc9-c9ccccc98)cc7)cc6)CCCCC5)cc4)n3)c2)cc1 ; c1ccc(-c2cc(-c3ccccc3)cc(-c3nc(-c4ccccc4)nc(-c4ccc(C5(c6ccc(B7c8ccccc8-c8ccccc87)cc6)CCCCC5)cc4)n3)c2)cc1] 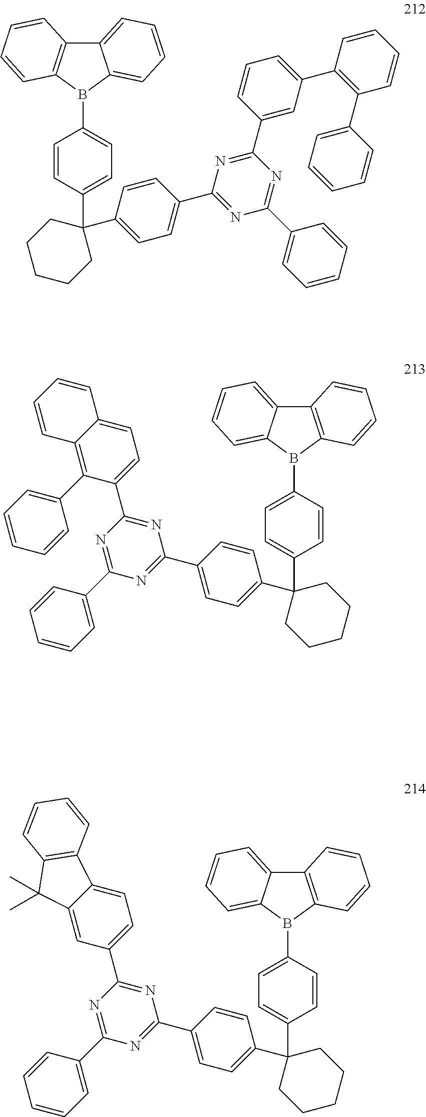 [SMILES: c1ccc(-c2nc(-c3ccc(C4(c5ccc(B6c7ccccc7-c7ccccc76)cc5)CCCCC4)cc3)nc(-c3cccc(-c4ccccc4-c4ccccc4)c3)n2)cc1 ; c1ccc(-c2nc(-c3ccc(C4(c5ccc(B6c7ccccc7-c7ccccc76)cc5)CCCCC4)cc3)nc(-c3ccc4ccccc4c3-c3ccccc3)n2)cc1 ; CC1(C)c2ccccc2-c2ccc(-c3nc(-c4ccccc4)nc(-c4ccc(C5(c6ccc(B7c8ccccc8-c8ccccc87)cc6)CCCCC5)cc4)n3)cc21] 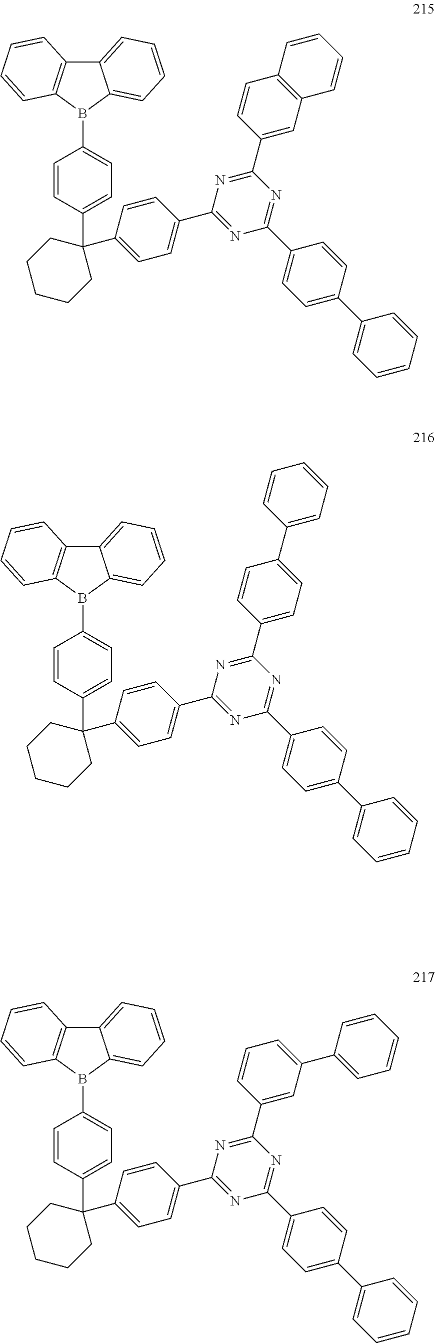 [SMILES: c1ccc(-c2ccc(-c3nc(-c4ccc(C5(c6ccc(B7c8ccccc8-c8ccccc87)cc6)CCCCC5)cc4)nc(-c4ccc5ccccc5c4)n3)cc2)cc1 ; c1ccc(-c2ccc(-c3nc(-c4ccc(-c5ccccc5)cc4)nc(-c4ccc(C5(c6ccc(B7c8ccccc8-c8ccccc87)cc6)CCCCC5)cc4)n3)cc2)cc1 ; c1ccc(-c2ccc(-c3nc(-c4ccc(C5(c6ccc(B7c8ccccc8-c8ccccc87)cc6)CCCCC5)cc4)nc(-c4cccc(-c5ccccc5)c4)n3)cc2)cc1] 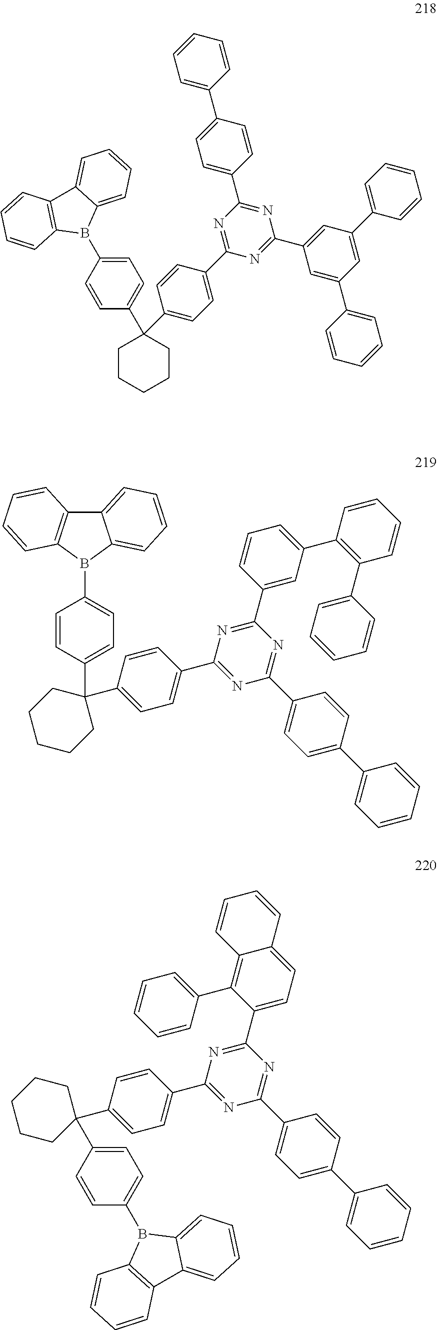 [SMILES: c1ccc(-c2ccc(-c3nc(-c4ccc(C5(c6ccc(B7c8ccccc8-c8ccccc87)cc6)CCCCC5)cc4)nc(-c4cc(-c5ccccc5)cc(-c5ccccc5)c4)n3)cc2)cc1 ; c1ccc(-c2ccc(-c3nc(-c4ccc(C5(c6ccc(B7c8ccccc8-c8ccccc87)cc6)CCCCC5)cc4)nc(-c4cccc(-c5ccccc5-c5ccccc5)c4)n3)cc2)cc1 ; c1ccc(-c2ccc(-c3nc(-c4ccc(C5(c6ccc(B7c8ccccc8-c8ccccc87)cc6)CCCCC5)cc4)nc(-c4ccc5ccccc5c4-c4ccccc4)n3)cc2)cc1] 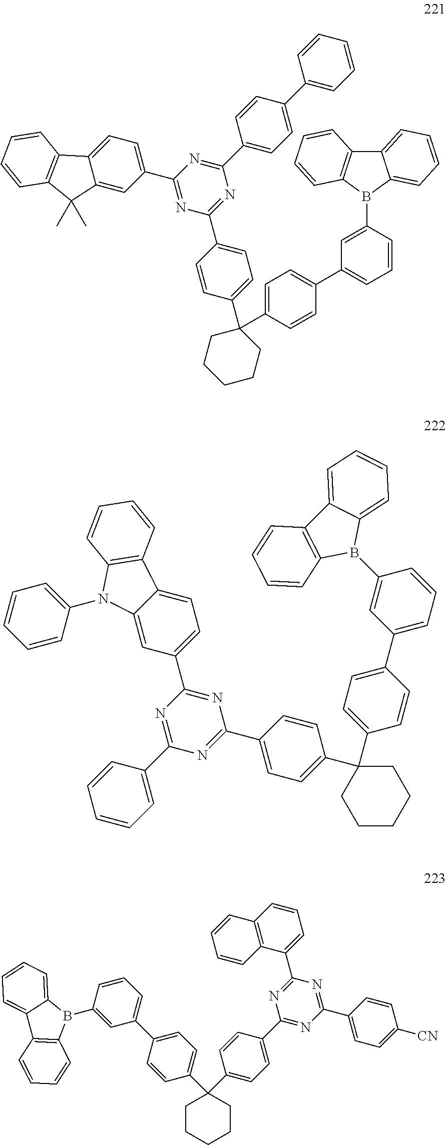 [SMILES: CC1(C)c2ccccc2-c2ccc(-c3nc(-c4ccc(-c5ccccc5)cc4)nc(-c4ccc(C5(c6ccc(-c7cccc(B8c9ccccc9-c9ccccc98)c7)cc6)CCCCC5)cc4)n3)cc21 ; c1ccc(-c2nc(-c3ccc(C4(c5ccc(-c6cccc(B7c8ccccc8-c8ccccc87)c6)cc5)CCCCC4)cc3)nc(-c3ccc4c5ccccc5n(-c5ccccc5)c4c3)n2)cc1 ; N#Cc1ccc(-c2nc(-c3ccc(C4(c5ccc(-c6cccc(B7c8ccccc8-c8ccccc87)c6)cc5)CCCCC4)cc3)nc(-c3cccc4ccccc34)n2)cc1] 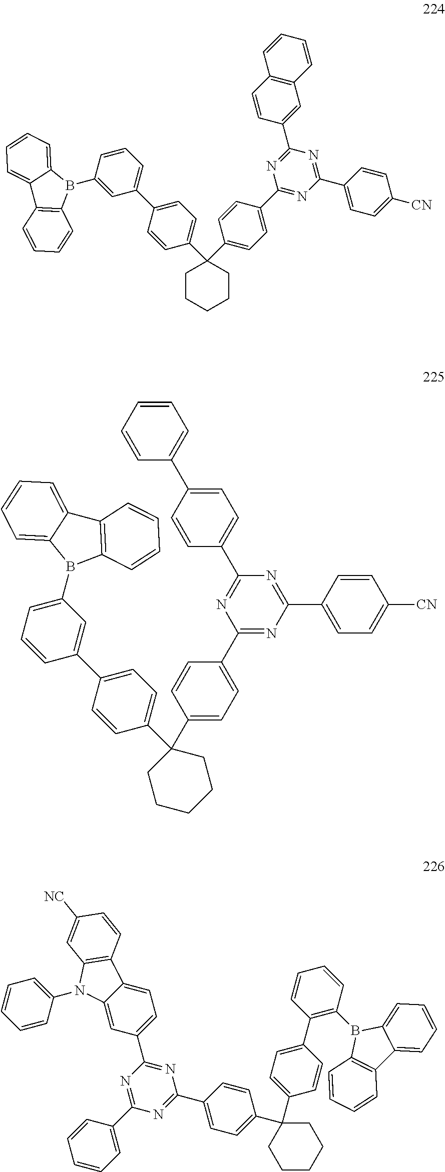 [SMILES: N#Cc1ccc(-c2nc(-c3ccc(C4(c5ccc(-c6cccc(B7c8ccccc8-c8ccccc87)c6)cc5)CCCCC4)cc3)nc(-c3ccc4ccccc4c3)n2)cc1 ; N#Cc1ccc(-c2nc(-c3ccc(-c4ccccc4)cc3)nc(-c3ccc(C4(c5ccc(-c6cccc(B7c8ccccc8-c8ccccc87)c6)cc5)CCCCC4)cc3)n2)cc1 ; N#Cc1ccc2c3ccc(-c4nc(-c5ccccc5)nc(-c5ccc(C6(c7ccc(-c8ccccc8B8c9ccccc9-c9ccccc98)cc7)CCCCC6)cc5)n4)cc3n(-c3ccccc3)c2c1] 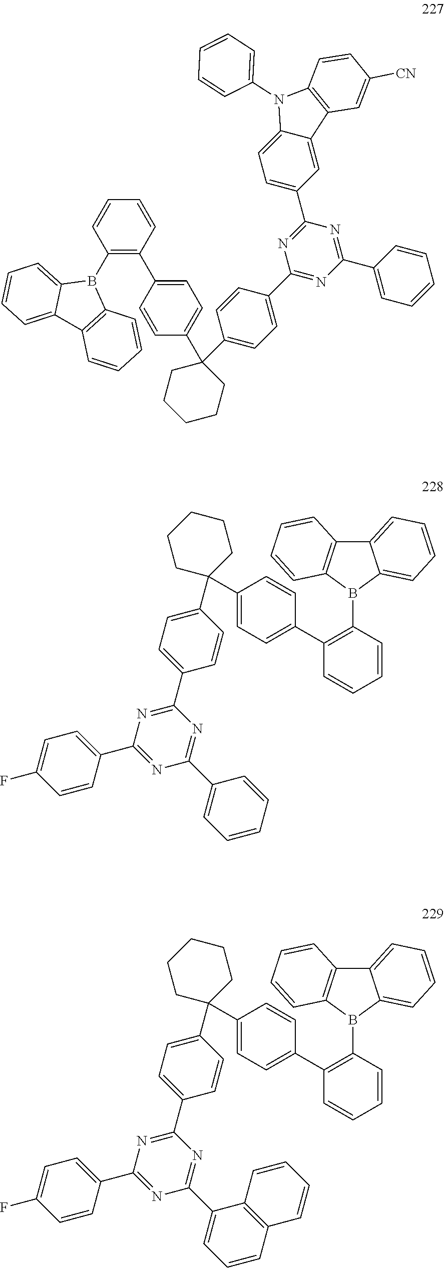 [SMILES: N#Cc1ccc2c(c1)c1cc(-c3nc(-c4ccccc4)nc(-c4ccc(C5(c6ccc(-c7ccccc7B7c8ccccc8-c8ccccc87)cc6)CCCCC5)cc4)n3)ccc1n2-c1ccccc1 ; Fc1ccc(-c2nc(-c3ccccc3)nc(-c3ccc(C4(c5ccc(-c6ccccc6B6c7ccccc7-c7ccccc76)cc5)CCCCC4)cc3)n2)cc1 ; Fc1ccc(-c2nc(-c3ccc(C4(c5ccc(-c6ccccc6B6c7ccccc7-c7ccccc76)cc5)CCCCC4)cc3)nc(-c3cccc4ccccc34)n2)cc1] 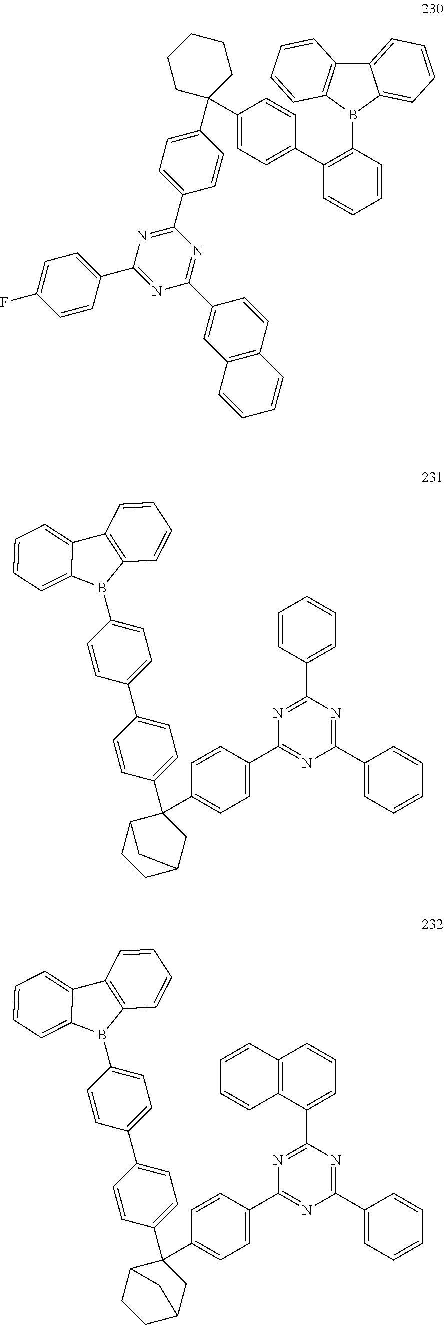 [SMILES: Fc1ccc(-c2nc(-c3ccc(C4(c5ccc(-c6ccccc6B6c7ccccc7-c7ccccc76)cc5)CCCCC4)cc3)nc(-c3ccc4ccccc4c3)n2)cc1 ; c1ccc(-c2nc(-c3ccccc3)nc(-c3ccc(C4(c5ccc(-c6ccc(B7c8ccccc8-c8ccccc87)cc6)cc5)CC5CCC4C5)cc3)n2)cc1 ; c1ccc(-c2nc(-c3ccc(C4(c5ccc(-c6ccc(B7c8ccccc8-c8ccccc87)cc6)cc5)CC5CCC4C5)cc3)nc(-c3cccc4ccccc34)n2)cc1] 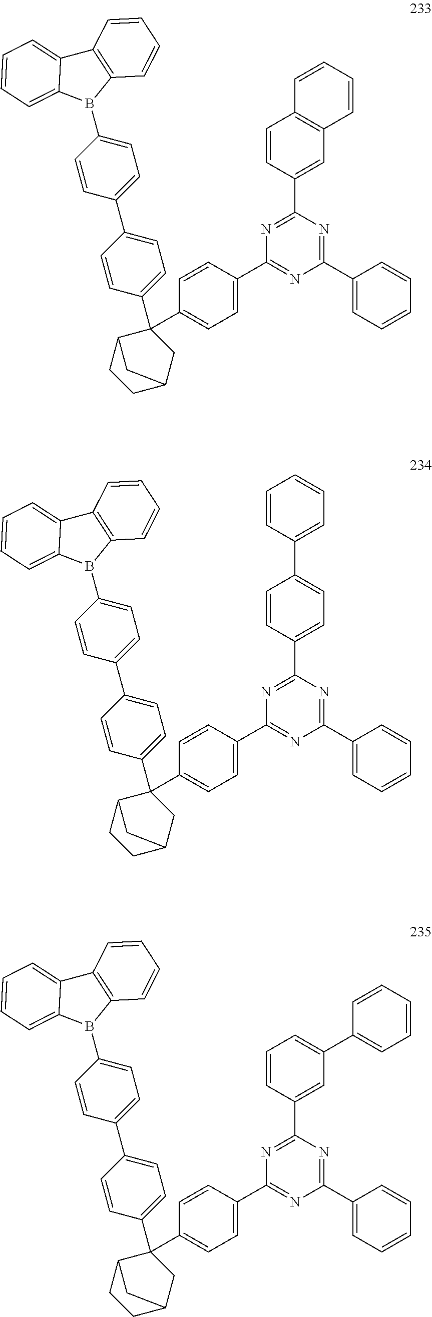 [SMILES: c1ccc(-c2nc(-c3ccc(C4(c5ccc(-c6ccc(B7c8ccccc8-c8ccccc87)cc6)cc5)CC5CCC4C5)cc3)nc(-c3ccc4ccccc4c3)n2)cc1 ; c1ccc(-c2ccc(-c3nc(-c4ccccc4)nc(-c4ccc(C5(c6ccc(-c7ccc(B8c9ccccc9-c9ccccc98)cc7)cc6)CC6CCC5C6)cc4)n3)cc2)cc1 ; c1ccc(-c2cccc(-c3nc(-c4ccccc4)nc(-c4ccc(C5(c6ccc(-c7ccc(B8c9ccccc9-c9ccccc98)cc7)cc6)CC6CCC5C6)cc4)n3)c2)cc1] 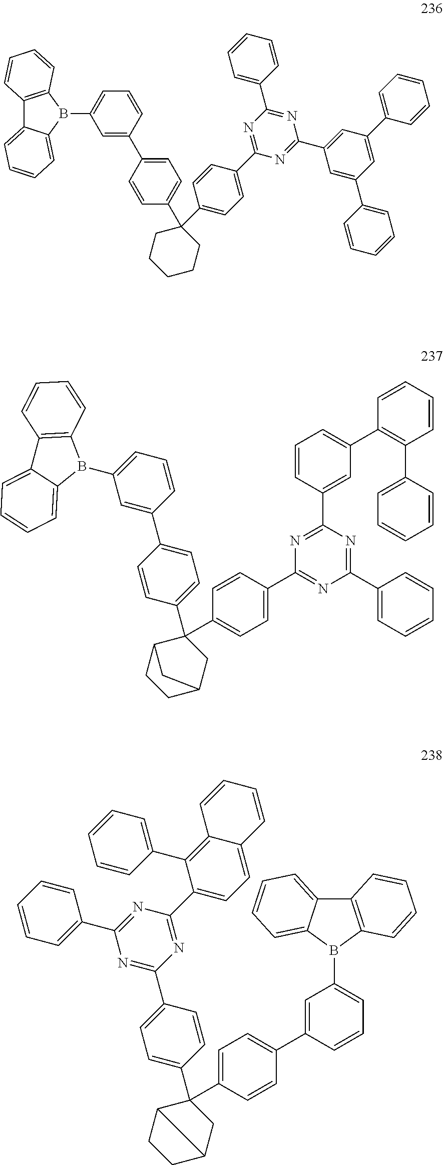 [SMILES: c1ccc(-c2cc(-c3ccccc3)cc(-c3nc(-c4ccccc4)nc(-c4ccc(C5(c6ccc(-c7cccc(B8c9ccccc9-c9ccccc98)c7)cc6)CCCCC5)cc4)n3)c2)cc1 ; c1ccc(-c2nc(-c3ccc(C4(c5ccc(-c6cccc(B7c8ccccc8-c8ccccc87)c6)cc5)CC5CCC4C5)cc3)nc(-c3cccc(-c4ccccc4-c4ccccc4)c3)n2)cc1 ; c1ccc(-c2nc(-c3ccc(C4(c5ccc(-c6cccc(B7c8ccccc8-c8ccccc87)c6)cc5)CC5CCC54)cc3)nc(-c3ccc4ccccc4c3-c3ccccc3)n2)cc1] 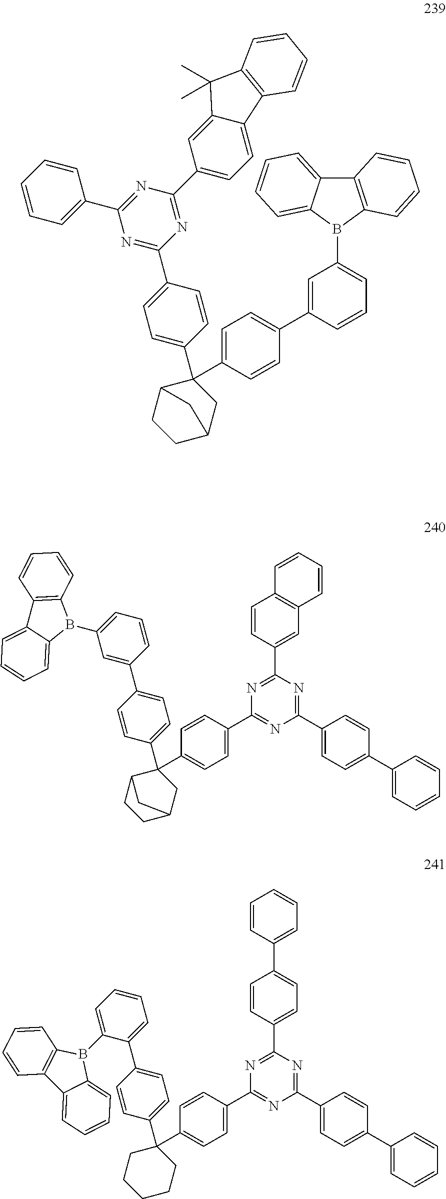 [SMILES: CC1(C)c2ccccc2-c2ccc(-c3nc(-c4ccccc4)nc(-c4ccc(C5(c6ccc(-c7cccc(B8c9ccccc9-c9ccccc98)c7)cc6)CC6CCC5C6)cc4)n3)cc21 ; c1ccc(-c2ccc(-c3nc(-c4ccc(C5(c6ccc(-c7cccc(B8c9ccccc9-c9ccccc98)c7)cc6)CC6CCC5C6)cc4)nc(-c4ccc5ccccc5c4)n3)cc2)cc1 ; c1ccc(-c2ccc(-c3nc(-c4ccc(-c5ccccc5)cc4)nc(-c4ccc(C5(c6ccc(-c7ccccc7B7c8ccccc8-c8ccccc87)cc6)CCCCC5)cc4)n3)cc2)cc1] 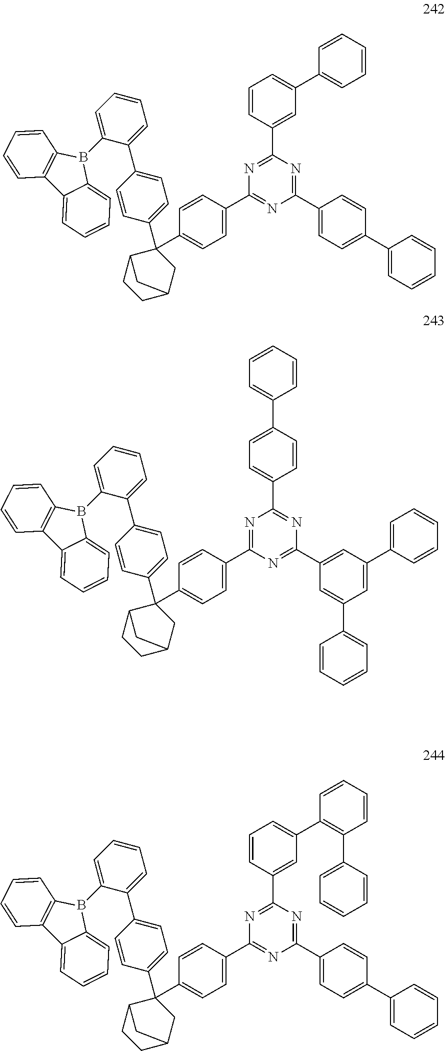 [SMILES: c1ccc(-c2ccc(-c3nc(-c4ccc(C5(c6ccc(-c7ccccc7B7c8ccccc8-c8ccccc87)cc6)CC6CCC5C6)cc4)nc(-c4cccc(-c5ccccc5)c4)n3)cc2)cc1 ; c1ccc(-c2ccc(-c3nc(-c4ccc(C5(c6ccc(-c7ccccc7B7c8ccccc8-c8ccccc87)cc6)CC6CCC5C6)cc4)nc(-c4cc(-c5ccccc5)cc(-c5ccccc5)c4)n3)cc2)cc1 ; c1ccc(-c2ccc(-c3nc(-c4ccc(C5(c6ccc(-c7ccccc7B7c8ccccc8-c8ccccc87)cc6)CC6CCC5C6)cc4)nc(-c4cccc(-c5ccccc5-c5ccccc5)c4)n3)cc2)cc1] 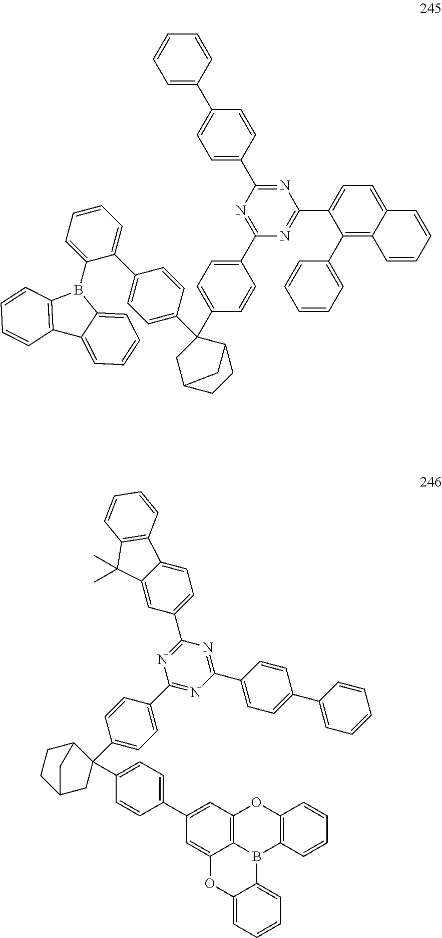 [SMILES: c1ccc(-c2ccc(-c3nc(-c4ccc(C5(c6ccc(-c7ccccc7B7c8ccccc8-c8ccccc87)cc6)CC6CCC5C6)cc4)nc(-c4ccc5ccccc5c4-c4ccccc4)n3)cc2)cc1 ; CC1(C)c2ccccc2-c2ccc(-c3nc(-c4ccc(-c5ccccc5)cc4)nc(-c4ccc(C5(c6ccc(-c7cc8c9c(c7)Oc7ccccc7B9c7ccccc7O8)cc6)CC6CCC5C6)cc4)n3)cc21] 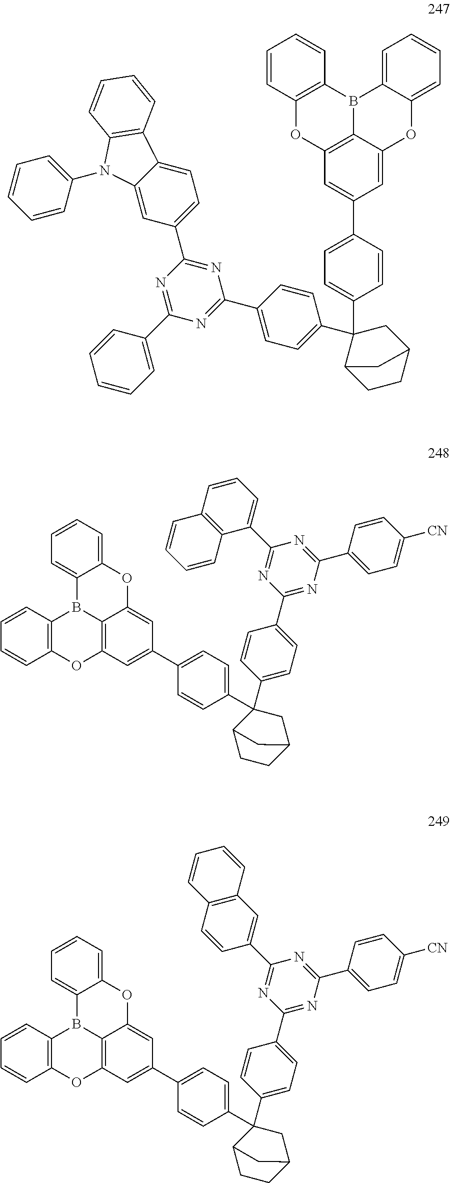 [SMILES: c1ccc(-c2nc(-c3ccc(C4(c5ccc(-c6cc7c8c(c6)Oc6ccccc6B8c6ccccc6O7)cc5)CC5CCC4C5)cc3)nc(-c3ccc4c5ccccc5n(-c5ccccc5)c4c3)n2)cc1 ; N#Cc1ccc(-c2nc(-c3ccc(C4(c5ccc(-c6cc7c8c(c6)Oc6ccccc6B8c6ccccc6O7)cc5)CC5CCC4C5)cc3)nc(-c3cccc4ccccc34)n2)cc1 ; N#Cc1ccc(-c2nc(-c3ccc(C4(c5ccc(-c6cc7c8c(c6)Oc6ccccc6B8c6ccccc6O7)cc5)CC5CCC4C5)cc3)nc(-c3ccc4ccccc4c3)n2)cc1] 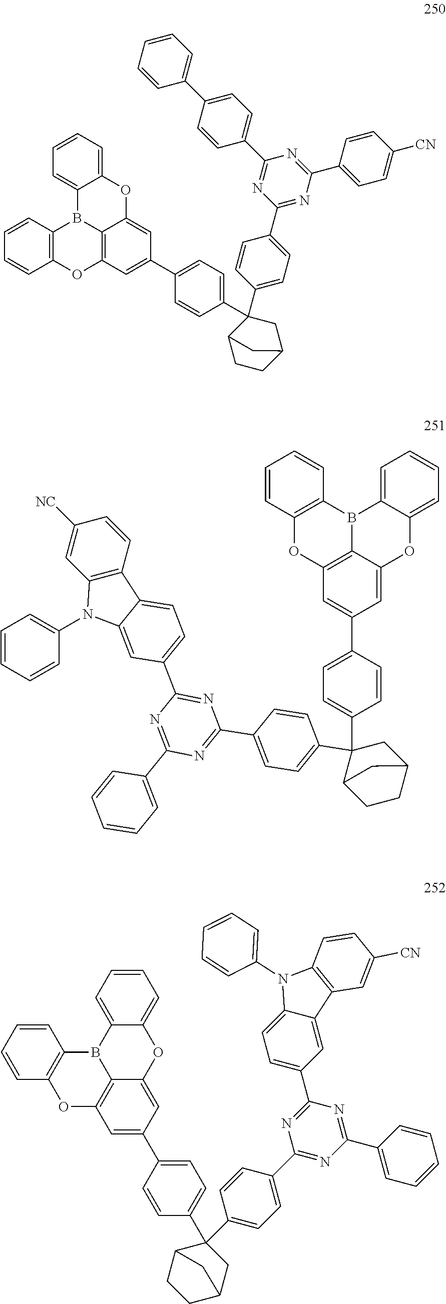 [SMILES: N#Cc1ccc(-c2nc(-c3ccc(-c4ccccc4)cc3)nc(-c3ccc(C4(c5ccc(-c6cc7c8c(c6)Oc6ccccc6B8c6ccccc6O7)cc5)CC5CCC4C5)cc3)n2)cc1 ; N#Cc1ccc2c3ccc(-c4nc(-c5ccccc5)nc(-c5ccc(C6(c7ccc(-c8cc9c%10c(c8)Oc8ccccc8B%10c8ccccc8O9)cc7)CC7CCC6C7)cc5)n4)cc3n(-c3ccccc3)c2c1 ; N#Cc1ccc2c(c1)c1cc(-c3nc(-c4ccccc4)nc(-c4ccc(C5(c6ccc(-c7cc8c9c(c7)Oc7ccccc7B9c7ccccc7O8)cc6)CC6CCC5C6)cc4)n3)ccc1n2-c1ccccc1] 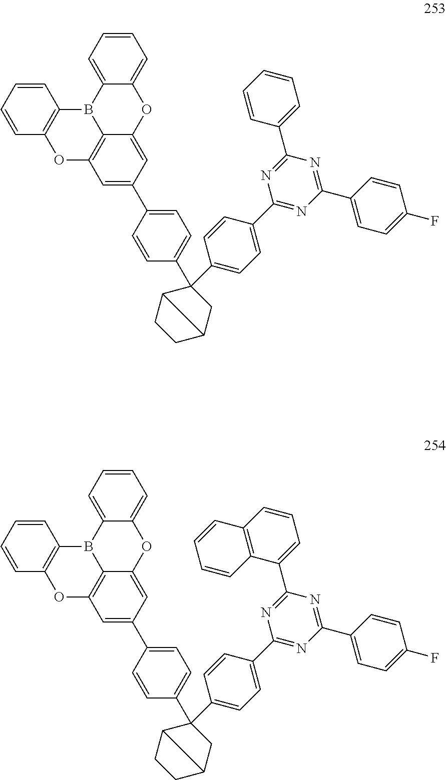 [SMILES: Fc1ccc(-c2nc(-c3ccccc3)nc(-c3ccc(C4(c5ccc(-c6cc7c8c(c6)Oc6ccccc6B8c6ccccc6O7)cc5)CC5CCC54)cc3)n2)cc1 ; Fc1ccc(-c2nc(-c3ccc(C4(c5ccc(-c6cc7c8c(c6)Oc6ccccc6B8c6ccccc6O7)cc5)CC5CCC54)cc3)nc(-c3cccc4ccccc34)n2)cc1] 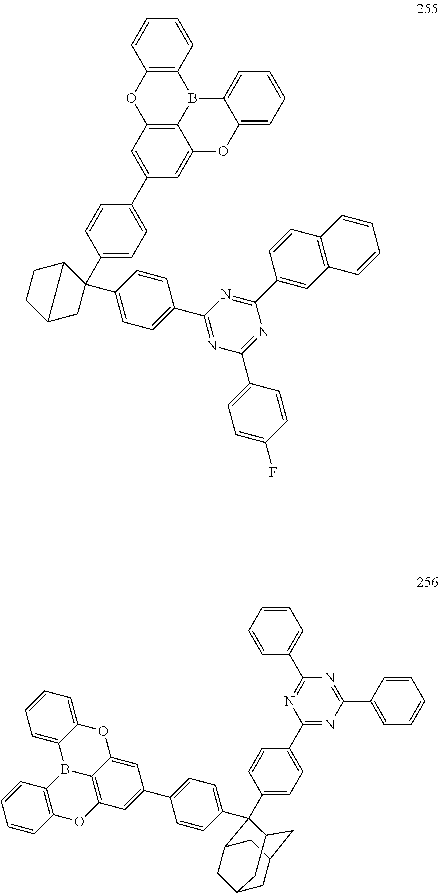 [SMILES: Fc1ccc(-c2nc(-c3ccc(C4(c5ccc(-c6cc7c8c(c6)Oc6ccccc6B8c6ccccc6O7)cc5)CC5CCC54)cc3)nc(-c3ccc4ccccc4c3)n2)cc1 ; c1ccc(-c2nc(-c3ccccc3)nc(-c3ccc(C4(c5ccc(-c6cc7c8c(c6)Oc6ccccc6B8c6ccccc6O7)cc5)C5CC6CC(C5)CC4C6)cc3)n2)cc1] 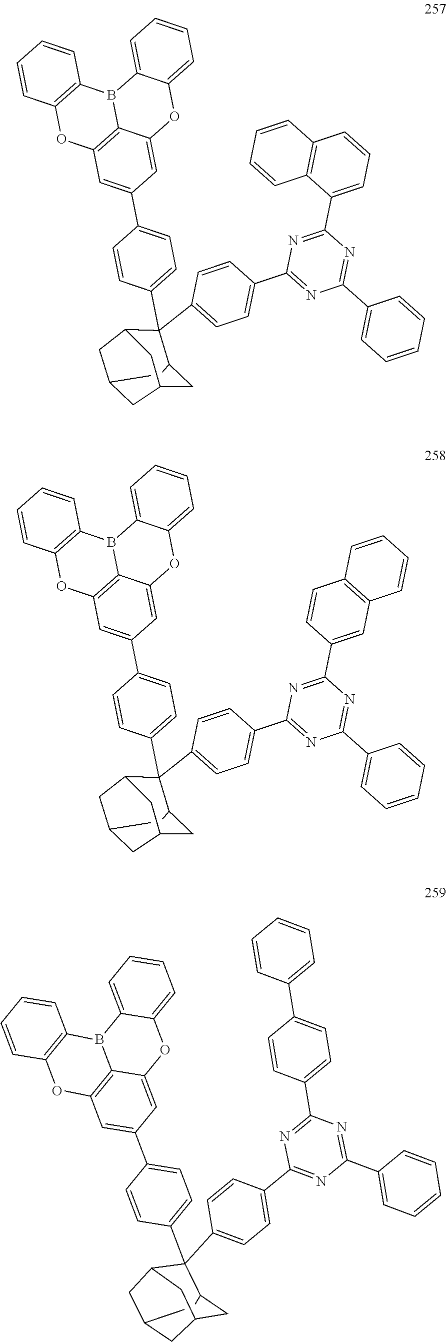 [SMILES: CC1CC2CC(C)C(c3ccc(-c4cc5c6c(c4)Oc4ccccc4B6c4ccccc4O5)cc3)(c3ccc(-c4nc(-c5ccccc5)nc(-c5cccc6ccccc56)n4)cc3)C(C1)C2 ; CC1CC2CC(C)C(c3ccc(-c4cc5c6c(c4)Oc4ccccc4B6c4ccccc4O5)cc3)(c3ccc(-c4nc(-c5ccccc5)nc(-c5ccc6ccccc6c5)n4)cc3)C(C1)C2 ; CC1CC2CC(C)C(c3ccc(-c4cc5c6c(c4)Oc4ccccc4B6c4ccccc4O5)cc3)(c3ccc(-c4nc(-c5ccccc5)nc(-c5ccc(-c6ccccc6)cc5)n4)cc3)C(C1)C2] 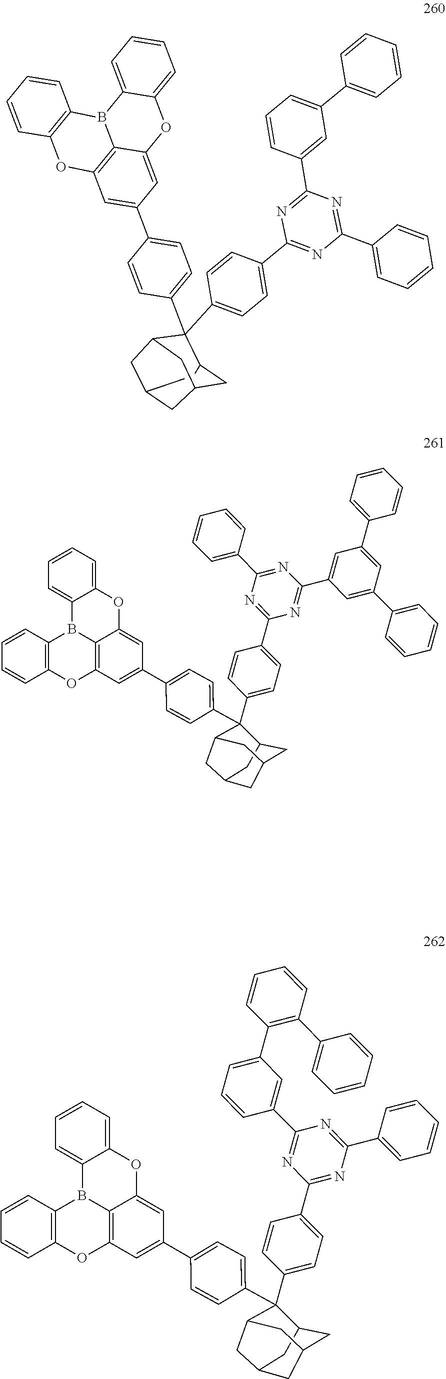 [SMILES: CC1CC2CC(C)C(c3ccc(-c4cc5c6c(c4)Oc4ccccc4B6c4ccccc4O5)cc3)(c3ccc(-c4nc(-c5ccccc5)nc(-c5cccc(-c6ccccc6)c5)n4)cc3)C(C1)C2 ; c1ccc(-c2cc(-c3ccccc3)cc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)c2)cc1 ; c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3cccc(-c4ccccc4-c4ccccc4)c3)n2)cc1] 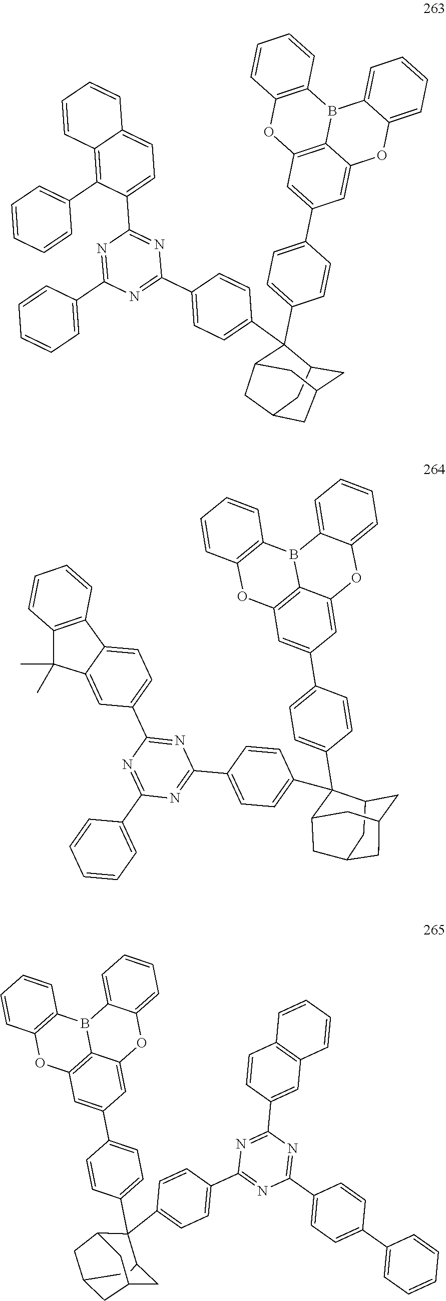 [SMILES: c1ccc(-c2nc(-c3ccc(C4(c5ccc(-c6cc7c8c(c6)Oc6ccccc6B8c6ccccc6O7)cc5)C5CC6CC(C5)CC4C6)cc3)nc(-c3ccc4ccccc4c3-c3ccccc3)n2)cc1 ; CC1(C)c2ccccc2-c2ccc(-c3nc(-c4ccccc4)nc(-c4ccc(C5(c6ccc(-c7cc8c9c(c7)Oc7ccccc7B9c7ccccc7O8)cc6)C6CC7CC(C6)CC5C7)cc4)n3)cc21 ; CC1CC2CC(C)C(c3ccc(-c4cc5c6c(c4)Oc4ccccc4B6c4ccccc4O5)cc3)(c3ccc(-c4nc(-c5ccc(-c6ccccc6)cc5)nc(-c5ccc6ccccc6c5)n4)cc3)C(C1)C2] 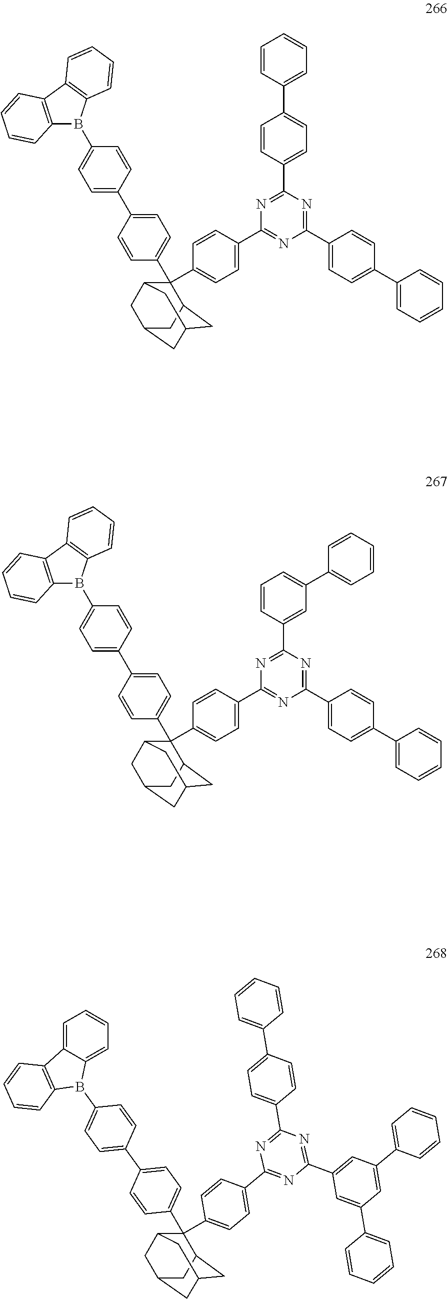 [SMILES: c1ccc(-c2ccc(-c3nc(-c4ccc(-c5ccccc5)cc4)nc(-c4ccc(C5(c6ccc(-c7ccc(B8c9ccccc9-c9ccccc98)cc7)cc6)C6CC7CC(C6)CC5C7)cc4)n3)cc2)cc1 ; c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cccc(-c5ccccc5)c4)n3)cc2)cc1 ; c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cc(-c5ccccc5)cc(-c5ccccc5)c4)n3)cc2)cc1] 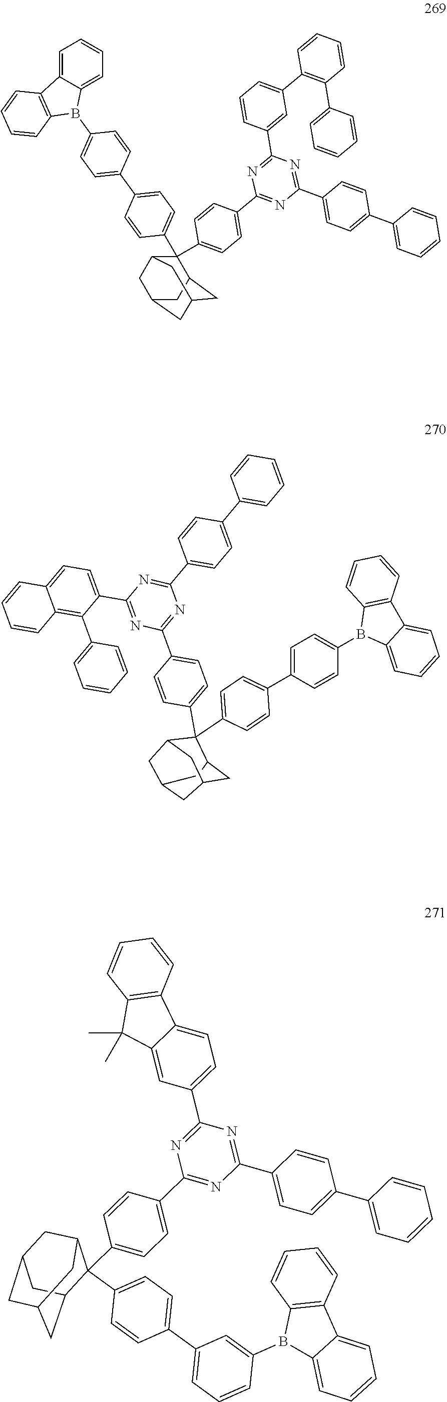 [SMILES: c1ccc(-c2ccc(-c3nc(-c4ccc(C5(c6ccc(-c7ccc(B8c9ccccc9-c9ccccc98)cc7)cc6)C6CC7CC(C6)CC5C7)cc4)nc(-c4cccc(-c5ccccc5-c5ccccc5)c4)n3)cc2)cc1 ; CC1CC2CC(C)C(c3ccc(-c4ccc(B5c6ccccc6-c6ccccc65)cc4)cc3)(c3ccc(-c4nc(-c5ccc(-c6ccccc6)cc5)nc(-c5ccc6ccccc6c5-c5ccccc5)n4)cc3)C(C1)C2 ; CC1(C)c2ccccc2-c2ccc(-c3nc(-c4ccc(-c5ccccc5)cc4)nc(-c4ccc(C5(c6ccc(-c7cccc(B8c9ccccc9-c9ccccc98)c7)cc6)C6CC7CC(C6)CC5C7)cc4)n3)cc21] 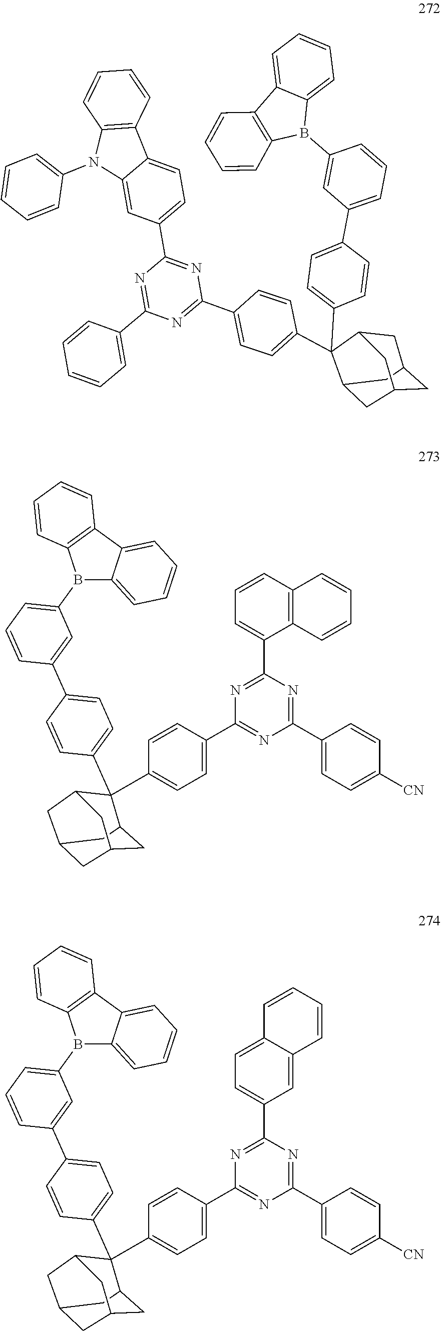 [SMILES: c1ccc(-c2nc(-c3ccc(C4(c5ccc(-c6cccc(B7c8ccccc8-c8ccccc87)c6)cc5)C5CC6CC(C5)CC4C6)cc3)nc(-c3ccc4c5ccccc5n(-c5ccccc5)c4c3)n2)cc1 ; N#Cc1ccc(-c2nc(-c3ccc(C4(c5ccc(-c6cccc(B7c8ccccc8-c8ccccc87)c6)cc5)C5CC6CC(C5)CC4C6)cc3)nc(-c3cccc4ccccc34)n2)cc1 ; N#Cc1ccc(-c2nc(-c3ccc(C4(c5ccc(-c6cccc(B7c8ccccc8-c8ccccc87)c6)cc5)C5CC6CC(C5)CC4C6)cc3)nc(-c3ccc4ccccc4c3)n2)cc1] 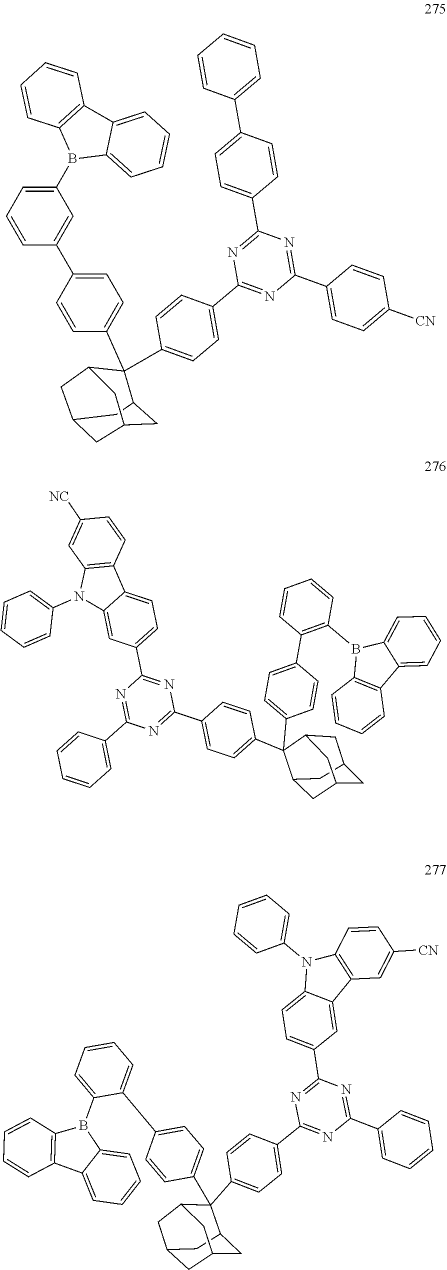 [SMILES: N#Cc1ccc(-c2nc(-c3ccc(-c4ccccc4)cc3)nc(-c3ccc(C4(c5ccc(-c6cccc(B7c8ccccc8-c8ccccc87)c6)cc5)C5CC6CC(C5)CC4C6)cc3)n2)cc1 ; N#Cc1ccc2c3ccc(-c4nc(-c5ccccc5)nc(-c5ccc(C6(c7ccc(-c8ccccc8B8c9ccccc9-c9ccccc98)cc7)C7CC8CC(C7)CC6C8)cc5)n4)cc3n(-c3ccccc3)c2c1 ; N#Cc1ccc2c(c1)c1cc(-c3nc(-c4ccccc4)nc(-c4ccc(C5(c6ccc(-c7ccccc7B7c8ccccc8-c8ccccc87)cc6)C6CC7CC(C6)CC5C7)cc4)n3)ccc1n2-c1ccccc1] 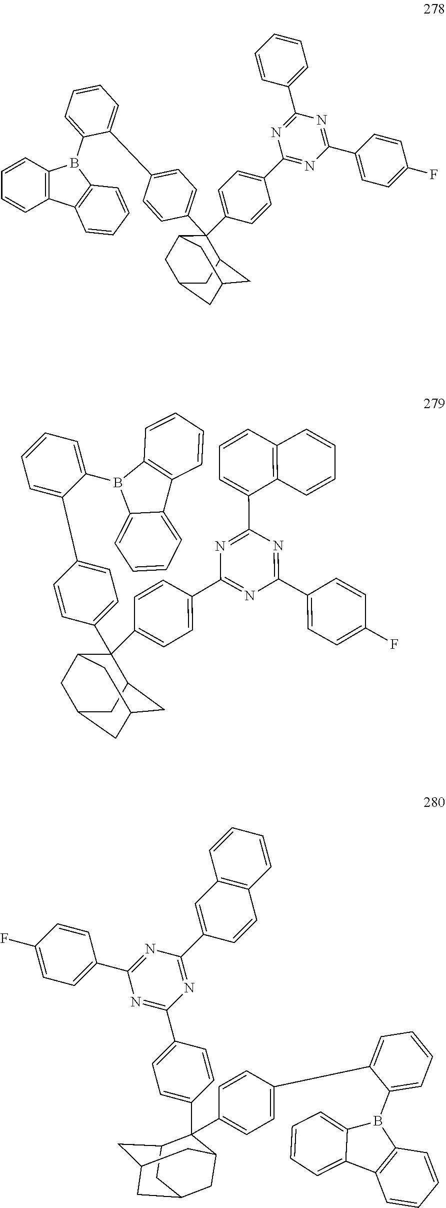 [SMILES: Fc1ccc(-c2nc(-c3ccccc3)nc(-c3ccc(C4(c5ccc(-c6ccccc6B6c7ccccc7-c7ccccc76)cc5)C5CC6CC(C5)CC4C6)cc3)n2)cc1 ; Fc1ccc(-c2nc(-c3ccc(C4(c5ccc(-c6ccccc6B6c7ccccc7-c7ccccc76)cc5)C5CC6CC(C5)CC4C6)cc3)nc(-c3cccc4ccccc34)n2)cc1 ; Fc1ccc(-c2nc(-c3ccc(C4(c5ccc(-c6ccccc6B6c7ccccc7-c7ccccc76)cc5)C5CC6CC(C5)CC4C6)cc3)nc(-c3ccc4ccccc4c3)n2)cc1] 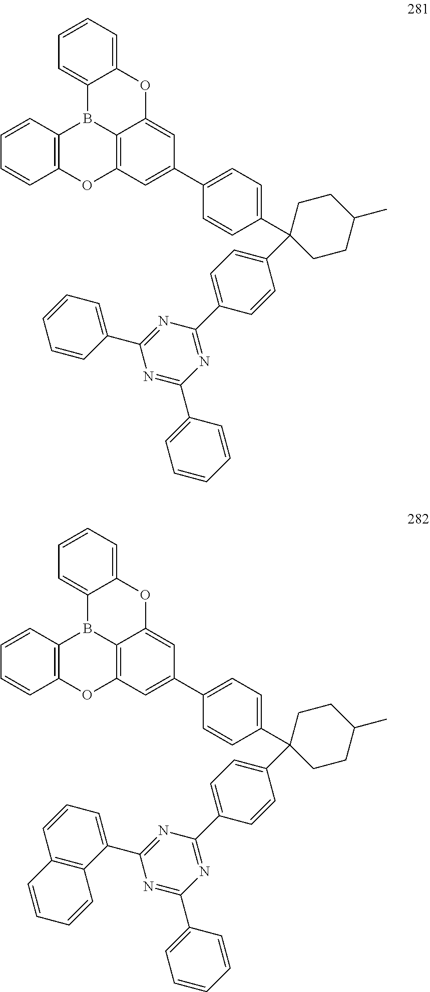 [SMILES: CC1CCC(c2ccc(-c3cc4c5c(c3)Oc3ccccc3B5c3ccccc3O4)cc2)(c2ccc(-c3nc(-c4ccccc4)nc(-c4ccccc4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4cccc5ccccc45)n3)cc2)CC1] 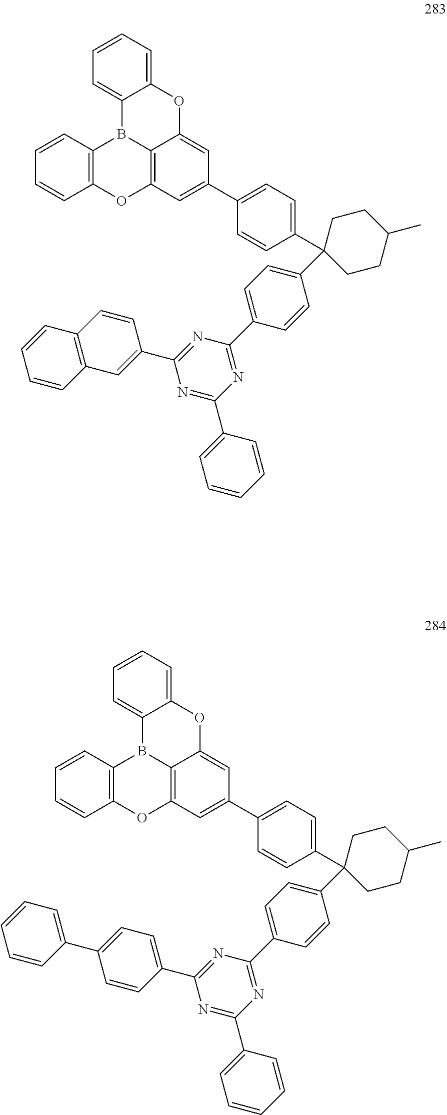 [SMILES: CC1CCC(c2ccc(-c3cc4c5c(c3)Oc3ccccc3B5c3ccccc3O4)cc2)(c2ccc(-c3nc(-c4ccccc4)nc(-c4ccc5ccccc5c4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4ccc(-c5ccccc5)cc4)n3)cc2)CC1] 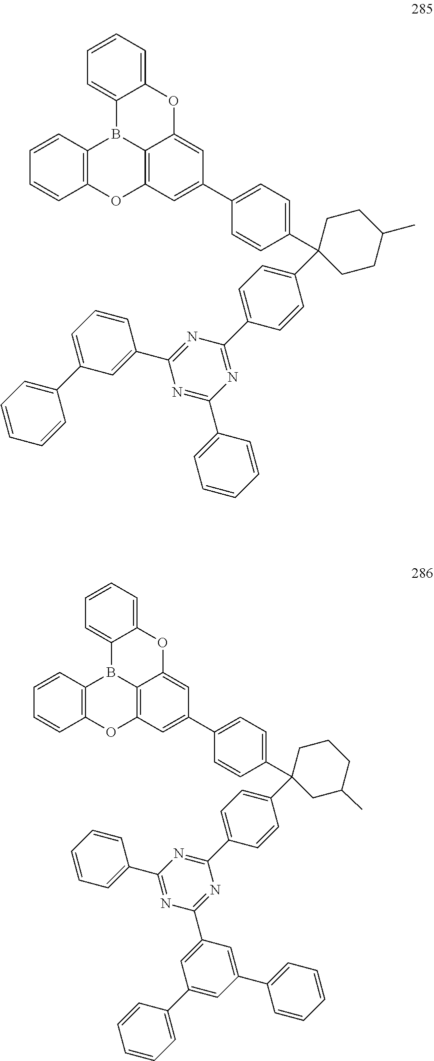 [SMILES: CC1CCC(c2ccc(-c3cc4c5c(c3)Oc3ccccc3B5c3ccccc3O4)cc2)(c2ccc(-c3nc(-c4ccccc4)nc(-c4cccc(-c5ccccc5)c4)n3)cc2)CC1 ; CC1CCCC(c2ccc(-c3cc4c5c(c3)Oc3ccccc3B5c3ccccc3O4)cc2)(c2ccc(-c3nc(-c4ccccc4)nc(-c4cc(-c5ccccc5)cc(-c5ccccc5)c4)n3)cc2)C1] 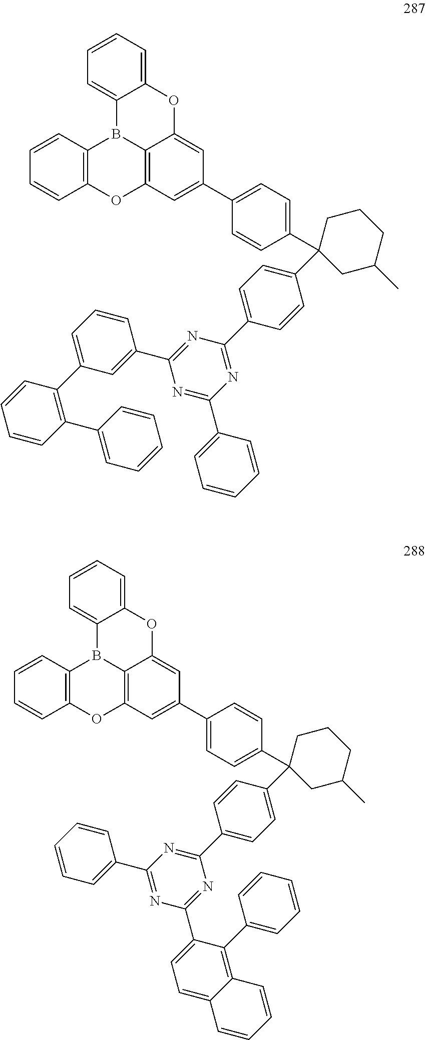 [SMILES: CC1CCCC(c2ccc(-c3cc4c5c(c3)Oc3ccccc3B5c3ccccc3O4)cc2)(c2ccc(-c3nc(-c4ccccc4)nc(-c4cccc(-c5ccccc5-c5ccccc5)c4)n3)cc2)C1 ; CC1CCCC(c2ccc(-c3cc4c5c(c3)Oc3ccccc3B5c3ccccc3O4)cc2)(c2ccc(-c3nc(-c4ccccc4)nc(-c4ccc5ccccc5c4-c4ccccc4)n3)cc2)C1] 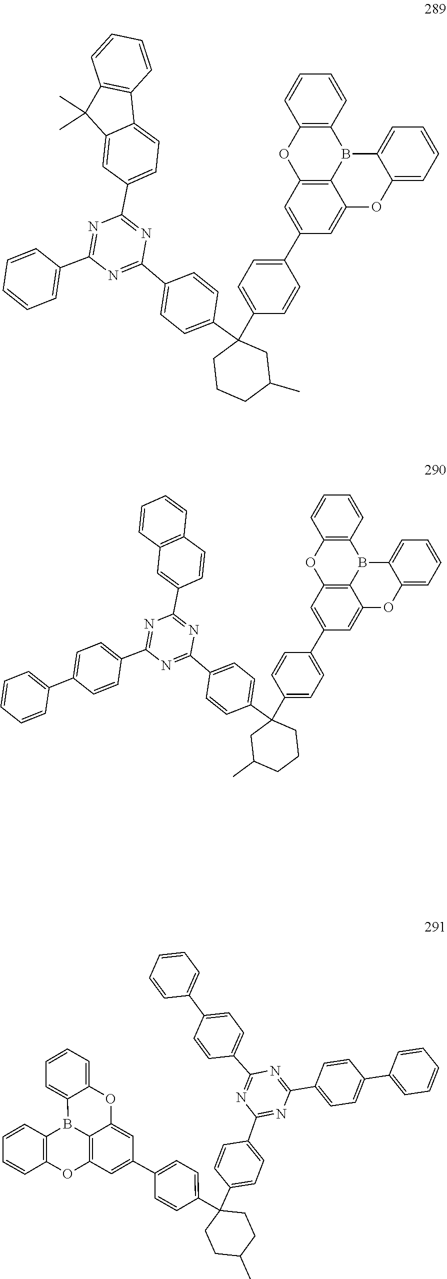 [SMILES: CC1CCCC(c2ccc(-c3cc4c5c(c3)Oc3ccccc3B5c3ccccc3O4)cc2)(c2ccc(-c3nc(-c4ccccc4)nc(-c4ccc5c(c4)C(C)(C)c4ccccc4-5)n3)cc2)C1 ; CC1CCCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5ccccc5c4)n3)cc2)C1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4ccc(-c5ccccc5)cc4)n3)cc2)CC1] 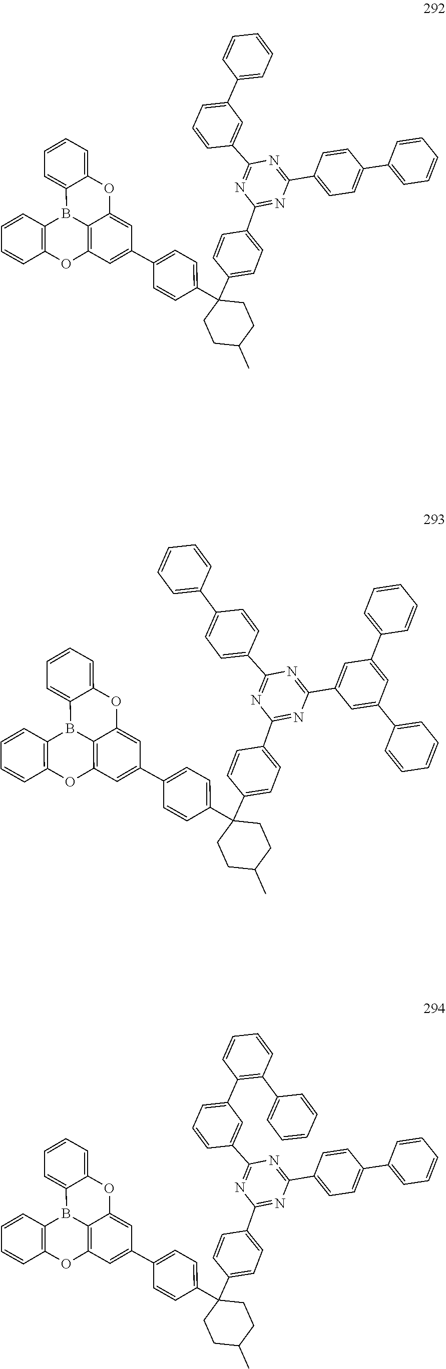 [SMILES: CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cc(-c5ccccc5)cc(-c5ccccc5)c4)n3)cc2)CC1 ; CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4cccc(-c5ccccc5-c5ccccc5)c4)n3)cc2)CC1] 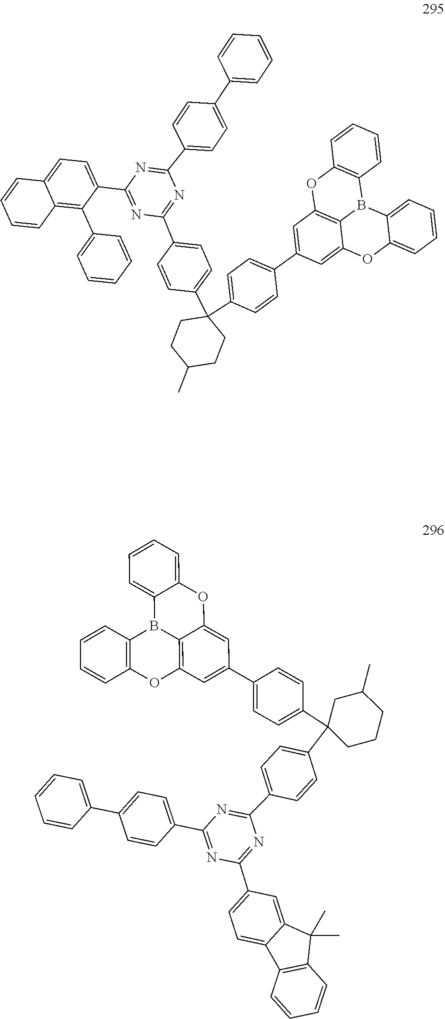 [SMILES: CC1CCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5ccccc5c4-c4ccccc4)n3)cc2)CC1 ; CC1CCCC(c2ccc(-c3cc4c5c(c3)Oc3ccccc3B5c3ccccc3O4)cc2)(c2ccc(-c3nc(-c4ccc(-c5ccccc5)cc4)nc(-c4ccc5c(c4)C(C)(C)c4ccccc4-5)n3)cc2)C1] 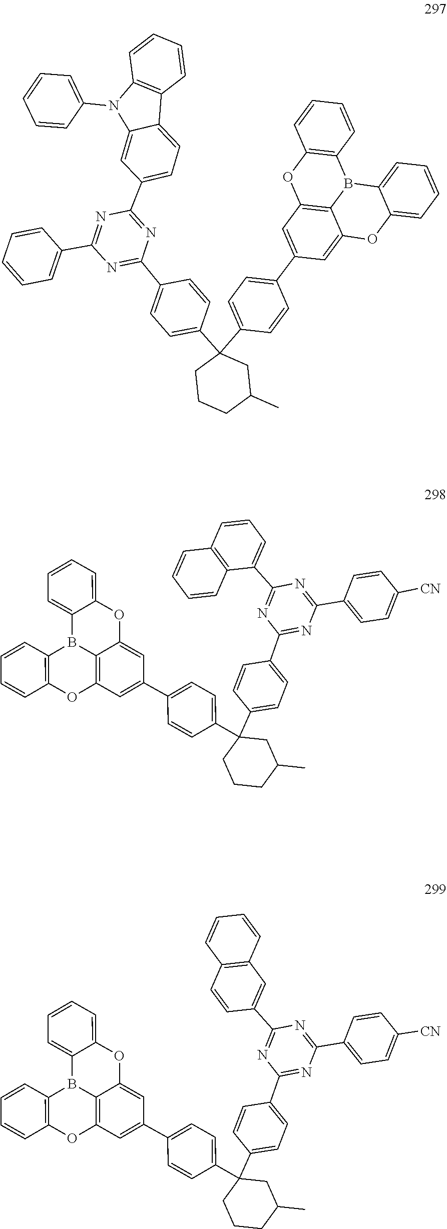 [SMILES: CC1CCCC(c2ccc(-c3cc4c5c(c3)Oc3ccccc3B5c3ccccc3O4)cc2)(c2ccc(-c3nc(-c4ccccc4)nc(-c4ccc5c6ccccc6n(-c6ccccc6)c5c4)n3)cc2)C1 ; CC1CCCC(c2ccc(-c3cc4c5c(c3)Oc3ccccc3B5c3ccccc3O4)cc2)(c2ccc(-c3nc(-c4ccc(C#N)cc4)nc(-c4cccc5ccccc45)n3)cc2)C1 ; CC1CCCC(c2ccc(-c3cc4c5c(c3)Oc3ccccc3B5c3ccccc3O4)cc2)(c2ccc(-c3nc(-c4ccc(C#N)cc4)nc(-c4ccc5ccccc5c4)n3)cc2)C1] 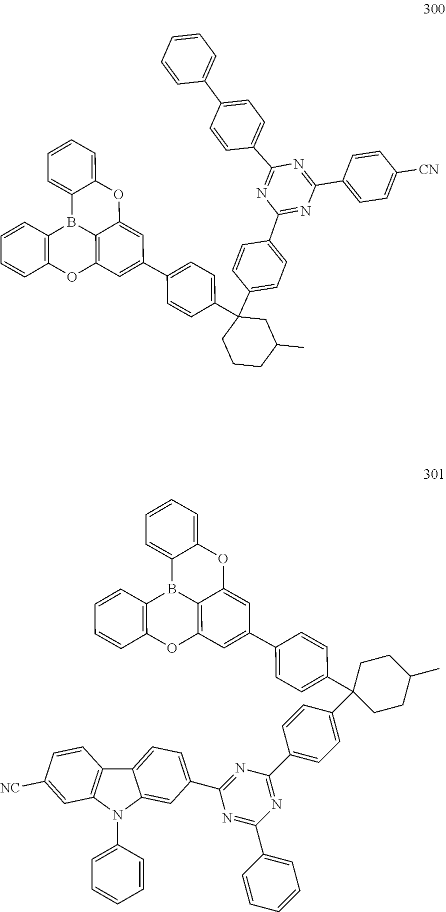 [SMILES: CC1CCCC(c2ccc(-c3cc4c5c(c3)Oc3ccccc3B5c3ccccc3O4)cc2)(c2ccc(-c3nc(-c4ccc(C#N)cc4)nc(-c4ccc(-c5ccccc5)cc4)n3)cc2)C1 ; CC1CCC(c2ccc(-c3cc4c5c(c3)Oc3ccccc3B5c3ccccc3O4)cc2)(c2ccc(-c3nc(-c4ccccc4)nc(-c4ccc5c6ccc(C#N)cc6n(-c6ccccc6)c5c4)n3)cc2)CC1] 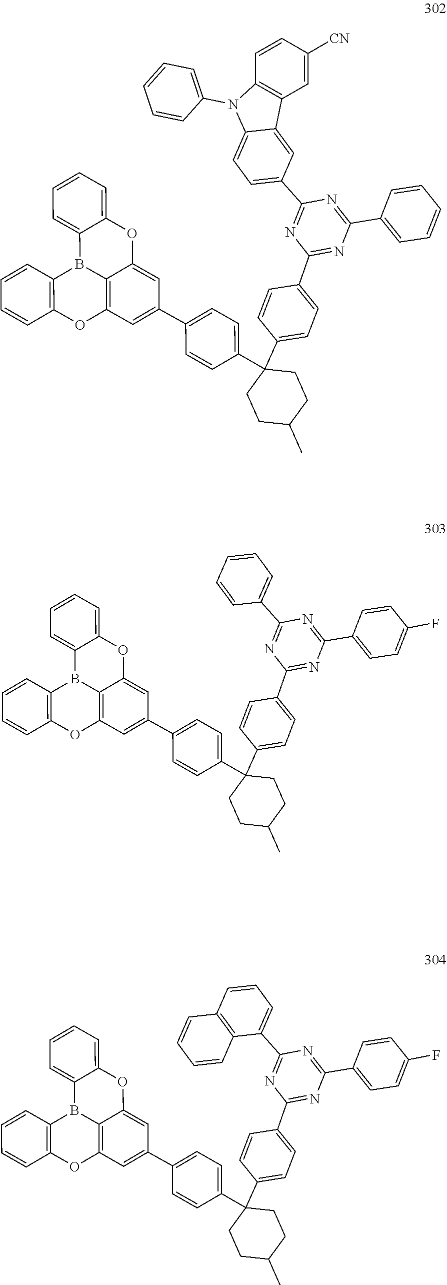 [SMILES: CC1CCC(c2ccc(-c3cc4c5c(c3)Oc3ccccc3B5c3ccccc3O4)cc2)(c2ccc(-c3nc(-c4ccccc4)nc(-c4ccc5c(c4)c4cc(C#N)ccc4n5-c4ccccc4)n3)cc2)CC1 ; CC1CCC(c2ccc(-c3cc4c5c(c3)Oc3ccccc3B5c3ccccc3O4)cc2)(c2ccc(-c3nc(-c4ccccc4)nc(-c4ccc(F)cc4)n3)cc2)CC1 ; CC1CCC(c2ccc(-c3cc4c5c(c3)Oc3ccccc3B5c3ccccc3O4)cc2)(c2ccc(-c3nc(-c4ccc(F)cc4)nc(-c4cccc5ccccc45)n3)cc2)CC1] 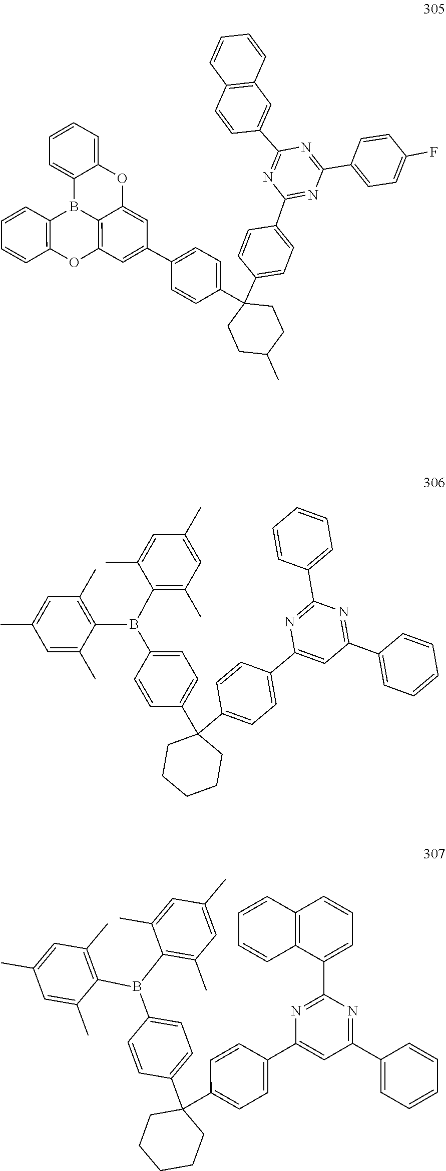 [SMILES: CC1CCC(c2ccc(-c3cc4c5c(c3)Oc3ccccc3B5c3ccccc3O4)cc2)(c2ccc(-c3nc(-c4ccc(F)cc4)nc(-c4ccc5ccccc5c4)n3)cc2)CC1 ; Cc1cc(C)c(B(c2ccc(C3(c4ccc(-c5cc(-c6ccccc6)nc(-c6ccccc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6cccc7ccccc67)n5)cc4)CCCCC3)cc2)c2c(C)cc(C)cc2C)c(C)c1] 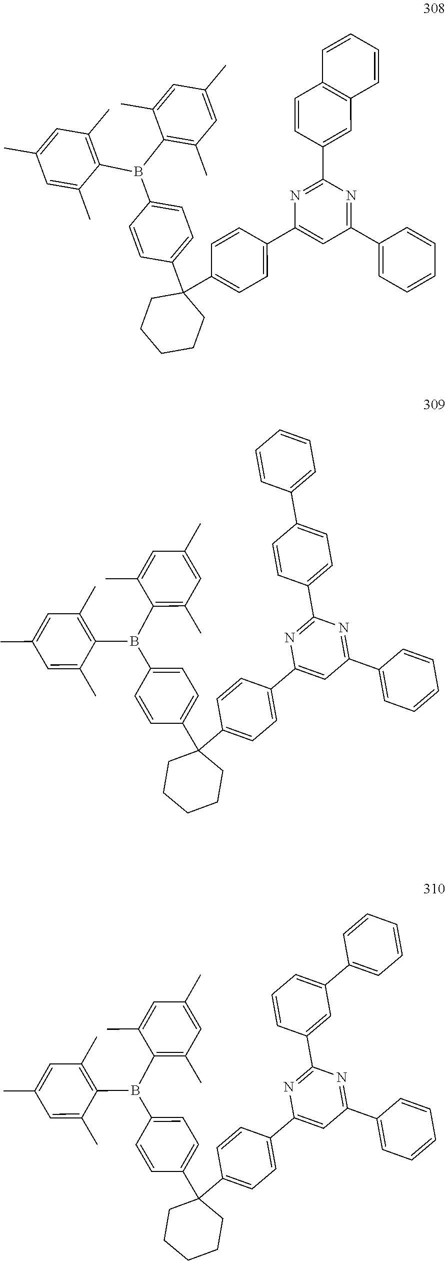 [SMILES: Cc1cc(C)c(B(c2ccc(C3(c4ccc(-c5cc(-c6ccccc6)nc(-c6ccc7ccccc7c6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6cccc(-c7ccccc7)c6)n5)cc4)CCCCC3)cc2)c2c(C)cc(C)cc2C)c(C)c1] 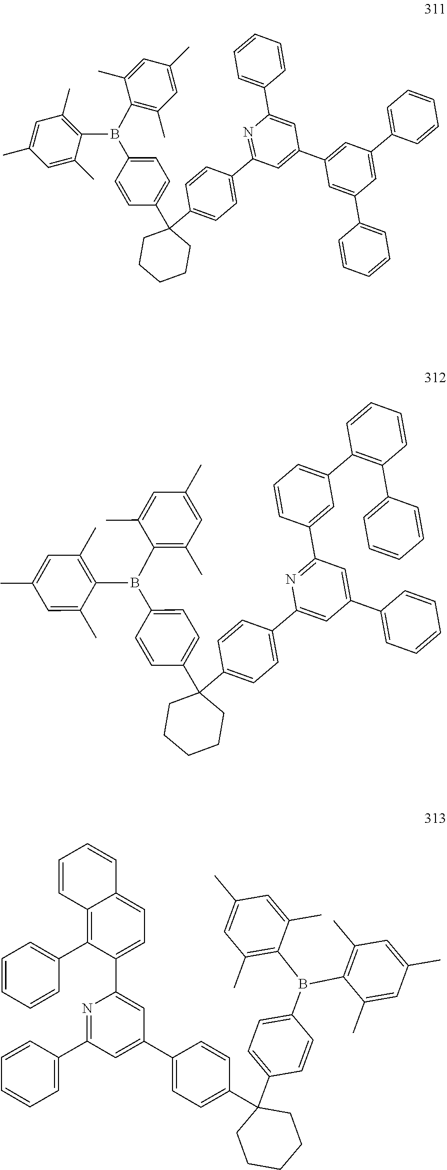 [SMILES: Cc1cc(C)c(B(c2ccc(C3(c4ccc(-c5cc(-c6cc(-c7ccccc7)cc(-c7ccccc7)c6)cc(-c6ccccc6)n5)cc4)CCCCC3)cc2)c2c(C)cc(C)cc2C)c(C)c1 ; Cc1cc(C)c(B(c2ccc(C3(c4ccc(-c5cc(-c6ccccc6)cc(-c6cccc(-c7ccccc7-c7ccccc7)c6)n5)cc4)CCCCC3)cc2)c2c(C)cc(C)cc2C)c(C)c1 ; Cc1cc(C)c(B(c2ccc(C3(c4ccc(-c5cc(-c6ccccc6)nc(-c6ccc7ccccc7c6-c6ccccc6)c5)cc4)CCCCC3)cc2)c2c(C)cc(C)cc2C)c(C)c1] 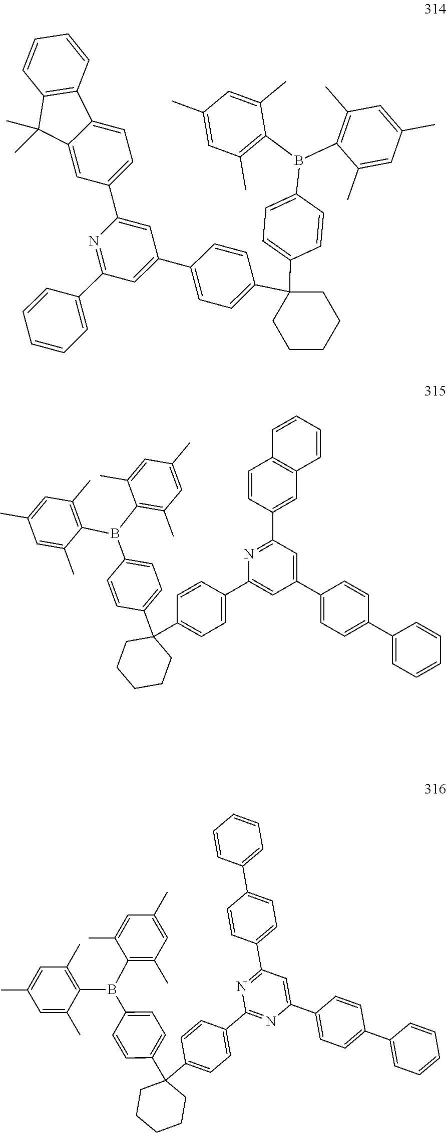 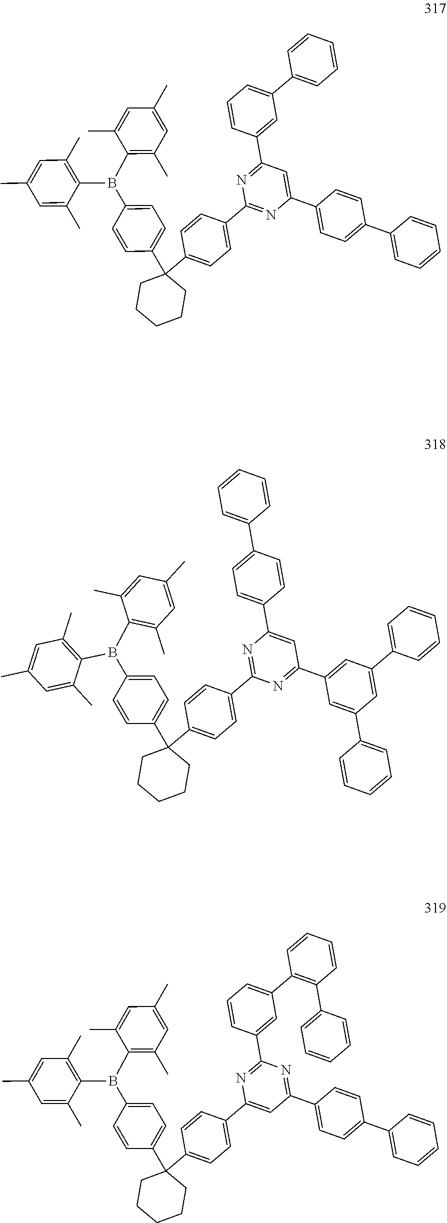 [SMILES: Cc1cc(C)c(B(c2ccc(C3(c4ccc(-c5nc(-c6ccc(-c7ccccc7)cc6)cc(-c6cccc(-c7ccccc7)c6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)cc(-c6cc(-c7ccccc7)cc(-c7ccccc7)c6)n5)cc4)CCCCC3)cc2)c2c(C)cc(C)cc2C)c(C)c1 ; Cc1cc(C)c(B(c2ccc(C3(c4ccc(-c5cc(-c6ccc(-c7ccccc7)cc6)nc(-c6cccc(-c7ccccc7-c7ccccc7)c6)n5)cc4)CCCCC3)cc2)c2c(C)cc(C)cc2C)c(C)c1] 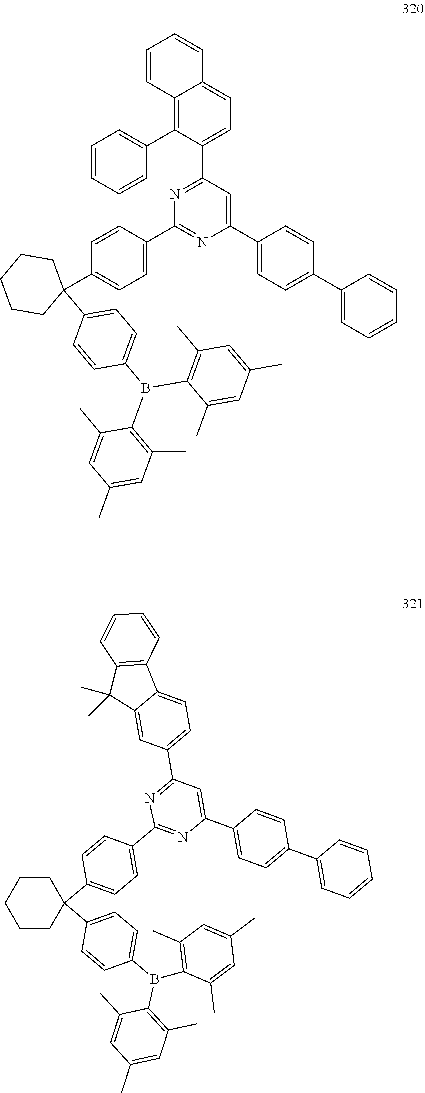 [SMILES: Cc1cc(C)c(B(c2ccc(C3(c4ccc(-c5nc(-c6ccc(-c7ccccc7)cc6)cc(-c6ccc7ccccc7c6-c6ccccc6)n5)cc4)CCCCC3)cc2)c2c(C)cc(C)cc2C)c(C)c1 ; Cc1cc(C)c(B(c2ccc(C3(c4ccc(-c5nc(-c6ccc(-c7ccccc7)cc6)cc(-c6ccc7c(c6)C(C)(C)c6ccccc6-7)n5)cc4)CCCCC3)cc2)c2c(C)cc(C)cc2C)c(C)c1] 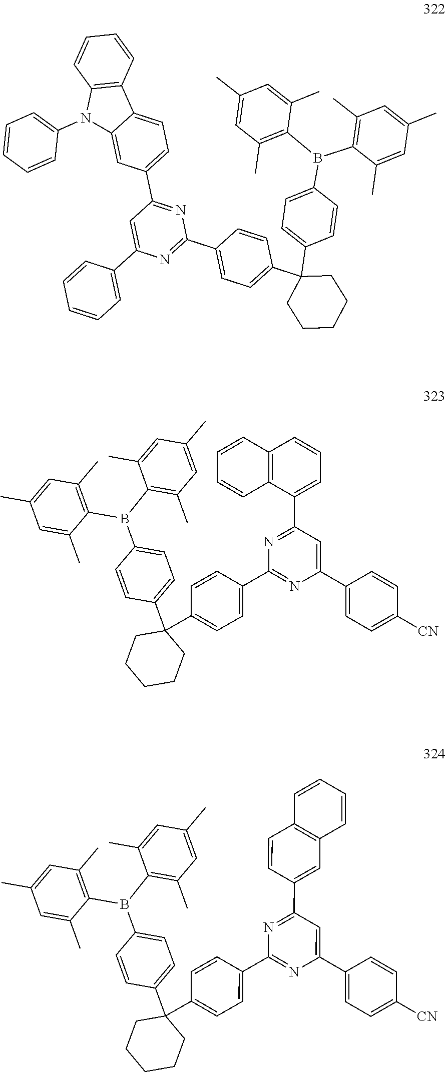 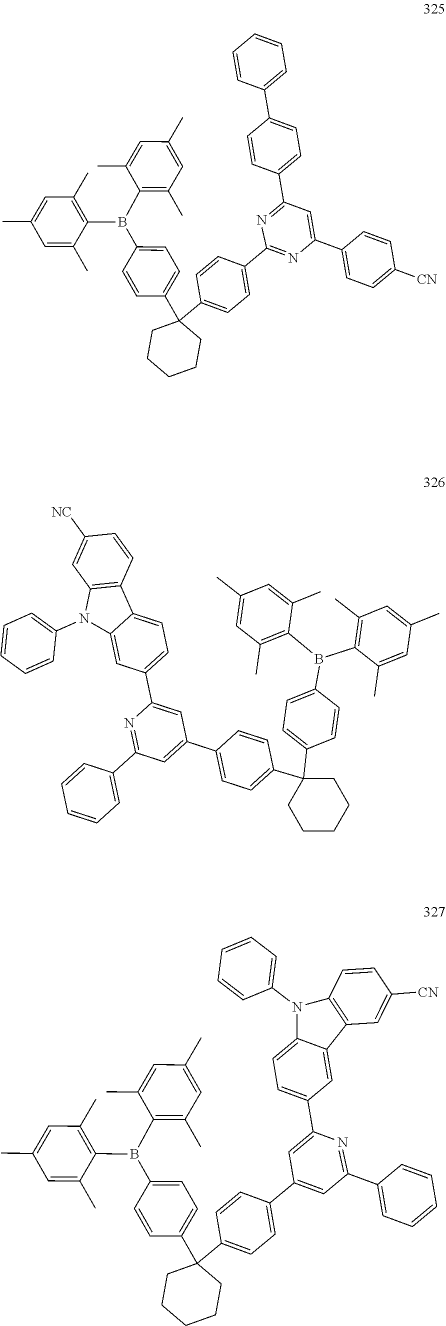 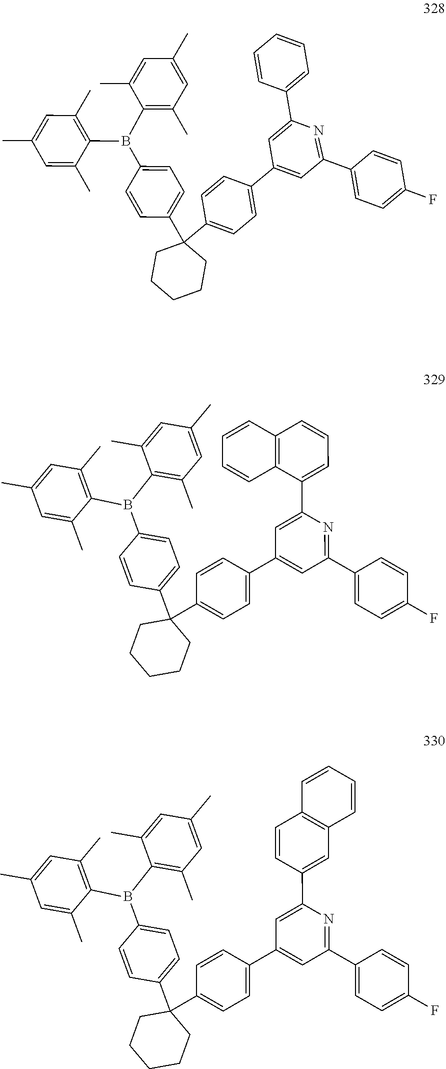 [SMILES: Cc1cc(C)c(B(c2ccc(C3(c4ccc(-c5cc(-c6ccccc6)nc(-c6ccc(F)cc6)c5)cc4)CCCCC3)cc2)c2c(C)cc(C)cc2C)c(C)c1 ; Cc1cc(C)c(B(c2ccc(C3(c4ccc(-c5cc(-c6ccc(F)cc6)nc(-c6cccc7ccccc67)c5)cc4)CCCCC3)cc2)c2c(C)cc(C)cc2C)c(C)c1 ; Cc1cc(C)c(B(c2ccc(C3(c4ccc(-c5cc(-c6ccc(F)cc6)nc(-c6ccc7ccccc7c6)c5)cc4)CCCCC3)cc2)c2c(C)cc(C)cc2C)c(C)c1] 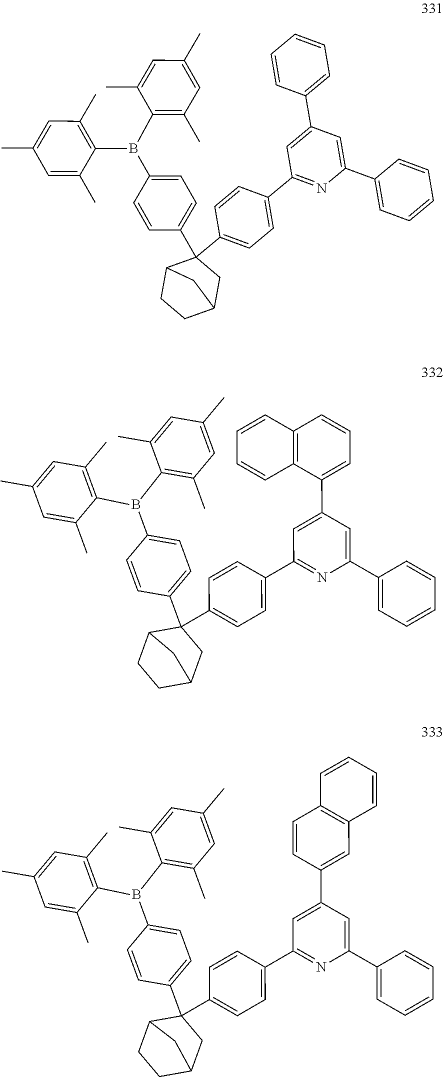 [SMILES: Cc1cc(C)c(B(c2ccc(C3(c4ccc(-c5cc(-c6ccccc6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cccc7ccccc67)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6ccc7ccccc7c6)cc(-c6ccccc6)n5)cc4)CC4CCC3C4)cc2)c2c(C)cc(C)cc2C)c(C)c1] 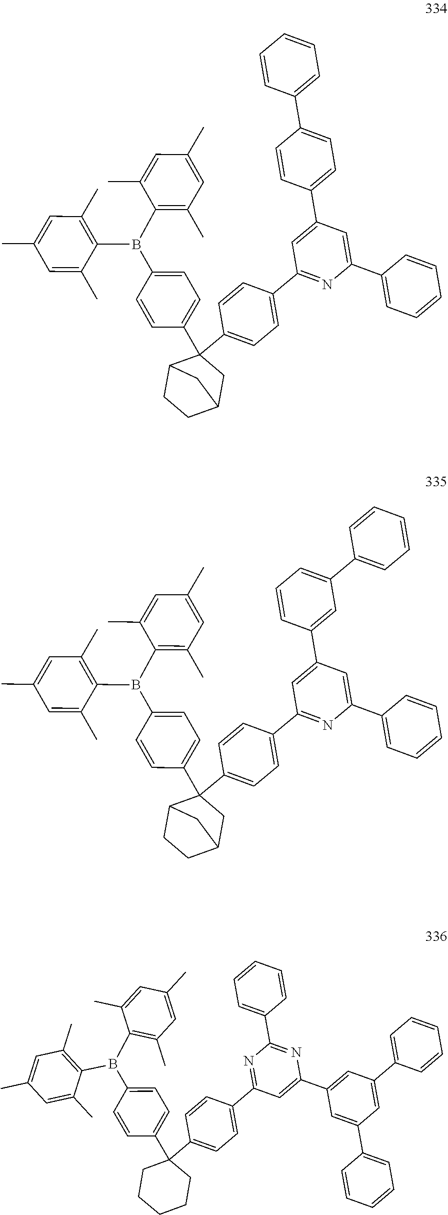 [SMILES: Cc1cc(C)c(B(c2ccc(C3(c4ccc(-c5cc(-c6ccc(-c7ccccc7)cc6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cccc(-c7ccccc7)c6)cc(-c6ccccc6)n5)cc4)CC4CCC3C4)cc2)c2c(C)cc(C)cc2C)c(C)c1 ; Cc1cc(C)c(B(c2ccc(C3(c4ccc(-c5cc(-c6cc(-c7ccccc7)cc(-c7ccccc7)c6)nc(-c6ccccc6)n5)cc4)CCCCC3)cc2)c2c(C)cc(C)cc2C)c(C)c1] 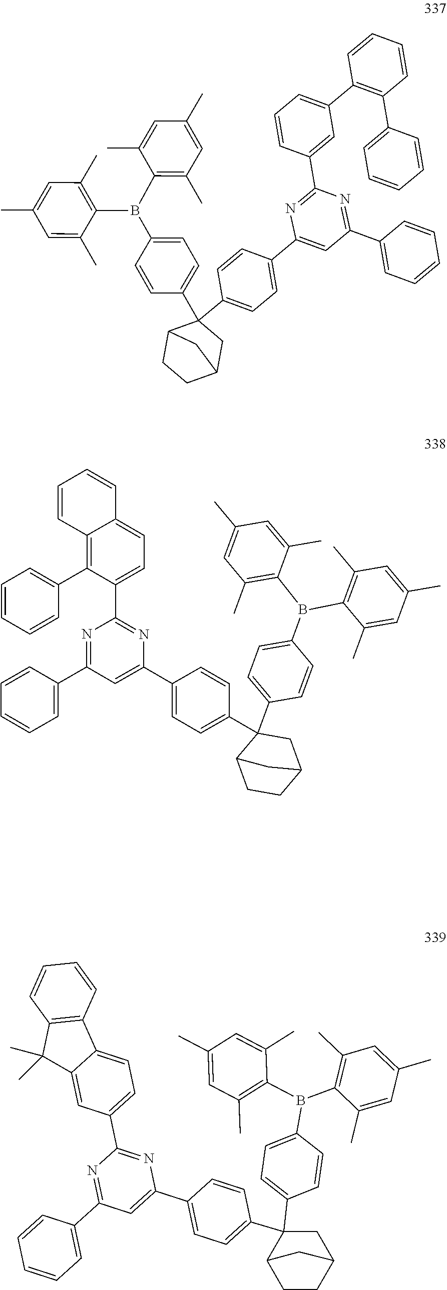 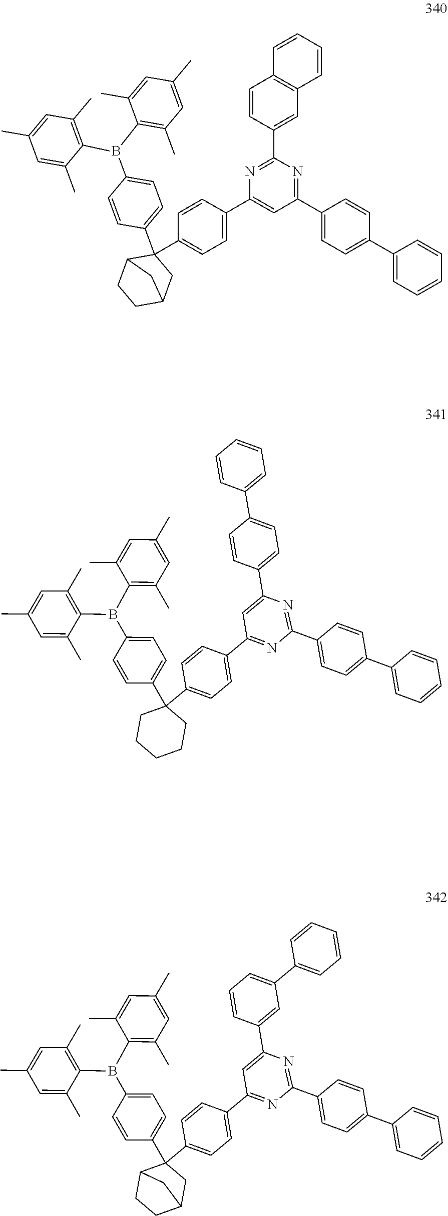 [SMILES: Cc1cc(C)c(B(c2ccc(C3(c4ccc(-c5cc(-c6ccc(-c7ccccc7)cc6)nc(-c6ccc7ccccc7c6)n5)cc4)CC4CCC3C4)cc2)c2c(C)cc(C)cc2C)c(C)c1 ; Cc1cc(C)c(B(c2ccc(C3(c4ccc(-c5cc(-c6ccc(-c7ccccc7)cc6)nc(-c6ccc(-c7ccccc7)cc6)n5)cc4)CCCCC3)cc2)c2c(C)cc(C)cc2C)c(C)c1 ; Cc1cc(C)c(B(c2ccc(C3(c4ccc(-c5cc(-c6cccc(-c7ccccc7)c6)nc(-c6ccc(-c7ccccc7)cc6)n5)cc4)CC4CCC3C4)cc2)c2c(C)cc(C)cc2C)c(C)c1] 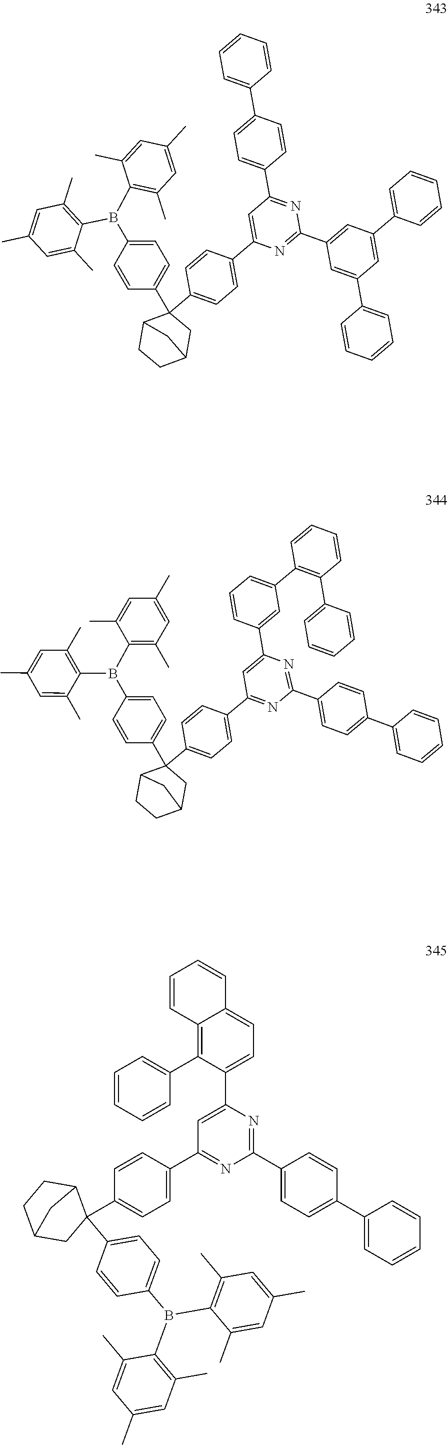 [SMILES: Cc1cc(C)c(B(c2ccc(C3(c4ccc(-c5cc(-c6ccc(-c7ccccc7)cc6)nc(-c6cc(-c7ccccc7)cc(-c7ccccc7)c6)n5)cc4)CC4CCC3C4)cc2)c2c(C)cc(C)cc2C)c(C)c1 ; Cc1cc(C)c(B(c2ccc(C3(c4ccc(-c5cc(-c6cccc(-c7ccccc7-c7ccccc7)c6)nc(-c6ccc(-c7ccccc7)cc6)n5)cc4)CC4CCC3C4)cc2)c2c(C)cc(C)cc2C)c(C)c1 ; Cc1cc(C)c(B(c2ccc(C3(c4ccc(-c5cc(-c6ccc7ccccc7c6-c6ccccc6)nc(-c6ccc(-c7ccccc7)cc6)n5)cc4)CC4CCC3C4)cc2)c2c(C)cc(C)cc2C)c(C)c1] 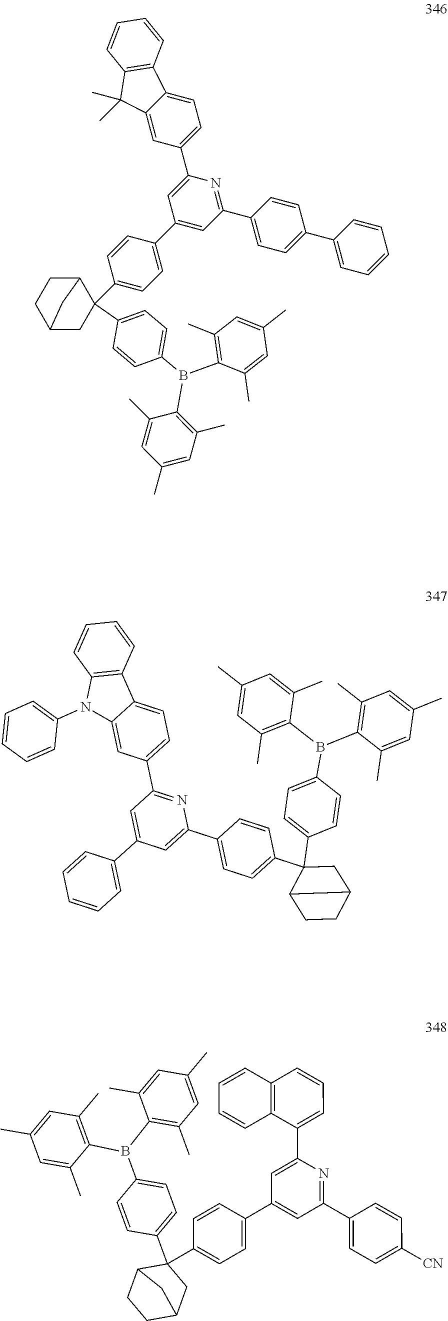 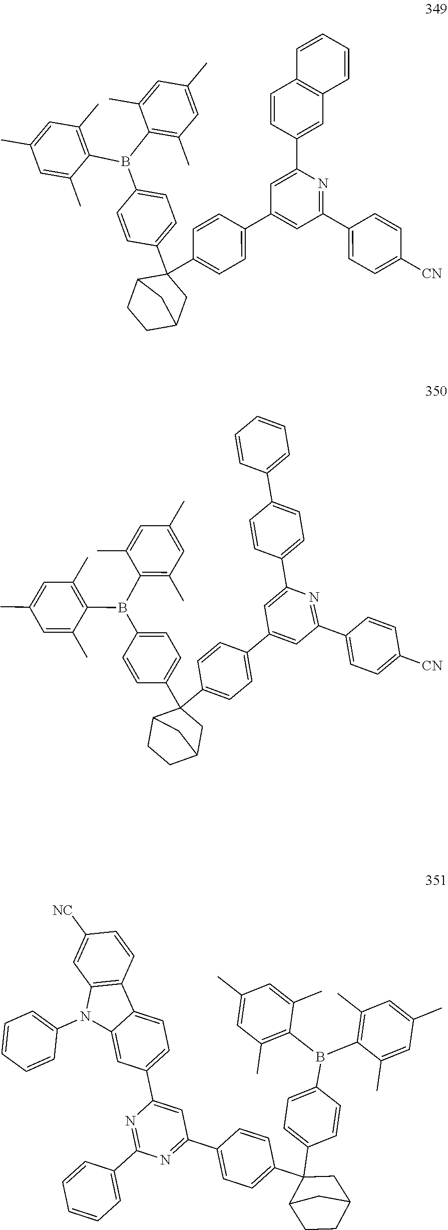 [SMILES: Cc1cc(C)c(B(c2ccc(C3(c4ccc(-c5cc(-c6ccc(C#N)cc6)nc(-c6ccc7ccccc7c6)c5)cc4)CC4CCC3C4)cc2)c2c(C)cc(C)cc2C)c(C)c1 ; Cc1cc(C)c(B(c2ccc(C3(c4ccc(-c5cc(-c6ccc(C#N)cc6)nc(-c6ccc(-c7ccccc7)cc6)c5)cc4)CC4CCC3C4)cc2)c2c(C)cc(C)cc2C)c(C)c1 ; Cc1cc(C)c(B(c2ccc(C3(c4ccc(-c5cc(-c6ccc7c8ccc(C#N)cc8n(-c8ccccc8)c7c6)nc(-c6ccccc6)n5)cc4)CC4CCC3C4)cc2)c2c(C)cc(C)cc2C)c(C)c1] 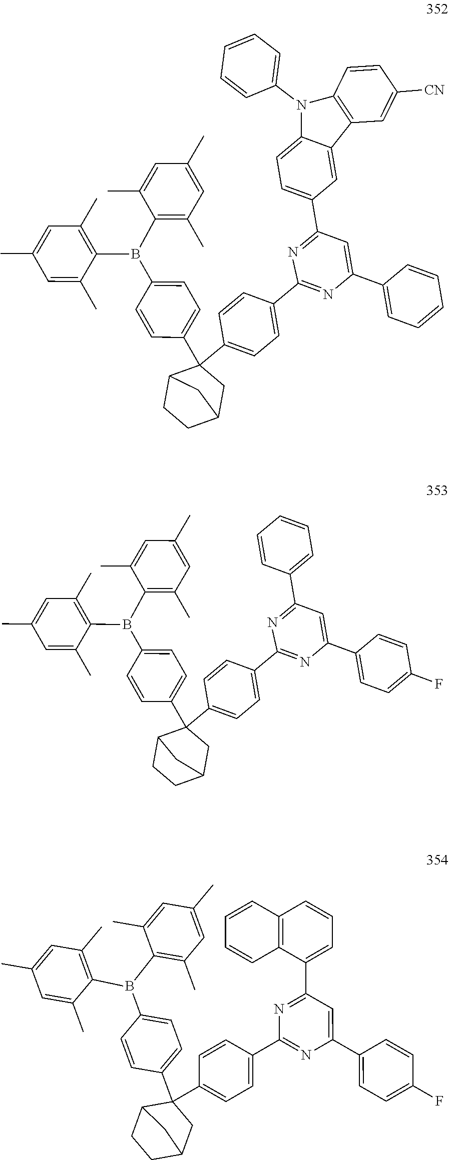 [SMILES: Cc1cc(C)c(B(c2ccc(C3(c4ccc(-c5nc(-c6ccccc6)cc(-c6ccc7c(c6)c6cc(C#N)ccc6n7-c6ccccc6)n5)cc4)CC4CCC3C4)cc2)c2c(C)cc(C)cc2C)c(C)c1 ; Cc1cc(C)c(B(c2ccc(C3(c4ccc(-c5nc(-c6ccccc6)cc(-c6ccc(F)cc6)n5)cc4)CC4CCC3C4)cc2)c2c(C)cc(C)cc2C)c(C)c1 ; Cc1cc(C)c(B(c2ccc(C3(c4ccc(-c5nc(-c6ccc(F)cc6)cc(-c6cccc7ccccc67)n5)cc4)CC4CCC3C4)cc2)c2c(C)cc(C)cc2C)c(C)c1] 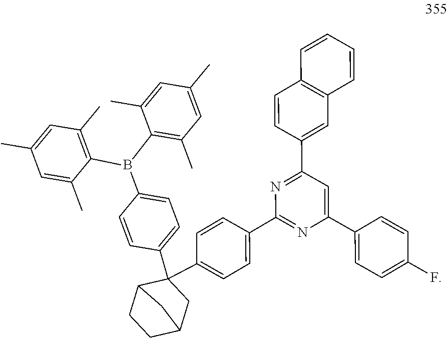 [SMILES: Cc1cc(C)c(B(c2ccc(C3(c4ccc(-c5nc(-c6ccc(F)cc6)cc(-c6ccc7ccccc7c6)n5)cc4)CC4CCC3C4)cc2)c2c(C)cc(C)cc2C)c(C)c1]
